(19) United States
(12) Patent Application Publication
(10) Pub. No.: US 2026/0068416 A1
(43) Pub. Date: Mar. 5, 2026

(54) ORGANIC ELECTROLUMINESCENT MATERIAL AND DEVICE

(71) Applicant: BEIJING SUMMER SPROUT TECHNOLOGY CO., LTD., Beijing (CN)

(72) Inventors: Wei CAI, Beijing (CN); Hongbo LI, Beijing (CN); Zheng WANG, Beijing (CN); Zhen WANG, Beijing (CN); Chi Yuen Raymond Kwong, Beijing (CN); Chuanjun Xia, Beijing (CN)

(21) Appl. No.: 19/314,280

(22) Filed: Aug. 29, 2025

(30) Foreign Application Priority Data
Aug. 29, 2024 (CN) 202411202902.3

(51) Int. Cl. H10K 50/11; C07F 15/00; C09K 11/06; H10K 85/30; H10K 85/60; H10K 101/00

(52) U.S. Cl. CPC H10K 50/11; C07F 15/0033; C09K 11/06; H10K 85/342; H10K 85/622; H10K 85/631; H10K 85/654; H10K 85/656; H10K 85/6572; H10K 85/6574; H10K 85/6576; C09K 2211/185; H10K 2101/90

(57) ABSTRACT

The present disclosure relates to compounds for organic electronic devices such as organic light-emitting devices. In particular, the present disclosure relates to a metal complex comprising a ligand Lₐ having a structure of Formula 1A and a ligand L_{b} having a structure of Formula 1B. These novel metal complexes can provide better device performance, can obtain more saturated green light emission, a narrower FWHM, and higher EQE, and can prepare devices with better performance. Further disclosed are an electroluminescent device comprising the metal complex, a compound combination comprising the metal complex, and a display assembly comprising the metal complex, wherein the electroluminescent device, compound combination, or display assembly has a relatively good application prospect.

### CROSS-REFERENCE TO RELATED APPLICATION(S)

This application claims priority to Chinese Patent Application No. 2024112029023 filed on Aug. 29, 2024, the disclosure of which is incorporated herein by reference in its entirety.

### TECHNICAL FIELD

The present disclosure relates to compounds for organic electronic devices such as organic light-emitting devices. In particular, the present disclosure relates to a metal complex comprising a ligand Lₐ having a structure of Formula 1A and a ligand L_{b} having a structure of Formula 1B, an electroluminescent device comprising the metal complex, a compound combination comprising the metal complex, and a display assembly comprising the metal complex.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may include multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may include one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

WO2019221484A1 has disclosed a metal complex having the following structure:

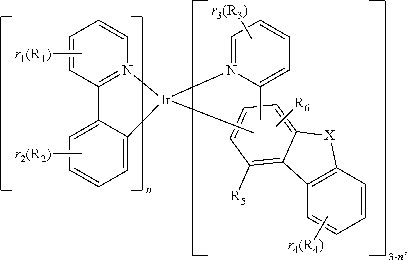

wherein R₅ is selected from groups such as halogen, a nitrile group, a nitro group, . . . and substituted or unsubstituted alkyl having 3 to 30 carbon atoms. WO2019221484A1 has further disclosed the following specific structures:

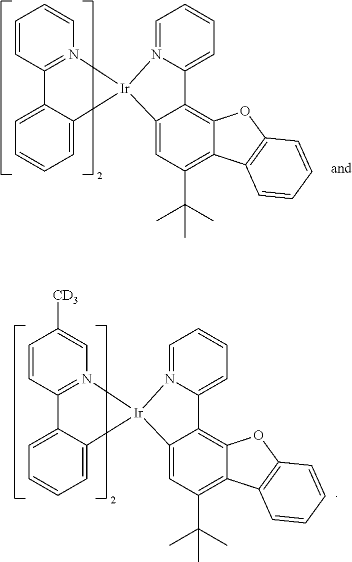

This application has disclosed and taught neither a metal complex that has a particular structure with “Rₙ₁”, “Rₙ₂”, and “Rₙ₃” and that at least one of X₁ to X₅ has at least one electron withdrawing group nor an effect of the metal complex on device performance.

US20230143449A1 has disclosed a compound comprising the following first ligand L_{A}:

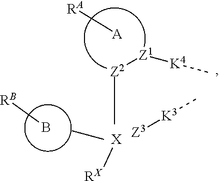

wherein the part X represents a fused polycyclic system comprising two or more five-membered or six-membered carbocyclic or heterocyclic rings; the ring A and the ring B are each independently a five-membered or six-membered carbocyclic or heterocyclic ring; and at least one of the following conditions is true: (1) the ring B is partially or fully deuterated, and (2) at least one R is an aryl or heteroaryl group that is partially or fully deuterated; among other features. As can be seen, this application focuses on the ring B and RB and has disclosed and taught neither a metal complex that has a particular structure with “Rₙ₁”, “Rₙ₂”, and “Rₙ₃” and that X₁ to X₅ has at least one electron withdrawing group nor an effect of the metal complex on device performance.

The present disclosure provides a metal complex comprising a ligand Lₐ having a structure of Formula 1A and a ligand L_{b} having a structure of Formula 1B, wherein the metal complex may be used as a charge transporting material, an emissive material, and a host material in an electroluminescent device. These novel metal complexes can provide better device performance.

### SUMMARY

The present disclosure aims to provide a metal complex (compound) comprising a ligand Lₐ having a structure of Formula 1A and a ligand L_{b} having a structure of Formula 1B to solve at least part of the preceding problems. The metal complex may be used as an emissive material (also referred to as an emissive dopant) in an organic electroluminescent device. These novel metal complexes can provide better device performance.

According to an embodiment of the present disclosure, disclosed is a metal complex having a general formula of M(Lₐ)ₘ(L_{b})₃₋ₘ, wherein m is selected from 1, 2, or 3; when m is selected from 1, two L_{b} are identical or different; when m is selected from 2 or 3, multiple Lₐ are identical or different;
the metal M is selected from a metal with a relative atomic mass greater than 40;
Lₐ has, at each occurrence identically or differently, a structure represented by Formula 1A, and L_{b} has, at each occurrence identically or differently, a structure represented by Formula 1B:

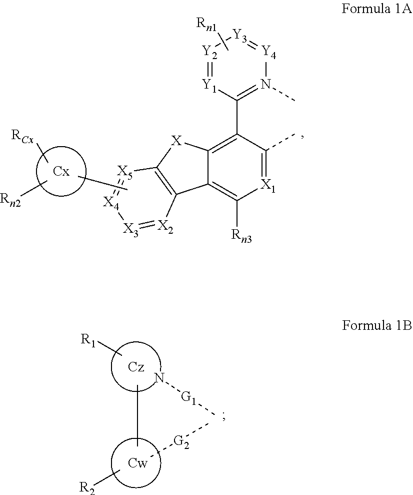

wherein X is, at each occurrence identically or differently, selected from O, S, or Se;
G₁ and G₂ are, at each occurrence identically or differently, selected from a single bond, O, or S;
the ring C_{X} is, at each occurrence identically or differently, selected from aryl having 6 to 24 ring atoms;
the ring Cz is, at each occurrence identically or differently, selected from heteroaryl having 5 to 24 ring atoms;
the ring Cw is, at each occurrence identically or differently, selected from aryl having 6 to 24 ring atoms, heteroaryl having 5 to 24 ring atoms, or a combination thereof;
X₁ is, at each occurrence identically or differently, selected from CRₓ or N; X₂ to X₅ are, at each occurrence identically or differently, selected from C, CRₓ, or N, and at least one of X₂ to X₅ is selected from C and joined to the ring C_{X}; Y₁ to Y₄ are, at each occurrence identically or differently, selected from C, CR_{y}, or N, and at least one of Y₁ to Y₄ is selected from C and joined to Rₙ₁;
R_{Cx} represents, at each occurrence identically or differently, mono-substitution, multiple substitutions, or non-substitution;
R₁ and R₂ represent, at each occurrence identically or differently, mono-substitution, multiple substitutions, or non-substitution;
Rₙ₁ and Rₙ₂ represent, at each occurrence identically or differently, mono-substitution or multiple substitutions;
R₁, R₂, R_{Cx}, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Rₙ₁ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, and combinations thereof;
Rₙ₂ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 10 to 30 carbon atoms, substituted or unsubstituted heteroaryl having 3 to 30 carbon atoms, substituted or unsubstituted alkylsilyl having 3 to 20 carbon atoms, and combinations thereof;
at least one of X₁ to X₅ is CRₓ, and the Rₓ is a group having at least one electron withdrawing group;
Rₙ₃ has a structure represented by Formula 2:

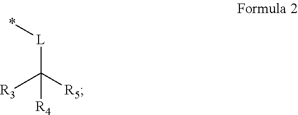

in Formula 2,
L is selected from the group consisting of: a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, and combinations thereof;
R₃, R₄, and R₅ are, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₓ, R_{Cx}, R_{y} can be optionally joined to form a ring;
adjacent substituents R₁, R₂ can be optionally joined to form a ring;
adjacent substituents R₃, R₄, and R₅ can be optionally joined to form a ring; and
“*” represents a position where Formula 2 is joined in Formula 1A.

According to another embodiment of the present disclosure, further disclosed is an application of the metal complex in an electroluminescent device.

According to another embodiment of the present disclosure, further disclosed is an electroluminescent device comprising an anode, a cathode, and an organic layer disposed between the anode and the cathode, wherein the organic layer comprises the metal complex comprising the ligand Lₐ having the structure of Formula 1A and the ligand L_{b} having the structure of Formula 1B in the preceding embodiment.

According to another embodiment of the present disclosure, further disclosed is a compound combination comprising the metal complex comprising the ligand Lₐ having the structure of Formula 1A and the ligand L_{b} having the structure of Formula 1B in the preceding embodiment.

According to another embodiment of the present disclosure, further disclosed is a display assembly comprising the metal complex comprising the ligand Lₐ having the structure of Formula 1A and the ligand L_{b} having the structure of Formula 1B in the preceding embodiment or the electroluminescent device in the preceding embodiment.

The novel metal complex disclosed in the present disclosure may be used as the emissive material in the electroluminescent device. These novel metal complexes can provide better device performance and, in particular, have significant effects and advantages in CE, EQE, and other aspects, have relatively narrow full widths at half maximum, can effectively achieve more saturated luminescence, and achieve a means of effectively adjusting emitted colors, better improving the overall performance of the electroluminescent device.

### BRIEF DESCRIPTION OF DRAWINGS

FIG. 1 is a schematic diagram of an organic light-emitting device that may comprise a compound and a compound combination disclosed herein.

FIG. 2 is a schematic diagram of another organic light-emitting device that may comprise a compound and a compound combination disclosed herein.

### DETAILED DESCRIPTION

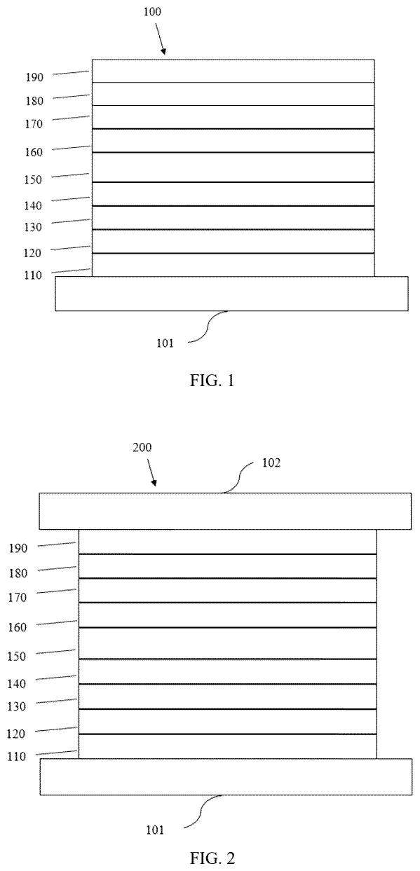

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 1 differs from FIG. 2 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small AES-T. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocyclic ring—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl having 6 to 20 carbon atoms, unsubstituted alkylgermanyl having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen can also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

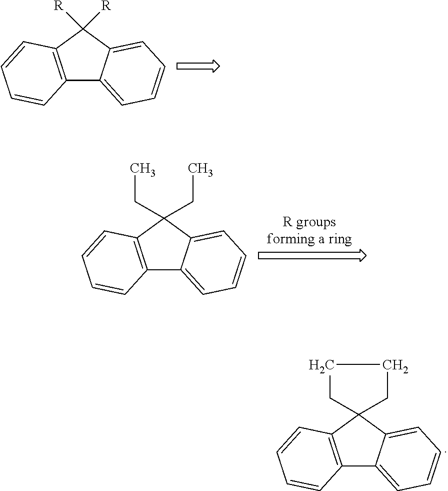

The expression that adjacent substituents can be optionally joined to form a ring is also intended to mean that two substituents bonded to carbon atoms which are directly bonded to each other are joined to each other via a chemical bond to form a ring, which can be exemplified by the following formula:

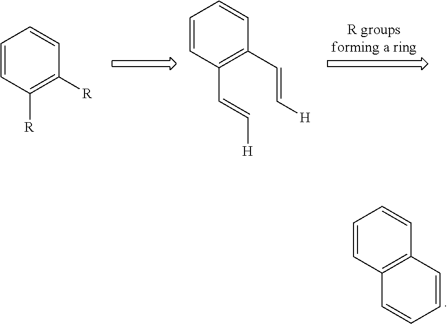

The expression that adjacent substituents can be optionally joined to form a ring is also intended to mean that two substituents bonded to a further distant carbon atom are joined to each other via a chemical bond to form a ring, which can be exemplified by the following formula:

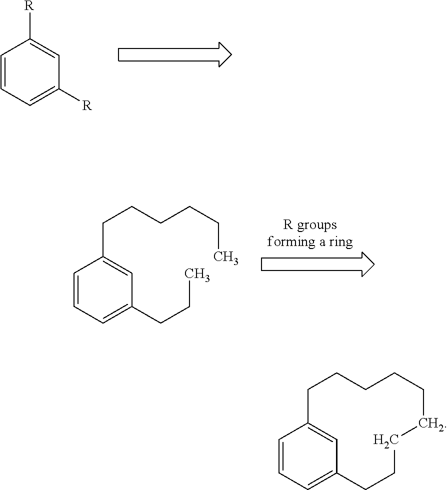

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula.

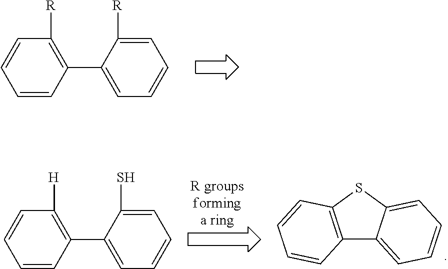

According to an embodiment of the present disclosure, disclosed is a metal complex having a general formula of M(Lₐ)ₘ(Ln)₃₋ₘ, wherein m is selected from 1, 2, or 3; when is selected from 1, two L are identical or different; when m is selected from 2 or 3, multiple Lₐ are identical or different;
the metal M is selected from a metal with a relative atomic mass greater than 40;
Lₐ has, at each occurrence identically or differently, a structure represented by Formula 1A, and L_{b} has, at each occurrence identically or differently, a structure represented by Formula 1B:

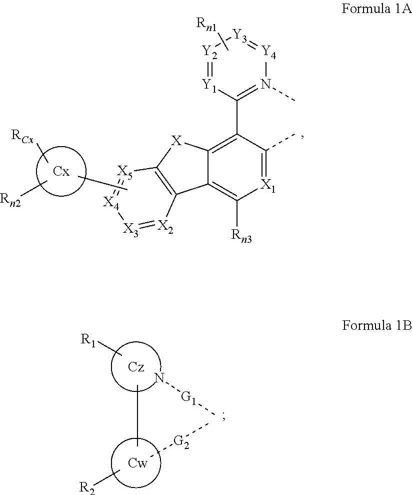

wherein X is, at each occurrence identically or differently, selected from O, S, or Se;
G₁ and G₂ are, at each occurrence identically or differently, selected from a single bond, O, or S;
the ring C_{X} is, at each occurrence identically or differently, selected from aryl having 6 to 24 ring atoms;
the ring Cz is, at each occurrence identically or differently, selected from heteroaryl having 5 to 24 ring atoms;
the ring Cw is, at each occurrence identically or differently, selected from aryl having 6 to 24 ring atoms, substituted or unsubstituted heteroaryl having 5 to 24 ring atoms, or a combination thereof;
X₁ is, at each occurrence identically or differently, selected from CRₓ or N; X₂ to X₅ are, at each occurrence identically or differently, selected from C, CRₓ, or N, and at least one of X₂ to X₅ is selected from C and joined to the ring C_{X}; Y₁ to Y₄ are, at each occurrence identically or differently, selected from C, CR_{y}, or N, and at least one of Y₁ to Y₄ is selected from C and joined to Rₙ₁;
R_{Cx} represents, at each occurrence identically or differently, mono-substitution, multiple substitutions, or non-substitution;
R₁ and R₂ represent, at each occurrence identically or differently, mono-substitution, multiple substitutions, or non-substitution;
Rₙ₁ and Rₙ₂ represent, at each occurrence identically or differently, mono-substitution or multiple substitutions;
R₁, R₂, R_{Cx}, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Rₙ₁ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, and combinations thereof;
Rₙ₂ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 10 to 30 carbon atoms, substituted or unsubstituted heteroaryl having 3 to 30 carbon atoms, substituted or unsubstituted alkylsilyl having 3 to 20 carbon atoms, and combinations thereof;
at least one of X₁ to X₅ is CRₓ, and the Rₓ is a group having at least one electron withdrawing group;
Rₙ₃ has a structure represented by Formula 2:

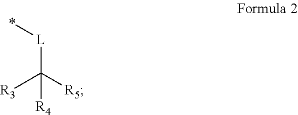

in Formula 2,
L is selected from the group consisting of: a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, and combinations thereof;
R₃, R₄, and R₅ are, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₓ, R_{Cx}, R_{y} can be optionally joined to form a ring;
adjacent substituents R₁, R₂ can be optionally joined to form a ring;
adjacent substituents R₃, R₄, and R₅ can be optionally joined to form a ring; and
“*” represents a position where Formula 2 is joined in Formula 1A.

According to an embodiment of the present disclosure, the electron withdrawing group is selected from the group consisting of: halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group, an aza-aromatic ring group, and any one of the following groups substituted with one or more of halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group, and an aza-aromatic ring group: alkyl having 1 to 20 carbon atoms, cycloalkyl having 3 to 20 ring carbon atoms, heteroalkyl having 1 to 20 carbon atoms, a heterocyclic group having 3 to 20 ring atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms, and combinations thereof.

According to an embodiment of the present disclosure, the electron withdrawing group is selected from the group consisting of: F, CF₃, CHF₂, OCF₃, SF₅, SO₂CF₃, cyano, isocyano, SCN, OCN, pyrimidinyl, triazinyl, and combinations thereof.

According to an embodiment of the present disclosure, the electron withdrawing group is selected from cyano or fluorine.

According to an embodiment of the present disclosure, at least one of X₁ to X₅ is CRₓ, and the Rₓ is cyano or fluorine.

In the present disclosure, the expression that “adjacent substituents Rₓ, R_{Cx}, R_{y} can be optionally joined to form a ring” is intended to mean that substituents Rₓ and Rₓ, substituents R_{y} and R_{y}, substituents R_{Cx} and R_{Cx}, substituents R_{Cx} and Rₓ, substituents R_{Cx} and R_{y}, and substituents Rₓ and R_{y} can be joined to form a ring. Obviously, it is also possible that none of these substituents are joined to form a ring.

In the present disclosure, the expression that “adjacent substituents R₁, R₂ can be optionally joined to form a ring” is intended to mean that substituents R₁ and R₁, substituents R₂ and R₂, and substituents R₁ and R₂ can be joined to form a ring. Obviously, it is also possible that none of these substituents are joined to form a ring.

In the present disclosure, the expression that “adjacent substituents R₃, R₄, and R₅ can be optionally joined to form a ring” is intended to mean that any one or more of groups of adjacent substituents, such as substituents R₃ and R₄, substituents R₄ and R₅, and substituents R₃ and R₅, can be joined to form a ring. Obviously, it is also possible that none of these substituents are joined to form a ring.

According to an embodiment of the present disclosure, L_{b} is, at each occurrence identically or differently, selected from any structure in the group consisting of the following:

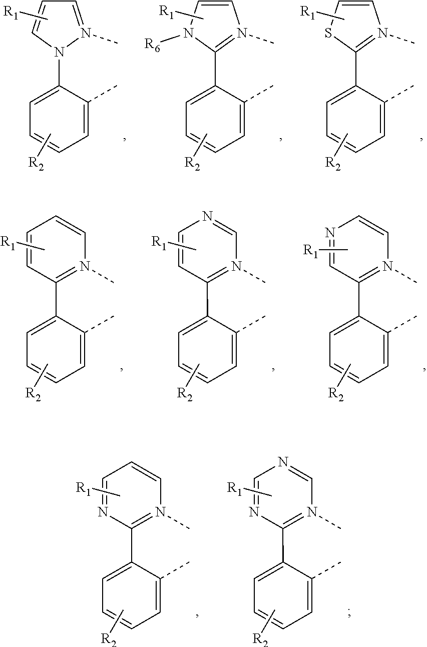

wherein R₁ and R₂ represent, at each occurrence identically or differently, mono-substitution, multiple substitutions, or non-substitution;
R₁, R₂, and R₆ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R₁, R₂, R₆ can be optionally joined to form a ring.

In the present disclosure, the expression that “adjacent substituents R₁, R₂, R₆ can be optionally joined to form a ring” is intended to mean that any one or more of groups of adjacent substituents, such as two substituents R₁, two substituents R₂, substituents R₁ and R₂, substituents R₁ and R₆, and substituents R₂ and R₆, can be joined to form a ring. Obviously, it is also possible that none of these substituents are joined to form a ring. For example, adjacent substituents R₁, R₂ in

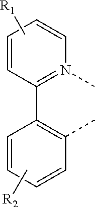

can be optionally joined to form a ring. When two substituents R₁ are optionally joined to form a ring,

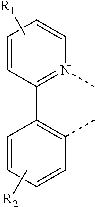

may form a structure of

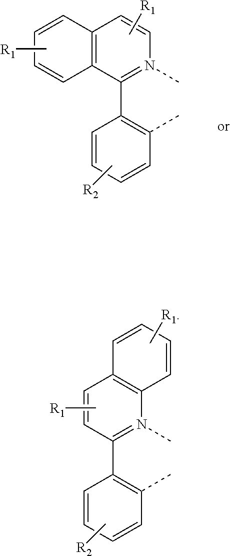

According to an embodiment of the present disclosure, G₁ and G₂ are, at each occurrence identically or differently, selected from a single bond or O; preferably, G₁ and G₂ are each a single bond.

According to an embodiment of the present disclosure, the metal M is, at each occurrence identically or differently, selected from the group consisting of Cu, Ag, Au, Ru, Rh, Pd, Os, Ir, and Pt.

According to an embodiment of the present disclosure, the metal M is, at each occurrence identically or differently, selected from Pt or Ir.

According to another embodiment of the present disclosure, the metal complex Ir(Lₐ)ₘ(L_{b})₃₋ₘ has a structure represented by Formula 2A or Formula 2B:

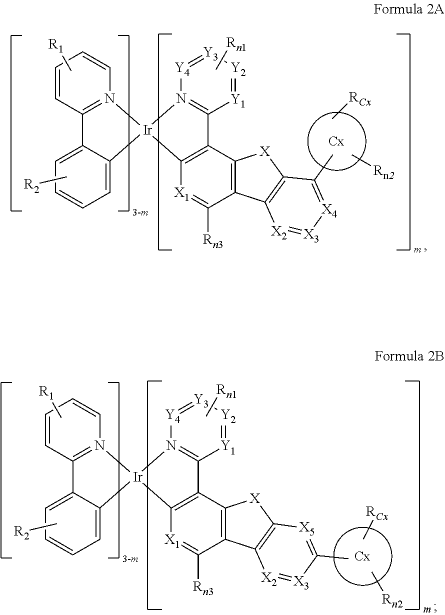

wherein m is selected from 1 or 2; preferably, m is selected from 1;
X is, at each occurrence identically or differently, selected from O, S, or Se;
the ring C_{X} is, at each occurrence identically or differently, selected from aryl having 6 to 24 ring atoms;
X₁ to X₅ are, at each occurrence identically or differently, selected from CRₓ or N;
Y₁ to Y₄ are, at each occurrence identically or differently, selected from C, CR_{y}, or N, and one of Y₁ to Y₄ is selected from C and joined to Rₙ₁;
R_{Cx} represents, at each occurrence identically or differently, mono-substitution, multiple substitutions, or non-substitution;
R₁ and R₂ represent, at each occurrence identically or differently, mono-substitution, multiple substitutions, or non-substitution;
Rₙ₁ and Rₙ₂ represent, at each occurrence identically or differently, mono-substitution or multiple substitutions;
R₁, R₂, R_{Cx}, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Rₙ₁ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, and combinations thereof;
Rₙ₂ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 10 to 30 carbon atoms, substituted or unsubstituted heteroaryl having 3 to 30 carbon atoms, substituted or unsubstituted alkylsilyl having 3 to 20 carbon atoms, and combinations thereof;
at least one of X₁ to X₅ is CRₓ, and the Rₓ is cyano or fluorine;
Rₙ₃ has a structure represented by Formula 2:

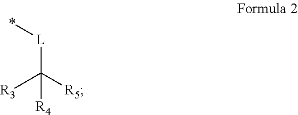

in Formula 2,
L is selected from the group consisting of: a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, and combinations thereof;
R₃, R₄, and R₅ are, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₓ, R_{Cx}, R_{y} can be optionally joined to form a ring;
adjacent substituents R₁, R₂ can be optionally joined to form a ring;
adjacent substituents R₃, R₄, and R₅ can be optionally joined to form a ring; and
“*” represents a position where Formula 2 is joined in Formula 1A.

According to an embodiment of the present disclosure, X is selected from O or S; preferably, X is selected from O.

According to an embodiment of the present disclosure, L is selected from a single bond or substituted or unsubstituted methylene.

According to an embodiment of the present disclosure, R₃, R₄, and R₅ are, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, cyano, and combinations thereof.

According to an embodiment of the present disclosure, R₃, R₄, and R₅ are, at each occurrence identically or differently, selected from the group consisting of: substituted or unsubstituted alkyl having 1 to 6 carbon atoms, substituted or unsubstituted cycloalkyl having 3 to 6 ring carbon atoms, and combinations thereof.

According to an embodiment of the present disclosure, Rₙ₁ and Rₙ₂ are, at each occurrence identically or differently, selected from the group consisting of: halogen, substituted or unsubstituted alkyl having 1 to 6 carbon atoms, substituted or unsubstituted cycloalkyl having 3 to 6 ring carbon atoms, and combinations thereof.

According to an embodiment of the present disclosure, Rₙ₁ is, at each occurrence identically or differently, selected from the group consisting of: fluorine, methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, phenyl, pyridyl, trimethylsilyl, carbazolyl, and combinations thereof.

According to an embodiment of the present disclosure, Rₙ₂ is, at each occurrence identically or differently, selected from the group consisting of: methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, trimethylsilyl, and combinations thereof.

According to an embodiment of the present disclosure, Rₙ₁ is, at each occurrence identically or differently, selected from the group consisting of: fluorine, methyl, ethyl, propyl, isopropyl, n-butyl, isobutyl, neopentyl, t-butyl, and combinations thereof.

According to an embodiment of the present disclosure, Rₙ₂ is, at each occurrence identically or differently, selected from the group consisting of: fluorine, methyl, ethyl, propyl, isopropyl, n-butyl, isobutyl, neopentyl, t-butyl, and combinations thereof.

According to an embodiment of the present disclosure, Rₙ₃ is, at each occurrence identically or differently, selected from the group consisting of the following:

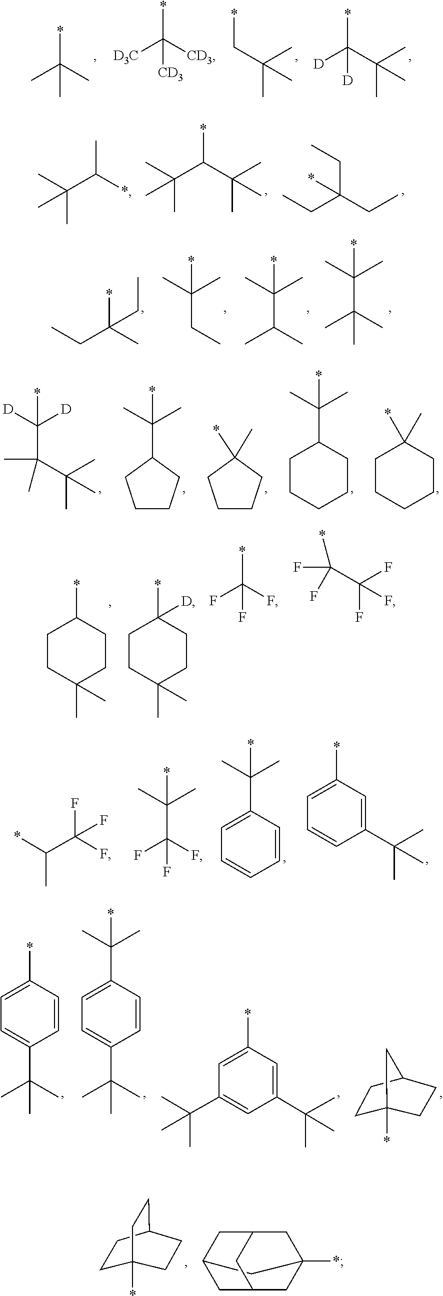

wherein optionally, hydrogens in the above Rₙ₃ can be partially or fully substituted with deuterium.

According to an embodiment of the present disclosure, at least one of X₁ to X₅ is N, and/or at least one of Y₁ to Y₄ is N.

According to an embodiment of the present disclosure, X₁ to X₅ are, at each occurrence identically or differently, selected from CRₓ, and/or Y₁ to Y₄ are, at each occurrence identically or differently, selected from C or CR_{y}, and at least one of Y₁ to Y₄ is selected from C and joined to Rₙ₁.

According to an embodiment of the present disclosure, X₁ to X₅ are, at each occurrence identically or differently, selected from CRₓ, and/or Y₃ and Y₄ are, at each occurrence identically or differently, selected from C or CR_{y}, and at least one of Y₃ and Y₄ is selected from C and joined to Rₙ₁; preferably, Y₃ is selected from C and joined to Rₙ₁; and
Rₓ, R_{Cx}, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, cyano, and combinations thereof.

According to an embodiment of the present disclosure, X₁ to X₅ are, at each occurrence identically or differently, selected from CRₓ, and/or Y₁, Y₂, and Y₄ are, at each occurrence identically or differently, selected from CR_{y}; and Rₓ and R_{y} are, at each occurrence identically or differently, selected from the group consisting of: hydrogen, deuterium, halogen, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, cyano, and combinations thereof.

According to an embodiment of the present disclosure, X₁ to X₅ are, at each occurrence identically or differently, selected from CRₓ, and/or Y₁, Y₂, and Y₄ are, at each occurrence identically or differently, selected from CR_{y}; and Rₓ and R_{y} are, at each occurrence identically or differently, selected from the group consisting of: hydrogen, deuterium, fluorine, cyano, methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, phenyl, pyridyl, trimethylsilyl, trimethylgermanyl, and combinations thereof.

According to an embodiment of the present disclosure, at least one of X₂ to X₅ is selected from CRₓ, and the Rₓ is cyano or fluorine.

According to an embodiment of the present disclosure, at least one of X₄ and X₅ is selected from CRₓ, and the Rₓ is cyano or fluorine.

According to an embodiment of the present disclosure, X₄ is selected from CRₓ, and the Rₓ is cyano or fluorine.

According to an embodiment of the present disclosure, at least one of Y₁ to Y₄ is, at each occurrence identically or differently, C, the rest of Y₁ to Y₄ is, at each occurrence identically or differently, CR_{y}, and R_{y} is selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, at least one of Y₁ to Y₄ is, at each occurrence identically or differently, C, the rest of Y₁ to Y₄ is, at each occurrence identically or differently, CR_{y}, and R_{y} is selected from the group consisting of: hydrogen, deuterium, halogen, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 6 to 12 carbon atoms, and combinations thereof.

According to an embodiment of the present disclosure, R_{Cx} is, at each occurrence identically or differently, selected from the group consisting of: hydrogen, deuterium, halogen, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, cyano, and combinations thereof.

According to an embodiment of the present disclosure, R_{Cx} is, at each occurrence identically or differently, selected from the group consisting of: hydrogen, deuterium, fluorine, cyano, methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, phenyl, pyridyl, trimethylsilyl, trimethylgermanyl, and combinations thereof.

According to an embodiment of the present disclosure, the ring Cx-Rₙ₂R_{Cx} is, at each occurrence identically or differently, selected from the group consisting of Ar₁ to Ar₆₆, wherein the structures of Ar₁ to Ar₆₆ are shown in claim 19.

According to an embodiment of the present disclosure, Lₐ is, at each occurrence identically or differently, selected from the group consisting of Lₐ₁ to Lₐ₁₉₃₁, wherein the structures of Lₐ₁ to Lₐ₁₉₃₁ are shown in claim 20.

According to an embodiment of the present disclosure, R₁ and R₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, cyano, isocyano, and combinations thereof.

According to an embodiment of the present disclosure, R₁ and R₂ are, at each occurrence identically or differently, selected from the group consisting of: hydrogen, deuterium, halogen, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, cyano, and combinations thereof.

According to an embodiment of the present disclosure, R₁ and R₂ are, at each occurrence identically or differently, selected from the group consisting of: hydrogen, deuterium, fluorine, cyano, methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, phenyl, pyridyl, trimethylsilyl, trimethylgermanyl, and combinations thereof.

According to an embodiment of the present disclosure, L_{b} is, at each occurrence identically or differently, selected from the group consisting of L_{b1} to L₁₆₀, wherein the structures of L_{b1} to L₁₆₀ are shown in claim 22.

According to another embodiment of the present disclosure, the metal complex has a structure of Ir(Lₐ)(L_{b})₂, wherein the two L_{b} are identical, Lₐ is selected from the group consisting of Lₐ₁ to Lₐ₁₉₃₁, and L_{b} is selected from the group consisting of L_{b1} to L_{b160}.

According to another embodiment of the present disclosure, the metal complex is selected from the group consisting of Metal Complex 1 to Metal Complex 4074, which are described in claim 23.

According to another embodiment of the present disclosure, optionally, hydrogens in Metal Complex 1 to Metal Complex 4074 can be partially or fully deuterated.

According to another embodiment of the present disclosure, further disclosed is an application of the metal complex in an electroluminescent device.

According to another embodiment of the present disclosure, further disclosed is an electroluminescent device comprising an anode, a cathode, and an organic layer disposed between the anode and the cathode, wherein the organic layer comprises the metal complex comprising the ligand Lₐ having the structure of Formula 1A and the ligand L_{b} having the structure of Formula 1B in the preceding embodiments.

According to another embodiment of the present disclosure, the organic layer is an emissive layer, and the metal complex is an emissive material.

According to another embodiment of the present disclosure, the emissive layer emits green light or white light.

According to an embodiment of the present disclosure, the organic layer further comprises a host material.

According to another embodiment of the present disclosure, the emissive layer comprises a first host compound.

According to another embodiment of the present disclosure, the emissive layer further comprises a second host compound.

According to another embodiment of the present disclosure, the first host compound and/or the second host compound comprise at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to another embodiment of the present disclosure, the first host compound has a structure represented by Formula 4:

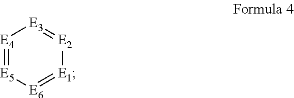

wherein
E₁ to E₆ are, at each occurrence identically or differently, selected from C, CRₑ, or N, at least two of E₁ to E₆ are N, and at least one of E₁ to E₆ is C and joined to Formula A:

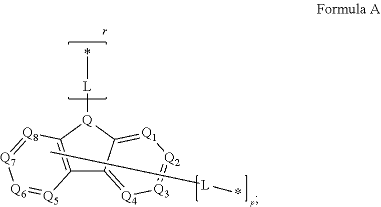

wherein
Q is, at each occurrence identically or differently, selected from the group consisting of O, S, Se, N, NR″, CR″R″, SiR″R″, GeR″R″, and R″C═CR″; when two R″ are present at the same time, the two R″ may be identical or different;
p is 0 or 1; r is 0 or 1;
when Q is selected from N, p is 0 and r is 1;
when Q is selected from the group consisting of O, S, Se, NR″, CR″R″, SiR″R″, GeR″R″, and R″C═CR″, p is 1 and r is 0;
L is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof;
Q₁ to Q₈ are, at each occurrence identically or differently, selected from C, CR_{q}, or N;
Rₑ, R″, and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
“*” represents a position where Formula A is joined to Formula 4; and
adjacent substituents Rₑ, R″, R_{q} can be optionally joined to form a ring.

In the present disclosure, the expression that “adjacent substituents Rₑ, R″, R_{q} can be optionally joined to form a ring” is intended to mean that any one or more of groups of adjacent substituents, such as two substituents Rₑ, two substituents R″, two substituents R_{q}, and two substituents R″ and R_{q}, can be joined to form a ring. Obviously, it is also possible that none of these substituents are joined to form a ring.

According to another embodiment of the present disclosure, E₁ to E₆ are, at each occurrence identically or differently, selected from C, CRₑ, or N, three of E₁ to E₆ are N, at least one of E₁ to E₆ is CRₑ, and Rₑ is, at each occurrence identically or differently, selected from the group consisting of: substituted or unsubstituted aryl having 6 to 30 carbon atoms, substituted or unsubstituted heteroaryl having 3 to 30 carbon atoms, and combinations thereof; and/or Q is, at each occurrence identically or differently, selected from O, S, N, or NR″; and/or at least one or at least two of Q₁ to Q₈ are selected from CR_{q}, and R_{q} is selected from substituted or unsubstituted aryl having 6 to 30 carbon atoms, substituted or unsubstituted heteroaryl having 5 to 30 carbon atoms, or a combination thereof; and/or L is, at each occurrence identically or differently, selected from a single bond, substituted or unsubstituted arylene having 6 to 20 carbon atoms, substituted or unsubstituted heteroarylene having 3 to 20 carbon atoms, or a combination thereof.

According to another embodiment of the present disclosure, the first host compound is selected from the group consisting of H-1 to H-163 whose structures are as follows:

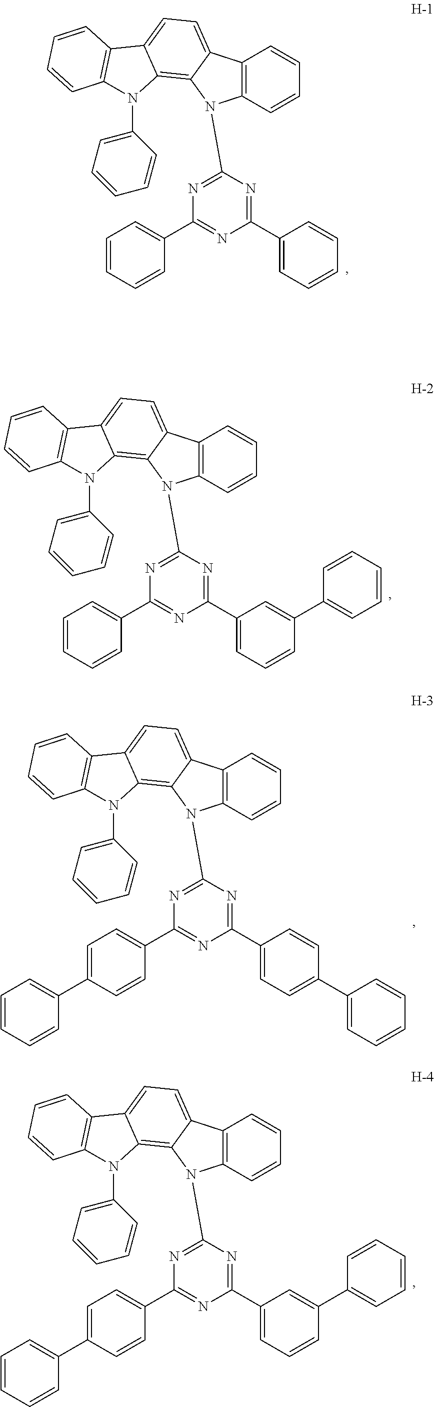 [SMILES: c1ccc(-c2nc(-c3ccccc3)nc(-n3c4ccccc4c4ccc5c6ccccc6n(-c6ccccc6)c5c43)n2)cc1 ; c1ccc(-c2cccc(-c3nc(-c4ccccc4)nc(-n4c5ccccc5c5ccc6c7ccccc7n(-c7ccccc7)c6c54)n3)c2)cc1 ; c1ccc(-c2ccc(-c3nc(-c4ccc(-c5ccccc5)cc4)nc(-n4c5ccccc5c5ccc6c7ccccc7n(-c7ccccc7)c6c54)n3)cc2)cc1 ; c1ccc(-c2ccc(-c3nc(-c4cccc(-c5ccccc5)c4)nc(-n4c5ccccc5c5ccc6c7ccccc7n(-c7ccccc7)c6c54)n3)cc2)cc1]

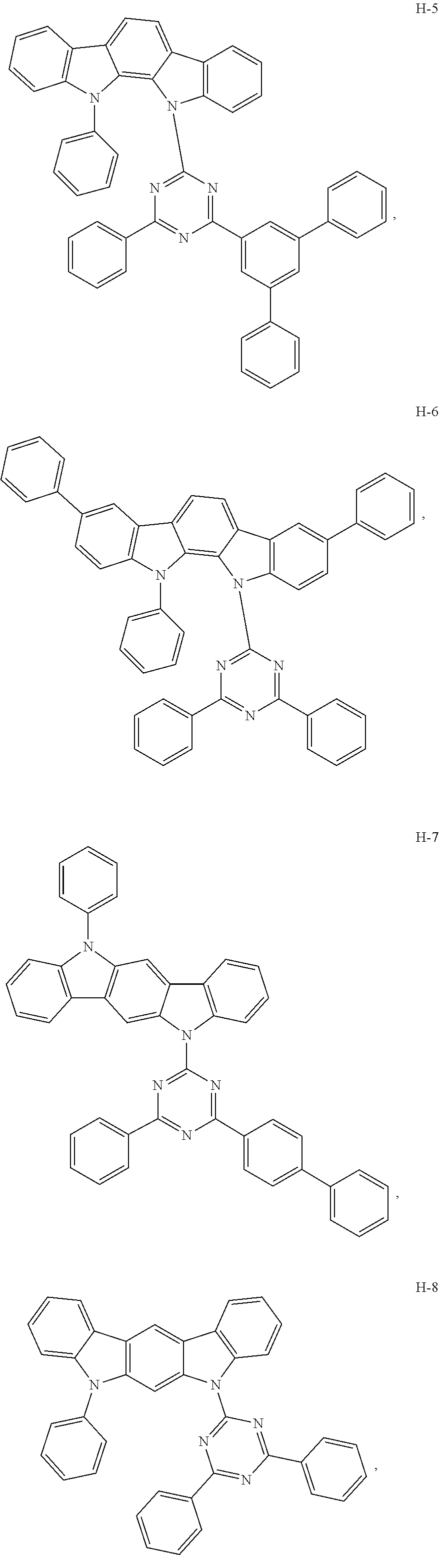 [SMILES: c1ccc(-c2cc(-c3ccccc3)cc(-c3nc(-c4ccccc4)nc(-n4c5ccccc5c5ccc6c7ccccc7n(-c7ccccc7)c6c54)n3)c2)cc1 ; c1ccc(-c2ccc3c(c2)c2ccc4c5cc(-c6ccccc6)ccc5n(-c5nc(-c6ccccc6)nc(-c6ccccc6)n5)c4c2n3-c2ccccc2)cc1 ; c1ccc(-c2ccc(-c3nc(-c4ccccc4)nc(-n4c5ccccc5c5cc6c(cc54)c4ccccc4n6-c4ccccc4)n3)cc2)cc1 ; c1ccc(-c2nc(-c3ccccc3)nc(-n3c4ccccc4c4cc5c6ccccc6n(-c6ccccc6)c5cc43)n2)cc1]

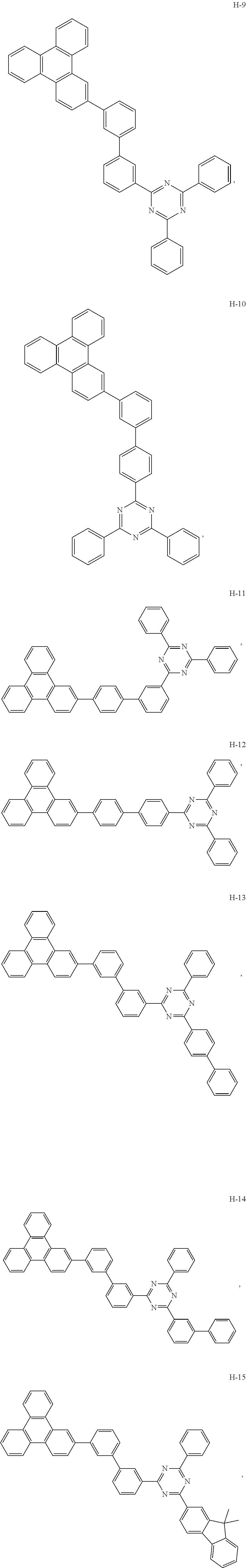

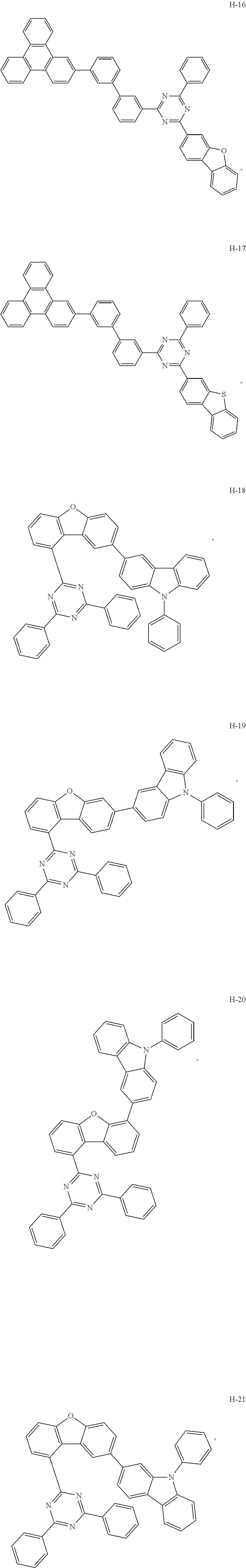

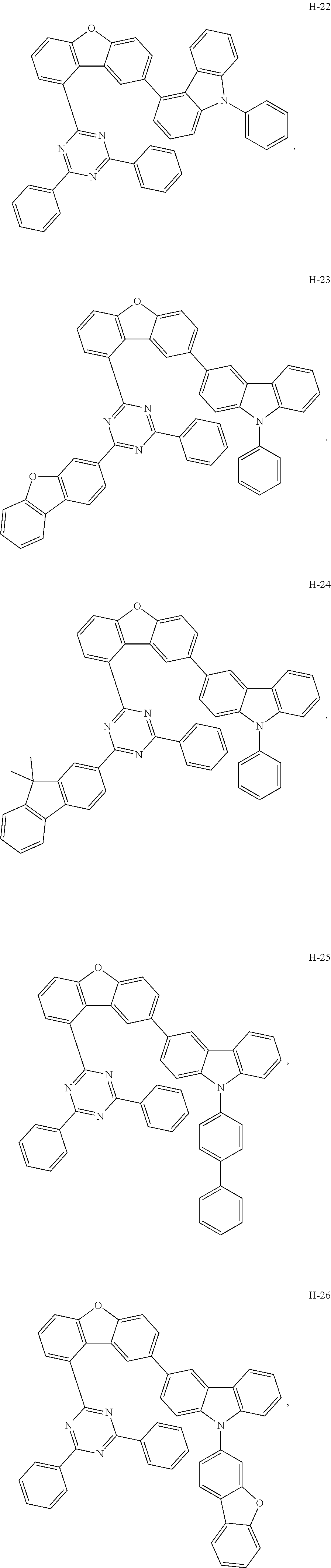 [SMILES: c1ccc(-c2nc(-c3ccccc3)nc(-c3cccc4oc5ccc(-c6cccc7c6c6ccccc6n7-c6ccccc6)cc5c34)n2)cc1 ; c1ccc(-c2nc(-c3ccc4c(c3)oc3ccccc34)nc(-c3cccc4oc5ccc(-c6ccc7c(c6)c6ccccc6n7-c6ccccc6)cc5c34)n2)cc1 ; CC1(C)c2ccccc2-c2ccc(-c3nc(-c4ccccc4)nc(-c4cccc5oc6ccc(-c7ccc8c(c7)c7ccccc7n8-c7ccccc7)cc6c45)n3)cc21 ; c1ccc(-c2ccc(-n3c4ccccc4c4cc(-c5ccc6oc7cccc(-c8nc(-c9ccccc9)nc(-c9ccccc9)n8)c7c6c5)ccc43)cc2)cc1 ; c1ccc(-c2nc(-c3ccccc3)nc(-c3cccc4oc5ccc(-c6ccc7c(c6)c6ccccc6n7-c6ccc7c(c6)oc6ccccc67)cc5c34)n2)cc1]

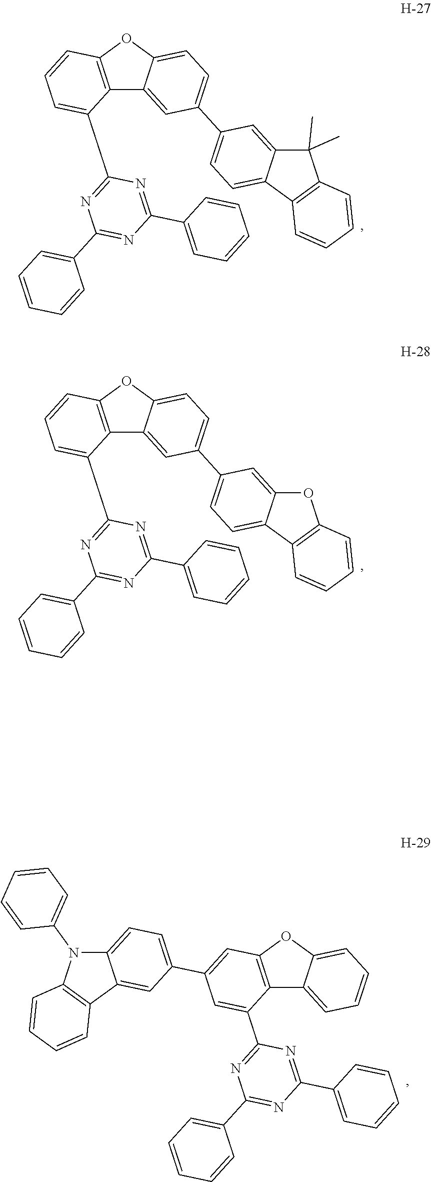 [SMILES: CC1(C)c2ccccc2-c2ccc(-c3ccc4oc5cccc(-c6nc(-c7ccccc7)nc(-c7ccccc7)n6)c5c4c3)cc21 ; c1ccc(-c2nc(-c3ccccc3)nc(-c3cccc4oc5ccc(-c6ccc7c(c6)oc6ccccc67)cc5c34)n2)cc1 ; c1ccc(-c2nc(-c3ccccc3)nc(-c3cc(-c4ccc5c(c4)c4ccccc4n5-c4ccccc4)cc4oc5ccccc5c34)n2)cc1]

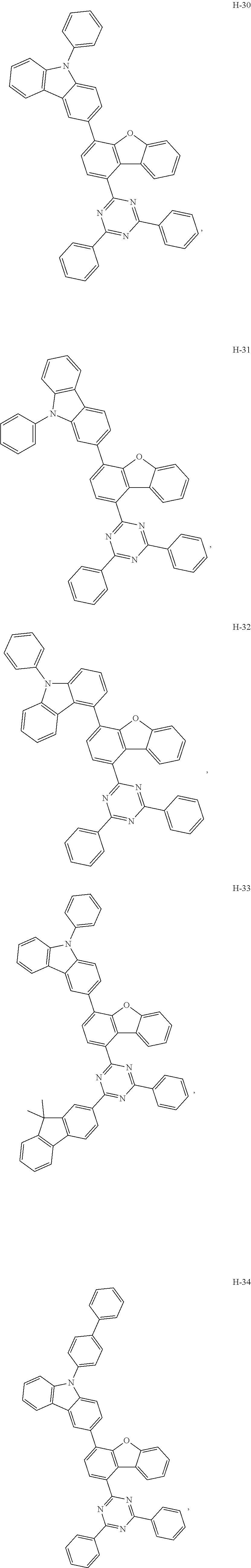

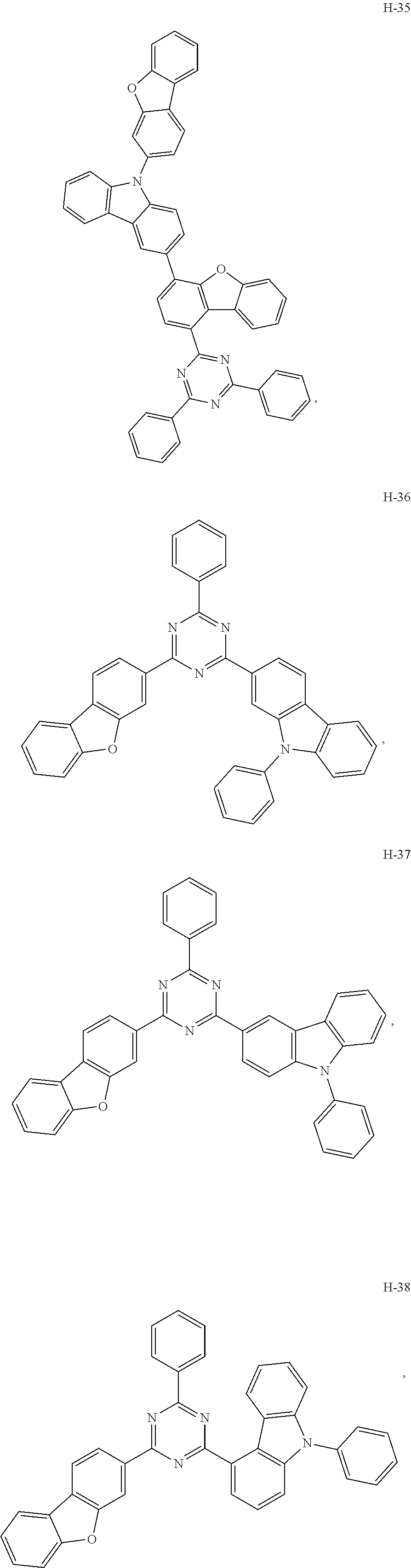 [SMILES: c1ccc(-c2nc(-c3ccccc3)nc(-c3ccc(-c4ccc5c(c4)c4ccccc4n5-c4ccc5c(c4)oc4ccccc45)c4oc5ccccc5c34)n2)cc1 ; c1ccc(-c2nc(-c3ccc4c(c3)oc3ccccc34)nc(-c3ccc4c5ccccc5n(-c5ccccc5)c4c3)n2)cc1 ; c1ccc(-c2nc(-c3ccc4c(c3)oc3ccccc34)nc(-c3ccc4c(c3)c3ccccc3n4-c3ccccc3)n2)cc1 ; c1ccc(-c2nc(-c3ccc4c(c3)oc3ccccc34)nc(-c3cccc4c3c3ccccc3n4-c3ccccc3)n2)cc1]

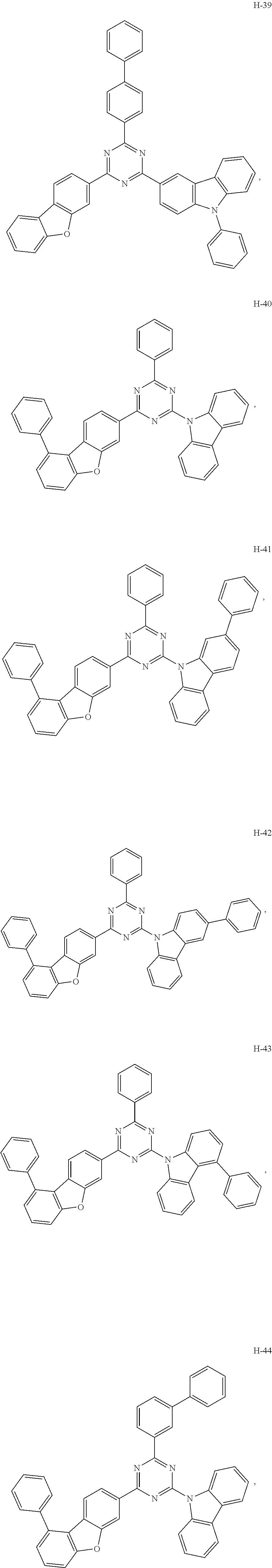

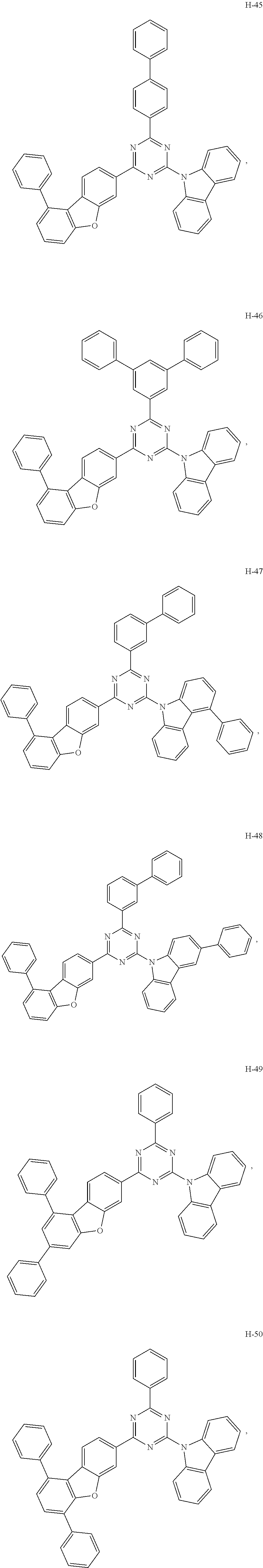

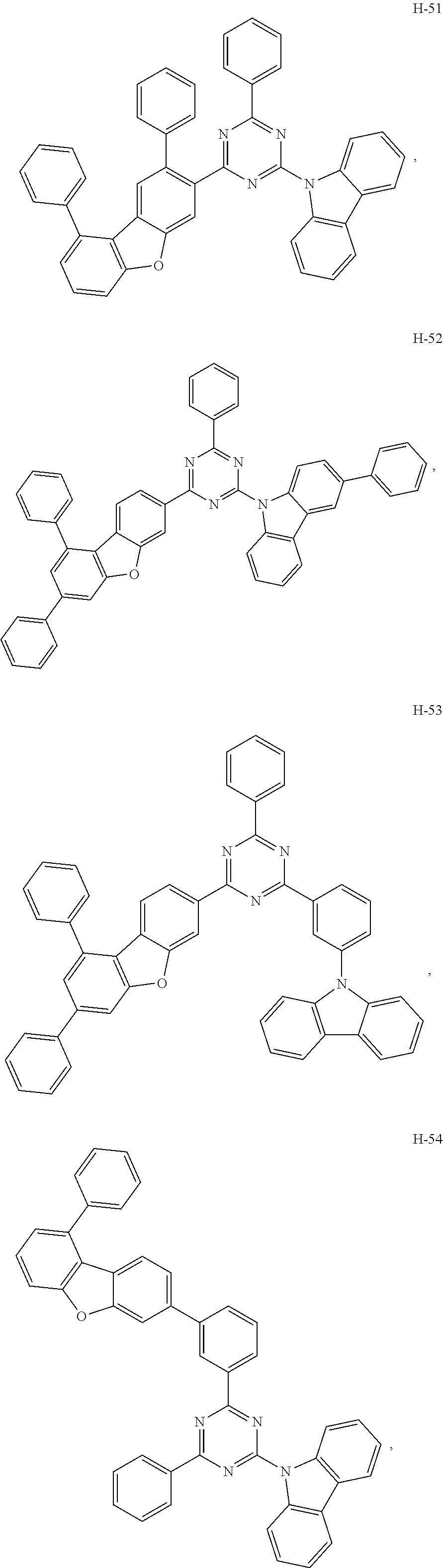 [SMILES: c1ccc(-c2nc(-c3cc4oc5cccc(-c6ccccc6)c5c4cc3-c3ccccc3)nc(-n3c4ccccc4c4ccccc43)n2)cc1 ; c1ccc(-c2cc(-c3ccccc3)c3c(c2)oc2cc(-c4nc(-c5ccccc5)nc(-n5c6ccccc6c6cc(-c7ccccc7)ccc65)n4)ccc23)cc1 ; c1ccc(-c2cc(-c3ccccc3)c3c(c2)oc2cc(-c4nc(-c5ccccc5)nc(-c5cccc(-n6c7ccccc7c7ccccc76)c5)n4)ccc23)cc1 ; c1ccc(-c2nc(-c3cccc(-c4ccc5c(c4)oc4cccc(-c6ccccc6)c45)c3)nc(-n3c4ccccc4c4ccccc43)n2)cc1]

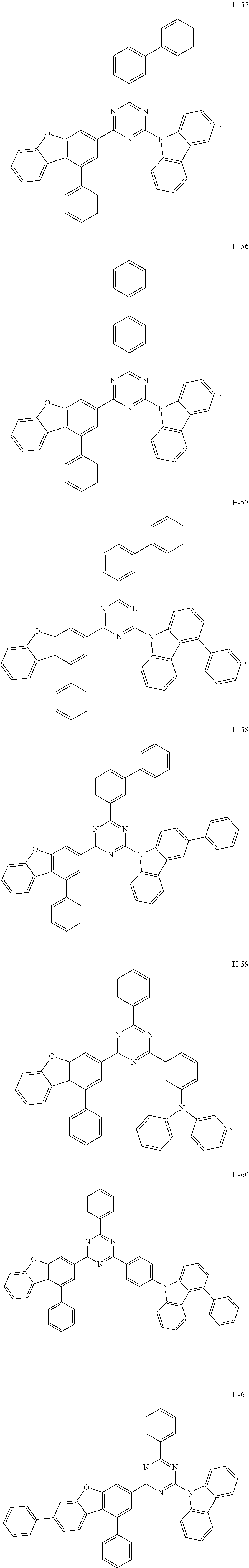

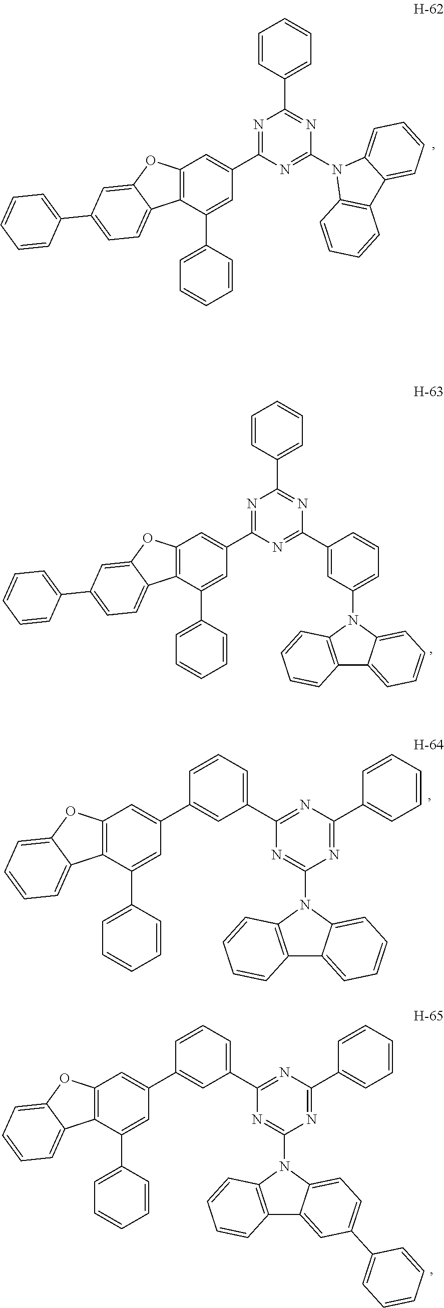 [SMILES: c1ccc(-c2ccc3c(c2)oc2cc(-c4nc(-c5ccccc5)nc(-n5c6ccccc6c6ccccc65)n4)cc(-c4ccccc4)c23)cc1 ; c1ccc(-c2ccc3c(c2)oc2cc(-c4nc(-c5ccccc5)nc(-c5cccc(-n6c7ccccc7c7ccccc76)c5)n4)cc(-c4ccccc4)c23)cc1 ; c1ccc(-c2nc(-c3cccc(-c4cc(-c5ccccc5)c5c(c4)oc4ccccc45)c3)nc(-n3c4ccccc4c4ccccc43)n2)cc1 ; c1ccc(-c2ccc3c(c2)c2ccccc2n3-c2nc(-c3ccccc3)nc(-c3cccc(-c4cc(-c5ccccc5)c5c(c4)oc4ccccc45)c3)n2)cc1]

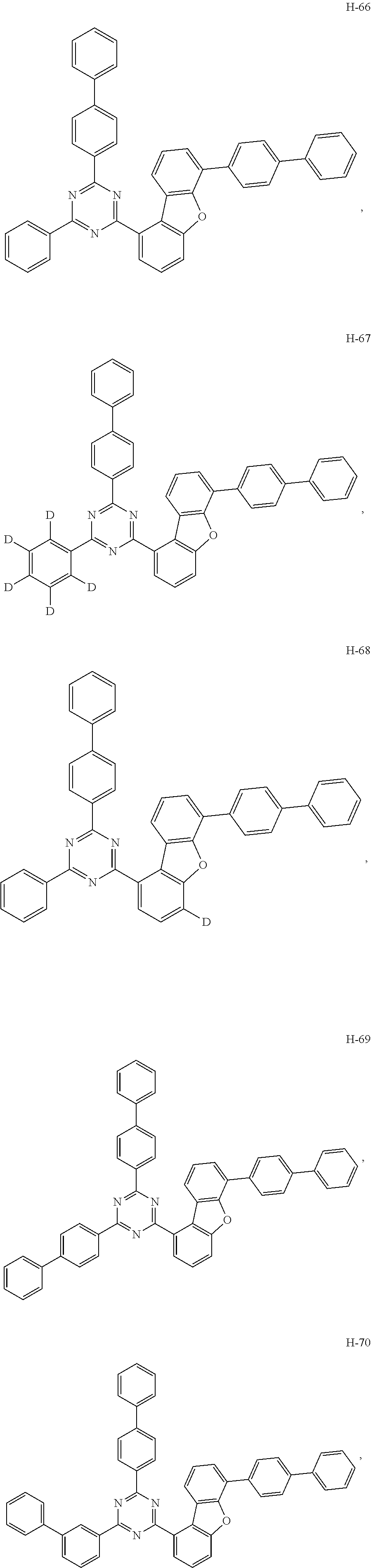 [SMILES: c1ccc(-c2ccc(-c3nc(-c4ccccc4)nc(-c4cccc5oc6c(-c7ccc(-c8ccccc8)cc7)cccc6c45)n3)cc2)cc1 ; [2H]c1c([2H])c([2H])c(-c2nc(-c3ccc(-c4ccccc4)cc3)nc(-c3cccc4oc5c(-c6ccc(-c7ccccc7)cc6)cccc5c34)n2)c([2H])c1[2H] ; [2H]c1ccc(-c2nc(-c3ccccc3)nc(-c3ccc(-c4ccccc4)cc3)n2)c2c1oc1c(-c3ccc(-c4ccccc4)cc3)cccc12 ; c1ccc(-c2ccc(-c3nc(-c4ccc(-c5ccccc5)cc4)nc(-c4cccc5oc6c(-c7ccc(-c8ccccc8)cc7)cccc6c45)n3)cc2)cc1 ; c1ccc(-c2ccc(-c3nc(-c4cccc(-c5ccccc5)c4)nc(-c4cccc5oc6c(-c7ccc(-c8ccccc8)cc7)cccc6c45)n3)cc2)cc1]

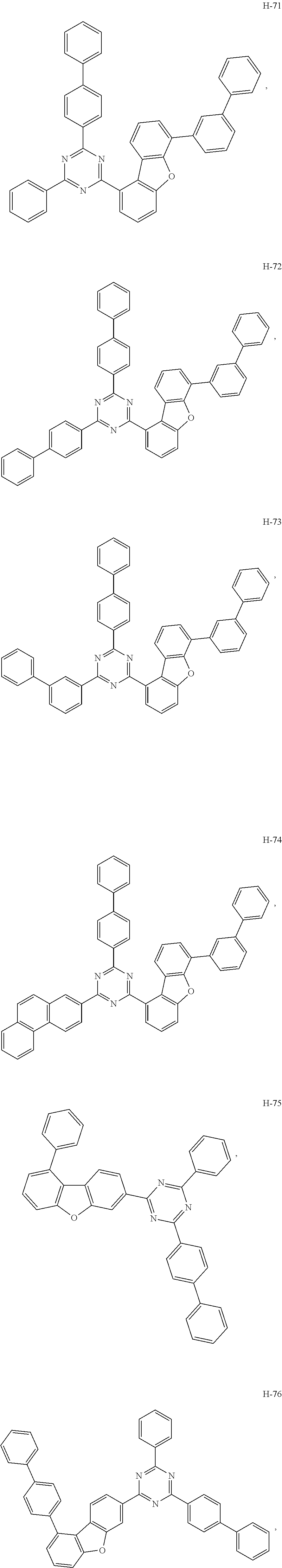

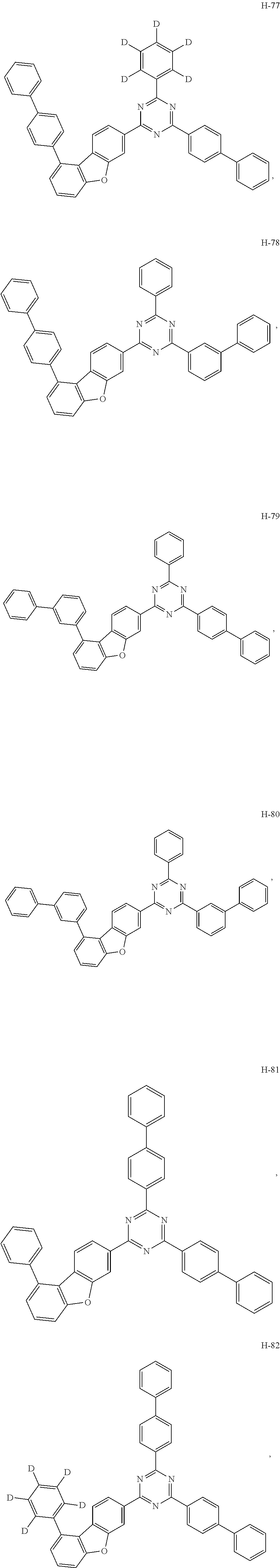

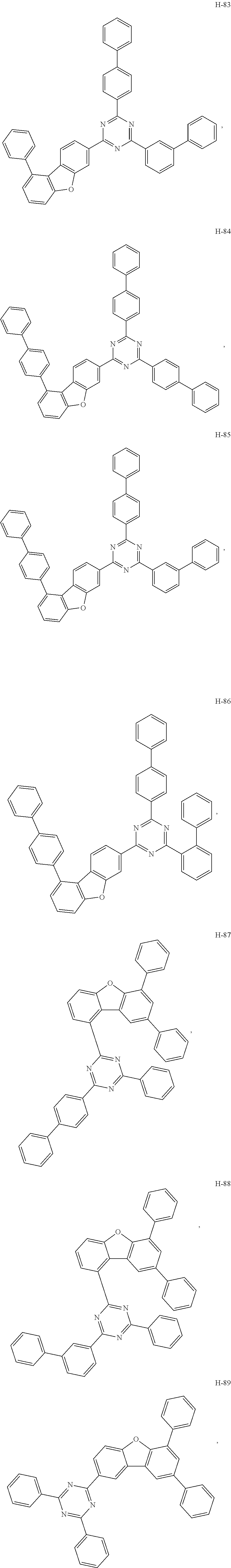

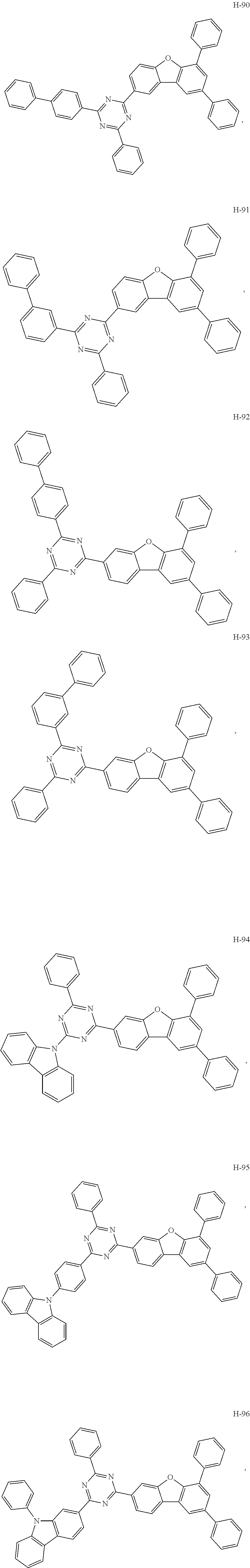

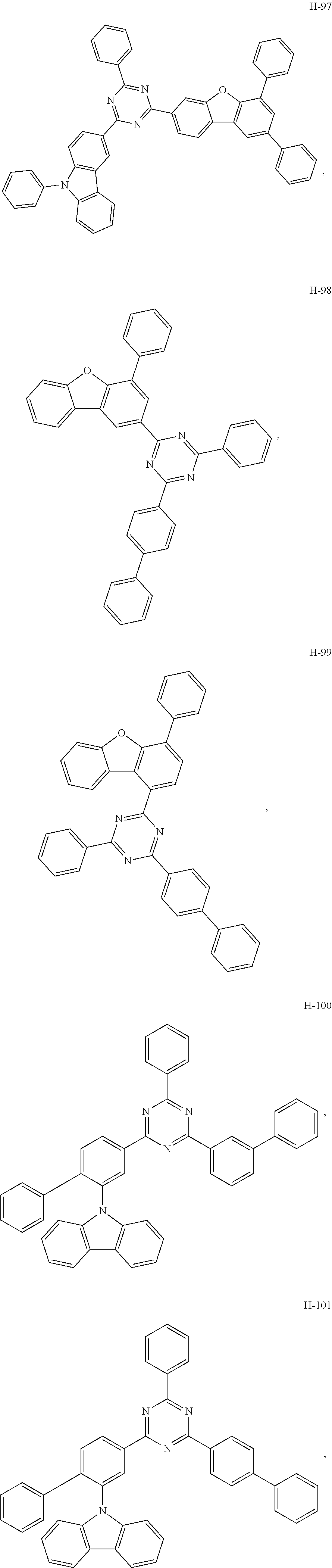 [SMILES: c1ccc(-c2cc(-c3ccccc3)c3oc4cc(-c5nc(-c6ccccc6)nc(-c6ccc7c(c6)c6ccccc6n7-c6ccccc6)n5)ccc4c3c2)cc1 ; c1ccc(-c2ccc(-c3nc(-c4ccccc4)nc(-c4cc(-c5ccccc5)c5oc6ccccc6c5c4)n3)cc2)cc1 ; c1ccc(-c2ccc(-c3nc(-c4ccccc4)nc(-c4ccc(-c5ccccc5)c5oc6ccccc6c45)n3)cc2)cc1 ; c1ccc(-c2cccc(-c3nc(-c4ccccc4)nc(-c4ccc(-c5ccccc5)c(-n5c6ccccc6c6ccccc65)c4)n3)c2)cc1 ; c1ccc(-c2ccc(-c3nc(-c4ccccc4)nc(-c4ccc(-c5ccccc5)c(-n5c6ccccc6c6ccccc65)c4)n3)cc2)cc1]

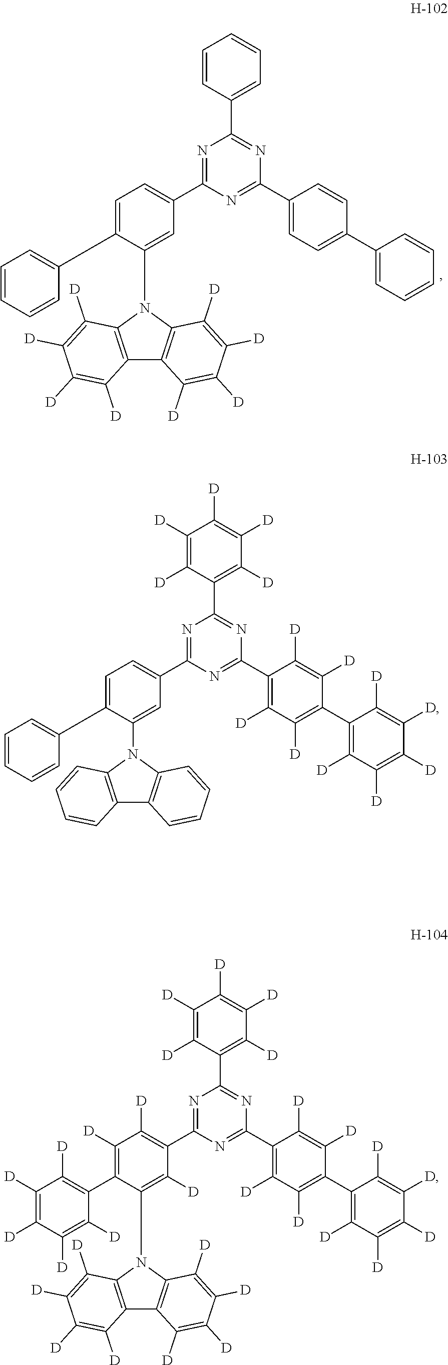

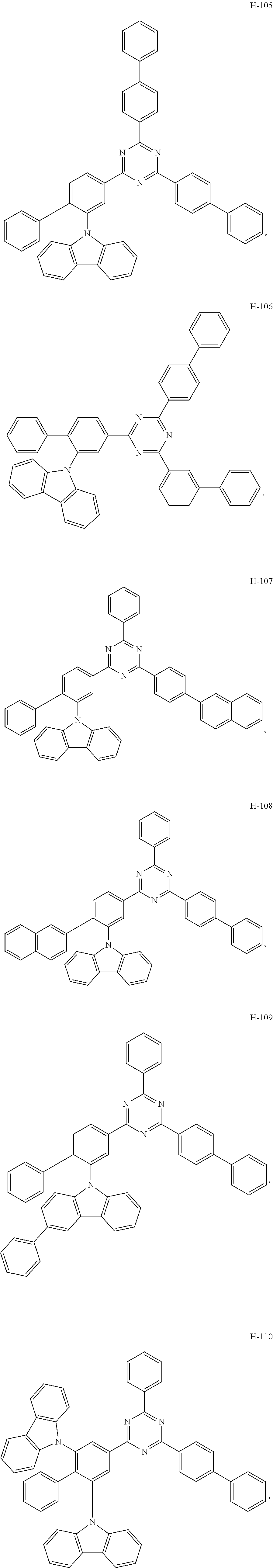

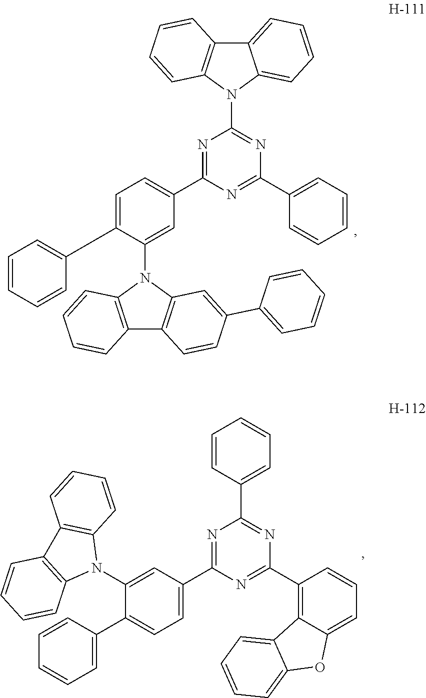 [SMILES: c1ccc(-c2ccc3c4ccccc4n(-c4cc(-c5nc(-c6ccccc6)nc(-n6c7ccccc7c7ccccc76)n5)ccc4-c4ccccc4)c3c2)cc1 ; c1ccc(-c2nc(-c3ccc(-c4ccccc4)c(-n4c5ccccc5c5ccccc54)c3)nc(-c3cccc4oc5ccccc5c34)n2)cc1]

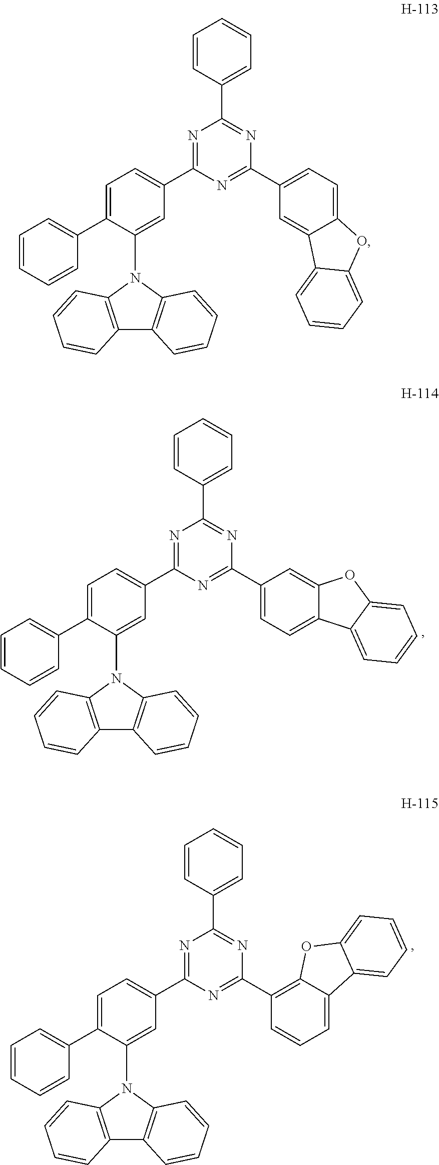 [SMILES: c1ccc(-c2nc(-c3ccc(-c4ccccc4)c(-n4c5ccccc5c5ccccc54)c3)nc(-c3ccc4oc5ccccc5c4c3)n2)cc1 ; c1ccc(-c2nc(-c3ccc(-c4ccccc4)c(-n4c5ccccc5c5ccccc54)c3)nc(-c3ccc4c(c3)oc3ccccc34)n2)cc1 ; c1ccc(-c2nc(-c3ccc(-c4ccccc4)c(-n4c5ccccc5c5ccccc54)c3)nc(-c3cccc4c3oc3ccccc34)n2)cc1]

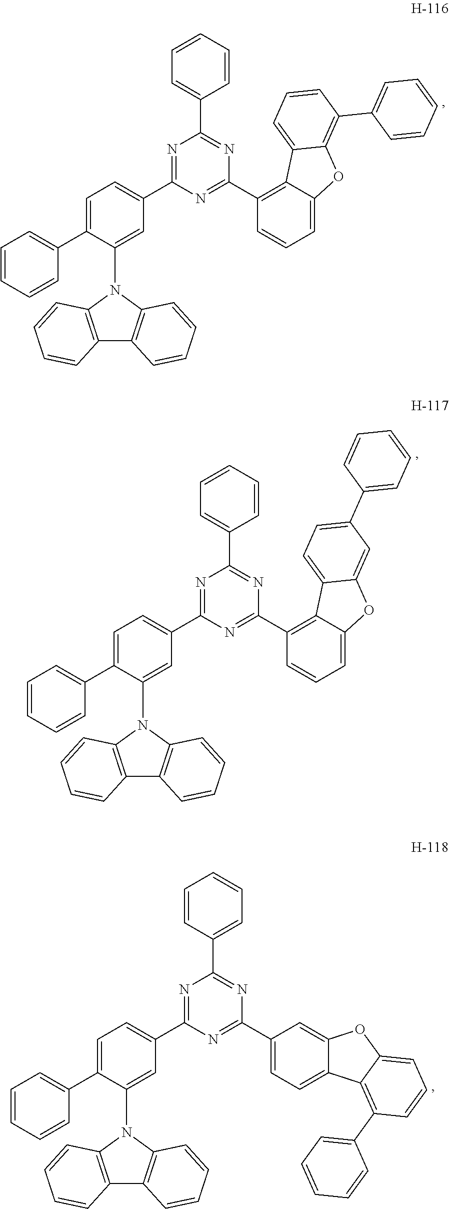 [SMILES: c1ccc(-c2nc(-c3ccc(-c4ccccc4)c(-n4c5ccccc5c5ccccc54)c3)nc(-c3cccc4oc5c(-c6ccccc6)cccc5c34)n2)cc1 ; c1ccc(-c2ccc3c(c2)oc2cccc(-c4nc(-c5ccccc5)nc(-c5ccc(-c6ccccc6)c(-n6c7ccccc7c7ccccc76)c5)n4)c23)cc1 ; c1ccc(-c2nc(-c3ccc(-c4ccccc4)c(-n4c5ccccc5c5ccccc54)c3)nc(-c3ccc4c(c3)oc3cccc(-c5ccccc5)c34)n2)cc1]

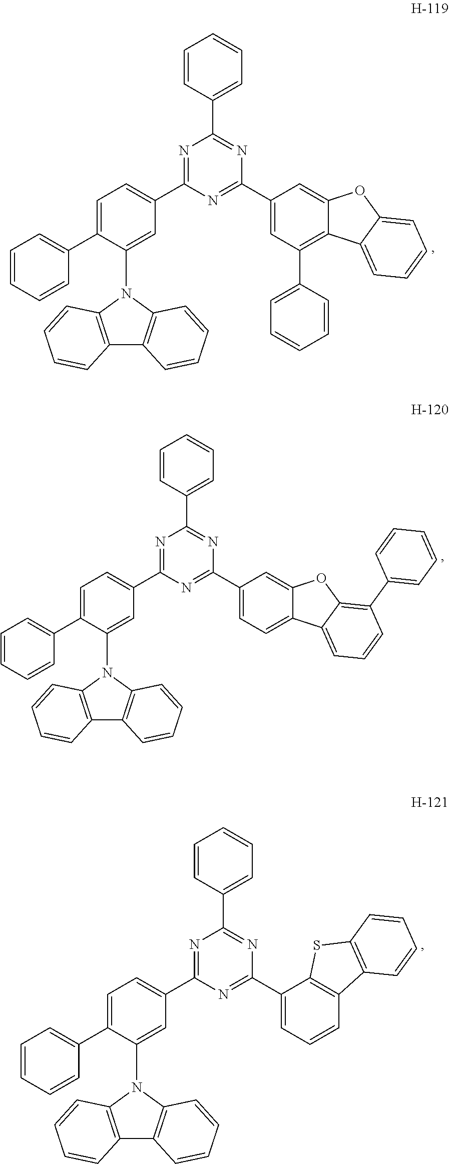 [SMILES: c1ccc(-c2nc(-c3ccc(-c4ccccc4)c(-n4c5ccccc5c5ccccc54)c3)nc(-c3cc(-c4ccccc4)c4c(c3)oc3ccccc34)n2)cc1 ; c1ccc(-c2nc(-c3ccc(-c4ccccc4)c(-n4c5ccccc5c5ccccc54)c3)nc(-c3ccc4c(c3)oc3c(-c5ccccc5)cccc34)n2)cc1 ; c1ccc(-c2nc(-c3ccc(-c4ccccc4)c(-n4c5ccccc5c5ccccc54)c3)nc(-c3cccc4c3sc3ccccc34)n2)cc1]

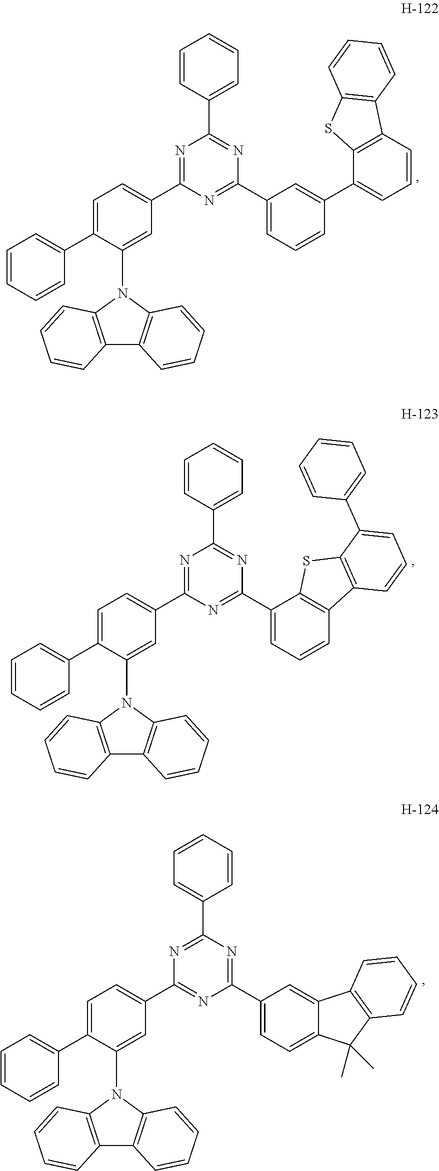 [SMILES: c1ccc(-c2nc(-c3cccc(-c4cccc5c4sc4ccccc45)c3)nc(-c3ccc(-c4ccccc4)c(-n4c5ccccc5c5ccccc54)c3)n2)cc1 ; c1ccc(-c2nc(-c3ccc(-c4ccccc4)c(-n4c5ccccc5c5ccccc54)c3)nc(-c3cccc4c3sc3c(-c5ccccc5)cccc34)n2)cc1 ; CC1(C)c2ccccc2-c2cc(-c3nc(-c4ccccc4)nc(-c4ccc(-c5ccccc5)c(-n5c6ccccc6c6ccccc65)c4)n3)ccc21]

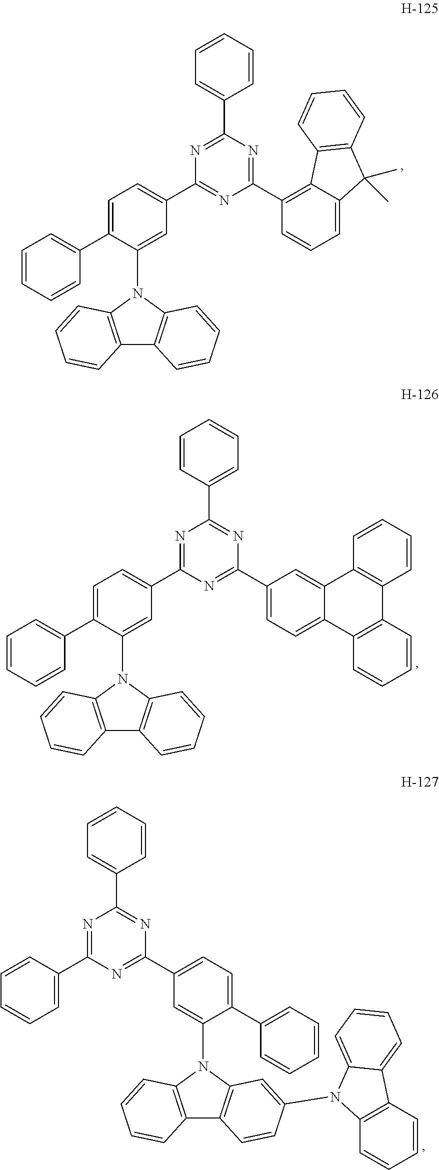 [SMILES: CC1(C)c2ccccc2-c2c(-c3nc(-c4ccccc4)nc(-c4ccc(-c5ccccc5)c(-n5c6ccccc6c6ccccc65)c4)n3)cccc21 ; c1ccc(-c2nc(-c3ccc(-c4ccccc4)c(-n4c5ccccc5c5ccccc54)c3)nc(-c3ccc4c5ccccc5c5ccccc5c4c3)n2)cc1 ; c1ccc(-c2nc(-c3ccccc3)nc(-c3ccc(-c4ccccc4)c(-n4c5ccccc5c5ccc(-n6c7ccccc7c7ccccc76)cc54)c3)n2)cc1]

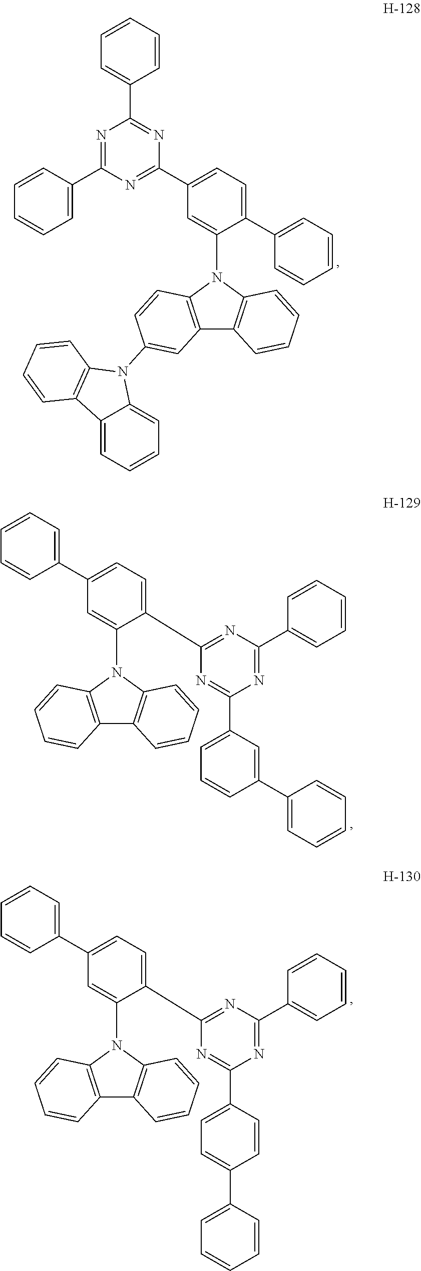 [SMILES: c1ccc(-c2nc(-c3ccccc3)nc(-c3ccc(-c4ccccc4)c(-n4c5ccccc5c5cc(-n6c7ccccc7c7ccccc76)ccc54)c3)n2)cc1 ; c1ccc(-c2cccc(-c3nc(-c4ccccc4)nc(-c4ccc(-c5ccccc5)cc4-n4c5ccccc5c5ccccc54)n3)c2)cc1 ; c1ccc(-c2ccc(-c3nc(-c4ccccc4)nc(-c4ccc(-c5ccccc5)cc4-n4c5ccccc5c5ccccc54)n3)cc2)cc1]

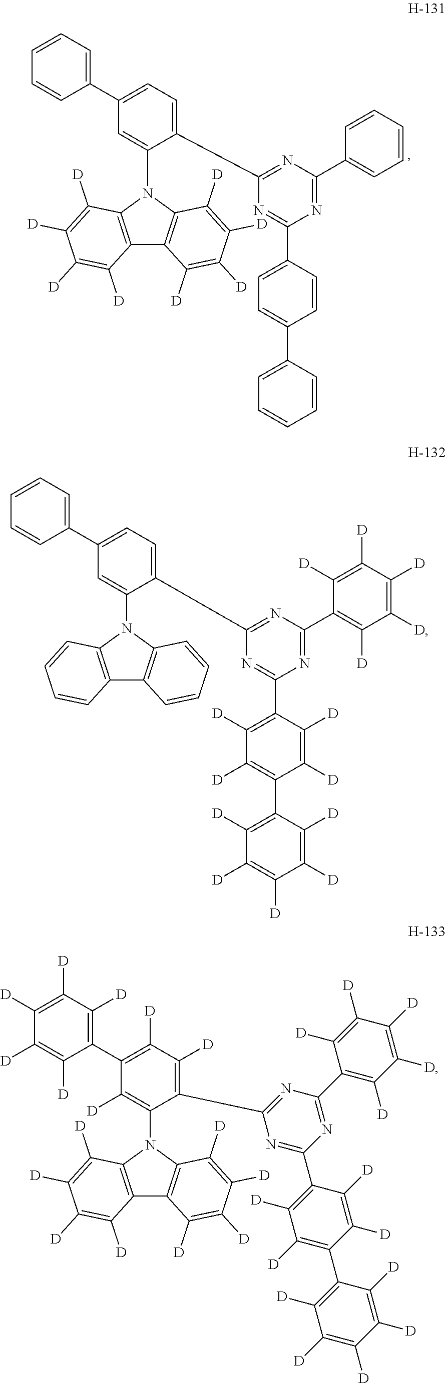

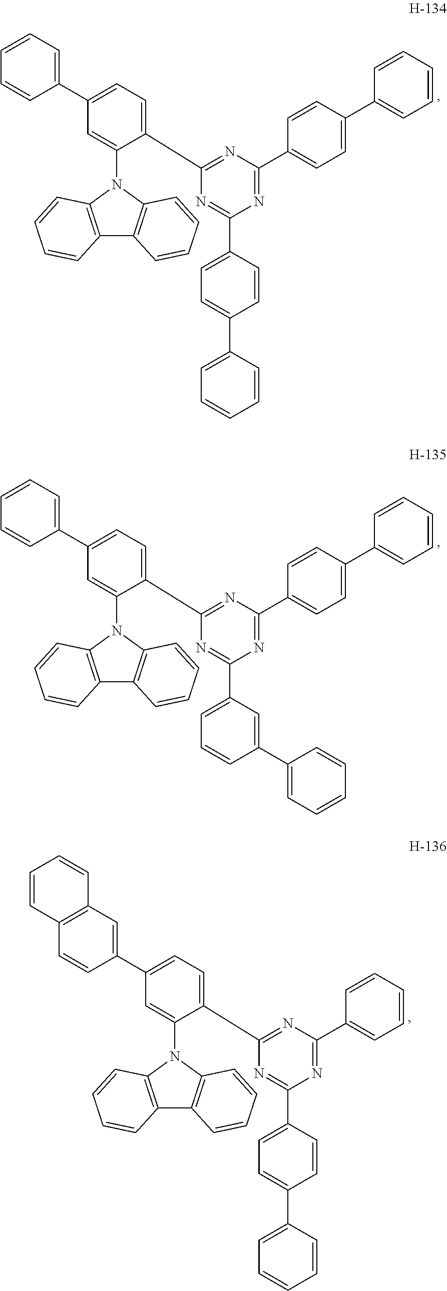 [SMILES: c1ccc(-c2ccc(-c3nc(-c4ccc(-c5ccccc5)cc4)nc(-c4ccc(-c5ccccc5)cc4-n4c5ccccc5c5ccccc54)n3)cc2)cc1 ; c1ccc(-c2ccc(-c3nc(-c4cccc(-c5ccccc5)c4)nc(-c4ccc(-c5ccccc5)cc4-n4c5ccccc5c5ccccc54)n3)cc2)cc1 ; c1ccc(-c2ccc(-c3nc(-c4ccccc4)nc(-c4ccc(-c5ccc6ccccc6c5)cc4-n4c5ccccc5c5ccccc54)n3)cc2)cc1]

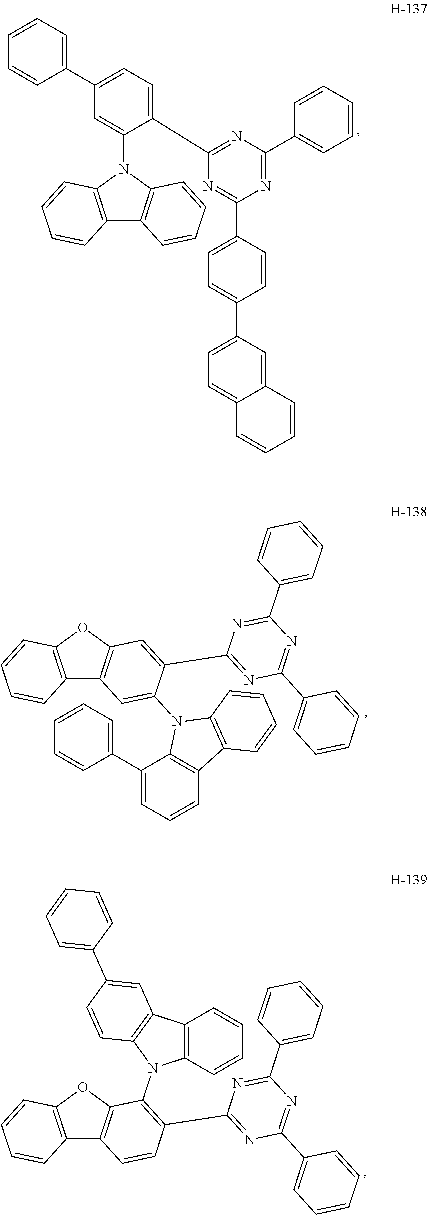 [SMILES: c1ccc(-c2ccc(-c3nc(-c4ccccc4)nc(-c4ccc(-c5ccc6ccccc6c5)cc4)n3)c(-n3c4ccccc4c4ccccc43)c2)cc1 ; c1ccc(-c2nc(-c3ccccc3)nc(-c3cc4oc5ccccc5c4cc3-n3c4ccccc4c4cccc(-c5ccccc5)c43)n2)cc1 ; c1ccc(-c2ccc3c(c2)c2ccccc2n3-c2c(-c3nc(-c4ccccc4)nc(-c4ccccc4)n3)ccc3c2oc2ccccc23)cc1]

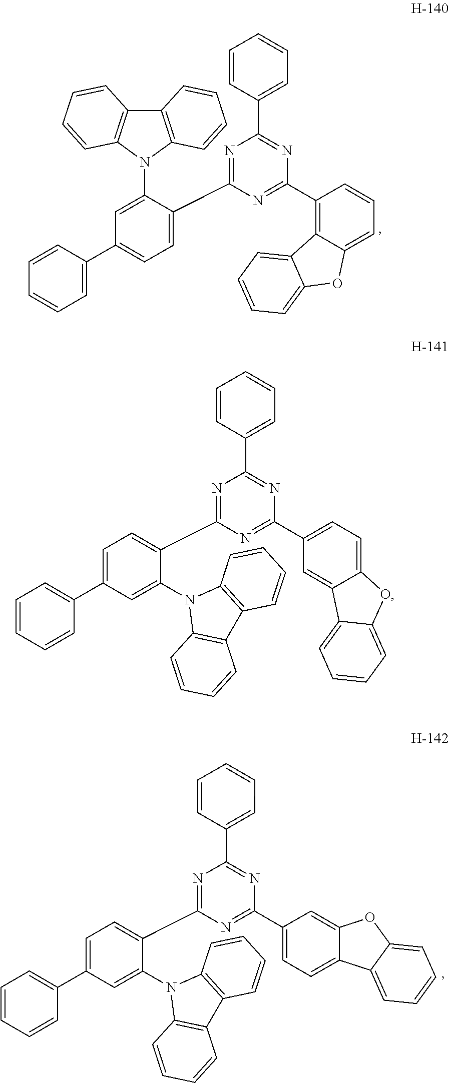 [SMILES: c1ccc(-c2ccc(-c3nc(-c4ccccc4)nc(-c4cccc5oc6ccccc6c45)n3)c(-n3c4ccccc4c4ccccc43)c2)cc1 ; c1ccc(-c2ccc(-c3nc(-c4ccccc4)nc(-c4ccc5oc6ccccc6c5c4)n3)c(-n3c4ccccc4c4ccccc43)c2)cc1 ; c1ccc(-c2ccc(-c3nc(-c4ccccc4)nc(-c4ccc5c(c4)oc4ccccc45)n3)c(-n3c4ccccc4c4ccccc43)c2)cc1]

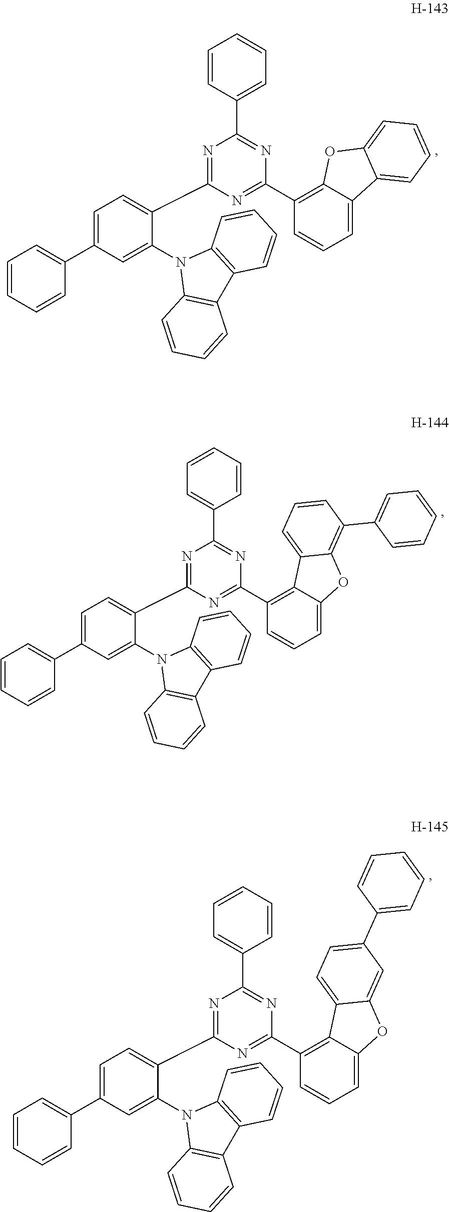 [SMILES: c1ccc(-c2ccc(-c3nc(-c4ccccc4)nc(-c4cccc5c4oc4ccccc45)n3)c(-n3c4ccccc4c4ccccc43)c2)cc1 ; c1ccc(-c2ccc(-c3nc(-c4ccccc4)nc(-c4cccc5oc6c(-c7ccccc7)cccc6c45)n3)c(-n3c4ccccc4c4ccccc43)c2)cc1 ; c1ccc(-c2ccc(-c3nc(-c4ccccc4)nc(-c4cccc5oc6cc(-c7ccccc7)ccc6c45)n3)c(-n3c4ccccc4c4ccccc43)c2)cc1]

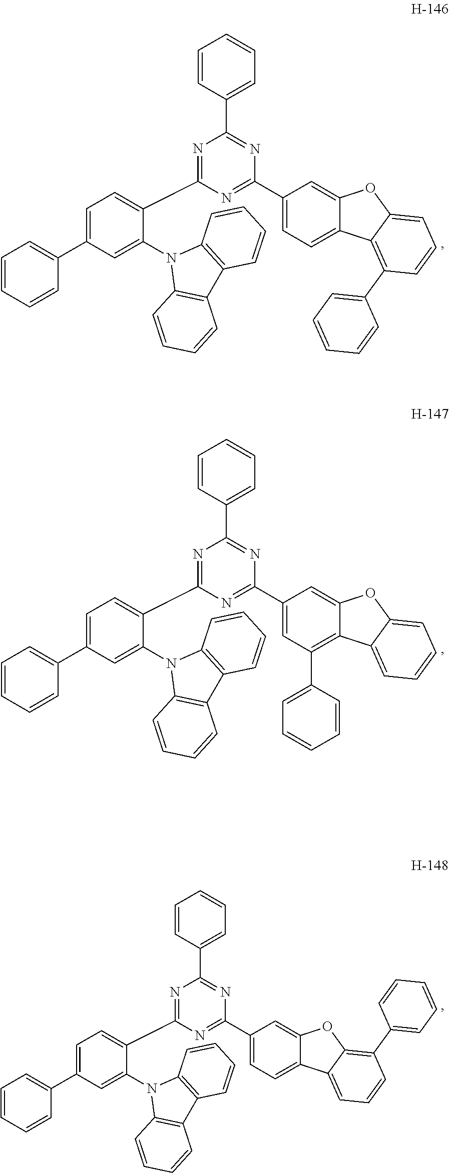 [SMILES: c1ccc(-c2ccc(-c3nc(-c4ccccc4)nc(-c4ccc5c(c4)oc4cccc(-c6ccccc6)c45)n3)c(-n3c4ccccc4c4ccccc43)c2)cc1 ; c1ccc(-c2ccc(-c3nc(-c4ccccc4)nc(-c4cc(-c5ccccc5)c5c(c4)oc4ccccc45)n3)c(-n3c4ccccc4c4ccccc43)c2)cc1 ; c1ccc(-c2ccc(-c3nc(-c4ccccc4)nc(-c4ccc5c(c4)oc4c(-c6ccccc6)cccc45)n3)c(-n3c4ccccc4c4ccccc43)c2)cc1]

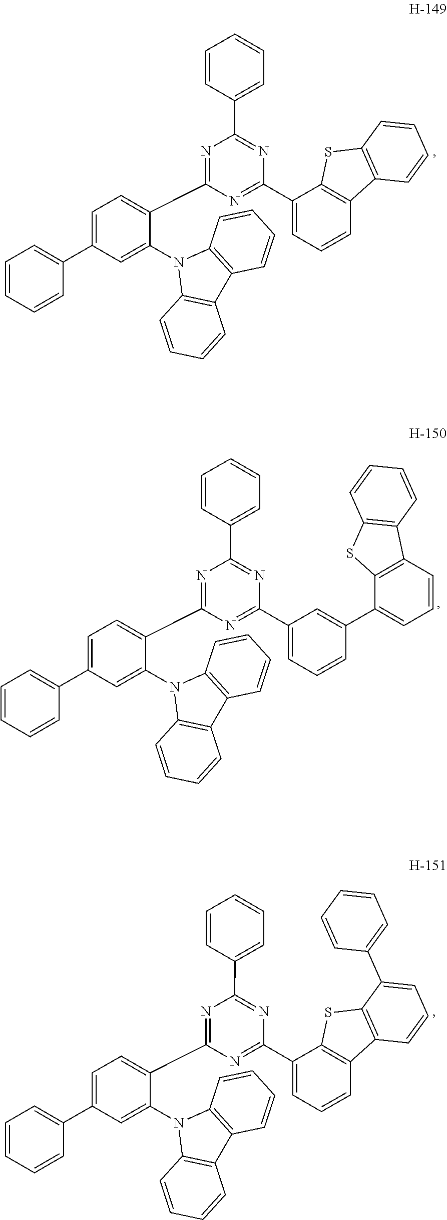 [SMILES: c1ccc(-c2ccc(-c3nc(-c4ccccc4)nc(-c4cccc5c4sc4ccccc45)n3)c(-n3c4ccccc4c4ccccc43)c2)cc1 ; c1ccc(-c2ccc(-c3nc(-c4ccccc4)nc(-c4cccc(-c5cccc6c5sc5ccccc56)c4)n3)c(-n3c4ccccc4c4ccccc43)c2)cc1 ; c1ccc(-c2ccc(-c3nc(-c4ccccc4)nc(-c4cccc5c4sc4c(-c6ccccc6)cccc45)n3)c(-n3c4ccccc4c4ccccc43)c2)cc1]

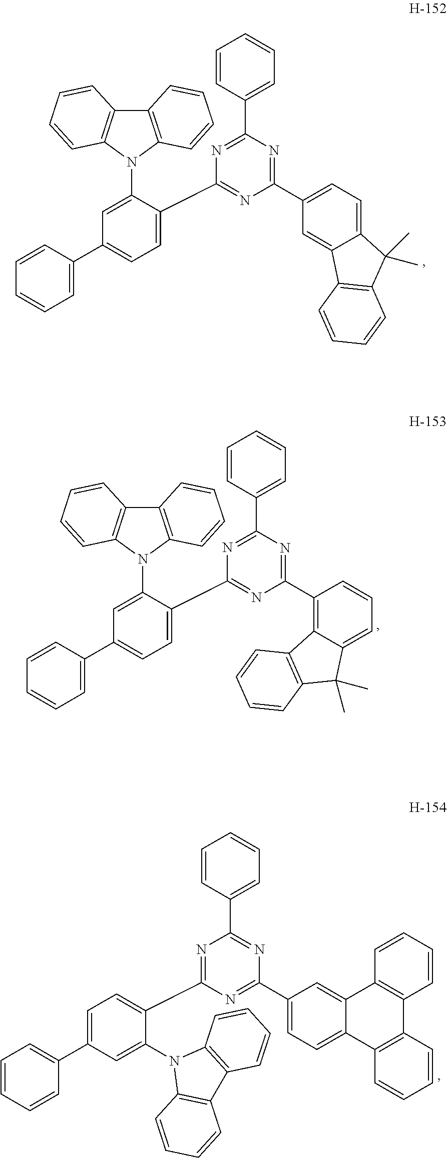 [SMILES: CC1(C)c2ccccc2-c2cc(-c3nc(-c4ccccc4)nc(-c4ccc(-c5ccccc5)cc4-n4c5ccccc5c5ccccc54)n3)ccc21 ; CC1(C)c2ccccc2-c2c(-c3nc(-c4ccccc4)nc(-c4ccc(-c5ccccc5)cc4-n4c5ccccc5c5ccccc54)n3)cccc21 ; c1ccc(-c2ccc(-c3nc(-c4ccccc4)nc(-c4ccc5c6ccccc6c6ccccc6c5c4)n3)c(-n3c4ccccc4c4ccccc43)c2)cc1]

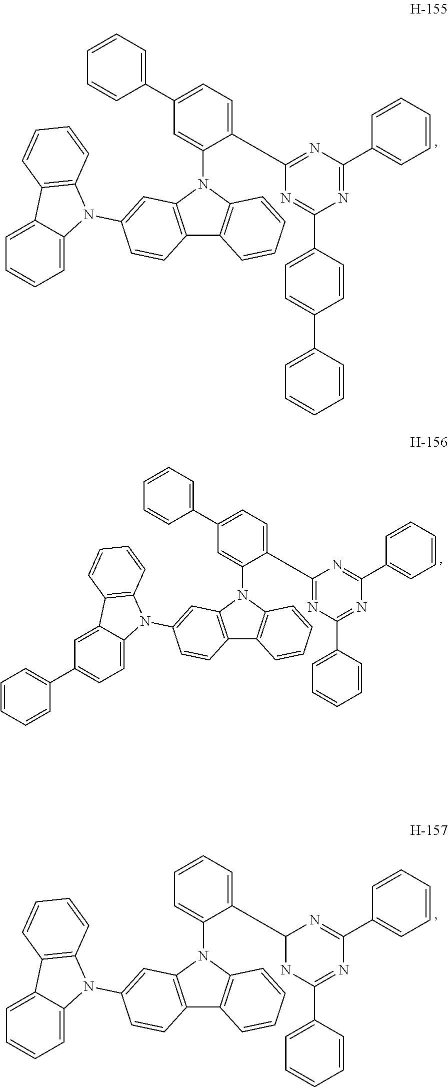 [SMILES: c1ccc(-c2ccc(-c3nc(-c4ccccc4)nc(-c4ccc(-c5ccccc5)cc4-n4c5ccccc5c5ccc(-n6c7ccccc7c7ccccc76)cc54)n3)cc2)cc1 ; c1ccc(-c2ccc(-c3nc(-c4ccccc4)nc(-c4ccccc4)n3)c(-n3c4ccccc4c4ccc(-n5c6ccccc6c6cc(-c7ccccc7)ccc65)cc43)c2)cc1 ; c1ccc(C2=NC(c3ccccc3-n3c4ccccc4c4ccc(-n5c6ccccc6c6ccccc65)cc43)NC(c3ccccc3)=N2)cc1]

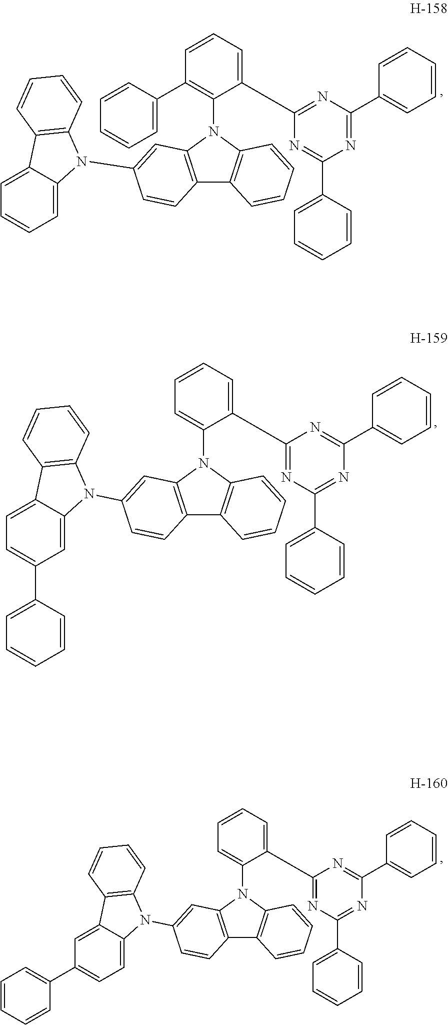 [SMILES: c1ccc(-c2nc(-c3ccccc3)nc(-c3cccc(-c4ccccc4)c3-n3c4ccccc4c4ccc(-n5c6ccccc6c6ccccc65)cc43)n2)cc1 ; c1ccc(-c2ccc3c4ccccc4n(-c4ccc5c6ccccc6n(-c6ccccc6-c6nc(-c7ccccc7)nc(-c7ccccc7)n6)c5c4)c3c2)cc1 ; c1ccc(-c2ccc3c(c2)c2ccccc2n3-c2ccc3c4ccccc4n(-c4ccccc4-c4nc(-c5ccccc5)nc(-c5ccccc5)n4)c3c2)cc1]

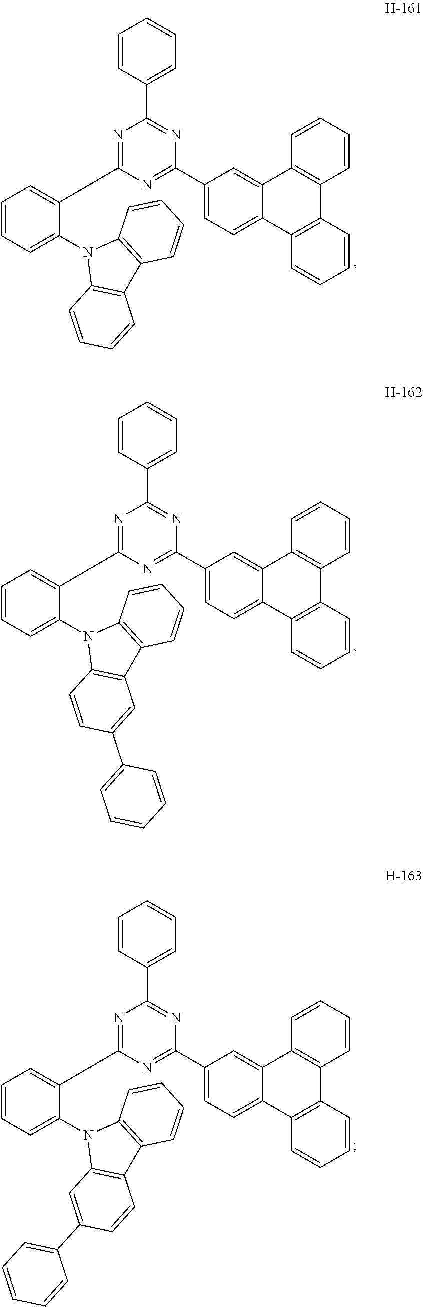 [SMILES: c1ccc(-c2nc(-c3ccc4c5ccccc5c5ccccc5c4c3)nc(-c3ccccc3-n3c4ccccc4c4ccccc43)n2)cc1 ; c1ccc(-c2ccc3c(c2)c2ccccc2n3-c2ccccc2-c2nc(-c3ccccc3)nc(-c3ccc4c5ccccc5c5ccccc5c4c3)n2)cc1 ; c1ccc(-c2ccc3c4ccccc4n(-c4ccccc4-c4nc(-c5ccccc5)nc(-c5ccc6c7ccccc7c7ccccc7c6c5)n4)c3c2)cc1]

wherein hydrogens in Compound H-1 to Compound H-163 can be partially or fully substituted with deuterium.

According to another embodiment of the present disclosure, the second host compound has a structure represented by Formula 5 or Formula 6:

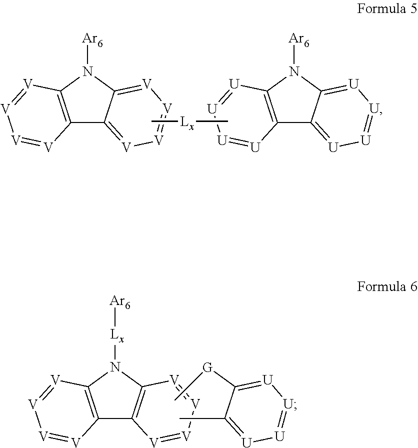

wherein
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof;
G is, at each occurrence identically or differently, selected from C(R_{g})₂, NR_{g}, O, or S;
V is, at each occurrence identically or differently, selected from C, CR_{y}, or N, and at least one V is C and joined to Lₓ;
U is, at each occurrence identically or differently, selected from C, CRᵤ, or N, and at least one U is C and joined to Lₓ;
R_{g}, Rᵥ, and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₆ is, at each occurrence identically or differently, selected from substituted or unsubstituted aryl having 6 to 30 carbon atoms, substituted or unsubstituted heteroaryl having 3 to 30 carbon atoms, or a combination thereof; and adjacent substituents R_{g}, Rᵥ, and Rᵤ can be optionally joined to form a ring.

According to another embodiment of the present disclosure, the second host compound has a structure represented by one of Formula 5-a to Formula 5-p:

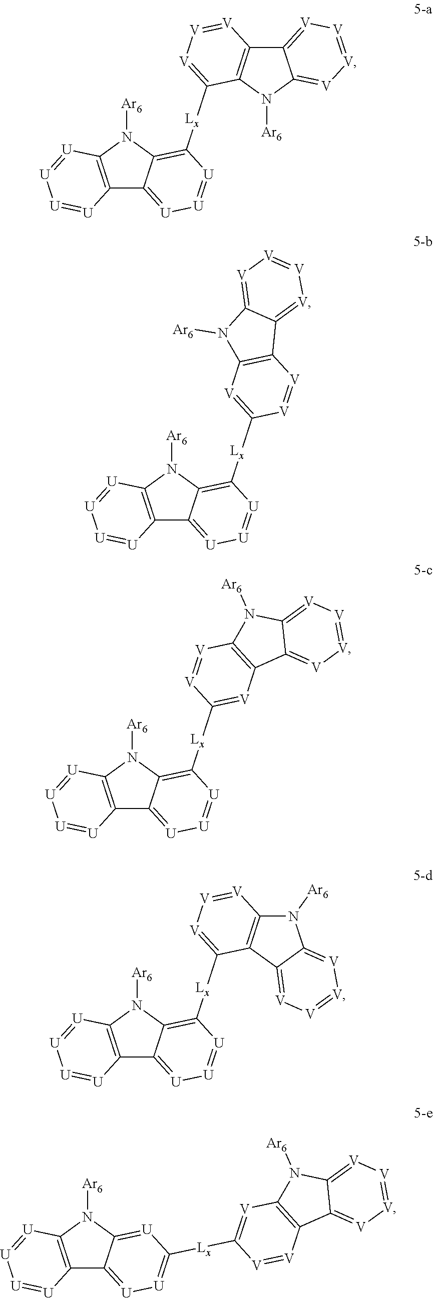

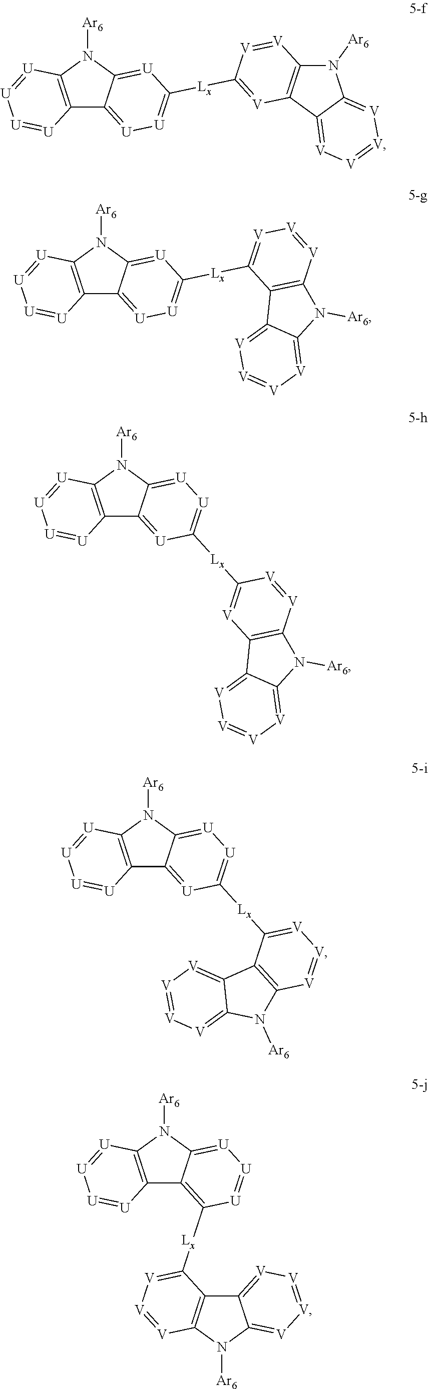

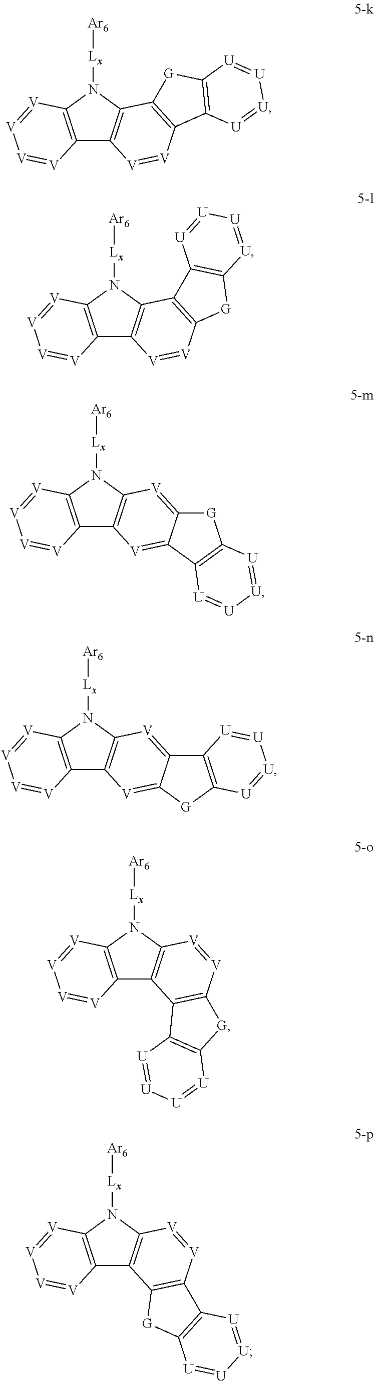

wherein
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof;
G is, at each occurrence identically or differently, selected from C(R_{g})₂, NR_{g}, O, or S;
V is, at each occurrence identically or differently, selected from C, CR_{y}, or N, and at least one V is C and joined to Lₓ;
U is, at each occurrence identically or differently, selected from C, CRᵤ, or N, and at least one U is C and joined to Lₓ;
R_{g}, Rᵥ, and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₆ is, at each occurrence identically or differently, selected from substituted or unsubstituted aryl having 6 to 30 carbon atoms, substituted or unsubstituted heteroaryl having 3 to 30 carbon atoms, or a combination thereof; and
adjacent substituents R_{g}, Rᵥ, and Rᵤ can be optionally joined to form a ring.

In the present disclosure, the expression that “adjacent substituents R_{g}, Rᵥ, and Rᵤ can be optionally joined to form a ring” is intended to mean that any one or more of groups of adjacent substituents, such as two substituents R_{g}, two substituents Rᵥ, two substituents Rᵤ, substituents Rᵥ and Rᵤ, substituents Rᵥ and R_{g}, and substituents R_{g} and Rᵤ, can be joined to form a ring. Obviously, it is also possible that none of these substituents are joined to form a ring.

According to another embodiment of the present disclosure, the second host compound is selected from the group consisting of PH-1 to PH-115 whose structures are as follows:

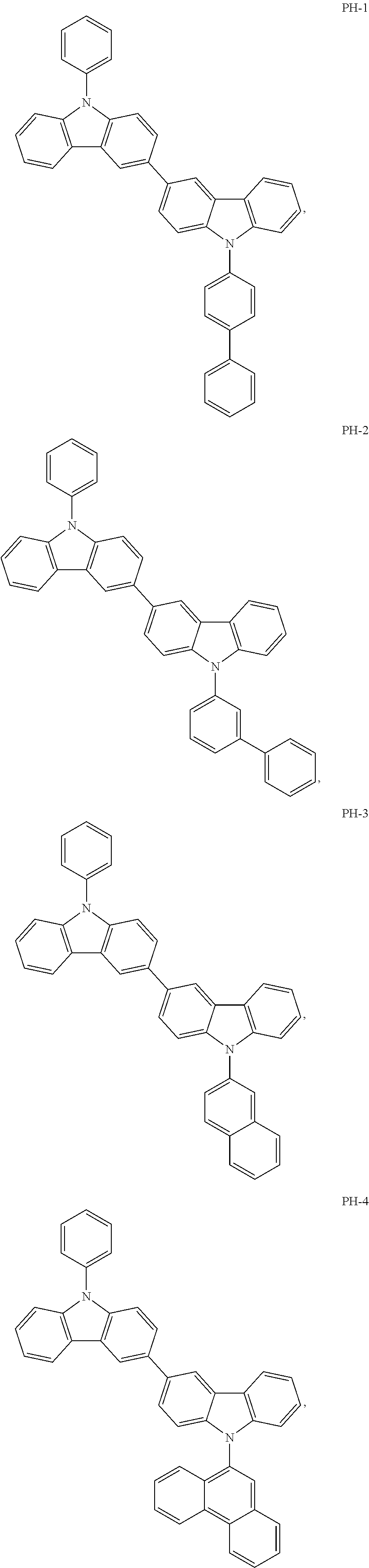 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cccc(-n3c4ccccc4c4cc(-c5ccc6c(c5)c5ccccc5n6-c5ccccc5)ccc43)c2)cc1 ; c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cc5ccccc5c5ccccc45)ccc32)cc1]

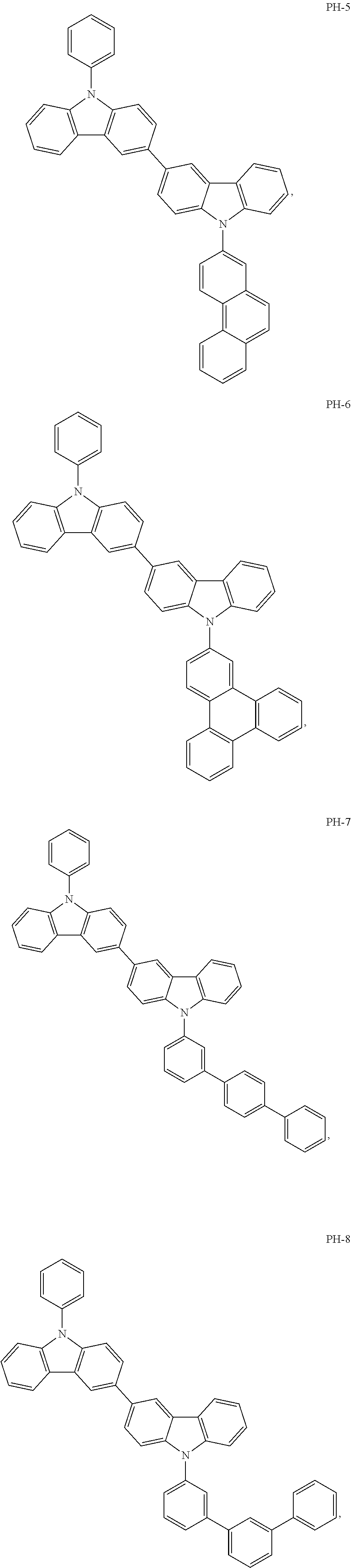 [SMILES: c1ccc(-n2c3ccccc3c3cc(-c4ccc5c(c4)c4ccccc4n5-c4ccc5c(ccc6ccccc65)c4)ccc32)cc1 ; c1ccc(-n2c3ccccc3c3cc(-c4ccc5c(c4)c4ccccc4n5-c4ccc5c6ccccc6c6ccccc6c5c4)ccc32)cc1 ; c1ccc(-c2ccc(-c3cccc(-n4c5ccccc5c5cc(-c6ccc7c(c6)c6ccccc6n7-c6ccccc6)ccc54)c3)cc2)cc1 ; c1ccc(-c2cccc(-c3cccc(-n4c5ccccc5c5cc(-c6ccc7c(c6)c6ccccc6n7-c6ccccc6)ccc54)c3)c2)cc1]

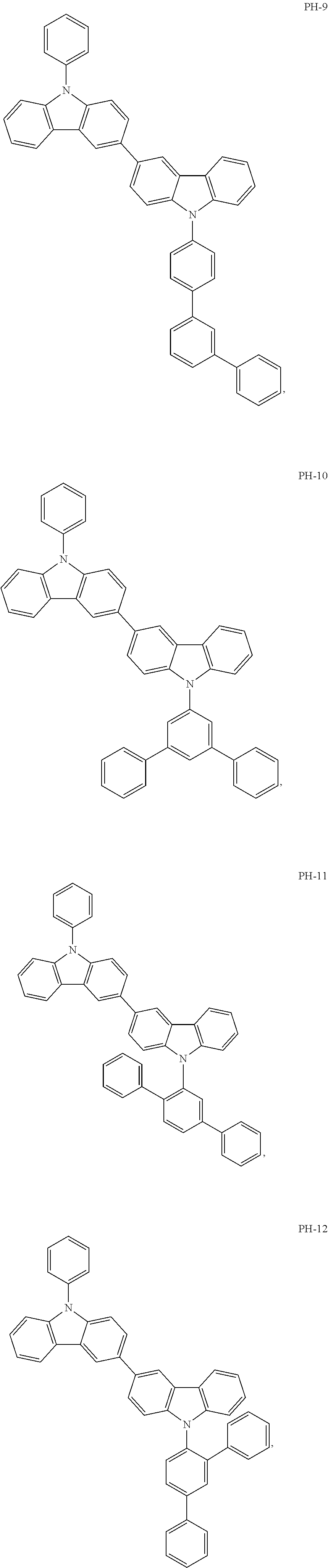 [SMILES: c1ccc(-c2cccc(-c3ccc(-n4c5ccccc5c5cc(-c6ccc7c(c6)c6ccccc6n7-c6ccccc6)ccc54)cc3)c2)cc1 ; c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2ccc(-c3ccccc3)c(-n3c4ccccc4c4cc(-c5ccc6c(c5)c5ccccc5n6-c5ccccc5)ccc43)c2)cc1 ; c1ccc(-c2ccc(-n3c4ccccc4c4cc(-c5ccc6c(c5)c5ccccc5n6-c5ccccc5)ccc43)c(-c3ccccc3)c2)cc1]

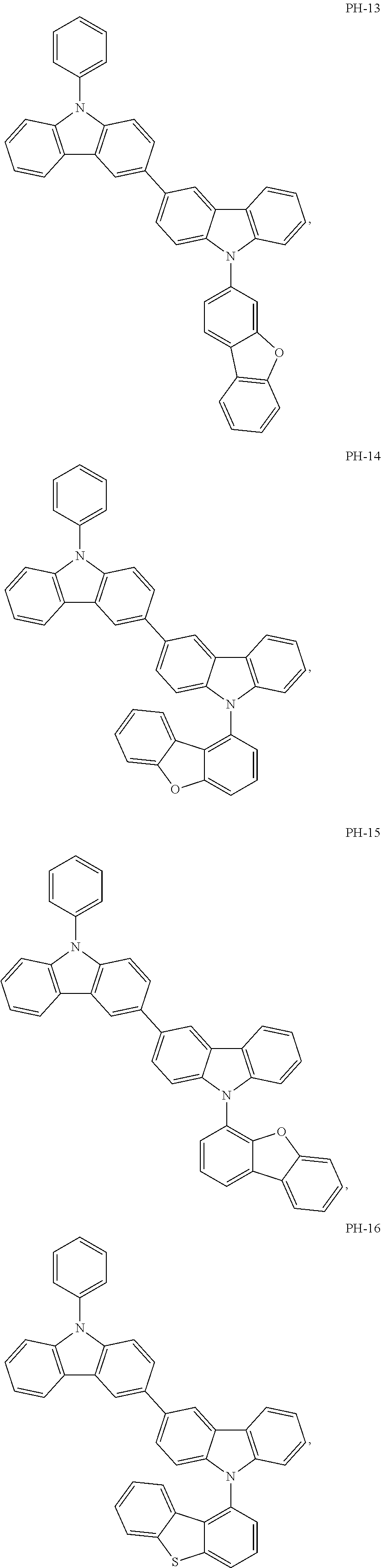 [SMILES: c1ccc(-n2c3ccccc3c3cc(-c4ccc5c(c4)c4ccccc4n5-c4ccc5c(c4)oc4ccccc45)ccc32)cc1 ; c1ccc(-n2c3ccccc3c3cc(-c4ccc5c(c4)c4ccccc4n5-c4cccc5oc6ccccc6c45)ccc32)cc1 ; c1ccc(-n2c3ccccc3c3cc(-c4ccc5c(c4)c4ccccc4n5-c4cccc5c4oc4ccccc45)ccc32)cc1 ; c1ccc(-n2c3ccccc3c3cc(-c4ccc5c(c4)c4ccccc4n5-c4cccc5sc6ccccc6c45)ccc32)cc1]

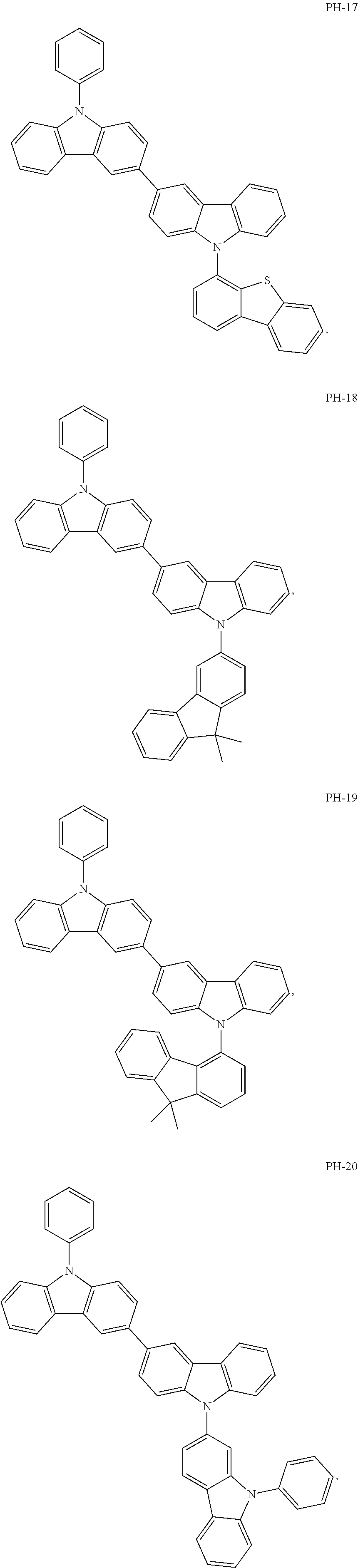 [SMILES: c1ccc(-n2c3ccccc3c3cc(-c4ccc5c(c4)c4ccccc4n5-c4cccc5c4sc4ccccc45)ccc32)cc1 ; CC1(C)c2ccccc2-c2cc(-n3c4ccccc4c4cc(-c5ccc6c(c5)c5ccccc5n6-c5ccccc5)ccc43)ccc21 ; CC1(C)c2ccccc2-c2c(-n3c4ccccc4c4cc(-c5ccc6c(c5)c5ccccc5n6-c5ccccc5)ccc43)cccc21 ; c1ccc(-n2c3ccccc3c3cc(-c4ccc5c(c4)c4ccccc4n5-c4ccc5c6ccccc6n(-c6ccccc6)c5c4)ccc32)cc1]

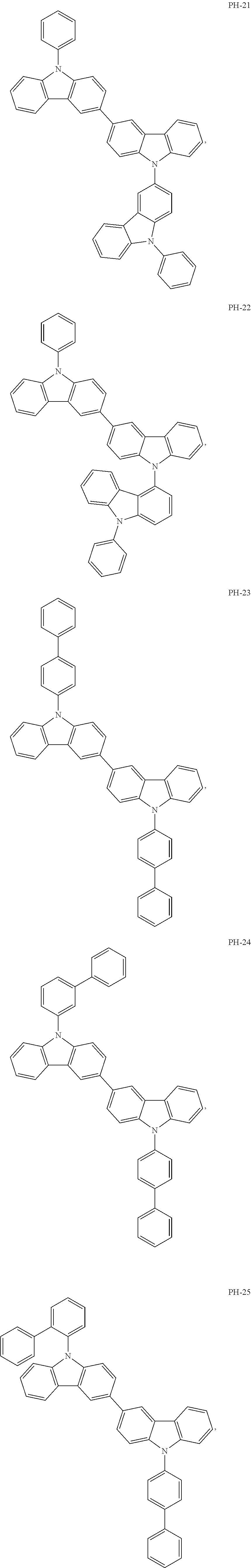 [SMILES: c1ccc(-n2c3ccccc3c3cc(-c4ccc5c(c4)c4ccccc4n5-c4ccc5c(c4)c4ccccc4n5-c4ccccc4)ccc32)cc1 ; c1ccc(-n2c3ccccc3c3cc(-c4ccc5c(c4)c4ccccc4n5-c4cccc5c4c4ccccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5-c5ccccc5)ccc43)cc2)cc1]

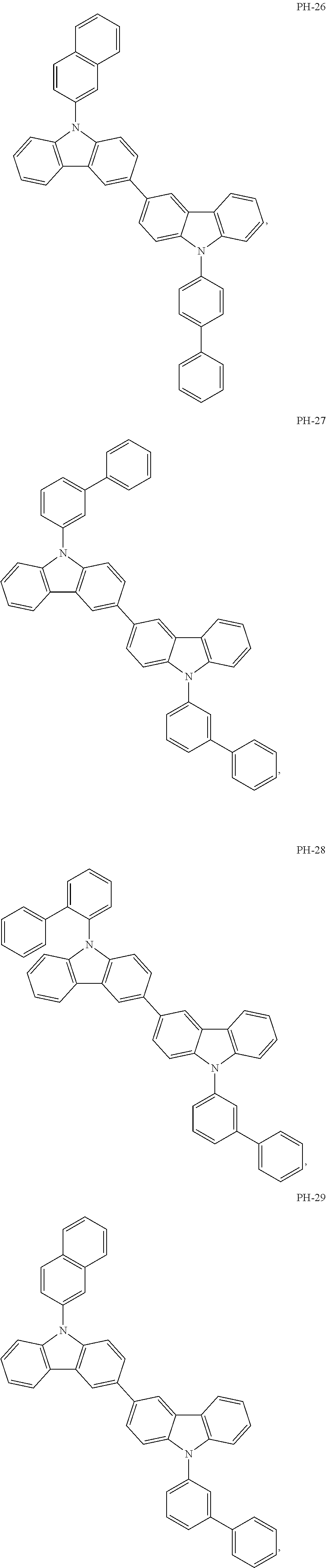 [SMILES: c1ccc(-c2ccc(-n3c4ccccc4c4cc(-c5ccc6c(c5)c5ccccc5n6-c5ccc6ccccc6c5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1 ; c1ccc(-c2cccc(-n3c4ccccc4c4cc(-c5ccc6c(c5)c5ccccc5n6-c5ccc6ccccc6c5)ccc43)c2)cc1]

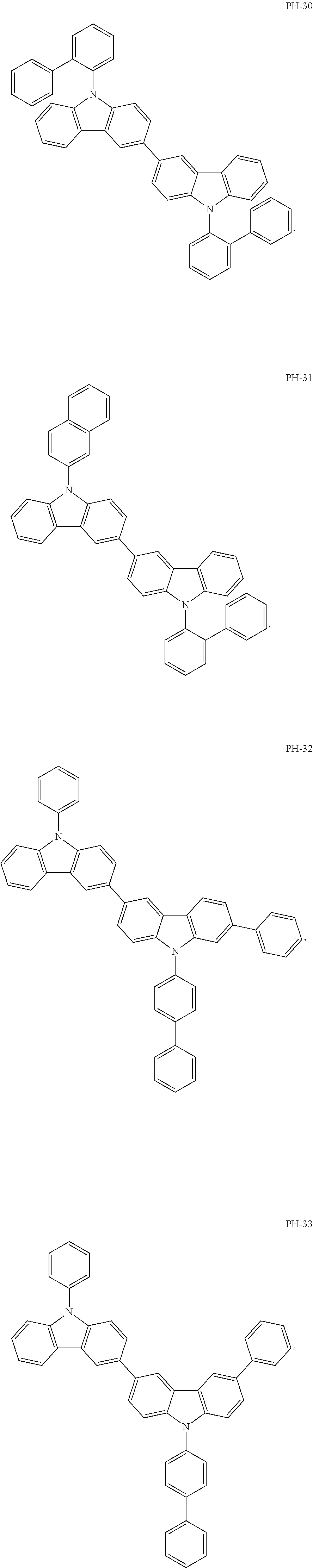 [SMILES: c1ccc(-c2ccccc2-n2c3ccccc3c3cc(-c4ccc5c(c4)c4ccccc4n5-c4ccccc4-c4ccccc4)ccc32)cc1 ; c1ccc(-c2ccccc2-n2c3ccccc3c3cc(-c4ccc5c(c4)c4ccccc4n5-c4ccc5ccccc5c4)ccc32)cc1 ; c1ccc(-c2ccc(-n3c4ccc(-c5ccc6c(c5)c5ccccc5n6-c5ccccc5)cc4c4ccc(-c5ccccc5)cc43)cc2)cc1 ; c1ccc(-c2ccc(-n3c4ccc(-c5ccccc5)cc4c4cc(-c5ccc6c(c5)c5ccccc5n6-c5ccccc5)ccc43)cc2)cc1]

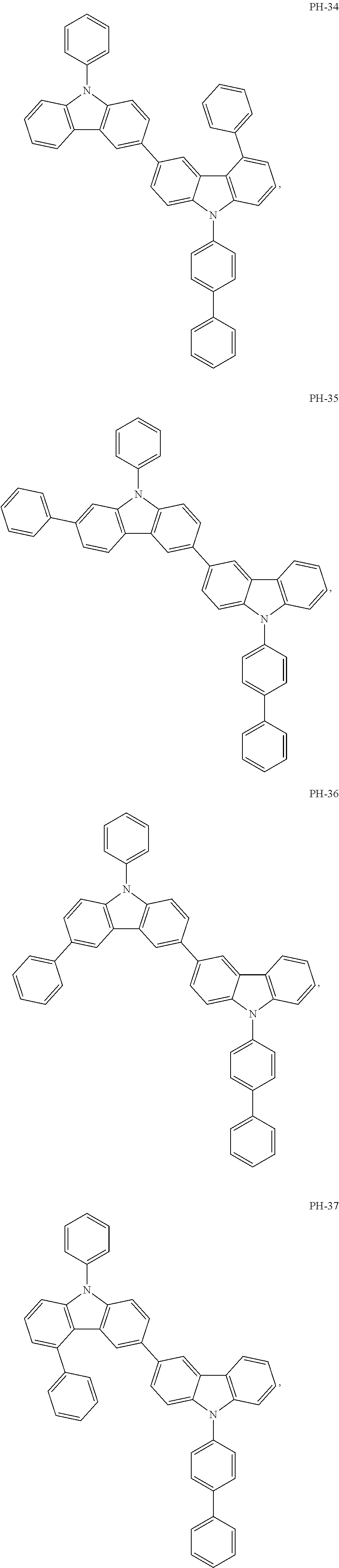 [SMILES: c1ccc(-c2ccc(-n3c4ccc(-c5ccc6c(c5)c5ccccc5n6-c5ccccc5)cc4c4c(-c5ccccc5)cccc43)cc2)cc1 ; c1ccc(-c2ccc(-n3c4ccccc4c4cc(-c5ccc6c(c5)c5ccc(-c7ccccc7)cc5n6-c5ccccc5)ccc43)cc2)cc1 ; c1ccc(-c2ccc(-n3c4ccccc4c4cc(-c5ccc6c(c5)c5cc(-c7ccccc7)ccc5n6-c5ccccc5)ccc43)cc2)cc1 ; c1ccc(-c2ccc(-n3c4ccccc4c4cc(-c5ccc6c(c5)c5c(-c7ccccc7)cccc5n6-c5ccccc5)ccc43)cc2)cc1]

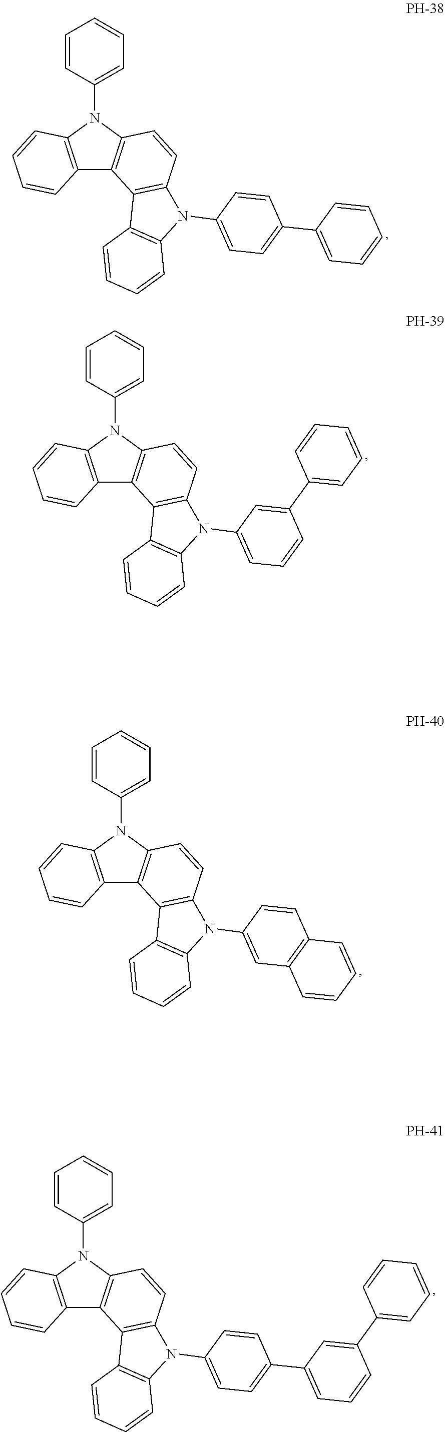

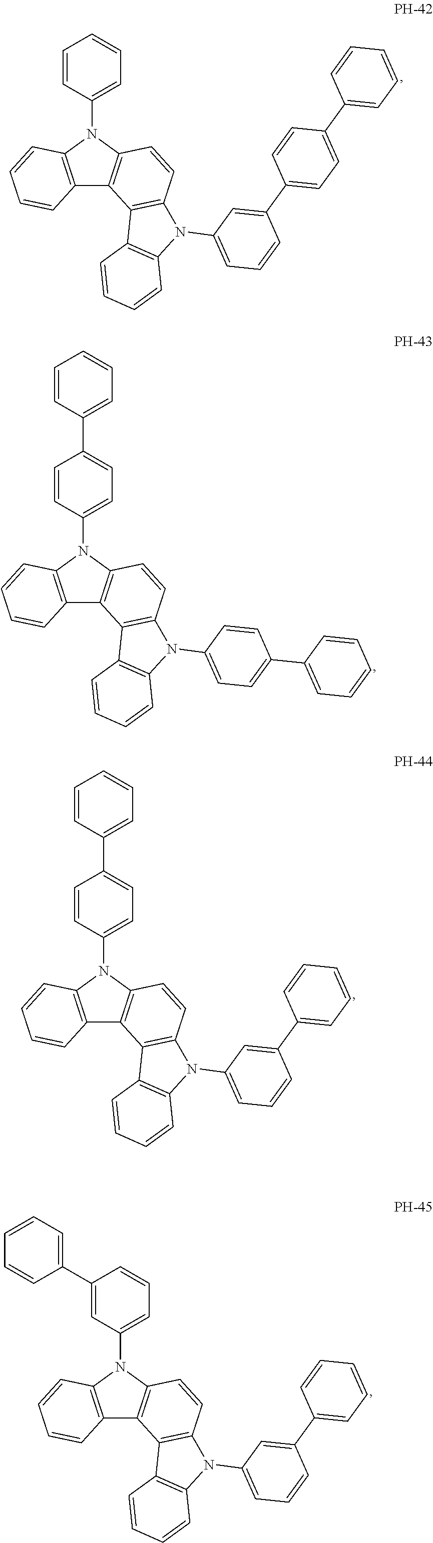 [SMILES: c1ccc(-c2ccc(-c3cccc(-n4c5ccccc5c5c6c7ccccc7n(-c7ccccc7)c6ccc54)c3)cc2)cc1 ; c1ccc(-c2ccc(-n3c4ccccc4c4c5c6ccccc6n(-c6ccc(-c7ccccc7)cc6)c5ccc43)cc2)cc1 ; c1ccc(-c2ccc(-n3c4ccccc4c4c5c6ccccc6n(-c6cccc(-c7ccccc7)c6)c5ccc43)cc2)cc1 ; c1ccc(-c2cccc(-n3c4ccccc4c4c5c6ccccc6n(-c6cccc(-c7ccccc7)c6)c5ccc43)c2)cc1]

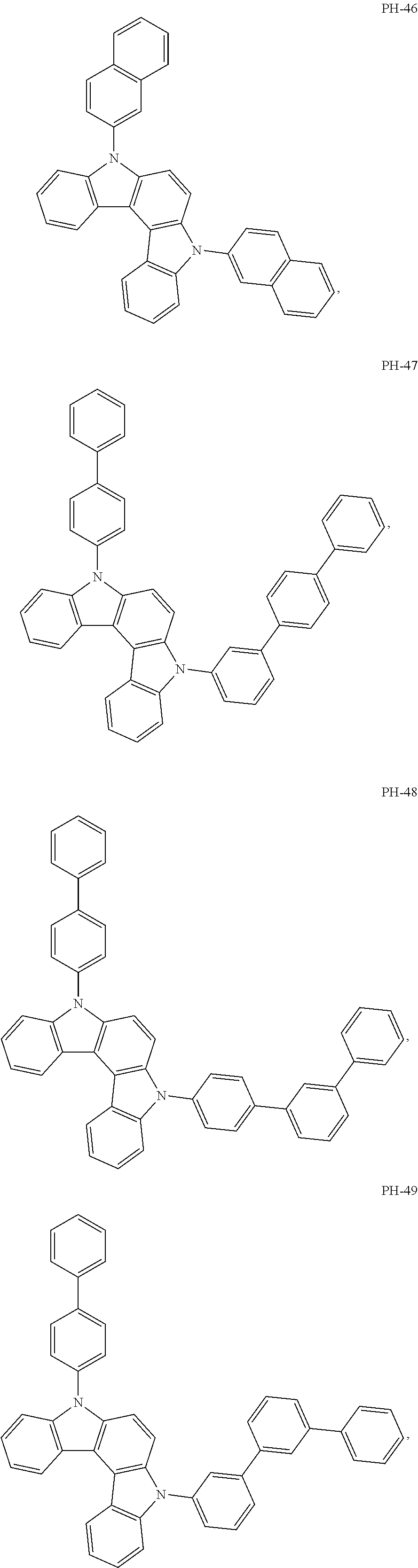 [SMILES: c1ccc2cc(-n3c4ccccc4c4c5c6ccccc6n(-c6ccc7ccccc7c6)c5ccc43)ccc2c1 ; c1ccc(-c2ccc(-c3cccc(-n4c5ccccc5c5c6c7ccccc7n(-c7ccc(-c8ccccc8)cc7)c6ccc54)c3)cc2)cc1 ; c1ccc(-c2ccc(-n3c4ccccc4c4c5c6ccccc6n(-c6ccc(-c7cccc(-c8ccccc8)c7)cc6)c5ccc43)cc2)cc1 ; c1ccc(-c2ccc(-n3c4ccccc4c4c5c6ccccc6n(-c6cccc(-c7cccc(-c8ccccc8)c7)c6)c5ccc43)cc2)cc1]

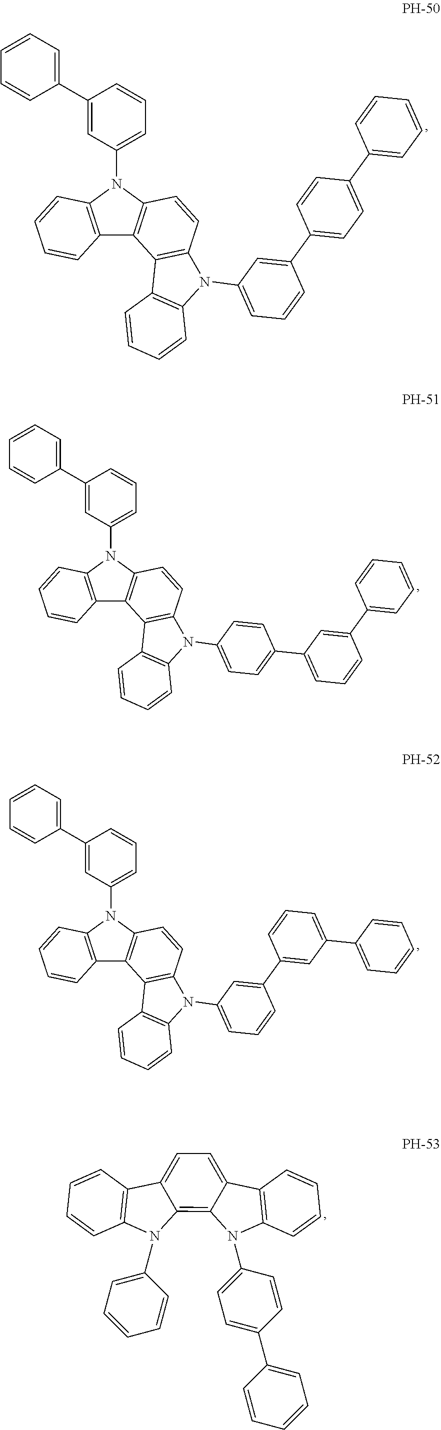 [SMILES: c1ccc(-c2ccc(-c3cccc(-n4c5ccccc5c5c6c7ccccc7n(-c7cccc(-c8ccccc8)c7)c6ccc54)c3)cc2)cc1 ; c1ccc(-c2cccc(-c3ccc(-n4c5ccccc5c5c6c7ccccc7n(-c7cccc(-c8ccccc8)c7)c6ccc54)cc3)c2)cc1 ; c1ccc(-c2cccc(-c3cccc(-n4c5ccccc5c5c6c7ccccc7n(-c7cccc(-c8ccccc8)c7)c6ccc54)c3)c2)cc1 ; c1ccc(-c2ccc(-n3c4ccccc4c4ccc5c6ccccc6n(-c6ccccc6)c5c43)cc2)cc1]

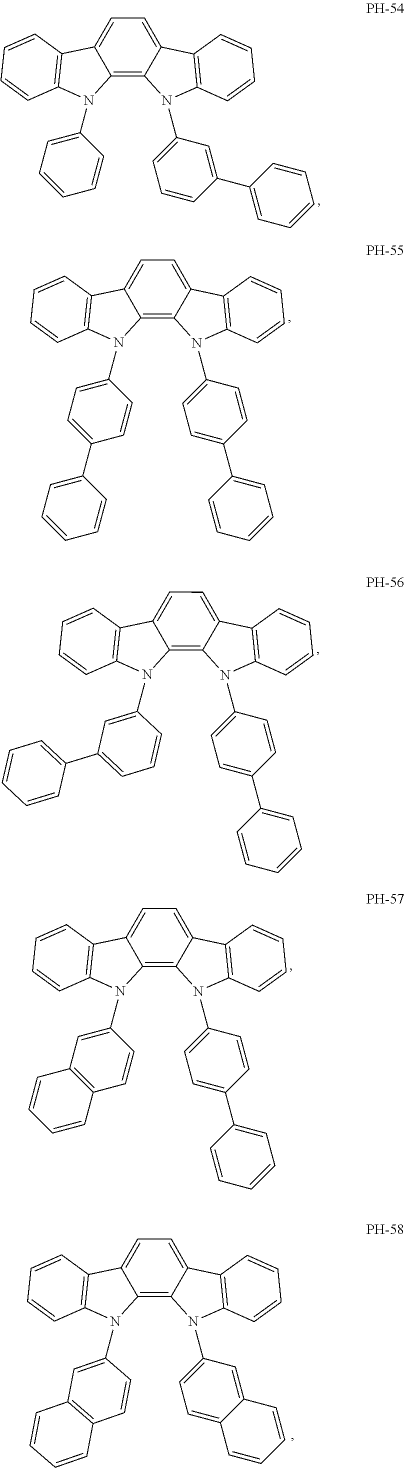 [SMILES: c1ccc(-c2cccc(-n3c4ccccc4c4ccc5c6ccccc6n(-c6ccccc6)c5c43)c2)cc1 ; c1ccc(-c2ccc(-n3c4ccccc4c4ccc5c6ccccc6n(-c6ccc(-c7ccccc7)cc6)c5c43)cc2)cc1 ; c1ccc(-c2ccc(-n3c4ccccc4c4ccc5c6ccccc6n(-c6cccc(-c7ccccc7)c6)c5c43)cc2)cc1 ; c1ccc(-c2ccc(-n3c4ccccc4c4ccc5c6ccccc6n(-c6ccc7ccccc7c6)c5c43)cc2)cc1 ; c1ccc2cc(-n3c4ccccc4c4ccc5c6ccccc6n(-c6ccc7ccccc7c6)c5c43)ccc2c1]

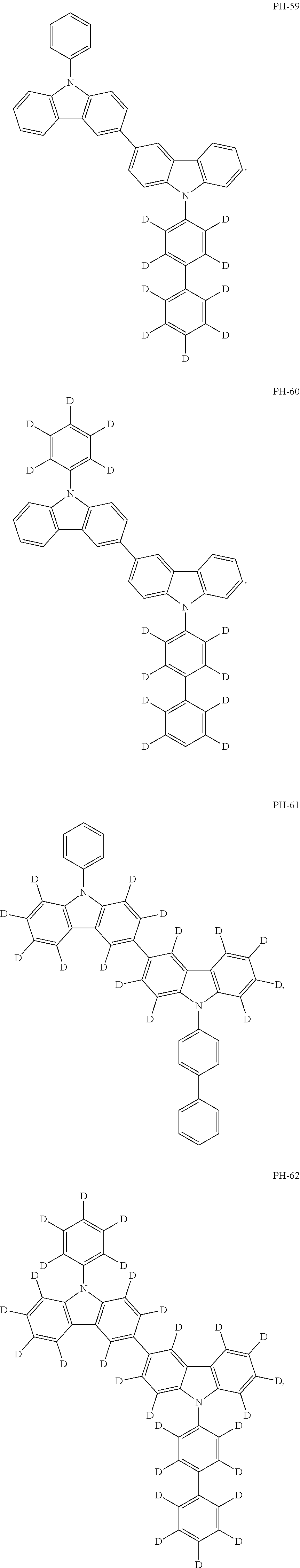

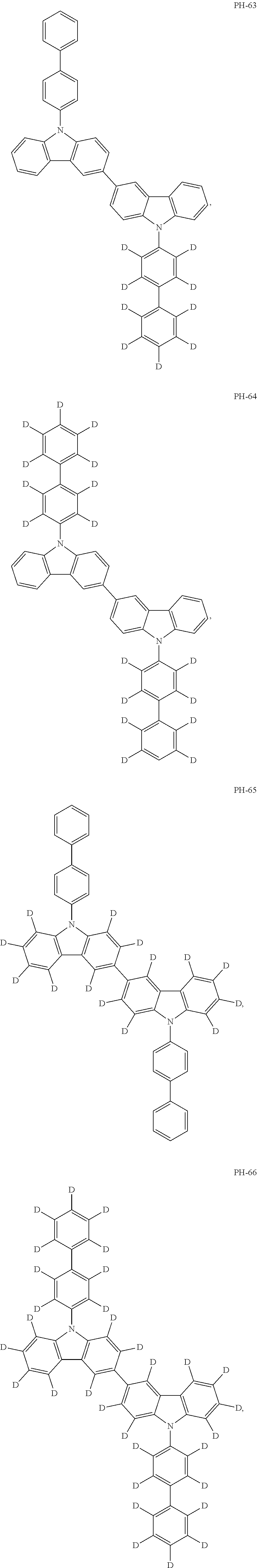

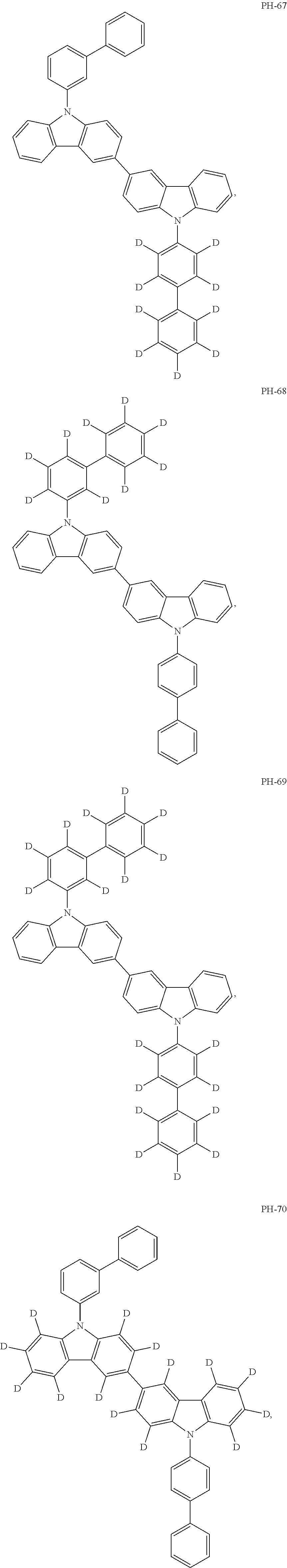

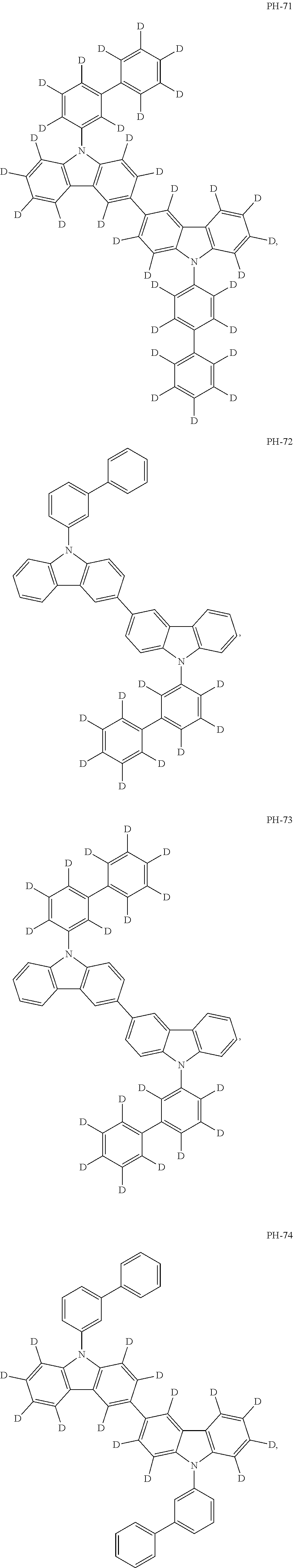

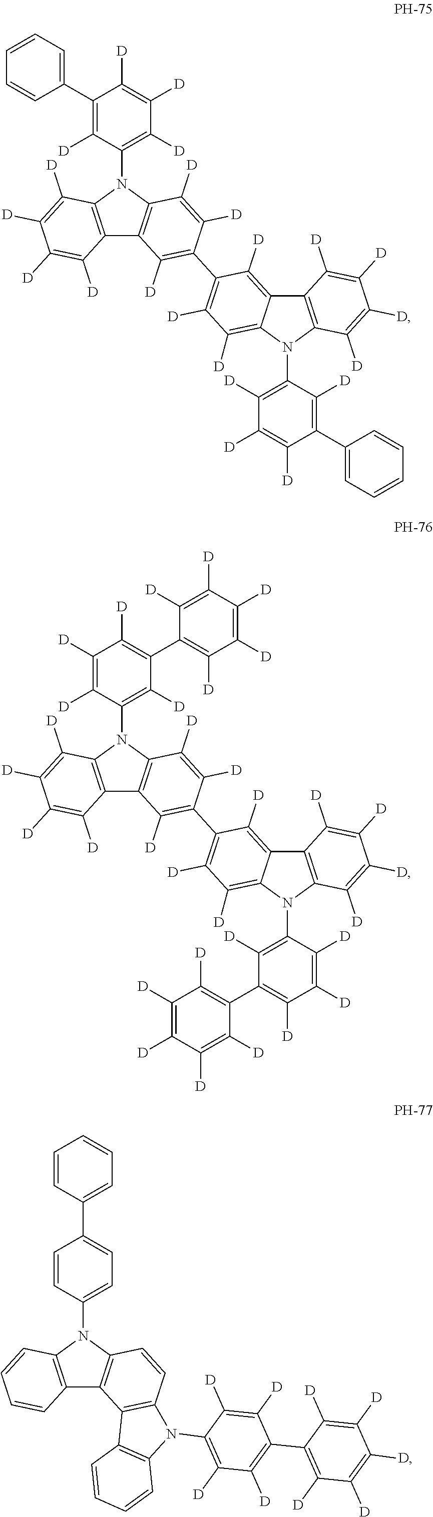

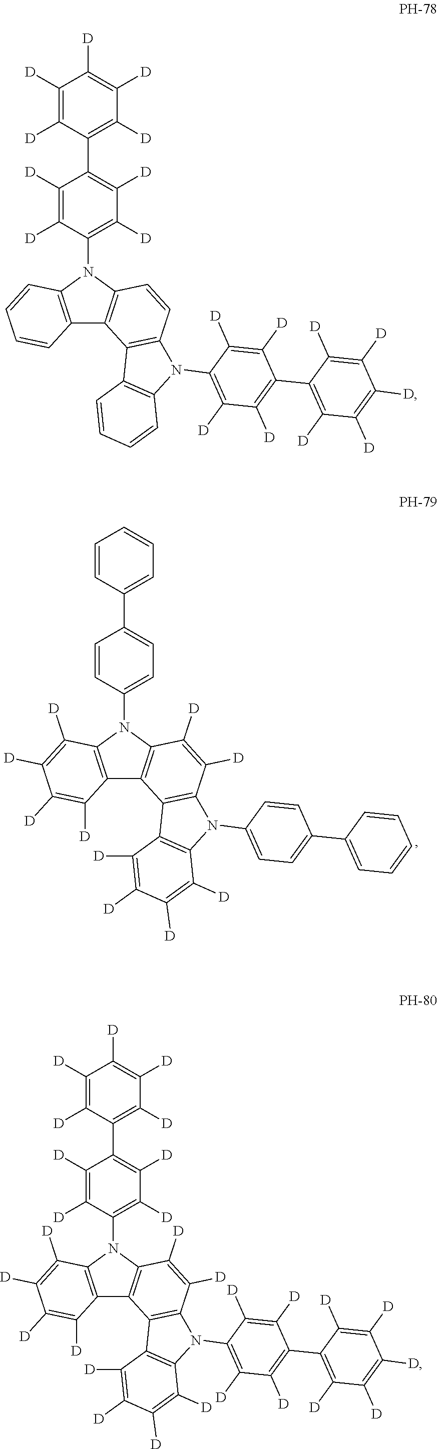

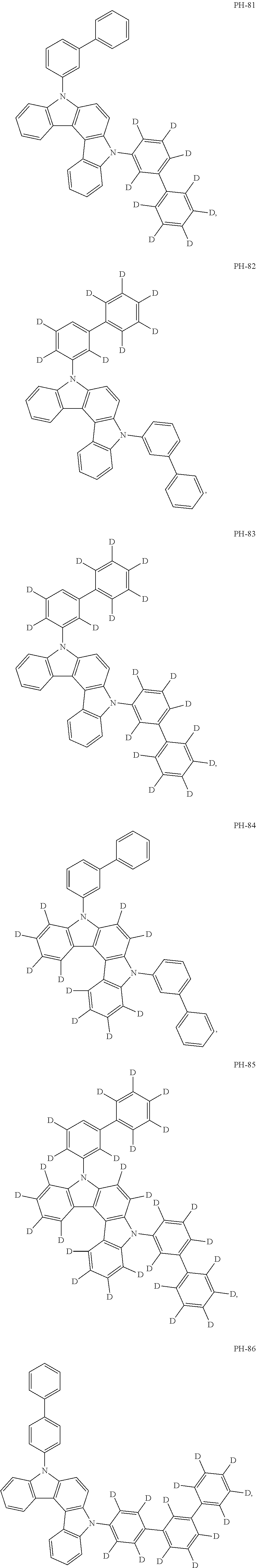

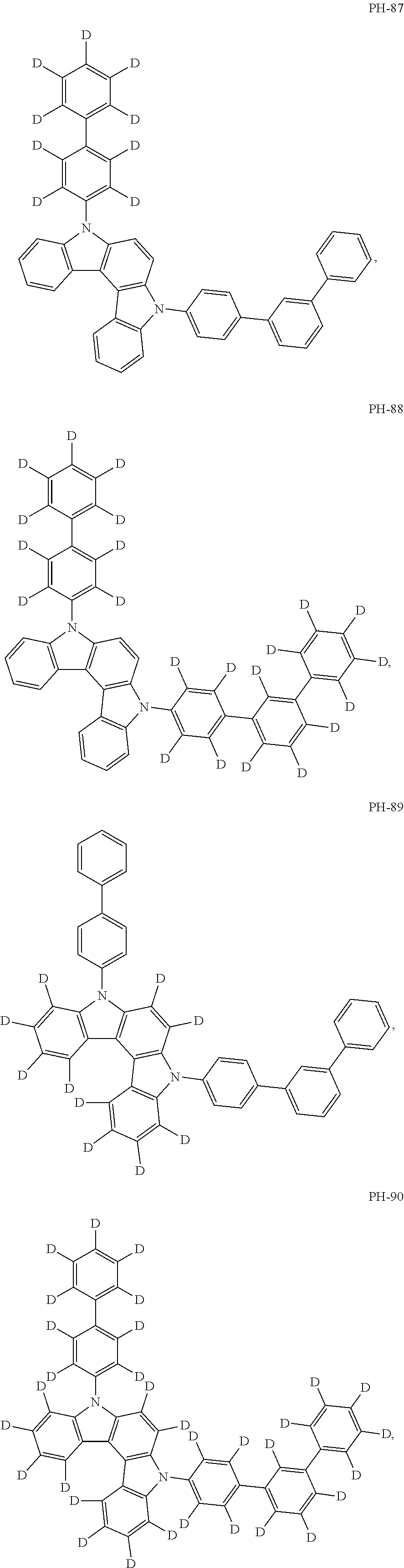

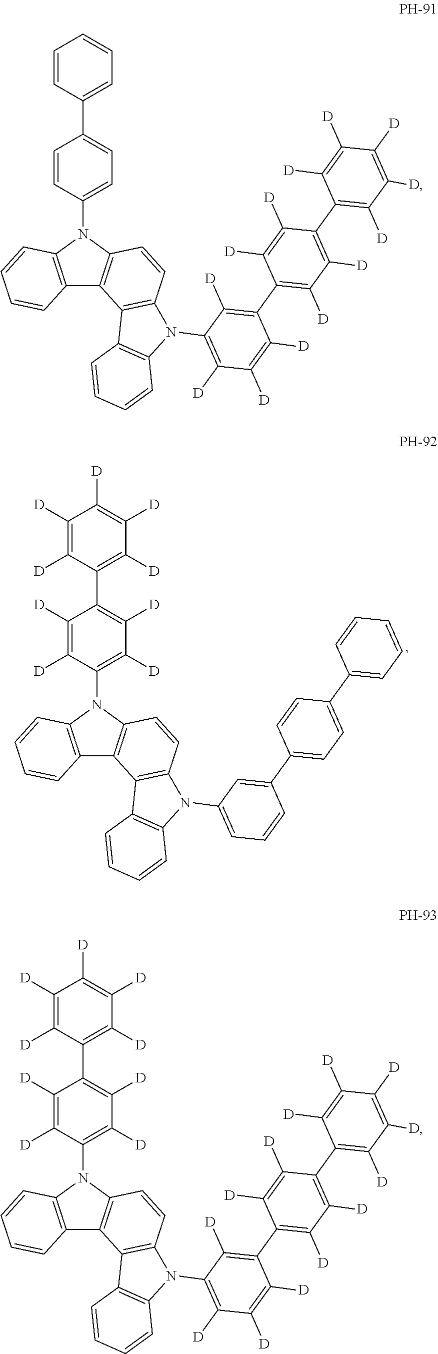

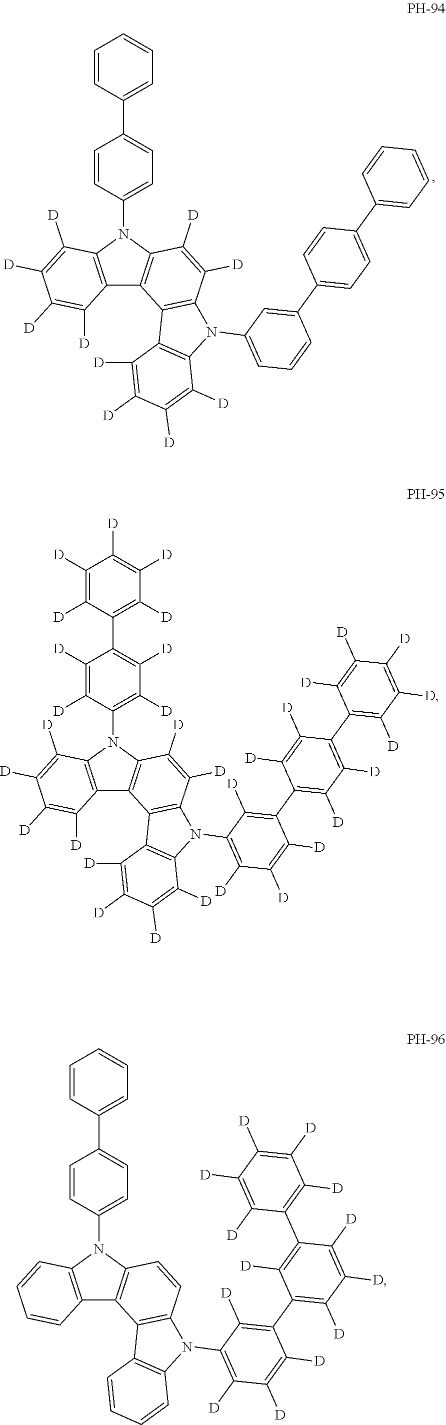

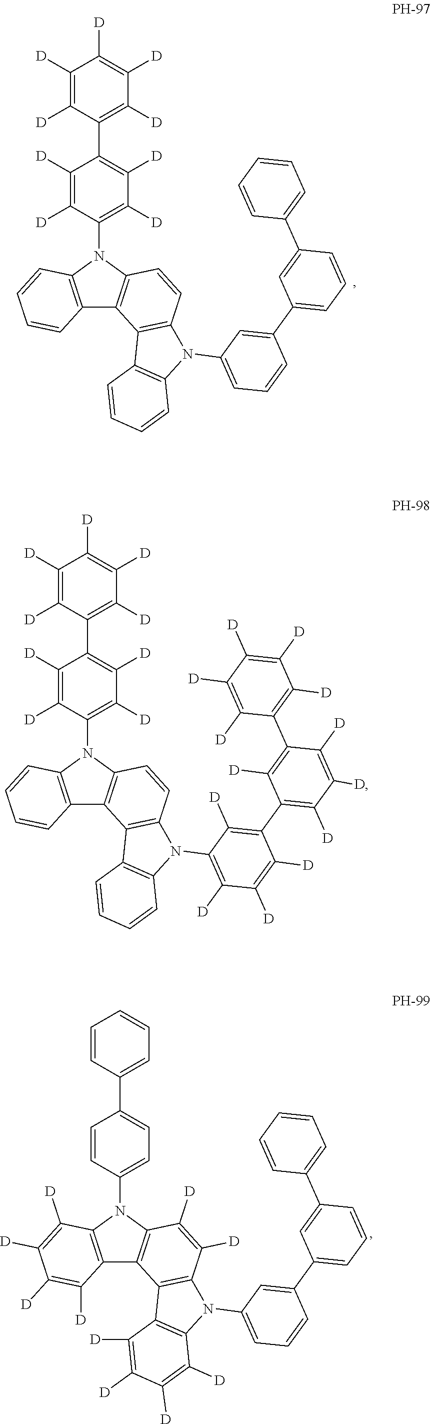

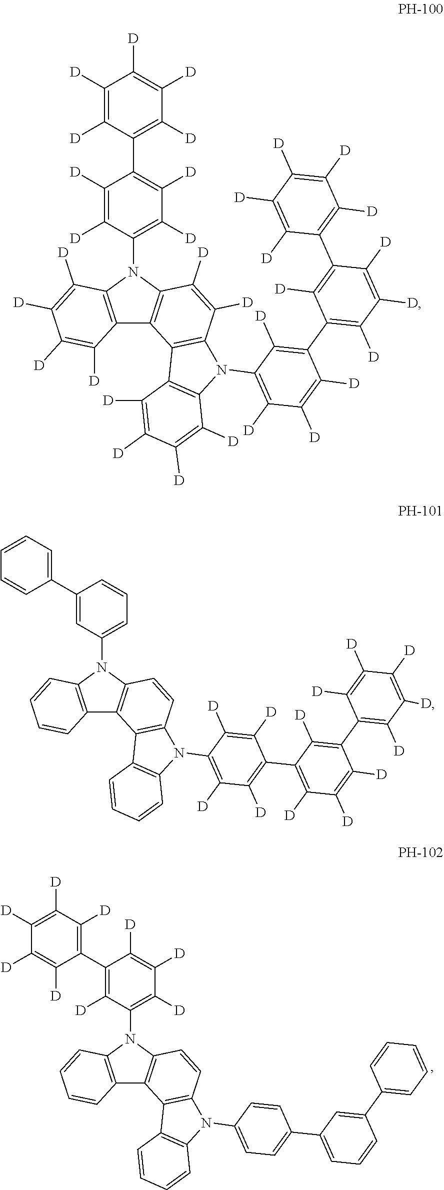

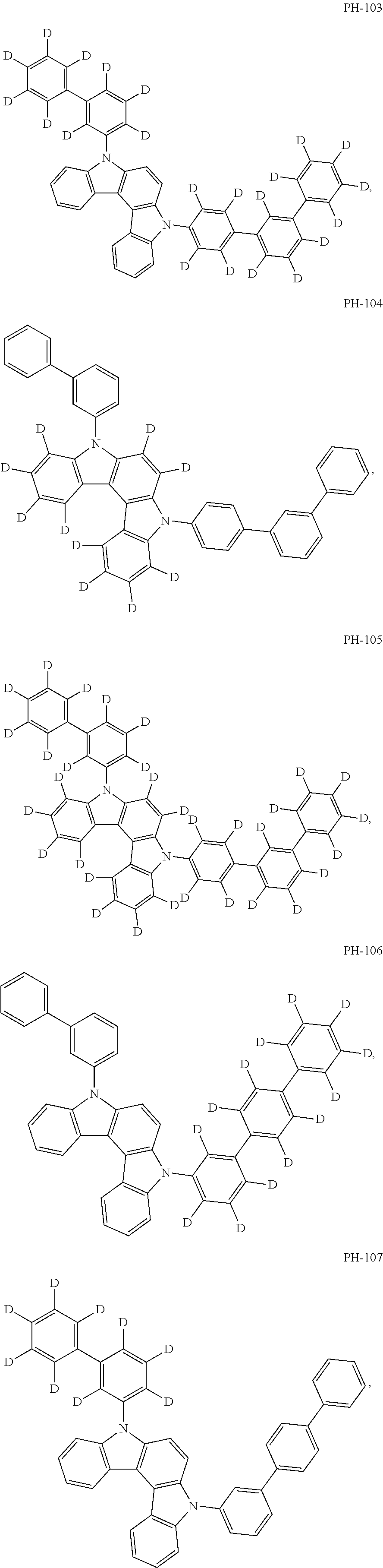

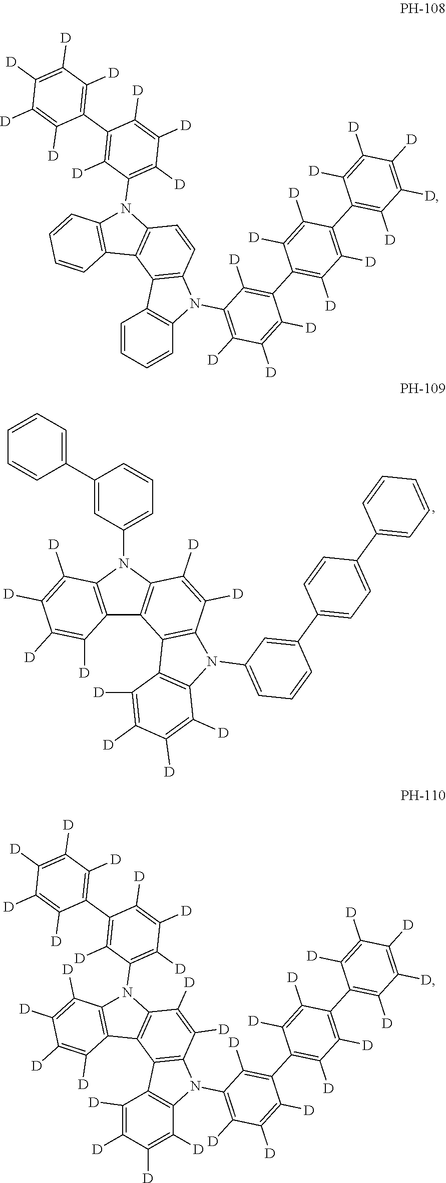

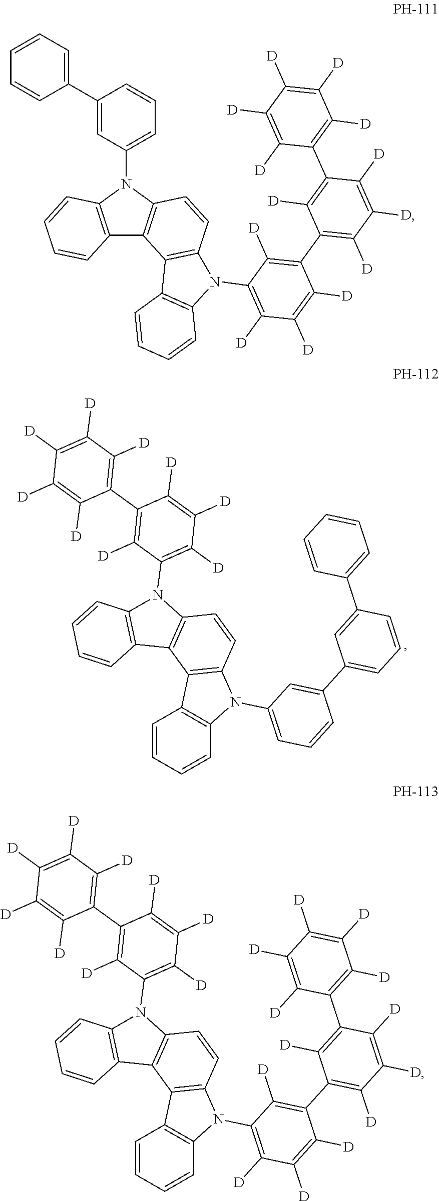

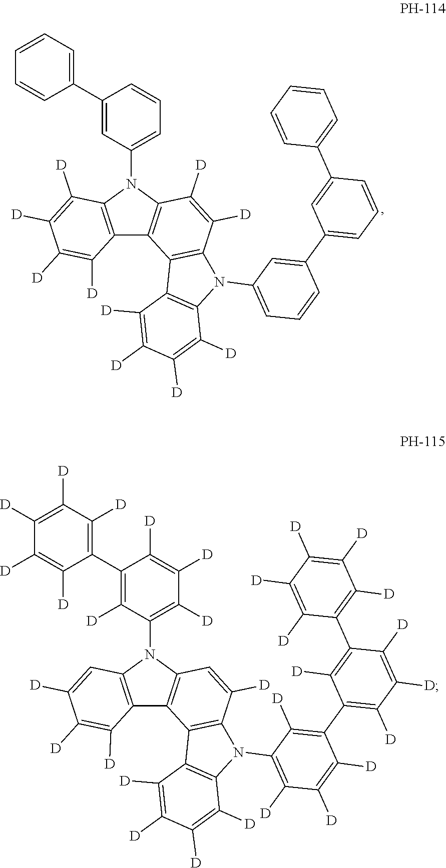

wherein hydrogens in Compound PH-1 to Compound PH-115 can be partially or fully substituted with deuterium.

According to an embodiment of the present disclosure, the organic electroluminescent device further comprises a hole injection layer. The hole injection layer may be a functional layer comprising a single material or a functional layer comprising multiple materials, wherein the comprised multiple materials are most commonly used as hole transporting materials doped with a certain proportion of p-type conductive doping material. Common p-type doping materials comprise

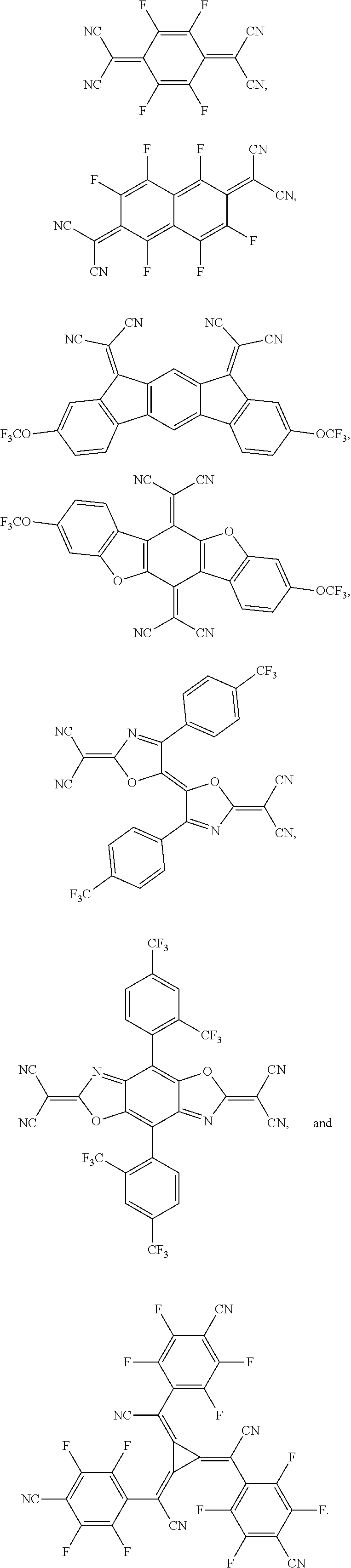

According to another embodiment of the present disclosure, in the emissive layer, the metal complex is doped in the first host compound and the second host compound, and the weight of the metal complex accounts for 1% to 30% of the total weight of the emissive layer.

According to another embodiment of the present disclosure, the weight of the metal complex accounts for 3% to 13% of the total weight of the emissive layer.

According to another embodiment of the present disclosure, further disclosed is a compound combination comprising the metal complex comprising the ligand Lₐ having the structure of Formula 1A and the ligand L_{b} having the structure of Formula 1B in the preceding embodiments.

According to another embodiment of the present disclosure, further disclosed is a display assembly comprising the metal complex comprising the ligand Lₐ having the structure of Formula 1A and the ligand L_{b} having the structure of Formula 1B in the preceding embodiments or the electroluminescent device in the preceding embodiments.

Combination with Other Materials

The materials described in the present disclosure for a particular layer in an organic light-emitting device can be used in combination with various other materials present in the device. The combinations of these materials are described in more detail in U.S. Pat. Pub. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light-emitting device may be used in combination with a variety of other materials present in the device. For example, dopants disclosed herein may be used in combination with a wide variety of hosts, transport layers, blocking layers, injection layers, electrodes and other layers that may be present. The combination of these materials is described in detail in paragraphs 0080-0101 of U.S. Pat. Pub. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

### MATERIAL SYNTHESIS EXAMPLE

A method for preparing the compound of the present disclosure is not limited. Typically, the following compound is used as an example without limitation, and the synthesis route and preparation method thereof are described below.

### Synthesis Example 1

### Step One:

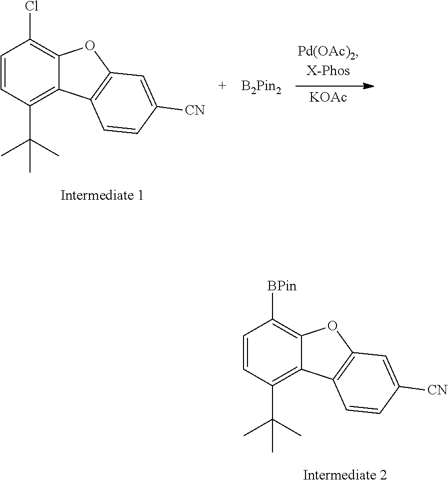

In a dry 500 mL round-bottom flask, Intermediate 1 (11.3 g, 39.8 mmol), bis(pinacolato)diboron (B₂Pin₂, 11.6 g, 45.77 mmol), X-Phos (1.14 g, 2.39 mmol), palladium acetate (266 mg, 1.19 mmol), potassium acetate (7.8 g, 79.6 mmol), and 100 mL of dioxane were added in sequence. The system was purged with N₂ three times, and heated to reflux, stirred, and reacted for 12 h under N₂ protection. After the reaction was completed, the reaction system was cooled to room temperature to obtain Intermediate 2 as a crude system directly used in the next step.

### Step Two:

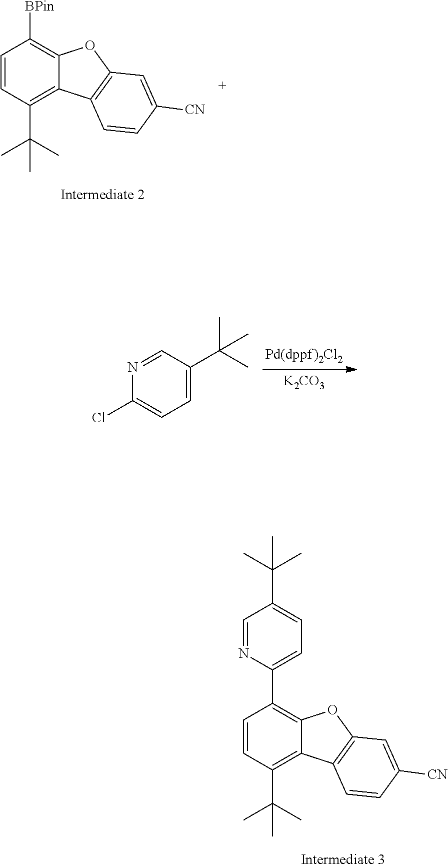

The reaction system of Intermediate 2 (crude product) in step one was cooled to room temperature, added with 50 mL of water, and then 2-chloro-5-t-butylpyridine (10.18 g, 59.7 mmol), Pd(dppf)Cl₂ (1.02 g, 1.39 mmol), potassium carbonate (10.98 g, 79.6 mmol), and 50 mL of dioxane were added. The system was purged with N₂ three times, and heated and reacted at 100° C. for 12 h under N₂ protection. After the reaction was completed, the reaction system was cooled to room temperature, extracted with dichloromethane, washed with saturated brine three times, dried over anhydrous magnesium sulfate, and concentrated under reduced pressure. The crude product was purified through column chromatography and eluted with PE:DCM at a gradient of 1:1 to 1:2 (v/v) to obtain Intermediate 3 as a brown-yellow solid (11.8 g, with a yield of 78%).

### Step Three:

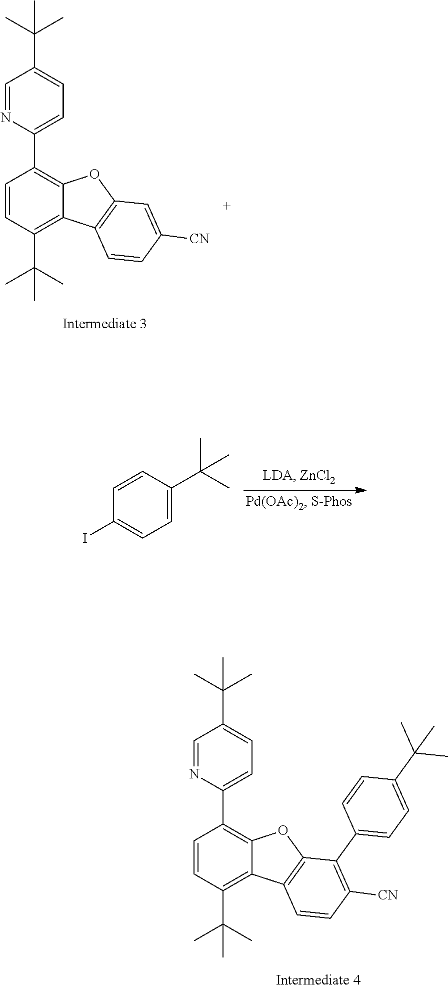 [SMILES: CC(C)(C)c1ccc(-c2ccc(C(C)(C)C)c3c2oc2cc(C#N)ccc23)nc1 ; CC(C)(C)c1ccc(I)cc1 ; "Pd(OAc)2, S-Phos" ; CC(C)(C)c1ccc(-c2c(C#N)ccc3c2oc2c(-c4ccc(C(C)(C)C)cn4)ccc(C(C)(C)C)c23)cc1]

At room temperature and under nitrogen protection, Intermediate 3 (11.8 g, 41.77 mmol) was added to a dry 500 mL two-necked flask, dissolved in tetrahydrofuran (TIF, 100 mL), and cooled to −78° C. in a dry ice/ethanol bath. Lithium diisopropylamide (LDA, 2.0 M, 28 ml) was added dropwise and reacted at −78° C. for 1 h. Then, a zinc chloride solution (2.0 M, 16 ml) was added at −78° C. After addition, the reaction system was returned to room temperature and reacted for 0.5 h to obtain an organic zinc reagent (solution A) for standby use. In another dry 500 mL two-necked flask, 4-t-butyliodobenzene (21.73 g, 83.54 mmol), palladium acetate (328 mg, 1.46 mmol), S-Phos (1.2 g, 2.92 mmol), and tetrahydrofuran (THF, 100 mL) were added in sequence and purged with N₂ three times. Under N₂ protection, the organic zinc reagent (solution A) was slowly added and stirred and reacted at room temperature for 12 h. After the reaction was completed, the reaction was quenched with a saturated ammonium chloride aqueous solution, extracted with dichloromethane, washed with saturated brine three times, dried over anhydrous magnesium sulfate, and concentrated under reduced pressure. The crude product was purified through column chromatography and eluted with PE:DCM at a gradient of 2:1 to 1:2 (v/v). The obtained product was beaten with PE:EA=10:1 (v/v) for 30 min and filtered to obtain Intermediate 4 (white solid, 8.3 g, with a yield of 39%).

### Step Four:

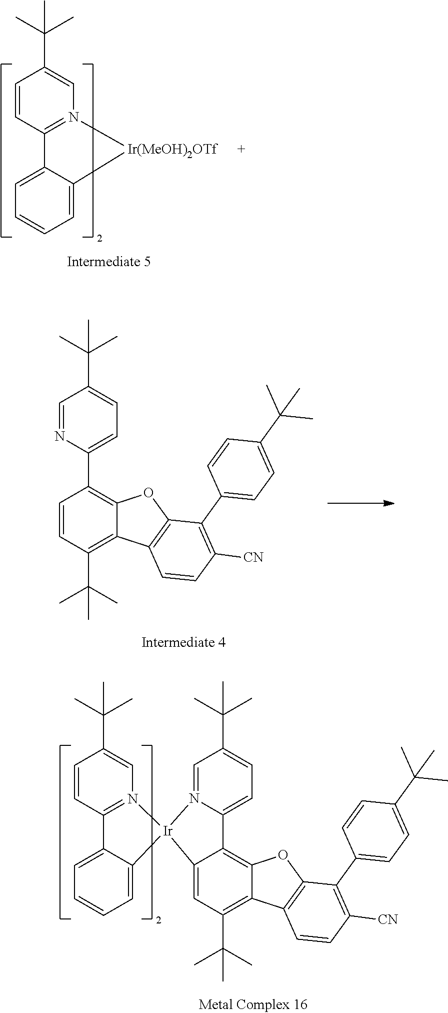

Intermediate 5 (2.1 g, 2.6 mmol), Intermediate 4 (1.5 g, 3.0 mmol), 2-ethoxyethanol (40 mL), and DMF (40 mL) were added to a dry 250 mL round-bottom flask in sequence and heated and reacted at 100° C. for 5 days under N₂ protection. After the reaction was cooled, the reaction system was concentrated under reduced pressure and purified through column chromatography to obtain Metal Complex 16 as a yellow solid (2.0 g, 1.8 mmol, with a yield of 68.3%). The product was determined as the target product with a molecular weight of 1126.5.

Those skilled in the art will appreciate that the above preparation method is merely exemplary. Those skilled in the art can obtain other compound structures of the present disclosure through the modifications of the preparation method.

### DEVICE EXAMPLE

### Device Example 1

A glass substrate having an indium tin oxide (ITO) anode with a thickness of 80 nm (with a sheet resistance of 14-20 Ω/sq and an emissive area of 0.04 cm²) was cleaned and treated with oxygen plasma and UV ozone. After the treatment, the substrate was dried in a glovebox to remove moisture. Then, the substrate was mounted on a substrate holder and placed in a vacuum chamber. The organic layers specified below were sequentially deposited through vacuum thermal evaporation on the ITO anode at a rate of 0.2-2 Angstroms per second and a vacuum degree of about 10⁻⁸ Torr. Compound HT and Compound PD were used as a hole injection layer (HIL, 97:3, 100 Å). Compound HT was used as a hole transporting layer (HTL, 1500 Å). Compound PH-1 was used as an electron blocking layer (EBL, 50 Å). Metal Complex 16 of the present disclosure was doped in Compound PH-95 and Compound H-106 and co-deposited for use as an emissive layer (EML, PH-95:H-106:Metal Complex 16=66:28:6, 400 Å). On the EML, Compound H-1 was used as a hole blocking layer (HBL, 50 Å). On the HBL, Compound ET and 8-hydroxyquinolinolato-lithium (Liq) were co-deposited as an electron transporting layer (ETL, 40:60, 350 Å). Finally, 8-hydroxyquinolinolato-lithium (Liq) was deposited for use as an electron injection layer with a thickness of 1 nm and Al was deposited for use as a cathode with a thickness of 120 nm. The device was transferred back to the glovebox and encapsulated with a glass lid and a moisture getter to complete the device.

### Device Comparative Example 1

Device Comparative Example 1 was implemented in the same manner as Device Example 1 except that in the emissive layer (EML), Metal Complex 16 of the present disclosure was replaced with Compound GDP1.

### Device Comparative Example 2

Device Comparative Example 2 was implemented in the same manner as Device Example 1 except that in the emissive layer (EML), Metal Complex 16 of the present disclosure was replaced with Compound GD2.

Detailed structures and thicknesses of layers of the devices are shown in the following table. A layer using more than one material is obtained by doping different compounds at their weight ratio as recorded.

TABLE 1
Device structures of Example 1 and Comparative Examples 1 and 2

| Device ID | HIL | HTL | EBL | EML | HBL | ETL |
|---|---|---|---|---|---|---|
| Example 1 | Compound | Compound | Compound | Compound | Compound | Compound |
| | HT:Compound | HT (1500 | PH-1 (50 | PH-95:Compound | H-1 (50 Å) | ET:Liq |
| | PD (97:3) | Å) | Å) | H-106:Metal | | (40:60) |
| | (100 Å) | | | Complex 16 | | (350 Å) |
| | | | | (66:28:6) (400 Å) | | |
| Comparative | Compound | Compound | Compound | Compound | Compound | Compound |
| Example 1 | HT:Compound | HT (1550 | PH-1 (50 | PH-95:Compound | H-1 (50 Å) | ET:Liq |
| | PD (97:3) | Å) | Å) | H-106:Compound | | (40:60) |
| | (100 Å) | | | GD1 (66:28:6) | | (350 Å) |
| | | | | (400 Å) | | |
| Comparative | Compound | Compound | Compound | Compound | Compound | Compound |
| Example 2 | HT:Compound | HT (1500 | PH-1 (50 | PH-95:Compound | H-1 (50 Å) | ET:Liq |
| | PD (97:3) | Å) | Å) | H-106:Compound | | (40:60) |
| | (100 Å) | | | GD2 (66:28:6) | | (350 Å) |
| | | | | (400 Å) | | |

The materials used in the devices have the following structures:

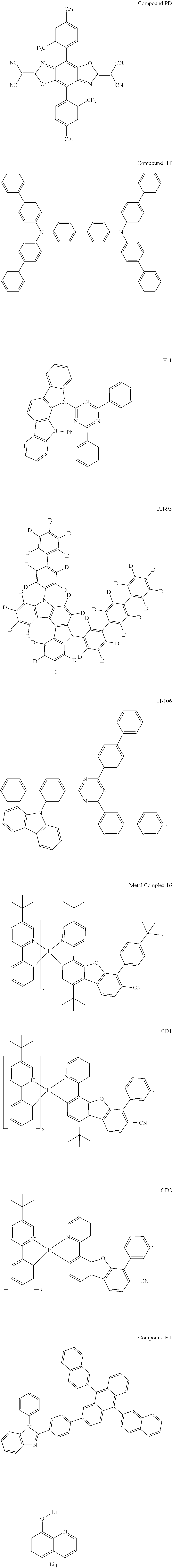

The current-voltage-luminance (IVL) characteristics of the devices were measured. The CIE data, maximum emission wavelength λₘₐₓ, full width at half maximum (FWHM), current efficiency (CE), and external quantum efficiency (EQE) of each device were measured at 1000 cd/m². The data are recorded and shown in Table 2.

TABLE 2
Device data of Example 1 and Comparative Examples 1 and 2

| | At 1000 cd/m² | | | | |
|---|---|---|---|---|---|
| Device ID | CIE (x, y) | λₘₐₓ (nm) | FWHM | CE (cd/m²) | EQE (%) |
| Example 1 | (0.266, | 520 | 25.6 | 102.1 | 27.2 |
| | 0.675) | | | | |
| Comparative | (0.285, | 522 | 27.8 | 94.2 | 24.7 |
| Example 1 | 0.667) | | | | |
| Comparative | (0.340, | 531 | 32.5 | 95.8 | 24.6 |
| Example 2 | 0.636) | | | | |

Discussion: As can be seen from the data in Table 2, Example 1 according to the present disclosure and Comparative Examples 1 and 2 had the same device structure. Example 1 differed from Comparative Examples 1 and 2 in that the ligand Lₐ of the metal complex has particular structural features of Rₙ₁, Rₙ₂, and Rₙ₃. At 1000 cd/m², compared with Comparative Examples 1 and 2, Example 1 had a FWHM narrowed by 2.2 nm and 6.9 nm respectively, EQE improved by 10.1% and 10.6% respectively, and CE up to 102.1 (improved by 8.4% and 6.6% respectively). The above data indicate that the metal complex with particular structures of Rₙ₁, Rₙ₂, and Rₙ₃ can reduce the FWHM, improve efficiency, and achieve a blue shift in the maximum emission wavelength λₘₐₓ.

The above data indicate that the metal complex of the present disclosure having particular structures can obtain more saturated green light emission, a narrower FWHM, and higher EQE than the comparative examples without the features of the present disclosure and can prepare devices with better performance, further improving the overall performance of the device on the basis of already high levels of device performance.

It should be understood that various embodiments described herein are merely examples and not intended to limit the scope of the present disclosure. Therefore, it is apparent to the persons skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. A metal complex having a general formula of M(Lₐ)ₘ(L_{b})₃₋ₘ, wherein m is selected from 1, 2, or 3; when m is selected from 1, two L_{b} are identical or different; when m is selected from 2 or 3, multiple Lₐ are identical or different;
the metal M is selected from a metal with a relative atomic mass greater than 40;
Lₐ has, at each occurrence identically or differently, a structure represented by Formula 1A, and L_{b} has, at each occurrence identically or differently, a structure represented by Formula 1B: 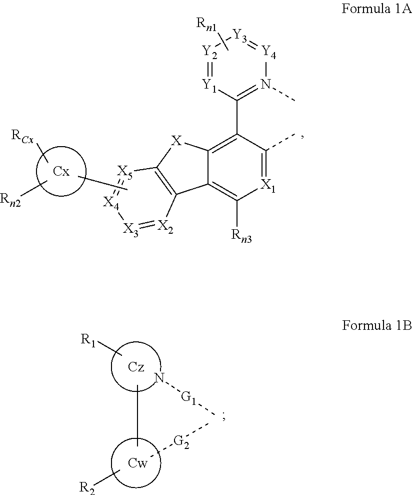
wherein X is, at each occurrence identically or differently, selected from O, S, or Se;
G₁ and G₂ are, at each occurrence identically or differently, selected from a single bond, O, or S;
the ring C_{X} is, at each occurrence identically or differently, selected from aryl having 6 to 24 ring atoms;
the ring Cz is, at each occurrence identically or differently, selected from heteroaryl having 5 to 24 ring atoms;
the ring Cw is, at each occurrence identically or differently, selected from aryl having 6 to 24 ring atoms, substituted or unsubstituted heteroaryl having 5 to 24 ring atoms, or a combination thereof;
X₁ is, at each occurrence identically or differently, selected from CRₓ or N; X₂ to X₅ are, at each occurrence identically or differently, selected from C, CRₓ, or N, and at least one of X₂ to X₅ is selected from C and joined to the ring C_{X}; Y₁ to Y₄ are, at each occurrence identically or differently, selected from C, CR_{y}, or N, and at least one of Y₁ to Y₄ is selected from C and joined to Rₙ₁;
R_{Cx} represents, at each occurrence identically or differently, mono-substitution, multiple substitutions, or non-substitution;
R₁ and R₂ represent, at each occurrence identically or differently, mono-substitution, multiple substitutions, or non-substitution;
Rₙ₁ and Rₙ₂ represent, at each occurrence identically or differently, mono-substitution or multiple substitutions;
R₁, R₂, R_{Cx}, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Rₙ₁ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, and combinations thereof;
Rₙ₂ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 10 to 30 carbon atoms, substituted or unsubstituted heteroaryl having 3 to 30 carbon atoms, substituted or unsubstituted alkylsilyl having 3 to 20 carbon atoms, and combinations thereof;
at least one of X₁ to X₅ is CRₓ, and the Rₓ is a group having at least one electron withdrawing group;
Rₙ₃ has a structure represented by Formula 2: 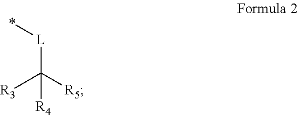
in Formula 2,
L is selected from the group consisting of: a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, and combinations thereof;
R₃, R₄, and R₅ are, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₓ, R_{Cx}, R_{y} can be optionally joined to form a ring;
adjacent substituents R₁, R₂ can be optionally joined to form a ring;
adjacent substituents R₃, R₄, and R₅ can be optionally joined to form a ring; and
“*” represents a position where Formula 2 is joined in Formula 1A.

2. The metal complex according to claim 1, wherein the electron withdrawing group is selected from the group consisting of: halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group, an aza-aromatic ring group, and any one of the following groups substituted with one or more of halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group, and an aza-aromatic ring group: alkyl having 1 to 20 carbon atoms, cycloalkyl having 3 to 20 ring carbon atoms, heteroalkyl having 1 to 20 carbon atoms, a heterocyclic group having 3 to 20 ring atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms, and combinations thereof;
preferably, the electron withdrawing group is selected from the group consisting of: F, CF₃, CHF₂, OCF₃, SF₅, SO₂CF₃, cyano, isocyano, SCN, OCN, pyrimidinyl, triazinyl, and combinations thereof.

3. The metal complex according to claim 1, wherein at least one of X₁ to X₅ is CRₓ, and the Rₓ is cyano or fluorine.

4. The metal complex according to claim 1, wherein L_{b} is, at each occurrence identically or differently, selected from any structure in the group consisting of the following: 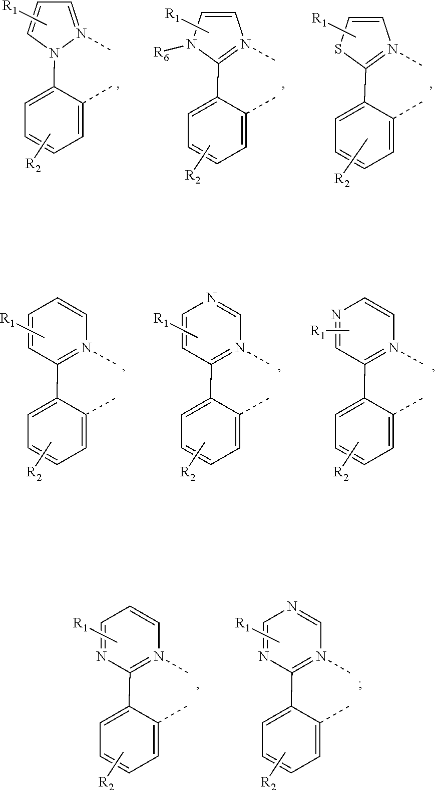
wherein
R₁ and R₂ represent, at each occurrence identically or differently, mono-substitution, multiple substitutions, or non-substitution;
R₁, R₂, and R₆ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R₁, R₂, R₆ can be optionally joined to form a ring.

5. The metal complex according to claim 3, wherein G₁ and G₂ are, at each occurrence identically or differently, selected from a single bond or O; preferably, G₁ and G₂ are each a single bond.

6. The metal complex according to claim 3, wherein the metal M is, at each occurrence identically or differently, selected from the group consisting of Cu, Ag, Au, Ru, Rh, Pd, Os, Ir, and Pt;
preferably, the metal M is, at each occurrence identically or differently, selected from Pt or Ir.

7. The metal complex according to claim 6, wherein the metal complex Ir(Lₐ)ₘ(L_{b})₃₋ₘ has a structure represented by Formula 2A or Formula 2B: 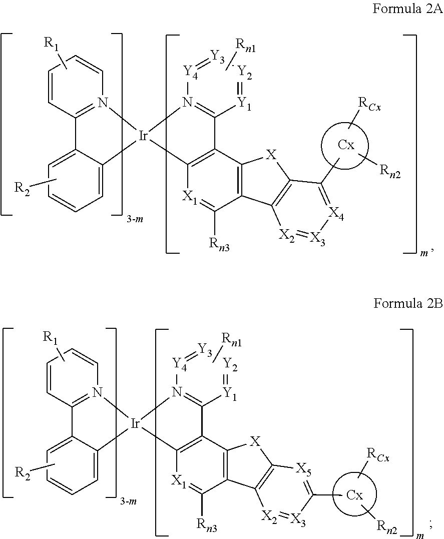
wherein m is selected from 1 or 2; preferably, m is selected from 1;
X is, at each occurrence identically or differently, selected from O, S, or Se;
the ring C_{X} is, at each occurrence identically or differently, selected from aryl having 6 to 24 ring atoms;
X₁ to X₅ are, at each occurrence identically or differently, selected from CRₓ or N;
Y₁ to Y₄ are, at each occurrence identically or differently, selected from C, CR_{y}, or N, and one of Y₁ to Y₄ is selected from C and joined to Rₙ₁;
R_{Cx} represents, at each occurrence identically or differently, mono-substitution, multiple substitutions, or non-substitution;
R₁ and R₂ represent, at each occurrence identically or differently, mono-substitution, multiple substitutions, or non-substitution;
Rₙ₁ and Rₙ₂ represent, at each occurrence identically or differently, mono-substitution or multiple substitutions;
R₁, R₂, R_{Cx}, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Rₙ₁ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, and combinations thereof;
Rₙ₂ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 10 to 30 carbon atoms, substituted or unsubstituted heteroaryl having 3 to 30 carbon atoms, substituted or unsubstituted alkylsilyl having 3 to 20 carbon atoms, and combinations thereof;
at least one of X₁ to X₅ is CRₓ, and the Rₓ is cyano or fluorine;
Rₙ₃ has a structure represented by Formula 2: 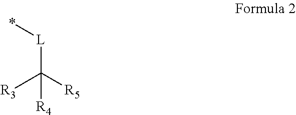
in Formula 2,
L is selected from the group consisting of: a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, and combinations thereof;
R₃, R₄, and R₅ are, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₓ, R_{Cx}, R_{y} can be optionally joined to form a ring;
adjacent substituents R₁, R₂ can be optionally joined to form a ring;
adjacent substituents R₃, R₄, and R₅ can be optionally joined to form a ring; and
“*” represents a position where Formula 2 is joined in Formula 1A.

8. The metal complex according to claim 3, wherein X is selected from O or S; preferably, X is selected from O.

9. The metal complex according to claim 1, wherein L is selected from a single bond or substituted or unsubstituted methylene.

10. The metal complex according to claim 3, wherein R₃, R₄, and R₅ are, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, cyano, and combinations thereof;
preferably, R₃, R₄, and R₅ are, at each occurrence identically or differently, selected from the group consisting of: substituted or unsubstituted alkyl having 1 to 6 carbon atoms, substituted or unsubstituted cycloalkyl having 3 to 6 ring carbon atoms, and combinations thereof.

11. The metal complex according to claim 3, wherein Rₙ₁ and Rₙ₂ are, at each occurrence identically or differently, selected from the group consisting of: halogen, substituted or unsubstituted alkyl having 1 to 6 carbon atoms, substituted or unsubstituted cycloalkyl having 3 to 6 ring carbon atoms, and combinations thereof;
preferably, Rₙ₁ is, at each occurrence identically or differently, selected from the group consisting of: fluorine, methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, phenyl, pyridyl, trimethylsilyl, carbazolyl, and combinations thereof;
preferably, Rₙ₂ is, at each occurrence identically or differently, selected from the group consisting of: methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, trimethylsilyl, and combinations thereof,
more preferably, Rₙ₁ is, at each occurrence identically or differently, selected from the group consisting of: fluorine, methyl, ethyl, propyl, isopropyl, n-butyl, isobutyl, neopentyl, t-butyl, and combinations thereof;
more preferably, Rₙ₂ is, at each occurrence identically or differently, selected from the group consisting of: fluorine, methyl, ethyl, propyl, isopropyl, n-butyl, isobutyl, neopentyl, t-butyl, and combinations thereof.

12. The metal complex according to claim 3, wherein Rₙ₃ is, at each occurrence identically or differently, selected from the group consisting of the following: 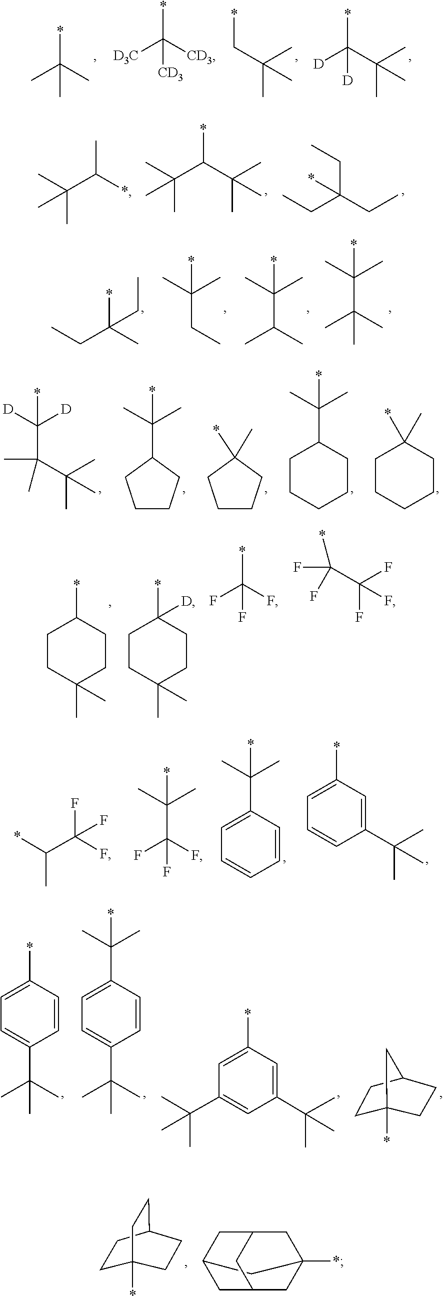
wherein optionally, hydrogens in the above Rₙ₃ can be partially or fully substituted with deuterium.

13. The metal complex according to claim 3, wherein at least one of X₁ to X₅ is N, and/or at least one of Y₁ to Y₄ is N.

14. The metal complex according to claim 3, wherein X₁ to X₅ are, at each occurrence identically or differently, selected from CRₓ, and/or Y₁ to Y₄ are, at each occurrence identically or differently, selected from C or CR_{y}, and at least one of Y₁ to Y₄ is selected from C and joined to Rₙ₁.

15. The metal complex according to claim 3, wherein X₁ to X₅ are, at each occurrence identically or differently, selected from CRₓ, and/or Y₃ and Y₄ are, at each occurrence identically or differently, selected from C or CR_{y}, and at least one of Y₃ and Y₄ is selected from C and joined to Rₙ₁; preferably, Y₃ is selected from C and joined to Rₙ₁; and
Rₓ, R_{Cx}, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, cyano, and combinations thereof;
preferably, X₁ to X₅ are, at each occurrence identically or differently, selected from CRₓ, and/or Y₁, Y₂, and Y₄ are, at each occurrence identically or differently, selected from CR_{y}; and Rₓ and R_{y} are, at each occurrence identically or differently, selected from the group consisting of: hydrogen, deuterium, halogen, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, cyano, and combinations thereof;
more preferably, X₁ to X₅ are, at each occurrence identically or differently, selected from CRₓ, and/or Y₁, Y₂, and Y₄ are, at each occurrence identically or differently, selected from CR_{y}; and Rₓ and R_{y} are, at each occurrence identically or differently, selected from the group consisting of: hydrogen, deuterium, fluorine, cyano, methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, phenyl, pyridyl, trimethylsilyl, trimethylgermanyl, and combinations thereof.

16. The metal complex according to claim 3, wherein at least one of X₂ to X₅ is selected from CRₓ, and the Rₓ is cyano or fluorine;
preferably, at least one of X₄ and X₅ is selected from CRₓ, and the Rₓ is cyano or fluorine;
more preferably, X₄ is selected from CRₓ, and the Rₓ is cyano or fluorine.

17. The metal complex according to claim 3, wherein at least one of Y₁ to Y₄ is, at each occurrence identically or differently, C, the rest of Y₁ to Y₄ is, at each occurrence identically or differently, CR_{y}, and R_{y} is selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof;
preferably, at least one of Y₁ to Y₄ is, at each occurrence identically or differently, C, the rest of Y₁ to Y₄ is, at each occurrence identically or differently, CR_{y}, and R_{y} is selected from the group consisting of: hydrogen, deuterium, halogen, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 6 to 12 carbon atoms, and combinations thereof.

18. The metal complex according to claim 3, wherein R_{Cx} is, at each occurrence identically or differently, selected from the group consisting of: hydrogen, deuterium, halogen, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, cyano, and combinations thereof;
preferably, R_{Cx} is, at each occurrence identically or differently, selected from the group consisting of: hydrogen, deuterium, fluorine, cyano, methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, phenyl, pyridyl, trimethylsilyl, trimethylgermanyl, and combinations thereof.

19. The metal complex according to claim 3, wherein the ring Cx-Rₙ₂R_{Cx} is, at each occurrence identically or differently, selected from the group consisting of Ar1 to Ar66 whose structures are as follows: 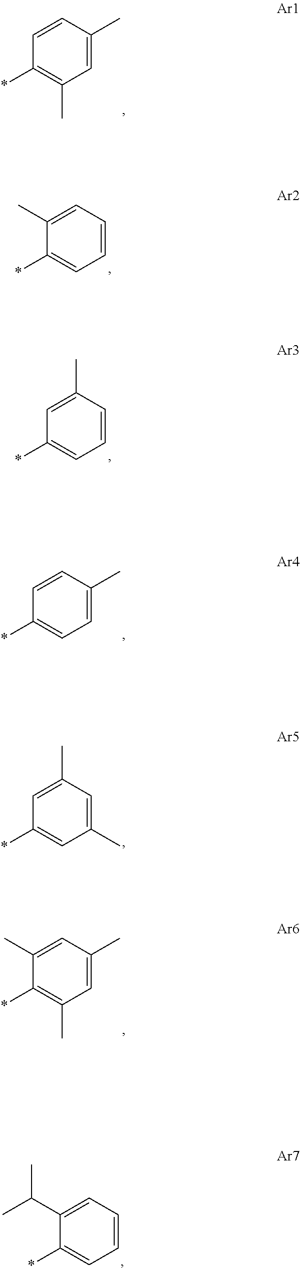 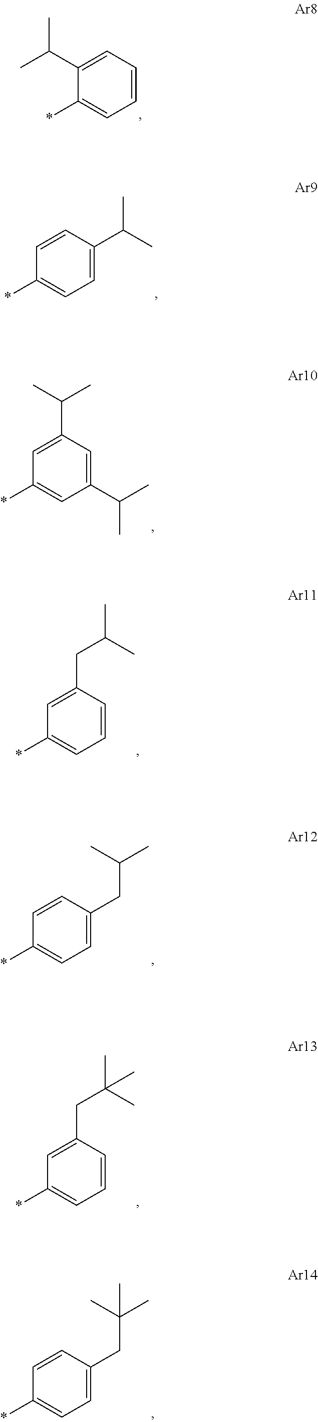 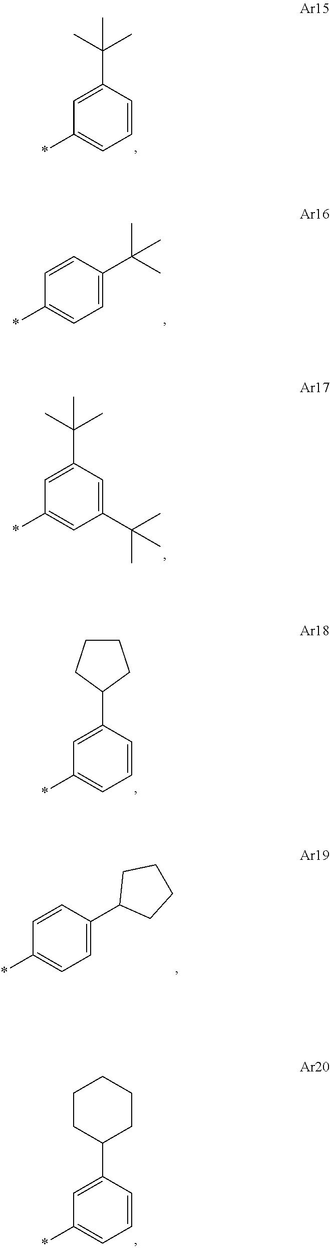 [SMILES: *c1cccc(C(C)(C)C)c1 ; *c1ccc(C(C)(C)C)cc1 ; *c1cc(C(C)(C)C)cc(C(C)(C)C)c1 ; *c1cccc(C2CCCC2)c1 ; *c1ccc(C2CCCC2)cc1 ; *c1cccc(C2CCCCC2)c1] 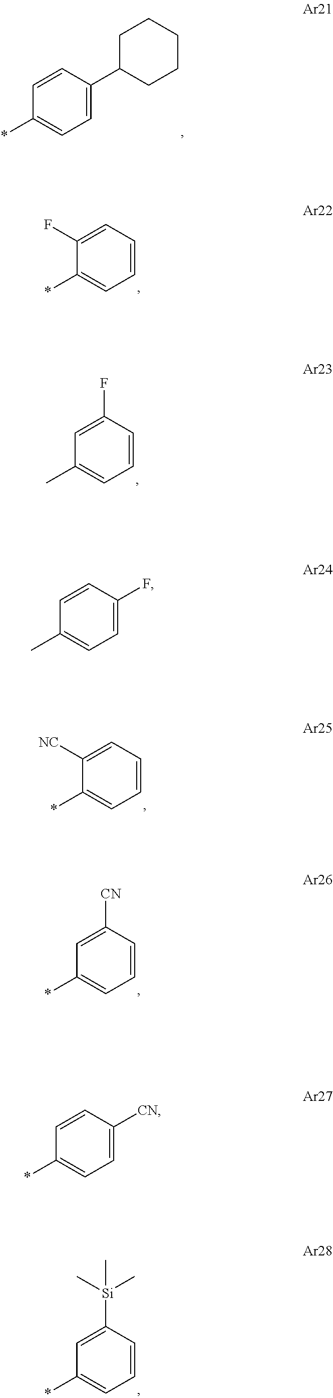 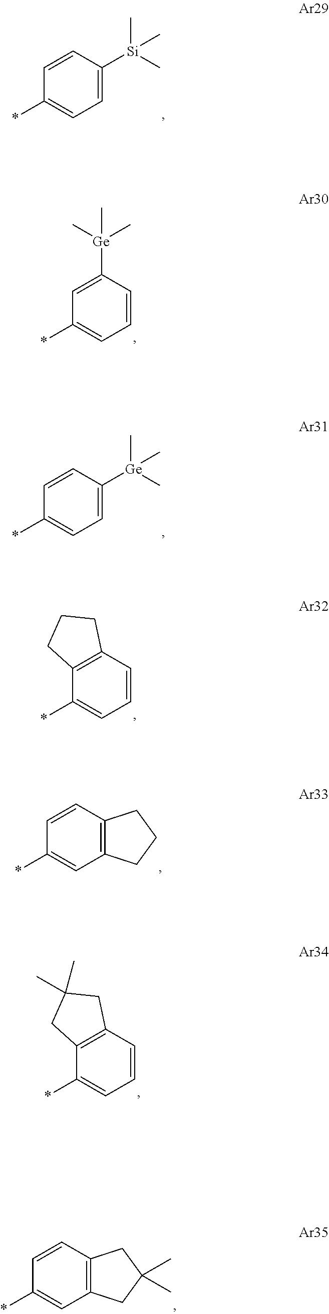 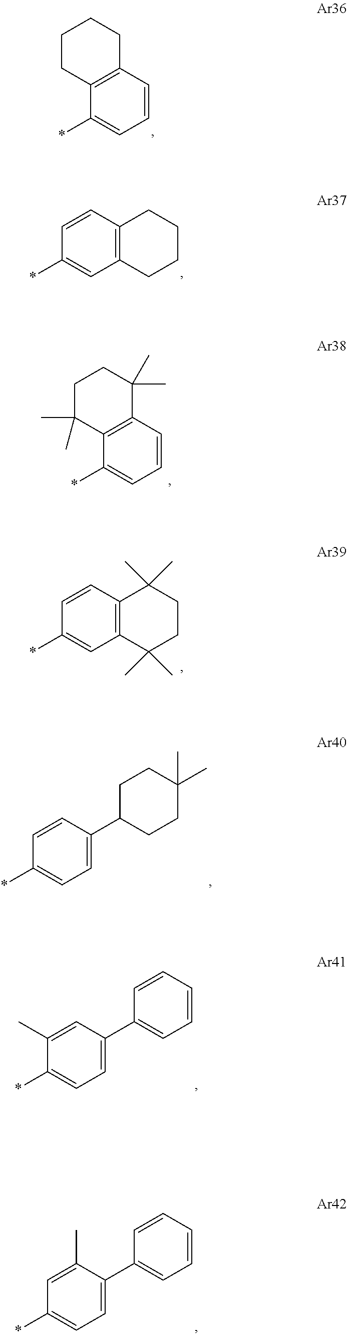 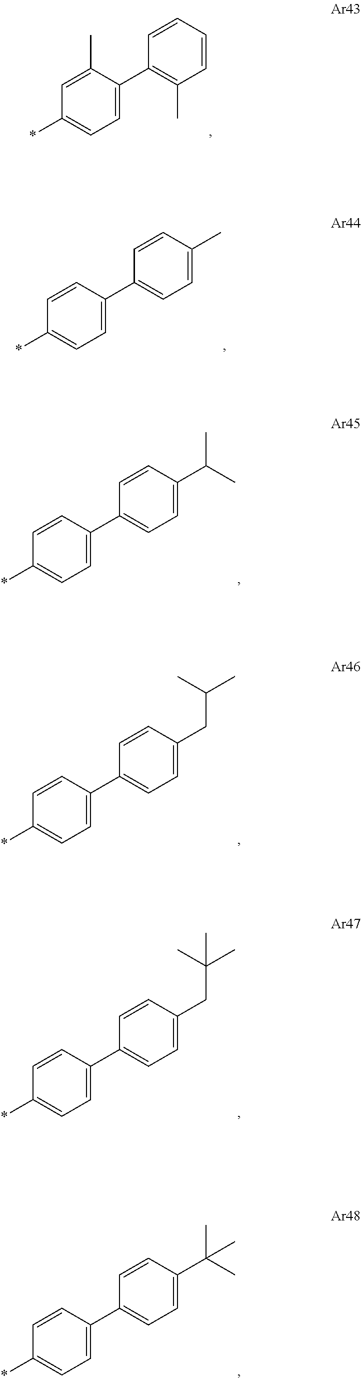 [SMILES: *c1ccc(-c2ccccc2C)c(C)c1 ; *c1ccc(-c2ccc(C)cc2)cc1 ; *c1ccc(-c2ccc(C(C)C)cc2)cc1 ; *c1ccc(-c2ccc(CC(C)C)cc2)cc1 ; *c1ccc(-c2ccc(CC(C)(C)C)cc2)cc1 ; *c1ccc(-c2ccc(C(C)(C)C)cc2)cc1] 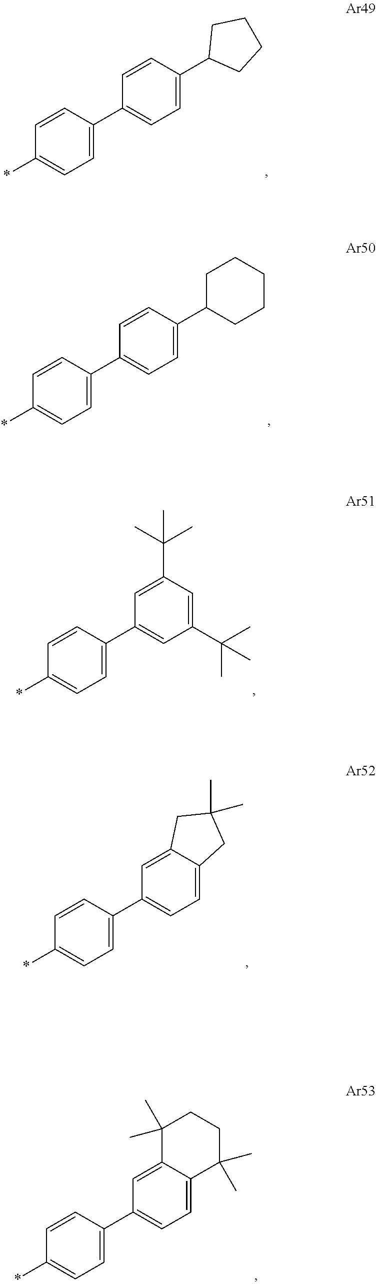 [SMILES: *c1ccc(-c2ccc(C3CCCC3)cc2)cc1 ; *c1ccc(-c2ccc(C3CCCCC3)cc2)cc1 ; *c1ccc(-c2cc(C(C)(C)C)cc(C(C)(C)C)c2)cc1 ; *c1ccc(-c2ccc3c(c2)CC(C)(C)C3)cc1 ; *c1ccc(-c2ccc3c(c2)C(C)(C)CCC3(C)C)cc1] 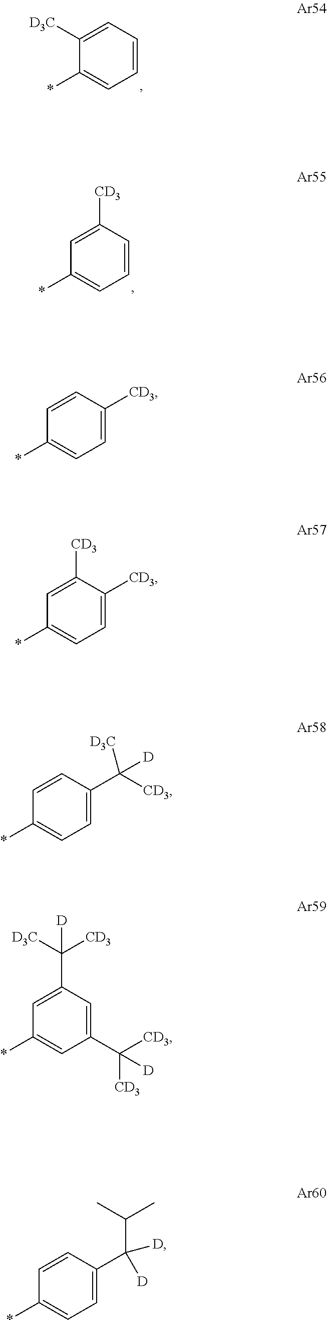 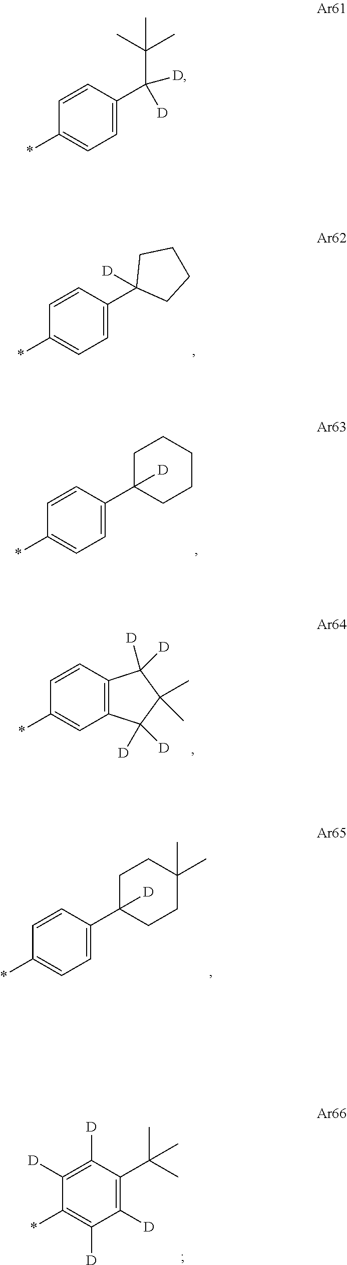
wherein optionally, hydrogens in the above Ar1 to Ar66 can be partially or fully substituted with deuterium; and
“L” represents a position where the ring Cx-Rₙ₂R_{Cx} is joined to X₄ or X₅.

20. The metal complex according to claim 19, wherein Lₐ is, at each occurrence identically or differently, selected from the group consisting of Lₐ₁ to Lₐ₁₉₃₁;
wherein Lₐ₁ to Lₐ₁₉₃₁ each have the following structure: 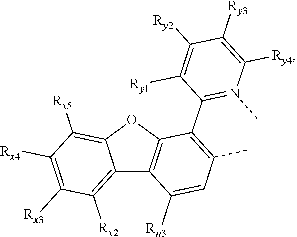
wherein Rₙ₃, Rₓ₂ to Rₓ₄, and R_{y1} to R_{y4} are selected from the atoms or groups in the following table:

| Lₐ | Rₙ₃ | R_{y1} | R_{y2} | R_{y3} | R_{y4} | Rₓ₂ | Rₓ₃ | Rₓ₄ | Rₓ₅ |
|---|---|---|---|---|---|---|---|---|---|
| Lₐ₁ | P6 | H | H | P6 | H | H | H | CN | Ar1 |
| Lₐ₂ | P6 | H | H | P6 | H | H | H | CN | Ar2 |
| Lₐ₃ | P6 | H | H | P6 | H | H | H | CN | Ar3 |
| Lₐ₄ | P6 | H | H | P6 | H | H | H | CN | Ar4 |
| Lₐ₅ | P6 | H | H | P6 | H | H | H | CN | Ar5 |
| Lₐ₆ | P6 | H | H | P6 | H | H | H | CN | Ar6 |
| Lₐ₇ | P6 | H | H | P6 | H | H | H | CN | Ar7 |
| Lₐ₈ | P6 | H | H | P6 | H | H | H | CN | Ar8 |
| Lₐ₉ | P6 | H | H | P6 | H | H | H | CN | Ar9 |
| Lₐ₁₀ | P6 | H | H | P6 | H | H | H | CN | Ar10 |
| Lₐ₁₁ | P6 | H | H | P6 | H | H | H | CN | Ar11 |
| Lₐ₁₂ | P6 | H | H | P6 | H | H | H | CN | Ar12 |
| Lₐ₁₃ | P6 | H | H | P6 | H | H | H | CN | Ar13 |
| Lₐ₁₄ | P6 | H | H | P6 | H | H | H | CN | Ar14 |
| Lₐ₁₅ | P6 | H | H | P6 | H | H | H | CN | Ar15 |
| Lₐ₁₆ | P6 | H | H | P6 | H | H | H | CN | Ar16 |
| Lₐ₁₇ | P6 | H | H | P6 | H | H | H | CN | Ar17 |
| Lₐ₁₈ | P6 | H | H | P6 | H | H | H | CN | Ar18 |
| Lₐ₁₉ | P6 | H | H | P6 | H | H | H | CN | Ar19 |
| Lₐ₂₀ | P6 | H | H | P6 | H | H | H | CN | Ar20 |
| Lₐ₂₁ | P6 | H | H | P6 | H | H | H | CN | Ar21 |
| Lₐ₂₂ | P6 | H | H | P6 | H | H | H | CN | Ar22 |
| Lₐ₂₃ | P6 | H | H | P6 | H | H | H | CN | Ar23 |
| Lₐ₂₄ | P6 | H | H | P6 | H | H | H | CN | Ar24 |
| Lₐ₂₅ | P6 | H | H | P6 | H | H | H | CN | Ar25 |
| Lₐ₂₆ | P6 | H | H | P6 | H | H | H | CN | Ar26 |
| Lₐ₂₇ | P6 | H | H | P6 | H | H | H | CN | Ar27 |
| Lₐ₂₈ | P6 | H | H | P6 | H | H | H | CN | Ar28 |
| Lₐ₂₉ | P6 | H | H | P6 | H | H | H | CN | Ar29 |
| Lₐ₃₀ | P6 | H | H | P6 | H | H | H | CN | Ar30 |
| Lₐ₃₁ | P6 | H | H | P6 | H | H | H | CN | Ar31 |
| Lₐ₃₂ | P6 | H | H | P6 | H | H | H | CN | Ar32 |
| Lₐ₃₃ | P6 | H | H | P6 | H | H | H | CN | Ar33 |
| Lₐ₃₄ | P6 | H | H | P6 | H | H | H | CN | Ar34 |
| Lₐ₃₅ | P6 | H | H | P6 | H | H | H | CN | Ar35 |
| Lₐ₃₆ | P6 | H | H | P6 | H | H | H | CN | Ar36 |
| Lₐ₃₇ | P6 | H | H | P6 | H | H | H | CN | Ar37 |
| Lₐ₃₈ | P6 | H | H | P6 | H | H | H | CN | Ar38 |
| Lₐ₃₉ | P6 | H | H | P6 | H | H | H | CN | Ar39 |
| Lₐ₄₀ | P6 | H | H | P6 | H | H | H | CN | Ar40 |
| Lₐ₄₁ | P6 | H | H | P6 | H | H | H | CN | Ar41 |
| Lₐ₄₂ | P6 | H | H | P6 | H | H | H | CN | Ar42 |
| Lₐ₄₃ | P6 | H | H | P6 | H | H | H | CN | Ar43 |
| Lₐ₄₄ | P6 | H | H | P6 | H | H | H | CN | Ar44 |
| Lₐ₄₅ | P6 | H | H | P6 | H | H | H | CN | Ar45 |
| Lₐ₄₆ | P6 | H | H | P6 | H | H | H | CN | Ar46 |
| Lₐ₄₇ | P6 | H | H | P6 | H | H | H | CN | Ar47 |
| Lₐ₄₈ | P6 | H | H | P6 | H | H | H | CN | Ar48 |
| Lₐ₄₉ | P6 | H | H | P6 | H | H | H | CN | Ar49 |
| Lₐ₅₀ | P6 | H | H | P6 | H | H | H | CN | Ar50 |
| Lₐ₅₁ | P6 | H | H | P6 | H | H | H | CN | Ar51 |
| Lₐ₅₂ | P6 | H | H | P6 | H | H | H | CN | Ar52 |
| Lₐ₅₃ | P6 | H | H | P6 | H | H | H | CN | Ar53 |
| Lₐ₅₄ | P6 | H | H | P6 | H | H | H | CN | Ar54 |
| Lₐ₅₅ | P6 | H | H | P6 | H | H | H | CN | Ar55 |
| Lₐ₅₆ | P6 | H | H | P6 | H | H | H | CN | Ar56 |
| Lₐ₅₇ | P6 | H | H | P6 | H | H | H | CN | Ar57 |
| Lₐ₅₈ | P6 | H | H | P6 | H | H | H | CN | Ar58 |
| Lₐ₅₉ | P6 | H | H | P6 | H | H | H | CN | Ar59 |
| Lₐ₆₀ | P6 | H | H | P6 | H | H | H | CN | Ar60 |
| Lₐ₆₁ | P6 | H | H | P6 | H | H | H | CN | Ar61 |
| Lₐ₆₂ | P6 | H | H | P6 | H | H | H | CN | Ar62 |
| Lₐ₆₃ | P6 | H | H | P6 | H | H | H | CN | Ar63 |
| Lₐ₆₄ | P6 | H | H | P6 | H | H | H | CN | Ar64 |
| Lₐ₆₅ | P6 | H | H | P6 | H | H | H | CN | Ar65 |
| Lₐ₆₆ | P6 | H | H | P6 | H | H | H | CN | Ar66 |
| Lₐ₆₇ | P6 | D | D | P6 | D | D | D | CN | Ar16 |
| Lₐ₆₈ | P6 | H | H | P10 | H | H | H | CN | Ar1 |
| Lₐ₆₉ | P6 | H | H | P10 | H | H | H | CN | Ar2 |
| Lₐ₇₀ | P6 | H | H | P10 | H | H | H | CN | Ar3 |
| Lₐ₇₁ | P6 | H | H | P10 | H | H | H | CN | Ar4 |
| Lₐ₇₂ | P6 | H | H | P10 | H | H | H | CN | Ar5 |
| Lₐ₇₃ | P6 | H | H | P10 | H | H | H | CN | Ar6 |
| Lₐ₇₄ | P6 | H | H | P10 | H | H | H | CN | Ar7 |
| Lₐ₇₅ | P6 | H | H | P10 | H | H | H | CN | Ar8 |
| Lₐ₇₆ | P6 | H | H | P10 | H | H | H | CN | Ar9 |
| Lₐ₇₇ | P6 | H | H | P10 | H | H | H | CN | Ar10 |
| Lₐ₇₈ | P6 | H | H | P10 | H | H | H | CN | Ar11 |
| Lₐ₇₉ | P6 | H | H | P10 | H | H | H | CN | Ar12 |
| Lₐ₈₀ | P6 | H | H | P10 | H | H | H | CN | Ar13 |
| Lₐ₈₁ | P6 | H | H | P10 | H | H | H | CN | Ar14 |
| Lₐ₈₂ | P6 | H | H | P10 | H | H | H | CN | Ar15 |
| Lₐ₈₃ | P6 | H | H | P10 | H | H | H | CN | Ar16 |
| Lₐ₈₄ | P6 | H | H | P10 | H | H | H | CN | Ar17 |
| Lₐ₈₅ | P6 | H | H | P10 | H | H | H | CN | Ar18 |
| Lₐ₈₆ | P6 | H | H | P10 | H | H | H | CN | Ar19 |
| Lₐ₈₇ | P6 | H | H | P10 | H | H | H | CN | Ar20 |
| Lₐ₈₈ | P6 | H | H | P10 | H | H | H | CN | Ar21 |
| Lₐ₈₉ | P6 | H | H | P10 | H | H | H | CN | Ar22 |
| Lₐ₉₀ | P6 | H | H | P10 | H | H | H | CN | Ar23 |
| Lₐ₉₁ | P6 | H | H | P10 | H | H | H | CN | Ar24 |
| Lₐ₉₂ | P6 | H | H | P10 | H | H | H | CN | Ar25 |
| Lₐ₉₃ | P6 | H | H | P10 | H | H | H | CN | Ar26 |
| Lₐ₉₄ | P6 | H | H | P10 | H | H | H | CN | Ar27 |
| Lₐ₉₅ | P6 | H | H | P10 | H | H | H | CN | Ar28 |
| Lₐ₉₆ | P6 | H | H | P10 | H | H | H | CN | Ar29 |
| Lₐ₉₇ | P6 | H | H | P10 | H | H | H | CN | Ar30 |
| Lₐ₉₈ | P6 | H | H | P10 | H | H | H | CN | Ar31 |
| Lₐ₉₉ | P6 | H | H | P10 | H | H | H | CN | Ar32 |
| Lₐ₁₀₀ | P6 | H | H | P10 | H | H | H | CN | Ar33 |
| Lₐ₁₀₁ | P6 | H | H | P10 | H | H | H | CN | Ar34 |
| Lₐ₁₀₂ | P6 | H | H | P10 | H | H | H | CN | Ar35 |
| Lₐ₁₀₃ | P6 | H | H | P10 | H | H | H | CN | Ar36 |
| Lₐ₁₀₄ | P6 | H | H | P10 | H | H | H | CN | Ar37 |
| Lₐ₁₀₅ | P6 | H | H | P10 | H | H | H | CN | Ar38 |
| Lₐ₁₀₆ | P6 | H | H | P10 | H | H | H | CN | Ar39 |
| Lₐ₁₀₇ | P6 | H | H | P10 | H | H | H | CN | Ar40 |
| Lₐ₁₀₈ | P6 | H | H | P10 | H | H | H | CN | Ar41 |
| Lₐ₁₀₉ | P6 | H | H | P10 | H | H | H | CN | Ar42 |
| Lₐ₁₁₀ | P6 | H | H | P10 | H | H | H | CN | Ar43 |
| Lₐ₁₁₁ | P6 | H | H | P10 | H | H | H | CN | Ar44 |
| Lₐ₁₁₂ | P6 | H | H | P10 | H | H | H | CN | Ar45 |
| Lₐ₁₁₃ | P6 | H | H | P10 | H | H | H | CN | Ar46 |
| Lₐ₁₁₄ | P6 | H | H | P10 | H | H | H | CN | Ar47 |
| Lₐ₁₁₅ | P6 | H | H | P10 | H | H | H | CN | Ar48 |
| Lₐ₁₁₆ | P6 | H | H | P10 | H | H | H | CN | Ar49 |
| Lₐ₁₁₇ | P6 | H | H | P10 | H | H | H | CN | Ar50 |
| Lₐ₁₁₈ | P6 | H | H | P10 | H | H | H | CN | Ar51 |
| Lₐ₁₁₉ | P6 | H | H | P10 | H | H | H | CN | Ar52 |
| Lₐ₁₂₀ | P6 | H | H | P10 | H | H | H | CN | Ar53 |
| Lₐ₁₂₁ | P6 | H | H | P10 | H | H | H | CN | Ar54 |
| Lₐ₁₂₂ | P6 | H | H | P10 | H | H | H | CN | Ar55 |
| Lₐ₁₂₃ | P6 | H | H | P10 | H | H | H | CN | Ar56 |
| Lₐ₁₂₄ | P6 | H | H | P10 | H | H | H | CN | Ar57 |
| Lₐ₁₂₅ | P6 | H | H | P10 | H | H | H | CN | Ar58 |
| Lₐ₁₂₆ | P6 | H | H | P10 | H | H | H | CN | Ar59 |
| Lₐ₁₂₇ | P6 | H | H | P10 | H | H | H | CN | Ar60 |
| Lₐ₁₂₈ | P6 | H | H | P10 | H | H | H | CN | Ar61 |
| Lₐ₁₂₉ | P6 | H | H | P10 | H | H | H | CN | Ar62 |
| Lₐ₁₃₀ | P6 | H | H | P10 | H | H | H | CN | Ar63 |
| Lₐ₁₃₁ | P6 | H | H | P10 | H | H | H | CN | Ar64 |
| Lₐ₁₃₂ | P6 | H | H | P10 | H | H | H | CN | Ar65 |
| Lₐ₁₃₃ | P6 | H | H | P10 | H | H | H | CN | Ar66 |
| Lₐ₁₃₄ | P6 | D | D | P11 | D | D | D | CN | Ar16 |
| Lₐ₁₃₅ | P6 | H | P1 | P6 | H | H | H | CN | Ar1 |
| Lₐ₁₃₆ | P6 | H | P1 | P6 | H | H | H | CN | Ar2 |
| Lₐ₁₃₇ | P6 | H | P1 | P6 | H | H | H | CN | Ar3 |
| Lₐ₁₃₈ | P6 | H | P1 | P6 | H | H | H | CN | Ar4 |
| Lₐ₁₃₉ | P6 | H | P1 | P6 | H | H | H | CN | Ar5 |
| Lₐ₁₄₀ | P6 | H | P1 | P6 | H | H | H | CN | Ar6 |
| Lₐ₁₄₁ | P6 | H | P1 | P6 | H | H | H | CN | Ar7 |
| Lₐ₁₄₂ | P6 | H | P1 | P6 | H | H | H | CN | Ar8 |
| Lₐ₁₄₃ | P6 | H | P1 | P6 | H | H | H | CN | Ar9 |
| Lₐ₁₄₄ | P6 | H | P1 | P6 | H | H | H | CN | Ar10 |
| Lₐ₁₄₅ | P6 | H | P1 | P6 | H | H | H | CN | Ar11 |
| Lₐ₁₄₆ | P6 | H | P1 | P6 | H | H | H | CN | Ar12 |
| Lₐ₁₄₇ | P6 | H | P1 | P6 | H | H | H | CN | Ar13 |
| Lₐ₁₄₈ | P6 | H | P1 | P6 | H | H | H | CN | Ar14 |
| Lₐ₁₄₉ | P6 | H | P1 | P6 | H | H | H | CN | Ar15 |
| Lₐ₁₅₀ | P6 | H | P1 | P6 | H | H | H | CN | Ar16 |
| Lₐ₁₅₁ | P6 | H | P1 | P6 | H | H | H | CN | Ar17 |
| Lₐ₁₅₂ | P6 | H | P1 | P6 | H | H | H | CN | Ar18 |
| Lₐ₁₅₃ | P6 | H | P1 | P6 | H | H | H | CN | Ar19 |
| Lₐ₁₅₄ | P6 | H | P1 | P6 | H | H | H | CN | Ar20 |
| Lₐ₁₅₅ | P6 | H | P1 | P6 | H | H | H | CN | Ar21 |
| Lₐ₁₅₆ | P6 | H | P1 | P6 | H | H | H | CN | Ar22 |
| Lₐ₁₅₇ | P6 | H | P1 | P6 | H | H | H | CN | Ar23 |
| Lₐ₁₅₈ | P6 | H | P1 | P6 | H | H | H | CN | Ar24 |
| Lₐ₁₅₉ | P6 | H | P1 | P6 | H | H | H | CN | Ar25 |
| Lₐ₁₆₀ | P6 | H | P1 | P6 | H | H | H | CN | Ar26 |
| Lₐ₁₆₁ | P6 | H | P1 | P6 | H | H | H | CN | Ar27 |
| Lₐ₁₆₂ | P6 | H | P1 | P6 | H | H | H | CN | Ar28 |
| Lₐ₁₆₃ | P6 | H | P1 | P6 | H | H | H | CN | Ar29 |
| Lₐ₁₆₄ | P6 | H | P1 | P6 | H | H | H | CN | Ar30 |
| Lₐ₁₆₅ | P6 | H | P1 | P6 | H | H | H | CN | Ar31 |
| Lₐ₁₆₆ | P6 | H | P1 | P6 | H | H | H | CN | Ar32 |
| Lₐ₁₆₇ | P6 | H | P1 | P6 | H | H | H | CN | Ar33 |
| Lₐ₁₆₈ | P6 | H | P1 | P6 | H | H | H | CN | Ar34 |
| Lₐ₁₆₉ | P6 | H | P1 | P6 | H | H | H | CN | Ar35 |
| Lₐ₁₇₀ | P6 | H | P1 | P6 | H | H | H | CN | Ar36 |
| Lₐ₁₇₁ | P6 | H | P1 | P6 | H | H | H | CN | Ar37 |
| Lₐ₁₇₂ | P6 | H | P1 | P6 | H | H | H | CN | Ar38 |
| Lₐ₁₇₃ | P6 | H | P1 | P6 | H | H | H | CN | Ar39 |
| Lₐ₁₇₄ | P6 | H | P1 | P6 | H | H | H | CN | Ar40 |
| Lₐ₁₇₅ | P6 | H | P1 | P6 | H | H | H | CN | Ar41 |
| Lₐ₁₇₆ | P6 | H | P1 | P6 | H | H | H | CN | Ar42 |
| Lₐ₁₇₇ | P6 | H | P1 | P6 | H | H | H | CN | Ar43 |
| Lₐ₁₇₈ | P6 | H | P1 | P6 | H | H | H | CN | Ar44 |
| Lₐ₁₇₉ | P6 | H | P1 | P6 | H | H | H | CN | Ar45 |
| Lₐ₁₈₀ | P6 | H | P1 | P6 | H | H | H | CN | Ar46 |
| Lₐ₁₈₁ | P6 | H | P1 | P6 | H | H | H | CN | Ar47 |
| Lₐ₁₈₂ | P6 | H | P1 | P6 | H | H | H | CN | Ar48 |
| Lₐ₁₈₃ | P6 | H | P1 | P6 | H | H | H | CN | Ar49 |
| Lₐ₁₈₄ | P6 | H | P1 | P6 | H | H | H | CN | Ar50 |
| Lₐ₁₈₅ | P6 | H | P1 | P6 | H | H | H | CN | Ar51 |
| Lₐ₁₈₆ | P6 | H | P1 | P6 | H | H | H | CN | Ar52 |
| Lₐ₁₈₇ | P6 | H | P1 | P6 | H | H | H | CN | Ar53 |
| Lₐ₁₈₈ | P6 | H | P1 | P6 | H | H | H | CN | Ar54 |
| Lₐ₁₈₉ | P6 | H | P1 | P6 | H | H | H | CN | Ar55 |
| Lₐ₁₉₀ | P6 | H | P1 | P6 | H | H | H | CN | Ar56 |
| Lₐ₁₉₁ | P6 | H | P1 | P6 | H | H | H | CN | Ar57 |
| Lₐ₁₉₂ | P6 | H | P1 | P6 | H | H | H | CN | Ar58 |
| Lₐ₁₉₃ | P6 | H | P1 | P6 | H | H | H | CN | Ar59 |
| Lₐ₁₉₄ | P6 | H | P1 | P6 | H | H | H | CN | Ar60 |
| Lₐ₁₉₅ | P6 | H | P1 | P6 | H | H | H | CN | Ar61 |
| Lₐ₁₉₆ | P6 | H | P1 | P6 | H | H | H | CN | Ar62 |
| Lₐ₁₉₇ | P6 | H | P1 | P6 | H | H | H | CN | Ar63 |
| Lₐ₁₉₈ | P6 | H | P1 | P6 | H | H | H | CN | Ar64 |
| Lₐ₁₉₉ | P6 | H | P1 | P6 | H | H | H | CN | Ar65 |
| Lₐ₂₀₀ | P6 | H | P1 | P6 | H | H | H | CN | Ar66 |
| Lₐ₂₀₁ | P6 | D | P2 | P6 | D | D | D | CN | Ar16 |
| Lₐ₂₀₂ | P6 | H | P1 | P10 | H | H | H | CN | Ar1 |
| Lₐ₂₀₃ | P6 | H | P1 | P10 | H | H | H | CN | Ar2 |
| Lₐ₂₀₄ | P6 | H | P1 | P10 | H | H | H | CN | Ar3 |
| Lₐ₂₀₅ | P6 | H | P1 | P10 | H | H | H | CN | Ar4 |
| Lₐ₂₀₆ | P6 | H | P1 | P10 | H | H | H | CN | Ar5 |
| Lₐ₂₀₇ | P6 | H | P1 | P10 | H | H | H | CN | Ar6 |
| Lₐ₂₀₈ | P6 | H | P1 | P10 | H | H | H | CN | Ar7 |
| Lₐ₂₀₉ | P6 | H | P1 | P10 | H | H | H | CN | Ar8 |
| Lₐ₂₁₀ | P6 | H | P1 | P10 | H | H | H | CN | Ar9 |
| Lₐ₂₁₁ | P6 | H | P1 | P10 | H | H | H | CN | Ar10 |
| Lₐ₂₁₂ | P6 | H | P1 | P10 | H | H | H | CN | Ar11 |
| Lₐ₂₁₃ | P6 | H | P1 | P10 | H | H | H | CN | Ar12 |
| Lₐ₂₁₄ | P6 | H | P1 | P10 | H | H | H | CN | Ar13 |
| Lₐ₂₁₅ | P6 | H | P1 | P10 | H | H | H | CN | Ar14 |
| Lₐ₂₁₆ | P6 | H | P1 | P10 | H | H | H | CN | Ar15 |
| Lₐ₂₁₇ | P6 | H | P1 | P10 | H | H | H | CN | Ar16 |
| Lₐ₂₁₈ | P6 | H | P1 | P10 | H | H | H | CN | Ar17 |
| Lₐ₂₁₉ | P6 | H | P1 | P10 | H | H | H | CN | Ar18 |
| Lₐ₂₂₀ | P6 | H | P1 | P10 | H | H | H | CN | Ar19 |
| Lₐ₂₂₁ | P6 | H | P1 | P10 | H | H | H | CN | Ar20 |
| Lₐ₂₂₂ | P6 | H | P1 | P10 | H | H | H | CN | Ar21 |
| Lₐ₂₂₃ | P6 | H | P1 | P10 | H | H | H | CN | Ar22 |
| Lₐ₂₂₄ | P6 | H | P1 | P10 | H | H | H | CN | Ar23 |
| Lₐ₂₂₅ | P6 | H | P1 | P10 | H | H | H | CN | Ar24 |
| Lₐ₂₂₆ | P6 | H | P1 | P10 | H | H | H | CN | Ar25 |
| Lₐ₂₂₇ | P6 | H | P1 | P10 | H | H | H | CN | Ar26 |
| Lₐ₂₂₈ | P6 | H | P1 | P10 | H | H | H | CN | Ar27 |
| Lₐ₂₂₉ | P6 | H | P1 | P10 | H | H | H | CN | Ar28 |
| Lₐ₂₃₀ | P6 | H | P1 | P10 | H | H | H | CN | Ar29 |
| Lₐ₂₃₁ | P6 | H | P1 | P10 | H | H | H | CN | Ar30 |
| Lₐ₂₃₂ | P6 | H | P1 | P10 | H | H | H | CN | Ar31 |
| Lₐ₂₃₃ | P6 | H | P1 | P10 | H | H | H | CN | Ar32 |
| Lₐ₂₃₄ | P6 | H | P1 | P10 | H | H | H | CN | Ar33 |
| Lₐ₂₃₅ | P6 | H | P1 | P10 | H | H | H | CN | Ar34 |
| Lₐ₂₃₆ | P6 | H | P1 | P10 | H | H | H | CN | Ar35 |
| Lₐ₂₃₇ | P6 | H | P1 | P10 | H | H | H | CN | Ar36 |
| Lₐ₂₃₈ | P6 | H | P1 | P10 | H | H | H | CN | Ar37 |
| Lₐ₂₃₉ | P6 | H | P1 | P10 | H | H | H | CN | Ar38 |
| Lₐ₂₄₀ | P6 | H | P1 | P10 | H | H | H | CN | Ar39 |
| Lₐ₂₄₁ | P6 | H | P1 | P10 | H | H | H | CN | Ar40 |
| Lₐ₂₄₂ | P6 | H | P1 | P10 | H | H | H | CN | Ar41 |
| Lₐ₂₄₃ | P6 | H | P1 | P10 | H | H | H | CN | Ar42 |
| Lₐ₂₄₄ | P6 | H | P1 | P10 | H | H | H | CN | Ar43 |
| Lₐ₂₄₅ | P6 | H | P1 | P10 | H | H | H | CN | Ar44 |
| Lₐ₂₄₆ | P6 | H | P1 | P10 | H | H | H | CN | Ar45 |
| Lₐ₂₄₇ | P6 | H | P1 | P10 | H | H | H | CN | Ar46 |
| Lₐ₂₄₈ | P6 | H | P1 | P10 | H | H | H | CN | Ar47 |
| Lₐ₂₄₉ | P6 | H | P1 | P10 | H | H | H | CN | Ar48 |
| Lₐ₂₅₀ | P6 | H | P1 | P10 | H | H | H | CN | Ar49 |
| Lₐ₂₅₁ | P6 | H | P1 | P10 | H | H | H | CN | Ar50 |
| Lₐ₂₅₂ | P6 | H | P1 | P10 | H | H | H | CN | Ar51 |
| Lₐ₂₅₃ | P6 | H | P1 | P10 | H | H | H | CN | Ar52 |
| Lₐ₂₅₄ | P6 | H | P1 | P10 | H | H | H | CN | Ar53 |
| Lₐ₂₅₅ | P6 | H | P1 | P10 | H | H | H | CN | Ar54 |
| Lₐ₂₅₆ | P6 | H | P1 | P10 | H | H | H | CN | Ar55 |
| Lₐ₂₅₇ | P6 | H | P1 | P10 | H | H | H | CN | Ar56 |
| Lₐ₂₅₈ | P6 | H | P1 | P10 | H | H | H | CN | Ar57 |
| Lₐ₂₅₉ | P6 | H | P1 | P10 | H | H | H | CN | Ar58 |
| Lₐ₂₆₀ | P6 | H | P1 | P10 | H | H | H | CN | Ar59 |
| Lₐ₂₆₁ | P6 | H | P1 | P10 | H | H | H | CN | Ar60 |
| Lₐ₂₆₂ | P6 | H | P1 | P10 | H | H | H | CN | Ar61 |
| Lₐ₂₆₃ | P6 | H | P1 | P10 | H | H | H | CN | Ar62 |
| Lₐ₂₆₄ | P6 | H | P1 | P10 | H | H | H | CN | Ar63 |
| Lₐ₂₆₅ | P6 | H | P1 | P10 | H | H | H | CN | Ar64 |
| Lₐ₂₆₆ | P6 | H | P1 | P10 | H | H | H | CN | Ar65 |
| Lₐ₂₆₇ | P6 | H | P1 | P10 | H | H | H | CN | Ar66 |
| Lₐ₂₆₈ | P6 | D | P2 | P11 | D | D | D | CN | Ar16 |
| Lₐ₂₆₉ | P6 | H | P6 | H | H | H | H | CN | Ar1 |
| Lₐ₂₇₀ | P6 | H | P6 | H | H | H | H | CN | Ar2 |
| Lₐ₂₇₁ | P6 | H | P6 | H | H | H | H | CN | Ar3 |
| Lₐ₂₇₂ | P6 | H | P6 | H | H | H | H | CN | Ar4 |
| Lₐ₂₇₃ | P6 | H | P6 | H | H | H | H | CN | Ar5 |
| Lₐ₂₇₄ | P6 | H | P6 | H | H | H | H | CN | Ar6 |
| Lₐ₂₇₅ | P6 | H | P6 | H | H | H | H | CN | Ar7 |
| Lₐ₂₇₆ | P6 | H | P6 | H | H | H | H | CN | Ar8 |
| Lₐ₂₇₇ | P6 | H | P6 | H | H | H | H | CN | Ar9 |
| Lₐ₂₇₈ | P6 | H | P6 | H | H | H | H | CN | Ar10 |
| Lₐ₂₇₉ | P6 | H | P6 | H | H | H | H | CN | Ar11 |
| Lₐ₂₈₀ | P6 | H | P6 | H | H | H | H | CN | Ar12 |
| Lₐ₂₈₁ | P6 | H | P6 | H | H | H | H | CN | Ar13 |
| Lₐ₂₈₂ | P6 | H | P6 | H | H | H | H | CN | Ar14 |
| Lₐ₂₈₃ | P6 | H | P6 | H | H | H | H | CN | Ar15 |
| Lₐ₂₈₄ | P6 | H | P6 | H | H | H | H | CN | Ar16 |
| Lₐ₂₈₅ | P6 | H | P6 | H | H | H | H | CN | Ar17 |
| Lₐ₂₈₆ | P6 | H | P6 | H | H | H | H | CN | Ar18 |
| Lₐ₂₈₇ | P6 | H | P6 | H | H | H | H | CN | Ar19 |
| Lₐ₂₈₈ | P6 | H | P6 | H | H | H | H | CN | Ar20 |
| Lₐ₂₈₉ | P6 | H | P6 | H | H | H | H | CN | Ar21 |
| Lₐ₂₉₀ | P6 | H | P6 | H | H | H | H | CN | Ar22 |
| Lₐ₂₉₁ | P6 | H | P6 | H | H | H | H | CN | Ar23 |
| Lₐ₂₉₂ | P6 | H | P6 | H | H | H | H | CN | Ar24 |
| Lₐ₂₉₃ | P6 | H | P6 | H | H | H | H | CN | Ar25 |
| Lₐ₂₉₄ | P6 | H | P6 | H | H | H | H | CN | Ar26 |
| Lₐ₂₉₅ | P6 | H | P6 | H | H | H | H | CN | Ar27 |
| Lₐ₂₉₆ | P6 | H | P6 | H | H | H | H | CN | Ar28 |
| Lₐ₂₉₇ | P6 | H | P6 | H | H | H | H | CN | Ar29 |
| Lₐ₂₉₈ | P6 | H | P6 | H | H | H | H | CN | Ar30 |
| Lₐ₂₉₉ | P6 | H | P6 | H | H | H | H | CN | Ar31 |
| Lₐ₃₀₀ | P6 | H | P6 | H | H | H | H | CN | Ar32 |
| Lₐ₃₀₁ | P6 | H | P6 | H | H | H | H | CN | Ar33 |
| Lₐ₃₀₂ | P6 | H | P6 | H | H | H | H | CN | Ar34 |
| Lₐ₃₀₃ | P6 | H | P6 | H | H | H | H | CN | Ar35 |
| Lₐ₃₀₄ | P6 | H | P6 | H | H | H | H | CN | Ar36 |
| Lₐ₃₀₅ | P6 | H | P6 | H | H | H | H | CN | Ar37 |
| Lₐ₃₀₆ | P6 | H | P6 | H | H | H | H | CN | Ar38 |
| Lₐ₃₀₇ | P6 | H | P6 | H | H | H | H | CN | Ar39 |
| Lₐ₃₀₈ | P6 | H | P6 | H | H | H | H | CN | Ar40 |
| Lₐ₃₀₉ | P6 | H | P6 | H | H | H | H | CN | Ar41 |
| Lₐ₃₁₀ | P6 | H | P6 | H | H | H | H | CN | Ar42 |
| Lₐ₃₁₁ | P6 | H | P6 | H | H | H | H | CN | Ar43 |
| Lₐ₃₁₂ | P6 | H | P6 | H | H | H | H | CN | Ar44 |
| Lₐ₃₁₃ | P6 | H | P6 | H | H | H | H | CN | Ar45 |
| Lₐ₃₁₄ | P6 | H | P6 | H | H | H | H | CN | Ar46 |
| Lₐ₃₁₅ | P6 | H | P6 | H | H | H | H | CN | Ar47 |
| Lₐ₃₁₆ | P6 | H | P6 | H | H | H | H | CN | Ar48 |
| Lₐ₃₁₇ | P6 | H | P6 | H | H | H | H | CN | Ar49 |
| Lₐ₃₁₈ | P6 | H | P6 | H | H | H | H | CN | Ar50 |
| Lₐ₃₁₉ | P6 | H | P6 | H | H | H | H | CN | Ar51 |
| Lₐ₃₂₀ | P6 | H | P6 | H | H | H | H | CN | Ar52 |
| Lₐ₃₂₁ | P6 | H | P6 | H | H | H | H | CN | Ar53 |
| Lₐ₃₂₂ | P6 | H | P6 | H | H | H | H | CN | Ar54 |
| Lₐ₃₂₃ | P6 | H | P6 | H | H | H | H | CN | Ar55 |
| Lₐ₃₂₄ | P6 | H | P6 | H | H | H | H | CN | Ar56 |
| Lₐ₃₂₅ | P6 | H | P6 | H | H | H | H | CN | Ar57 |
| Lₐ₃₂₆ | P6 | H | P6 | H | H | H | H | CN | Ar58 |
| Lₐ₃₂₇ | P6 | H | P6 | H | H | H | H | CN | Ar59 |
| Lₐ₃₂₈ | P6 | H | P6 | H | H | H | H | CN | Ar60 |
| Lₐ₃₂₉ | P6 | H | P6 | H | H | H | H | CN | Ar61 |
| Lₐ₃₃₀ | P6 | H | P6 | H | H | H | H | CN | Ar62 |
| Lₐ₃₃₁ | P6 | H | P6 | H | H | H | H | CN | Ar63 |
| Lₐ₃₃₂ | P6 | H | P6 | H | H | H | H | CN | Ar64 |
| Lₐ₃₃₃ | P6 | H | P6 | H | H | H | H | CN | Ar65 |
| Lₐ₃₃₄ | P6 | H | P6 | H | H | H | H | CN | Ar66 |
| Lₐ₃₃₅ | P6 | D | P6 | D | D | D | D | CN | Ar16 |
| Lₐ₃₃₆ | P6 | H | P10 | H | H | H | H | CN | Ar1 |
| Lₐ₃₃₇ | P6 | H | P10 | H | H | H | H | CN | Ar2 |
| Lₐ₃₃₈ | P6 | H | P10 | H | H | H | H | CN | Ar3 |
| Lₐ₃₃₉ | P6 | H | P10 | H | H | H | H | CN | Ar4 |
| Lₐ₃₄₀ | P6 | H | P10 | H | H | H | H | CN | Ar5 |
| Lₐ₃₄₁ | P6 | H | P10 | H | H | H | H | CN | Ar6 |
| Lₐ₃₄₂ | P6 | H | P10 | H | H | H | H | CN | Ar7 |
| Lₐ₃₄₃ | P6 | H | P10 | H | H | H | H | CN | Ar8 |
| Lₐ₃₄₄ | P6 | H | P10 | H | H | H | H | CN | Ar9 |
| Lₐ₃₄₅ | P6 | H | P10 | H | H | H | H | CN | Ar10 |
| Lₐ₃₄₆ | P6 | H | P10 | H | H | H | H | CN | Ar11 |
| Lₐ₃₄₇ | P6 | H | P10 | H | H | H | H | CN | Ar12 |
| Lₐ₃₄₈ | P6 | H | P10 | H | H | H | H | CN | Ar13 |
| Lₐ₃₄₉ | P6 | H | P10 | H | H | H | H | CN | Ar14 |
| Lₐ₃₅₀ | P6 | H | P10 | H | H | H | H | CN | Ar15 |
| Lₐ₃₅₁ | P6 | H | P10 | H | H | H | H | CN | Ar16 |
| Lₐ₃₅₂ | P6 | H | P10 | H | H | H | H | CN | Ar17 |
| Lₐ₃₅₃ | P6 | H | P10 | H | H | H | H | CN | Ar18 |
| Lₐ₃₅₄ | P6 | H | P10 | H | H | H | H | CN | Ar19 |
| Lₐ₃₅₅ | P6 | H | P10 | H | H | H | H | CN | Ar20 |
| Lₐ₃₅₆ | P6 | H | P10 | H | H | H | H | CN | Ar21 |
| Lₐ₃₅₇ | P6 | H | P10 | H | H | H | H | CN | Ar22 |
| Lₐ₃₅₈ | P6 | H | P10 | H | H | H | H | CN | Ar23 |
| Lₐ₃₅₉ | P6 | H | P10 | H | H | H | H | CN | Ar24 |
| Lₐ₃₆₀ | P6 | H | P10 | H | H | H | H | CN | Ar25 |
| Lₐ₃₆₁ | P6 | H | P10 | H | H | H | H | CN | Ar26 |
| Lₐ₃₆₂ | P6 | H | P10 | H | H | H | H | CN | Ar27 |
| Lₐ₃₆₃ | P6 | H | P10 | H | H | H | H | CN | Ar28 |
| Lₐ₃₆₄ | P6 | H | P10 | H | H | H | H | CN | Ar29 |
| Lₐ₃₆₅ | P6 | H | P10 | H | H | H | H | CN | Ar30 |
| Lₐ₃₆₆ | P6 | H | P10 | H | H | H | H | CN | Ar31 |
| Lₐ₃₆₇ | P6 | H | P10 | H | H | H | H | CN | Ar32 |
| Lₐ₃₆₈ | P6 | H | P10 | H | H | H | H | CN | Ar33 |
| Lₐ₃₆₉ | P6 | H | P10 | H | H | H | H | CN | Ar34 |
| Lₐ₃₇₀ | P6 | H | P10 | H | H | H | H | CN | Ar35 |
| Lₐ₃₇₁ | P6 | H | P10 | H | H | H | H | CN | Ar36 |
| Lₐ₃₇₂ | P6 | H | P10 | H | H | H | H | CN | Ar37 |
| Lₐ₃₇₃ | P6 | H | P10 | H | H | H | H | CN | Ar38 |
| Lₐ₃₇₄ | P6 | H | P10 | H | H | H | H | CN | Ar39 |
| Lₐ₃₇₅ | P6 | H | P10 | H | H | H | H | CN | Ar40 |
| Lₐ₃₇₆ | P6 | H | P10 | H | H | H | H | CN | Ar41 |
| Lₐ₃₇₇ | P6 | H | P10 | H | H | H | H | CN | Ar42 |
| Lₐ₃₇₈ | P6 | H | P10 | H | H | H | H | CN | Ar43 |
| Lₐ₃₇₉ | P6 | H | P10 | H | H | H | H | CN | Ar44 |
| Lₐ₃₈₀ | P6 | H | P10 | H | H | H | H | CN | Ar45 |
| Lₐ₃₈₁ | P6 | H | P10 | H | H | H | H | CN | Ar46 |
| Lₐ₃₈₂ | P6 | H | P10 | H | H | H | H | CN | Ar47 |
| Lₐ₃₈₃ | P6 | H | P10 | H | H | H | H | CN | Ar48 |
| Lₐ₃₈₄ | P6 | H | P10 | H | H | H | H | CN | Ar49 |
| Lₐ₃₈₅ | P6 | H | P10 | H | H | H | H | CN | Ar50 |
| Lₐ₃₈₆ | P6 | H | P10 | H | H | H | H | CN | Ar51 |
| Lₐ₃₈₇ | P6 | H | P10 | H | H | H | H | CN | Ar52 |
| Lₐ₃₈₈ | P6 | H | P10 | H | H | H | H | CN | Ar53 |
| Lₐ₃₈₉ | P6 | H | P10 | H | H | H | H | CN | Ar54 |
| Lₐ₃₉₀ | P6 | H | P10 | H | H | H | H | CN | Ar55 |
| Lₐ₃₉₁ | P6 | H | P10 | H | H | H | H | CN | Ar56 |
| Lₐ₃₉₂ | P6 | H | P10 | H | H | H | H | CN | Ar57 |
| Lₐ₃₉₃ | P6 | H | P10 | H | H | H | H | CN | Ar58 |
| Lₐ₃₉₄ | P6 | H | P10 | H | H | H | H | CN | Ar59 |
| Lₐ₃₉₅ | P6 | H | P10 | H | H | H | H | CN | Ar60 |
| Lₐ₃₉₆ | P6 | H | P10 | H | H | H | H | CN | Ar61 |
| Lₐ₃₉₇ | P6 | H | P10 | H | H | H | H | CN | Ar62 |
| Lₐ₃₉₈ | P6 | H | P10 | H | H | H | H | CN | Ar63 |
| Lₐ₃₉₉ | P6 | H | P10 | H | H | H | H | CN | Ar64 |
| Lₐ₄₀₀ | P6 | H | P10 | H | H | H | H | CN | Ar65 |
| Lₐ₄₀₁ | P6 | H | P10 | H | H | H | H | CN | Ar66 |
| Lₐ₄₀₂ | P6 | D | P11 | D | D | D | D | CN | Ar16 |
| Lₐ₄₀₃ | P6 | H | P6 | P1 | H | H | H | CN | Ar1 |
| Lₐ₄₀₄ | P6 | H | P6 | P1 | H | H | H | CN | Ar2 |
| Lₐ₄₀₅ | P6 | H | P6 | P1 | H | H | H | CN | Ar3 |
| Lₐ₄₀₆ | P6 | H | P6 | P1 | H | H | H | CN | Ar4 |
| Lₐ₄₀₇ | P6 | H | P6 | P1 | H | H | H | CN | Ar5 |
| Lₐ₄₀₈ | P6 | H | P6 | P1 | H | H | H | CN | Ar6 |
| Lₐ₄₀₉ | P6 | H | P6 | P1 | H | H | H | CN | Ar7 |
| Lₐ₄₁₀ | P6 | H | P6 | P1 | H | H | H | CN | Ar8 |
| Lₐ₄₁₁ | P6 | H | P6 | P1 | H | H | H | CN | Ar9 |
| Lₐ₄₁₂ | P6 | H | P6 | P1 | H | H | H | CN | Ar10 |
| Lₐ₄₁₃ | P6 | H | P6 | P1 | H | H | H | CN | Ar11 |
| Lₐ₄₁₄ | P6 | H | P6 | P1 | H | H | H | CN | Ar12 |
| Lₐ₄₁₅ | P6 | H | P6 | P1 | H | H | H | CN | Ar13 |
| Lₐ₄₁₆ | P6 | H | P6 | P1 | H | H | H | CN | Ar14 |
| Lₐ₄₁₇ | P6 | H | P6 | P1 | H | H | H | CN | Ar15 |
| Lₐ₄₁₈ | P6 | H | P6 | P1 | H | H | H | CN | Ar16 |
| Lₐ₄₁₉ | P6 | H | P6 | P1 | H | H | H | CN | Ar17 |
| Lₐ₄₂₀ | P6 | H | P6 | P1 | H | H | H | CN | Ar18 |
| Lₐ₄₂₁ | P6 | H | P6 | P1 | H | H | H | CN | Ar19 |
| Lₐ₄₂₂ | P6 | H | P6 | P1 | H | H | H | CN | Ar20 |
| Lₐ₄₂₃ | P6 | H | P6 | P1 | H | H | H | CN | Ar21 |
| Lₐ₄₂₄ | P6 | H | P6 | P1 | H | H | H | CN | Ar22 |
| Lₐ₄₂₅ | P6 | H | P6 | P1 | H | H | H | CN | Ar23 |
| Lₐ₄₂₆ | P6 | H | P6 | P1 | H | H | H | CN | Ar24 |
| Lₐ₄₂₇ | P6 | H | P6 | P1 | H | H | H | CN | Ar25 |
| Lₐ₄₂₈ | P6 | H | P6 | P1 | H | H | H | CN | Ar26 |
| Lₐ₄₂₉ | P6 | H | P6 | P1 | H | H | H | CN | Ar27 |
| Lₐ₄₃₀ | P6 | H | P6 | P1 | H | H | H | CN | Ar28 |
| Lₐ₄₃₁ | P6 | H | P6 | P1 | H | H | H | CN | Ar29 |
| Lₐ₄₃₂ | P6 | H | P6 | P1 | H | H | H | CN | Ar30 |
| Lₐ₄₃₃ | P6 | H | P6 | P1 | H | H | H | CN | Ar31 |
| Lₐ₄₃₄ | P6 | H | P6 | P1 | H | H | H | CN | Ar32 |
| Lₐ₄₃₅ | P6 | H | P6 | P1 | H | H | H | CN | Ar33 |
| Lₐ₄₃₆ | P6 | H | P6 | P1 | H | H | H | CN | Ar34 |
| Lₐ₄₃₇ | P6 | H | P6 | P1 | H | H | H | CN | Ar35 |
| Lₐ₄₃₈ | P6 | H | P6 | P1 | H | H | H | CN | Ar36 |
| Lₐ₄₃₉ | P6 | H | P6 | P1 | H | H | H | CN | Ar37 |
| Lₐ₄₄₀ | P6 | H | P6 | P1 | H | H | H | CN | Ar38 |
| Lₐ₄₄₁ | P6 | H | P6 | P1 | H | H | H | CN | Ar39 |
| Lₐ₄₄₂ | P6 | H | P6 | P1 | H | H | H | CN | Ar40 |
| Lₐ₄₄₃ | P6 | H | P6 | P1 | H | H | H | CN | Ar41 |
| Lₐ₄₄₄ | P6 | H | P6 | P1 | H | H | H | CN | Ar42 |
| Lₐ₄₄₅ | P6 | H | P6 | P1 | H | H | H | CN | Ar43 |
| Lₐ₄₄₆ | P6 | H | P6 | P1 | H | H | H | CN | Ar44 |
| Lₐ₄₄₇ | P6 | H | P6 | P1 | H | H | H | CN | Ar45 |
| Lₐ₄₄₈ | P6 | H | P6 | P1 | H | H | H | CN | Ar46 |
| Lₐ₄₄₉ | P6 | H | P6 | P1 | H | H | H | CN | Ar47 |
| Lₐ₄₅₀ | P6 | H | P6 | P1 | H | H | H | CN | Ar48 |
| Lₐ₄₅₁ | P6 | H | P6 | P1 | H | H | H | CN | Ar49 |
| Lₐ₄₅₂ | P6 | H | P6 | P1 | H | H | H | CN | Ar50 |
| Lₐ₄₅₃ | P6 | H | P6 | P1 | H | H | H | CN | Ar51 |
| Lₐ₄₅₄ | P6 | H | P6 | P1 | H | H | H | CN | Ar52 |
| Lₐ₄₅₅ | P6 | H | P6 | P1 | H | H | H | CN | Ar53 |
| Lₐ₄₅₆ | P6 | H | P6 | P1 | H | H | H | CN | Ar54 |
| Lₐ₄₅₇ | P6 | H | P6 | P1 | H | H | H | CN | Ar55 |
| Lₐ₄₅₈ | P6 | H | P6 | P1 | H | H | H | CN | Ar56 |
| Lₐ₄₅₉ | P6 | H | P6 | P1 | H | H | H | CN | Ar57 |
| Lₐ₄₆₀ | P6 | H | P6 | P1 | H | H | H | CN | Ar58 |
| Lₐ₄₆₁ | P6 | H | P6 | P1 | H | H | H | CN | Ar59 |
| Lₐ₄₆₂ | P6 | H | P6 | P1 | H | H | H | CN | Ar60 |
| Lₐ₄₆₃ | P6 | H | P6 | P1 | H | H | H | CN | Ar61 |
| Lₐ₄₆₄ | P6 | H | P6 | P1 | H | H | H | CN | Ar62 |
| Lₐ₄₆₅ | P6 | H | P6 | P1 | H | H | H | CN | Ar63 |
| Lₐ₄₆₆ | P6 | H | P6 | P1 | H | H | H | CN | Ar64 |
| Lₐ₄₆₇ | P6 | H | P6 | P1 | H | H | H | CN | Ar65 |
| Lₐ₄₆₈ | P6 | H | P6 | P1 | H | H | H | CN | Ar66 |
| Lₐ₄₆₉ | P6 | D | P6 | P2 | D | D | D | CN | Ar16 |
| Lₐ₄₇₀ | P6 | H | P10 | P1 | H | H | H | CN | Ar1 |
| Lₐ₄₇₁ | P6 | H | P10 | P1 | H | H | H | CN | Ar2 |
| Lₐ₄₇₂ | P6 | H | P10 | P1 | H | H | H | CN | Ar3 |
| Lₐ₄₇₃ | P6 | H | P10 | P1 | H | H | H | CN | Ar4 |
| Lₐ₄₇₄ | P6 | H | P10 | P1 | H | H | H | CN | Ar5 |
| Lₐ₄₇₅ | P6 | H | P10 | P1 | H | H | H | CN | Ar6 |
| Lₐ₄₇₆ | P6 | H | P10 | P1 | H | H | H | CN | Ar7 |
| Lₐ₄₇₇ | P6 | H | P10 | P1 | H | H | H | CN | Ar8 |
| Lₐ₄₇₈ | P6 | H | P10 | P1 | H | H | H | CN | Ar9 |
| Lₐ₄₇₉ | P6 | H | P10 | P1 | H | H | H | CN | Ar10 |
| Lₐ₄₈₀ | P6 | H | P10 | P1 | H | H | H | CN | Ar11 |
| Lₐ₄₈₁ | P6 | H | P10 | P1 | H | H | H | CN | Ar12 |
| Lₐ₄₈₂ | P6 | H | P10 | P1 | H | H | H | CN | Ar13 |
| Lₐ₄₈₃ | P6 | H | P10 | P1 | H | H | H | CN | Ar14 |
| Lₐ₄₈₄ | P6 | H | P10 | P1 | H | H | H | CN | Ar15 |
| Lₐ₄₈₅ | P6 | H | P10 | P1 | H | H | H | CN | Ar16 |
| Lₐ₄₈₆ | P6 | H | P10 | P1 | H | H | H | CN | Ar17 |
| Lₐ₄₈₇ | P6 | H | P10 | P1 | H | H | H | CN | Ar18 |
| Lₐ₄₈₈ | P6 | H | P10 | P1 | H | H | H | CN | Ar19 |
| Lₐ₄₈₉ | P6 | H | P10 | P1 | H | H | H | CN | Ar20 |
| Lₐ₄₉₀ | P6 | H | P10 | P1 | H | H | H | CN | Ar21 |
| Lₐ₄₉₁ | P6 | H | P10 | P1 | H | H | H | CN | Ar22 |
| Lₐ₄₉₂ | P6 | H | P10 | P1 | H | H | H | CN | Ar23 |
| Lₐ₄₉₃ | P6 | H | P10 | P1 | H | H | H | CN | Ar24 |
| Lₐ₄₉₄ | P6 | H | P10 | P1 | H | H | H | CN | Ar25 |
| Lₐ₄₉₅ | P6 | H | P10 | P1 | H | H | H | CN | Ar26 |
| Lₐ₄₉₆ | P6 | H | P10 | P1 | H | H | H | CN | Ar27 |
| Lₐ₄₉₇ | P6 | H | P10 | P1 | H | H | H | CN | Ar28 |
| Lₐ₄₉₈ | P6 | H | P10 | P1 | H | H | H | CN | Ar29 |
| Lₐ₄₉₉ | P6 | H | P10 | P1 | H | H | H | CN | Ar30 |
| Lₐ₅₀₀ | P6 | H | P10 | P1 | H | H | H | CN | Ar31 |
| Lₐ₅₀₁ | P6 | H | P10 | P1 | H | H | H | CN | Ar32 |
| Lₐ₅₀₂ | P6 | H | P10 | P1 | H | H | H | CN | Ar33 |
| Lₐ₅₀₃ | P6 | H | P10 | P1 | H | H | H | CN | Ar34 |
| Lₐ₅₀₄ | P6 | H | P10 | P1 | H | H | H | CN | Ar35 |
| Lₐ₅₀₅ | P6 | H | P10 | P1 | H | H | H | CN | Ar36 |
| Lₐ₅₀₆ | P6 | H | P10 | P1 | H | H | H | CN | Ar37 |
| Lₐ₅₀₇ | P6 | H | P10 | P1 | H | H | H | CN | Ar38 |
| Lₐ₅₀₈ | P6 | H | P10 | P1 | H | H | H | CN | Ar39 |
| Lₐ₅₀₉ | P6 | H | P10 | P1 | H | H | H | CN | Ar40 |
| Lₐ₅₁₀ | P6 | H | P10 | P1 | H | H | H | CN | Ar41 |
| Lₐ₅₁₁ | P6 | H | P10 | P1 | H | H | H | CN | Ar42 |
| Lₐ₅₁₂ | P6 | H | P10 | P1 | H | H | H | CN | Ar43 |
| Lₐ₅₁₃ | P6 | H | P10 | P1 | H | H | H | CN | Ar44 |
| Lₐ₅₁₄ | P6 | H | P10 | P1 | H | H | H | CN | Ar45 |
| Lₐ₅₁₅ | P6 | H | P10 | P1 | H | H | H | CN | Ar46 |
| Lₐ₅₁₆ | P6 | H | P10 | P1 | H | H | H | CN | Ar47 |
| Lₐ₅₁₇ | P6 | H | P10 | P1 | H | H | H | CN | Ar48 |
| Lₐ₅₁₈ | P6 | H | P10 | P1 | H | H | H | CN | Ar49 |
| Lₐ₅₁₉ | P6 | H | P10 | P1 | H | H | H | CN | Ar50 |
| Lₐ₅₂₀ | P6 | H | P10 | P1 | H | H | H | CN | Ar51 |
| Lₐ₅₂₁ | P6 | H | P10 | P1 | H | H | H | CN | Ar52 |
| Lₐ₅₂₂ | P6 | H | P10 | P1 | H | H | H | CN | Ar53 |
| Lₐ₅₂₃ | P6 | H | P10 | P1 | H | H | H | CN | Ar54 |
| Lₐ₅₂₄ | P6 | H | P10 | P1 | H | H | H | CN | Ar55 |
| Lₐ₅₂₅ | P6 | H | P10 | P1 | H | H | H | CN | Ar56 |
| Lₐ₅₂₆ | P6 | H | P10 | P1 | H | H | H | CN | Ar57 |
| Lₐ₅₂₇ | P6 | H | P10 | P1 | H | H | H | CN | Ar58 |
| Lₐ₅₂₈ | P6 | H | P10 | P1 | H | H | H | CN | Ar59 |
| Lₐ₅₂₉ | P6 | H | P10 | P1 | H | H | H | CN | Ar60 |
| Lₐ₅₃₀ | P6 | H | P10 | P1 | H | H | H | CN | Ar61 |
| Lₐ₅₃₁ | P6 | H | P10 | P1 | H | H | H | CN | Ar62 |
| Lₐ₅₃₂ | P6 | H | P10 | P1 | H | H | H | CN | Ar63 |
| Lₐ₅₃₃ | P6 | H | P10 | P1 | H | H | H | CN | Ar64 |
| Lₐ₅₃₄ | P6 | H | P10 | P1 | H | H | H | CN | Ar65 |
| Lₐ₅₃₅ | P6 | H | P10 | P1 | H | H | H | CN | Ar66 |
| Lₐ₅₃₆ | P6 | D | P11 | P2 | D | D | D | CN | Ar16 |
| Lₐ₅₃₇ | P6 | H | P3 | H | H | H | H | CN | Ar16 |
| Lₐ₅₃₈ | P6 | H | P4 | H | H | H | H | CN | Ar16 |
| Lₐ₅₃₉ | P6 | H | P5 | H | H | H | H | CN | Ar16 |
| Lₐ₅₄₀ | P6 | H | P7 | H | H | H | H | CN | Ar16 |
| Lₐ₅₄₁ | P6 | H | P8 | H | H | H | H | CN | Ar16 |
| Lₐ₅₄₂ | P6 | H | P9 | H | H | H | H | CN | Ar16 |
| Lₐ₅₄₃ | P6 | H | P12 | H | H | H | H | CN | Ar16 |
| Lₐ₅₄₄ | P6 | H | P13 | H | H | H | H | CN | Ar16 |
| Lₐ₅₄₅ | P6 | H | P14 | H | H | H | H | CN | Ar16 |
| Lₐ₅₄₆ | P6 | H | P15 | H | H | H | H | CN | Ar16 |
| Lₐ₅₄₇ | P6 | H | P16 | H | H | H | H | CN | Ar16 |
| Lₐ₅₄₈ | P6 | H | P17 | H | H | H | H | CN | Ar16 |
| Lₐ₅₄₉ | P6 | H | P18 | H | H | H | H | CN | Ar16 |
| Lₐ₅₅₀ | P6 | H | P19 | H | H | H | H | CN | Ar16 |
| Lₐ₅₅₁ | P6 | H | P20 | H | H | H | H | CN | Ar16 |
| Lₐ₅₅₂ | P6 | H | P21 | H | H | H | H | CN | Ar16 |
| Lₐ₅₅₃ | P6 | H | P22 | H | H | H | H | CN | Ar16 |
| Lₐ₅₅₄ | P6 | H | P23 | H | H | H | H | CN | Ar16 |
| Lₐ₅₅₅ | P6 | H | P24 | H | H | H | H | CN | Ar16 |
| Lₐ₅₅₆ | P6 | H | P25 | H | H | H | H | CN | Ar16 |
| Lₐ₅₅₇ | P6 | H | P26 | H | H | H | H | CN | Ar16 |
| Lₐ₅₅₈ | P6 | H | P27 | H | H | H | H | CN | Ar16 |
| Lₐ₅₅₉ | P6 | H | P28 | H | H | H | H | CN | Ar16 |
| Lₐ₅₆₀ | P6 | H | P29 | H | H | H | H | CN | Ar16 |
| Lₐ₅₆₁ | P6 | H | P30 | H | H | H | H | CN | Ar16 |
| Lₐ₅₆₂ | P6 | H | P3 | H | H | H | H | CN | Ar16 |
| Lₐ₅₆₃ | P6 | H | P32 | H | H | H | H | CN | Ar16 |
| Lₐ₅₆₄ | P6 | H | P33 | H | H | H | H | CN | Ar16 |
| Lₐ₅₆₅ | P6 | H | P34 | H | H | H | H | CN | Ar16 |
| Lₐ₅₆ | P6 | H | P35 | H | H | H | H | CN | Ar16 |
| Lₐ₅₆₇ | P6 | H | P36 | H | H | H | H | CN | Ar16 |
| Lₐ₅₆₈ | P6 | H | P37 | H | H | H | H | CN | Ar16 |
| Lₐ₅₆₉ | P6 | H | P38 | H | H | H | H | CN | Ar16 |
| Lₐ₅₇₀ | P6 | H | P39 | H | H | H | H | CN | Ar16 |
| Lₐ₅₇₁ | P6 | H | P40 | H | H | H | H | CN | Ar16 |
| Lₐ₅₇₂ | P6 | H | P41 | H | H | H | H | CN | Ar16 |
| Lₐ₅₇₃ | P6 | H | P42 | H | H | H | H | CN | Ar16 |
| Lₐ₅₇₄ | P6 | H | P43 | H | H | H | H | CN | Ar16 |
| Lₐ₅₇₅ | P6 | H | P44 | H | H | H | H | CN | Ar16 |
| Lₐ₅₇₆ | P6 | H | P45 | H | H | H | H | CN | Ar16 |
| Lₐ₅₇₇ | P6 | H | P46 | H | H | H | H | CN | Ar16 |
| Lₐ₅₇₈ | P6 | H | P47 | H | H | H | H | CN | Ar16 |
| Lₐ₅₇₉ | P6 | H | P48 | H | H | H | H | CN | Ar16 |
| Lₐ₅₈₀ | P6 | H | P49 | H | H | H | H | CN | Ar16 |
| Lₐ₅₈₁ | P6 | H | P50 | H | H | H | H | CN | Ar16 |
| Lₐ₅₈₂ | P6 | H | P5 | H | H | H | H | CN | Ar16 |
| Lₐ₅₈₃ | P6 | H | P52 | H | H | H | H | CN | Ar16 |
| Lₐ₅₈₄ | P6 | H | P53 | H | H | H | H | CN | Ar16 |
| Lₐ₅₈₅ | P6 | H | P54 | H | H | H | H | CN | Ar16 |
| Lₐ₅₈₆ | P6 | H | H | P3 | H | H | H | CN | Ar16 |
| Lₐ₅₈₇ | P6 | H | H | P4 | H | H | H | CN | Ar16 |
| Lₐ₅₈₈ | P6 | H | H | P5 | H | H | H | CN | Ar16 |
| Lₐ₅₈₉ | P6 | H | H | P7 | H | H | H | CN | Ar16 |
| Lₐ₅₉₀ | P6 | H | H | P8 | H | H | H | CN | Ar16 |
| Lₐ₅₉₁ | P6 | H | H | P9 | H | H | H | CN | Ar16 |
| Lₐ₅₉₂ | P6 | H | H | P12 | H | H | H | CN | Ar16 |
| Lₐ₅₉₃ | P6 | H | H | P13 | H | H | H | CN | Ar16 |
| Lₐ₅₉₄ | P6 | H | H | P14 | H | H | H | CN | Ar16 |
| Lₐ₅₉₅ | P6 | H | H | P15 | H | H | H | CN | Ar16 |
| Lₐ₅₉₆ | P6 | H | H | P16 | H | H | H | CN | Ar16 |
| Lₐ₅₉₇ | P6 | H | H | P17 | H | H | H | CN | Ar16 |
| Lₐ₅₉₈ | P6 | H | H | P18 | H | H | H | CN | Ar16 |
| Lₐ₅₉₉ | P6 | H | H | P19 | H | H | H | CN | Ar16 |
| Lₐ₆₀₀ | P6 | H | H | P20 | H | H | H | CN | Ar16 |
| Lₐ₆₀₁ | P6 | H | H | P21 | H | H | H | CN | Ar16 |
| Lₐ₆₀₂ | P6 | H | H | P22 | H | H | H | CN | Ar16 |
| Lₐ₆₀₃ | P6 | H | H | P23 | H | H | H | CN | Ar16 |
| Lₐ₆₀₄ | P6 | H | H | P24 | H | H | H | CN | Ar16 |
| Lₐ₆₀₅ | P6 | H | H | P25 | H | H | H | CN | Ar16 |
| Lₐ₆₀₆ | P6 | H | H | P26 | H | H | H | CN | Ar16 |
| Lₐ₆₀₇ | P6 | H | H | P27 | H | H | H | CN | Ar16 |
| Lₐ₆₀₈ | P6 | H | H | P28 | H | H | H | CN | Ar16 |
| Lₐ₆₀₉ | P6 | H | H | P29 | H | H | H | CN | Ar16 |
| Lₐ₆₁₀ | P6 | H | H | P30 | H | H | H | CN | Ar16 |
| Lₐ₆₁₁ | P6 | H | H | P31 | H | H | H | CN | Ar16 |
| Lₐ₆₁₂ | P6 | H | H | P32 | H | H | H | CN | Ar16 |
| Lₐ₆₁₃ | P6 | H | H | P33 | H | H | H | CN | Ar16 |
| Lₐ₆₁₄ | P6 | H | H | P34 | H | H | H | CN | Ar16 |
| Lₐ₆₁₅ | P6 | H | H | P35 | H | H | H | CN | Ar16 |
| Lₐ₆₁₆ | P6 | H | H | P36 | H | H | H | CN | Ar16 |
| Lₐ₆₁₇ | P6 | H | H | P37 | H | H | H | CN | Ar16 |
| Lₐ₆₁₈ | P6 | H | H | P38 | H | H | H | CN | Ar16 |
| Lₐ₆₁₉ | P6 | H | H | P39 | H | H | H | CN | Ar16 |
| Lₐ₆₂₀ | P6 | H | H | P40 | H | H | H | CN | Ar16 |
| Lₐ₆₂₁ | P6 | H | H | P41 | H | H | H | CN | Ar16 |
| Lₐ₆₂₂ | P6 | H | H | P42 | H | H | H | CN | Ar16 |
| Lₐ₆₂₃ | P6 | H | H | P43 | H | H | H | CN | Ar16 |
| Lₐ₆₂₄ | P6 | H | H | P44 | H | H | H | CN | Ar16 |
| Lₐ₆₂₅ | P6 | H | H | P45 | H | H | H | CN | Ar16 |
| Lₐ₆₂₆ | P6 | H | H | P46 | H | H | H | CN | Ar16 |
| Lₐ₆₂₇ | P6 | H | H | P47 | H | H | H | CN | Ar16 |
| Lₐ₆₂₈ | P6 | H | H | P48 | H | H | H | CN | Ar16 |
| Lₐ₆₂₉ | P6 | H | H | P49 | H | H | H | CN | Ar16 |
| Lₐ₆₃₀ | P6 | H | H | P50 | H | H | H | CN | Ar16 |
| Lₐ₆₃₁ | P6 | H | H | P51 | H | H | H | CN | Ar16 |
| Lₐ₆₃₂ | P6 | H | H | P52 | H | H | H | CN | Ar16 |
| Lₐ₆₃₃ | P6 | H | H | P53 | H | H | H | CN | Ar16 |
| Lₐ₆₃₄ | P6 | H | H | P54 | H | H | H | CN | Ar16 |
| Lₐ₆₃₅ | P6 | H | H | P6 | H | H | H | Ar1 | CN |
| Lₐ₆₃₆ | P6 | H | H | P6 | H | H | H | Ar2 | CN |
| Lₐ₆₃₇ | P6 | H | H | P6 | H | H | H | Ar3 | CN |
| Lₐ₆₃₈ | P6 | H | H | P6 | H | H | H | Ar4 | CN |
| Lₐ₆₃₉ | P6 | H | H | P6 | H | H | H | Ar5 | CN |
| Lₐ₆₄₀ | P6 | H | H | P6 | H | H | H | Ar6 | CN |
| Lₐ₆₄₁ | P6 | H | H | P6 | H | H | H | Ar7 | CN |
| Lₐ₆₄₂ | P6 | H | H | P6 | H | H | H | Ar8 | CN |
| Lₐ₆₄₃ | P6 | H | H | P6 | H | H | H | Ar9 | CN |
| Lₐ₆₄₄ | P6 | H | H | P6 | H | H | H | Ar10 | CN |
| Lₐ₆₄₅ | P6 | H | H | P6 | H | H | H | Ar11 | CN |
| Lₐ₆₄₆ | P6 | H | H | P6 | H | H | H | Ar12 | CN |
| Lₐ₆₄₇ | P6 | H | H | P6 | H | H | H | Ar13 | CN |
| Lₐ₆₄₈ | P6 | H | H | P6 | H | H | H | Ar14 | CN |
| Lₐ₆₄₉ | P6 | H | H | P6 | H | H | H | Ar15 | CN |
| Lₐ₆₅₀ | P6 | H | H | P6 | H | H | H | Ar16 | CN |
| Lₐ₆₅₁ | P6 | H | H | P6 | H | H | H | Ar17 | CN |
| Lₐ₆₅₂ | P6 | H | H | P6 | H | H | H | Ar18 | CN |
| Lₐ₆₅₃ | P6 | H | H | P6 | H | H | H | Ar19 | CN |
| Lₐ₆₅₄ | P6 | H | H | P6 | H | H | H | Ar20 | CN |
| Lₐ₆₅₅ | P6 | H | H | P6 | H | H | H | Ar21 | CN |
| Lₐ₆₅₆ | P6 | H | H | P6 | H | H | H | Ar22 | CN |
| Lₐ₆₅₇ | P6 | H | H | P6 | H | H | H | Ar23 | CN |
| Lₐ₆₅₈ | P6 | H | H | P6 | H | H | H | Ar24 | CN |
| Lₐ₆₅₉ | P6 | H | H | P6 | H | H | H | Ar25 | CN |
| Lₐ₆₆₀ | P6 | H | H | P6 | H | H | H | Ar26 | CN |
| Lₐ₆₆₁ | P6 | H | H | P6 | H | H | H | Ar27 | CN |
| Lₐ₆₆₂ | P6 | H | H | P6 | H | H | H | Ar28 | CN |
| Lₐ₆₆₃ | P6 | H | H | P6 | H | H | H | Ar29 | CN |
| Lₐ₆₆₄ | P6 | H | H | P6 | H | H | H | Ar30 | CN |
| Lₐ₆₆₅ | P6 | H | H | P6 | H | H | H | Ar31 | CN |
| Lₐ₆₆₆ | P6 | H | H | P6 | H | H | H | Ar32 | CN |
| Lₐ₆₆₇ | P6 | H | H | P6 | H | H | H | Ar33 | CN |
| Lₐ₆₆₈ | P6 | H | H | P6 | H | H | H | Ar34 | CN |
| Lₐ₆₆₉ | P6 | H | H | P6 | H | H | H | Ar35 | CN |
| Lₐ₆₇₀ | P6 | H | H | P6 | H | H | H | Ar36 | CN |
| Lₐ₆₇₁ | P6 | H | H | P6 | H | H | H | Ar37 | CN |
| Lₐ₆₇₂ | P6 | H | H | P6 | H | H | H | Ar38 | CN |
| Lₐ₆₇₃ | P6 | H | H | P6 | H | H | H | Ar39 | CN |
| Lₐ₆₇₄ | P6 | H | H | P6 | H | H | H | Ar40 | CN |
| Lₐ₆₇₅ | P6 | H | H | P6 | H | H | H | Ar41 | CN |
| Lₐ₆₇₆ | P6 | H | H | P6 | H | H | H | Ar42 | CN |
| Lₐ₆₇₇ | P6 | H | H | P6 | H | H | H | Ar43 | CN |
| Lₐ₆₇₈ | P6 | H | H | P6 | H | H | H | Ar44 | CN |
| Lₐ₆₇₉ | P6 | H | H | P6 | H | H | H | Ar45 | CN |
| Lₐ₆₈₀ | P6 | H | H | P6 | H | H | H | Ar46 | CN |
| Lₐ₆₈₁ | P6 | H | H | P6 | H | H | H | Ar47 | CN |
| Lₐ₆₈₂ | P6 | H | H | P6 | H | H | H | Ar48 | CN |
| Lₐ₆₈₃ | P6 | H | H | P6 | H | H | H | Ar49 | CN |
| Lₐ₆₈₄ | P6 | H | H | P6 | H | H | H | Ar50 | CN |
| Lₐ₆₈₅ | P6 | H | H | P6 | H | H | H | Ar51 | CN |
| Lₐ₆₈₆ | P6 | H | H | P6 | H | H | H | Ar52 | CN |
| Lₐ₆₈₇ | P6 | H | H | P6 | H | H | H | Ar53 | CN |
| Lₐ₆₈₈ | P6 | H | H | P6 | H | H | H | Ar54 | CN |
| Lₐ₆₈₉ | P6 | H | H | P6 | H | H | H | Ar55 | CN |
| Lₐ₆₉₀ | P6 | H | H | P6 | H | H | H | Ar56 | CN |
| Lₐ₆₉₁ | P6 | H | H | P6 | H | H | H | Ar57 | CN |
| Lₐ₆₉₂ | P6 | H | H | P6 | H | H | H | Ar58 | CN |
| Lₐ₆₉₃ | P6 | H | H | P6 | H | H | H | Ar59 | CN |
| Lₐ₆₉₄ | P6 | H | H | P6 | H | H | H | Ar60 | CN |
| Lₐ₆₉₅ | P6 | H | H | P6 | H | H | H | Ar61 | CN |
| Lₐ₆₉₆ | P6 | H | H | P6 | H | H | H | Ar62 | CN |
| Lₐ₆₉₇ | P6 | H | H | P6 | H | H | H | Ar63 | CN |
| Lₐ₆₉₈ | P6 | H | H | P6 | H | H | H | Ar64 | CN |
| Lₐ₆₉₉ | P6 | H | H | P6 | H | H | H | Ar65 | CN |
| Lₐ₇₀₀ | P6 | H | H | P6 | H | H | H | Ar66 | CN |
| Lₐ₇₀₁ | P6 | D | D | P6 | D | D | D | Ar16 | CN |
| Lₐ₇₀₂ | P6 | H | H | P10 | H | H | H | Ar1 | CN |
| Lₐ₇₀₃ | P6 | H | H | P10 | H | H | H | Ar2 | CN |
| Lₐ₇₀₄ | P6 | H | H | P10 | H | H | H | Ar3 | CN |
| Lₐ₇₀₅ | P6 | H | H | P10 | H | H | H | Ar4 | CN |
| Lₐ₇₀₆ | P6 | H | H | P10 | H | H | H | Ar5 | CN |
| Lₐ₇₀₇ | P6 | H | H | P10 | H | H | H | Ar6 | CN |
| Lₐ₇₀₈ | P6 | H | H | P10 | H | H | H | Ar7 | CN |
| Lₐ₇₀₉ | P6 | H | H | P10 | H | H | H | Ar8 | CN |
| Lₐ₇₁₀ | P6 | H | H | P10 | H | H | H | Ar9 | CN |
| Lₐ₇₁₁ | P6 | H | H | P10 | H | H | H | Ar10 | CN |
| Lₐ₇₁₂ | P6 | H | H | P10 | H | H | H | Ar11 | CN |
| Lₐ₇₁₃ | P6 | H | H | P10 | H | H | H | Ar12 | CN |
| Lₐ₇₁₄ | P6 | H | H | P10 | H | H | H | Ar13 | CN |
| Lₐ₇₁₅ | P6 | H | H | P10 | H | H | H | Ar14 | CN |
| Lₐ₇₁₆ | P6 | H | H | P10 | H | H | H | Ar15 | CN |
| Lₐ₇₁₇ | P6 | H | H | P10 | H | H | H | Ar16 | CN |
| Lₐ₇₁₈ | P6 | H | H | P10 | H | H | H | Ar17 | CN |
| Lₐ₇₁₉ | P6 | H | H | P10 | H | H | H | Ar18 | CN |
| Lₐ₇₂₀ | P6 | H | H | P10 | H | H | H | Ar19 | CN |
| Lₐ₇₂₁ | P6 | H | H | P10 | H | H | H | Ar20 | CN |
| Lₐ₇₂₂ | P6 | H | H | P10 | H | H | H | Ar21 | CN |
| Lₐ₇₂₃ | P6 | H | H | P10 | H | H | H | Ar22 | CN |
| Lₐ₇₂₄ | P6 | H | H | P10 | H | H | H | Ar23 | CN |
| Lₐ₇₂₅ | P6 | H | H | P10 | H | H | H | Ar24 | CN |
| Lₐ₇₂₆ | P6 | H | H | P10 | H | H | H | Ar25 | CN |
| Lₐ₇₂₇ | P6 | H | H | P10 | H | H | H | Ar26 | CN |
| Lₐ₇₂₈ | P6 | H | H | P10 | H | H | H | Ar27 | CN |
| Lₐ₇₂₉ | P6 | H | H | P10 | H | H | H | Ar28 | CN |
| Lₐ₇₃₀ | P6 | H | H | P10 | H | H | H | Ar29 | CN |
| Lₐ₇₃₁ | P6 | H | H | P10 | H | H | H | Ar30 | CN |
| Lₐ₇₃₂ | P6 | H | H | P10 | H | H | H | Ar31 | CN |
| Lₐ₇₃₃ | P6 | H | H | P10 | H | H | H | Ar32 | CN |
| Lₐ₇₃₄ | P6 | H | H | P10 | H | H | H | Ar33 | CN |
| Lₐ₇₃₅ | P6 | H | H | P10 | H | H | H | Ar34 | CN |
| Lₐ₇₃₆ | P6 | H | H | P10 | H | H | H | Ar35 | CN |
| Lₐ₇₃₇ | P6 | H | H | P10 | H | H | H | Ar36 | CN |
| Lₐ₇₃₈ | P6 | H | H | P10 | H | H | H | Ar37 | CN |
| Lₐ₇₃₉ | P6 | H | H | P10 | H | H | H | Ar38 | CN |
| Lₐ₇₄₀ | P6 | H | H | P10 | H | H | H | Ar39 | CN |
| Lₐ₇₄₁ | P6 | H | H | P10 | H | H | H | Ar40 | CN |
| Lₐ₇₄₂ | P6 | H | H | P10 | H | H | H | Ar41 | CN |
| Lₐ₇₄₃ | P6 | H | H | P10 | H | H | H | Ar42 | CN |
| Lₐ₇₄₄ | P6 | H | H | P10 | H | H | H | Ar43 | CN |
| Lₐ₇₄₅ | P6 | H | H | P10 | H | H | H | Ar44 | CN |
| Lₐ₇₄₆ | P6 | H | H | P10 | H | H | H | Ar45 | CN |
| Lₐ₇₄₇ | P6 | H | H | P10 | H | H | H | Ar46 | CN |
| Lₐ₇₄₈ | P6 | H | H | P10 | H | H | H | Ar47 | CN |
| Lₐ₇₄₉ | P6 | H | H | P10 | H | H | H | Ar48 | CN |
| Lₐ₇₅₀ | P6 | H | H | P10 | H | H | H | Ar49 | CN |
| Lₐ₇₅₁ | P6 | H | H | P10 | H | H | H | Ar50 | CN |
| Lₐ₇₅₂ | P6 | H | H | P10 | H | H | H | Ar51 | CN |
| Lₐ₇₅₃ | P6 | H | H | P10 | H | H | H | Ar52 | CN |
| Lₐ₇₅₄ | P6 | H | H | P10 | H | H | H | Ar53 | CN |
| Lₐ₇₅₅ | P6 | H | H | P10 | H | H | H | Ar54 | CN |
| Lₐ₇₅₆ | P6 | H | H | P10 | H | H | H | Ar55 | CN |
| Lₐ₇₅₇ | P6 | H | H | P10 | H | H | H | Ar56 | CN |
| Lₐ₇₅₈ | P6 | H | H | P10 | H | H | H | Ar57 | CN |
| Lₐ₇₅₉ | P6 | H | H | P10 | H | H | H | Ar58 | CN |
| Lₐ₇₆₀ | P6 | H | H | P10 | H | H | H | Ar59 | CN |
| Lₐ₇₆₁ | P6 | H | H | P10 | H | H | H | Ar60 | CN |
| Lₐ₇₆₂ | P6 | H | H | P10 | H | H | H | Ar61 | CN |
| Lₐ₇₆₃ | P6 | H | H | P10 | H | H | H | Ar62 | CN |
| Lₐ₇₆₄ | P6 | H | H | P10 | H | H | H | Ar63 | CN |
| Lₐ₇₆₅ | P6 | H | H | P10 | H | H | H | Ar64 | CN |
| Lₐ₇₆₆ | P6 | H | H | P10 | H | H | H | Ar65 | CN |
| Lₐ₇₆₇ | P6 | H | H | P10 | H | H | H | Ar66 | CN |
| Lₐ₇₆₈ | P6 | D | D | P11 | D | D | D | Ar16 | CN |
| Lₐ₇₆₉ | P6 | H | P1 | P6 | H | H | H | Ar1 | CN |
| Lₐ₇₇₀ | P6 | H | P1 | P6 | H | H | H | Ar2 | CN |
| Lₐ₇₇₁ | P6 | H | P1 | P6 | H | H | H | Ar3 | CN |
| Lₐ₇₇₂ | P6 | H | P1 | P6 | H | H | H | Ar4 | CN |
| Lₐ₇₇₃ | P6 | H | P1 | P6 | H | H | H | Ar5 | CN |
| Lₐ₇₇₄ | P6 | H | P1 | P6 | H | H | H | Ar6 | CN |
| Lₐ₇₇₅ | P6 | H | P1 | P6 | H | H | H | Ar7 | CN |
| Lₐ₇₇₆ | P6 | H | P1 | P6 | H | H | H | Ar8 | CN |
| Lₐ₇₇₇ | P6 | H | P1 | P6 | H | H | H | Ar9 | CN |
| Lₐ₇₇₈ | P6 | H | P1 | P6 | H | H | H | Ar10 | CN |
| Lₐ₇₇₉ | P6 | H | P1 | P6 | H | H | H | Ar11 | CN |
| Lₐ₇₈₀ | P6 | H | P1 | P6 | H | H | H | Ar12 | CN |
| Lₐ₇₈₁ | P6 | H | P1 | P6 | H | H | H | Ar13 | CN |
| Lₐ₇₈₂ | P6 | H | P1 | P6 | H | H | H | Ar14 | CN |
| Lₐ₇₈₃ | P6 | H | P1 | P6 | H | H | H | Ar15 | CN |
| Lₐ₇₈₄ | P6 | H | P1 | P6 | H | H | H | Ar16 | CN |
| Lₐ₇₈₅ | P6 | H | P1 | P6 | H | H | H | Ar17 | CN |
| Lₐ₇₈₆ | P6 | H | P1 | P6 | H | H | H | Ar18 | CN |
| Lₐ₇₈₇ | P6 | H | P1 | P6 | H | H | H | Ar19 | CN |
| Lₐ₇₈₈ | P6 | H | P1 | P6 | H | H | H | Ar20 | CN |
| Lₐ₇₈₉ | P6 | H | P1 | P6 | H | H | H | Ar21 | CN |
| Lₐ₇₉₀ | P6 | H | P1 | P6 | H | H | H | Ar22 | CN |
| Lₐ₇₉₁ | P6 | H | P1 | P6 | H | H | H | Ar23 | CN |
| Lₐ₇₉₂ | P6 | H | P1 | P6 | H | H | H | Ar24 | CN |
| Lₐ₇₉₃ | P6 | H | P1 | P6 | H | H | H | Ar25 | CN |
| Lₐ₇₉₄ | P6 | H | P1 | P6 | H | H | H | Ar26 | CN |
| Lₐ₇₉₅ | P6 | H | P1 | P6 | H | H | H | Ar27 | CN |
| Lₐ₇₉₆ | P6 | H | P1 | P6 | H | H | H | Ar28 | CN |
| Lₐ₇₉₇ | P6 | H | P1 | P6 | H | H | H | Ar29 | CN |
| Lₐ₇₉₈ | P6 | H | P1 | P6 | H | H | H | Ar30 | CN |
| Lₐ₇₉₉ | P6 | H | P1 | P6 | H | H | H | Ar31 | CN |
| Lₐ₈₀₀ | P6 | H | P1 | P6 | H | H | H | Ar32 | CN |
| Lₐ₈₀₁ | P6 | H | P1 | P6 | H | H | H | Ar33 | CN |
| Lₐ₈₀₂ | P6 | H | P1 | P6 | H | H | H | Ar34 | CN |
| Lₐ₈₀₃ | P6 | H | P1 | P6 | H | H | H | Ar35 | CN |
| Lₐ₈₀₄ | P6 | H | P1 | P6 | H | H | H | Ar36 | CN |
| Lₐ₈₀₅ | P6 | H | P1 | P6 | H | H | H | Ar37 | CN |
| Lₐ₈₀₆ | P6 | H | P1 | P6 | H | H | H | Ar38 | CN |
| Lₐ₈₀₇ | P6 | H | P1 | P6 | H | H | H | Ar39 | CN |
| Lₐ₈₀₈ | P6 | H | P1 | P6 | H | H | H | Ar40 | CN |
| Lₐ₈₀₉ | P6 | H | P1 | P6 | H | H | H | Ar41 | CN |
| Lₐ₈₁₀ | P6 | H | P1 | P6 | H | H | H | Ar42 | CN |
| Lₐ₈₁₁ | P6 | H | P1 | P6 | H | H | H | Ar43 | CN |
| Lₐ₈₁₂ | P6 | H | P1 | P6 | H | H | H | Ar44 | CN |
| Lₐ₈₁₃ | P6 | H | P1 | P6 | H | H | H | Ar45 | CN |
| Lₐ₈₁₄ | P6 | H | P1 | P6 | H | H | H | Ar46 | CN |
| Lₐ₈₁₅ | P6 | H | P1 | P6 | H | H | H | Ar47 | CN |
| Lₐ₈₁₆ | P6 | H | P1 | P6 | H | H | H | Ar48 | CN |
| Lₐ₈₁₇ | P6 | H | P1 | P6 | H | H | H | Ar49 | CN |
| Lₐ₈₁₈ | P6 | H | P1 | P6 | H | H | H | Ar50 | CN |
| Lₐ₈₁₉ | P6 | H | P1 | P6 | H | H | H | Ar51 | CN |
| Lₐ₈₂₀ | P6 | H | P1 | P6 | H | H | H | Ar52 | CN |
| Lₐ₈₂₁ | P6 | H | P1 | P6 | H | H | H | Ar53 | CN |
| Lₐ₈₂₂ | P6 | H | P1 | P6 | H | H | H | Ar54 | CN |
| Lₐ₈₂₃ | P6 | H | P1 | P6 | H | H | H | Ar55 | CN |
| Lₐ₈₂₄ | P6 | H | P1 | P6 | H | H | H | Ar56 | CN |
| Lₐ₈₂₅ | P6 | H | P1 | P6 | H | H | H | Ar57 | CN |
| Lₐ₈₂₆ | P6 | H | P1 | P6 | H | H | H | Ar58 | CN |
| Lₐ₈₂₇ | P6 | H | P1 | P6 | H | H | H | Ar59 | CN |
| Lₐ₈₂₈ | P6 | H | P1 | P6 | H | H | H | Ar60 | CN |
| Lₐ₈₂₉ | P6 | H | P1 | P6 | H | H | H | Ar61 | CN |
| Lₐ₈₃₀ | P6 | H | P1 | P6 | H | H | H | Ar62 | CN |
| Lₐ₈₃₁ | P6 | H | P1 | P6 | H | H | H | Ar63 | CN |
| Lₐ₈₃₂ | P6 | H | P1 | P6 | H | H | H | Ar64 | CN |
| Lₐ₈₃₃ | P6 | H | P1 | P6 | H | H | H | Ar65 | CN |
| Lₐ₈₃₄ | P6 | H | P1 | P6 | H | H | H | Ar66 | CN |
| Lₐ₈₃₅ | P6 | D | P2 | P6 | D | D | D | Ar16 | CN |
| Lₐ₈₃₆ | P6 | H | P1 | P10 | H | H | H | Ar1 | CN |
| Lₐ₈₃₇ | P6 | H | P1 | P10 | H | H | H | Ar2 | CN |
| Lₐ₈₃₈ | P6 | H | P1 | P10 | H | H | H | Ar3 | CN |
| Lₐ₈₃₉ | P6 | H | P1 | P10 | H | H | H | Ar4 | CN |
| Lₐ₈₄₀ | P6 | H | P1 | P10 | H | H | H | Ar5 | CN |
| Lₐ₈₄₁ | P6 | H | P1 | P10 | H | H | H | Ar6 | CN |
| Lₐ₈₄₂ | P6 | H | P1 | P10 | H | H | H | Ar7 | CN |
| Lₐ₈₄₃ | P6 | H | P1 | P10 | H | H | H | Ar8 | CN |
| Lₐ₈₄₄ | P6 | H | P1 | P10 | H | H | H | Ar9 | CN |
| Lₐ₈₄₅ | P6 | H | P1 | P10 | H | H | H | Ar10 | CN |
| Lₐ₈₄₆ | P6 | H | P1 | P10 | H | H | H | Ar11 | CN |
| Lₐ₈₄₇ | P6 | H | P1 | P10 | H | H | H | Ar12 | CN |
| Lₐ₈₄₈ | P6 | H | P1 | P10 | H | H | H | Ar13 | CN |
| Lₐ₈₄₉ | P6 | H | P1 | P10 | H | H | H | Ar14 | CN |
| Lₐ₈₅₀ | P6 | H | P1 | P10 | H | H | H | Ar15 | CN |
| Lₐ₈₅₁ | P6 | H | P1 | P10 | H | H | H | Ar16 | CN |
| Lₐ₈₅₂ | P6 | H | P1 | P10 | H | H | H | Ar17 | CN |
| Lₐ₈₅₃ | P6 | H | P1 | P10 | H | H | H | Ar18 | CN |
| Lₐ₈₅₄ | P6 | H | P1 | P10 | H | H | H | Ar19 | CN |
| Lₐ₈₅₅ | P6 | H | P1 | P10 | H | H | H | Ar20 | CN |
| Lₐ₈₅₆ | P6 | H | P1 | P10 | H | H | H | Ar21 | CN |
| Lₐ₈₅₇ | P6 | H | P1 | P10 | H | H | H | Ar22 | CN |
| Lₐ₈₅₈ | P6 | H | P1 | P10 | H | H | H | Ar23 | CN |
| Lₐ₈₅₉ | P6 | H | P1 | P10 | H | H | H | Ar24 | CN |
| Lₐ₈₆₀ | P6 | H | P1 | P10 | H | H | H | Ar25 | CN |
| Lₐ₈₆₁ | P6 | H | P1 | P10 | H | H | H | Ar26 | CN |
| Lₐ₈₆₂ | P6 | H | P1 | P10 | H | H | H | Ar27 | CN |
| Lₐ₈₆₃ | P6 | H | P1 | P10 | H | H | H | Ar28 | CN |
| Lₐ₈₆₄ | P6 | H | P1 | P10 | H | H | H | Ar29 | CN |
| Lₐ₈₆₅ | P6 | H | P1 | P10 | H | H | H | Ar30 | CN |
| Lₐ₈₆₆ | P6 | H | P1 | P10 | H | H | H | Ar31 | CN |
| Lₐ₈₆₇ | P6 | H | P1 | P10 | H | H | H | Ar32 | CN |
| Lₐ₈₆₈ | P6 | H | P1 | P10 | H | H | H | Ar33 | CN |
| Lₐ₈₆₉ | P6 | H | P1 | P10 | H | H | H | Ar34 | CN |
| Lₐ₈₇₀ | P6 | H | P1 | P10 | H | H | H | Ar35 | CN |
| Lₐ₈₇₁ | P6 | H | P1 | P10 | H | H | H | Ar36 | CN |
| Lₐ₈₇₂ | P6 | H | P1 | P10 | H | H | H | Ar37 | CN |
| Lₐ₈₇₃ | P6 | H | P1 | P10 | H | H | H | Ar38 | CN |
| Lₐ₈₇₄ | P6 | H | P1 | P10 | H | H | H | Ar39 | CN |
| Lₐ₈₇₅ | P6 | H | P1 | P10 | H | H | H | Ar40 | CN |
| Lₐ₈₇₆ | P6 | H | P1 | P10 | H | H | H | Ar41 | CN |
| Lₐ₈₇₇ | P6 | H | P1 | P10 | H | H | H | Ar42 | CN |
| Lₐ₈₇₈ | P6 | H | P1 | P10 | H | H | H | Ar43 | CN |
| Lₐ₈₇₉ | P6 | H | P1 | P10 | H | H | H | Ar44 | CN |
| Lₐ₈₈₀ | P6 | H | P1 | P10 | H | H | H | Ar45 | CN |
| Lₐ₈₈₁ | P6 | H | P1 | P10 | H | H | H | Ar46 | CN |
| Lₐ₈₈₂ | P6 | H | P1 | P10 | H | H | H | Ar47 | CN |
| Lₐ₈₈₃ | P6 | H | P1 | P10 | H | H | H | Ar48 | CN |
| Lₐ₈₈₄ | P6 | H | P1 | P10 | H | H | H | Ar49 | CN |
| Lₐ₈₈₅ | P6 | H | P1 | P10 | H | H | H | Ar50 | CN |
| Lₐ₈₈₆ | P6 | H | P1 | P10 | H | H | H | Ar51 | CN |
| Lₐ₈₈₇ | P6 | H | P1 | P10 | H | H | H | Ar52 | CN |
| Lₐ₈₈₈ | P6 | H | P1 | P10 | H | H | H | Ar53 | CN |
| Lₐ₈₈₉ | P6 | H | P1 | P10 | H | H | H | Ar54 | CN |
| Lₐ₈₉₀ | P6 | H | P1 | P10 | H | H | H | Ar55 | CN |
| Lₐ₈₉₁ | P6 | H | P1 | P10 | H | H | H | Ar56 | CN |
| Lₐ₈₉₂ | P6 | H | P1 | P10 | H | H | H | Ar57 | CN |
| Lₐ₈₉₃ | P6 | H | P1 | P10 | H | H | H | Ar58 | CN |
| Lₐ₈₉₄ | P6 | H | P1 | P10 | H | H | H | Ar59 | CN |
| Lₐ₈₉₅ | P6 | H | P1 | P10 | H | H | H | Ar60 | CN |
| Lₐ₈₉₆ | P6 | H | P1 | P10 | H | H | H | Ar61 | CN |
| Lₐ₈₉₇ | P6 | H | P1 | P10 | H | H | H | Ar62 | CN |
| Lₐ₈₉₈ | P6 | H | P1 | P10 | H | H | H | Ar63 | CN |
| Lₐ₈₉₉ | P6 | H | P1 | P10 | H | H | H | Ar64 | CN |
| Lₐ₉₀₀ | P6 | H | P1 | P10 | H | H | H | Ar65 | CN |
| Lₐ₉₀₁ | P6 | H | P1 | P10 | H | H | H | Ar66 | CN |
| Lₐ₉₀₂ | P6 | D | P2 | P11 | D | D | D | Ar16 | CN |
| Lₐ₉₀₃ | P6 | H | P6 | H | H | H | H | Ar1 | CN |
| Lₐ₉₀₄ | P6 | H | P6 | H | H | H | H | Ar2 | CN |
| Lₐ₉₀₅ | P6 | H | P6 | H | H | H | H | Ar3 | CN |
| Lₐ₉₀₆ | P6 | H | P6 | H | H | H | H | Ar4 | CN |
| Lₐ₉₀₇ | P6 | H | P6 | H | H | H | H | Ar5 | CN |
| Lₐ₉₀₈ | P6 | H | P6 | H | H | H | H | Ar6 | CN |
| Lₐ₉₀₉ | P6 | H | P6 | H | H | H | H | Ar7 | CN |
| Lₐ₉₁₀ | P6 | H | P6 | H | H | H | H | Ar8 | CN |
| Lₐ₉₁₁ | P6 | H | P6 | H | H | H | H | Ar9 | CN |
| Lₐ₉₁₂ | P6 | H | P6 | H | H | H | H | Ar10 | CN |
| Lₐ₉₁₃ | P6 | H | P6 | H | H | H | H | Ar11 | CN |
| Lₐ₉₁₄ | P6 | H | P6 | H | H | H | H | Ar12 | CN |
| Lₐ₉₁₅ | P6 | H | P6 | H | H | H | H | Ar13 | CN |
| Lₐ₉₁₆ | P6 | H | P6 | H | H | H | H | Ar14 | CN |
| Lₐ₉₁₇ | P6 | H | P6 | H | H | H | H | Ar15 | CN |
| Lₐ₉₁₈ | P6 | H | P6 | H | H | H | H | Ar16 | CN |
| Lₐ₉₁₉ | P6 | H | P6 | H | H | H | H | Ar17 | CN |
| Lₐ₉₂₀ | P6 | H | P6 | H | H | H | H | Ar18 | CN |
| Lₐ₉₂₁ | P6 | H | P6 | H | H | H | H | Ar19 | CN |
| Lₐ₉₂₂ | P6 | H | P6 | H | H | H | H | Ar20 | CN |
| Lₐ₉₂₃ | P6 | H | P6 | H | H | H | H | Ar21 | CN |
| Lₐ₉₂₄ | P6 | H | P6 | H | H | H | H | Ar22 | CN |
| Lₐ₉₂₅ | P6 | H | P6 | H | H | H | H | Ar23 | CN |
| Lₐ₉₂₆ | P6 | H | P6 | H | H | H | H | Ar24 | CN |
| Lₐ₉₂₇ | P6 | H | P6 | H | H | H | H | Ar25 | CN |
| Lₐ₉₂₈ | P6 | H | P6 | H | H | H | H | Ar26 | CN |
| Lₐ₉₂₉ | P6 | H | P6 | H | H | H | H | Ar27 | CN |
| Lₐ₉₃₀ | P6 | H | P6 | H | H | H | H | Ar28 | CN |
| Lₐ₉₃₁ | P6 | H | P6 | H | H | H | H | Ar29 | CN |
| Lₐ₉₃₂ | P6 | H | P6 | H | H | H | H | Ar30 | CN |
| Lₐ₉₃₃ | P6 | H | P6 | H | H | H | H | Ar31 | CN |
| Lₐ₉₃₄ | P6 | H | P6 | H | H | H | H | Ar32 | CN |
| Lₐ₉₃₅ | P6 | H | P6 | H | H | H | H | Ar33 | CN |
| Lₐ₉₃₆ | P6 | H | P6 | H | H | H | H | Ar34 | CN |
| Lₐ₉₃₇ | P6 | H | P6 | H | H | H | H | Ar35 | CN |
| Lₐ₉₃₈ | P6 | H | P6 | H | H | H | H | Ar36 | CN |
| Lₐ₉₃₉ | P6 | H | P6 | H | H | H | H | Ar37 | CN |
| Lₐ₉₄₀ | P6 | H | P6 | H | H | H | H | Ar38 | CN |
| Lₐ₉₄₁ | P6 | H | P6 | H | H | H | H | Ar39 | CN |
| Lₐ₉₄₂ | P6 | H | P6 | H | H | H | H | Ar40 | CN |
| Lₐ₉₄₃ | P6 | H | P6 | H | H | H | H | Ar41 | CN |
| Lₐ₉₄₄ | P6 | H | P6 | H | H | H | H | Ar42 | CN |
| Lₐ₉₄₅ | P6 | H | P6 | H | H | H | H | Ar43 | CN |
| Lₐ₉₄₆ | P6 | H | P6 | H | H | H | H | Ar44 | CN |
| Lₐ₉₄₇ | P6 | H | P6 | H | H | H | H | Ar45 | CN |
| Lₐ₉₄₈ | P6 | H | P6 | H | H | H | H | Ar46 | CN |
| Lₐ₉₄₉ | P6 | H | P6 | H | H | H | H | Ar47 | CN |
| Lₐ₉₅₀ | P6 | H | P6 | H | H | H | H | Ar48 | CN |
| Lₐ₉₅₁ | P6 | H | P6 | H | H | H | H | Ar49 | CN |
| Lₐ₉₅₂ | P6 | H | P6 | H | H | H | H | Ar50 | CN |
| Lₐ₉₅₃ | P6 | H | P6 | H | H | H | H | Ar51 | CN |
| Lₐ₉₅₄ | P6 | H | P6 | H | H | H | H | Ar52 | CN |
| Lₐ₉₅₅ | P6 | H | P6 | H | H | H | H | Ar53 | CN |
| Lₐ₉₅₆ | P6 | H | P6 | H | H | H | H | Ar54 | CN |
| Lₐ₉₅₇ | P6 | H | P6 | H | H | H | H | Ar55 | CN |
| Lₐ₉₅₈ | P6 | H | P6 | H | H | H | H | Ar56 | CN |
| Lₐ₉₅₉ | P6 | H | P6 | H | H | H | H | Ar57 | CN |
| Lₐ₉₆₀ | P6 | H | P6 | H | H | H | H | Ar58 | CN |
| Lₐ₉₆₁ | P6 | H | P6 | H | H | H | H | Ar59 | CN |
| Lₐ₉₆₂ | P6 | H | P6 | H | H | H | H | Ar60 | CN |
| Lₐ₉₆₃ | P6 | H | P6 | H | H | H | H | Ar61 | CN |
| Lₐ₉₆₄ | P6 | H | P6 | H | H | H | H | Ar62 | CN |
| Lₐ₉₆₅ | P6 | H | P6 | H | H | H | H | Ar63 | CN |
| Lₐ₉₆₆ | P6 | H | P6 | H | H | H | H | Ar64 | CN |
| Lₐ₉₆₇ | P6 | H | P6 | H | H | H | H | Ar65 | CN |
| Lₐ₉₆₈ | P6 | H | P6 | H | H | H | H | Ar66 | CN |
| Lₐ₉₆₉ | P6 | D | P6 | D | D | D | D | Ar16 | CN |
| Lₐ₉₇₀ | P6 | H | P10 | H | H | H | H | Ar1 | CN |
| Lₐ₉₇₁ | P6 | H | P10 | H | H | H | H | Ar2 | CN |
| Lₐ₉₇₂ | P6 | H | P10 | H | H | H | H | Ar3 | CN |
| Lₐ₉₇₃ | P6 | H | P10 | H | H | H | H | Ar4 | CN |
| Lₐ₉₇₄ | P6 | H | P10 | H | H | H | H | Ar5 | CN |
| Lₐ₉₇₅ | P6 | H | P10 | H | H | H | H | Ar6 | CN |
| Lₐ₉₇₆ | P6 | H | P10 | H | H | H | H | Ar7 | CN |
| Lₐ₉₇₇ | P6 | H | P10 | H | H | H | H | Ar8 | CN |
| Lₐ₉₇₈ | P6 | H | P10 | H | H | H | H | Ar9 | CN |
| Lₐ₉₇₉ | P6 | H | P10 | H | H | H | H | Ar10 | CN |
| Lₐ₉₈₀ | P6 | H | P10 | H | H | H | H | Ar11 | CN |
| Lₐ₉₈₁ | P6 | H | P10 | H | H | H | H | Ar12 | CN |
| Lₐ₉₈₂ | P6 | H | P10 | H | H | H | H | Ar13 | CN |
| Lₐ₉₈₃ | P6 | H | P10 | H | H | H | H | Ar14 | CN |
| Lₐ₉₈₄ | P6 | H | P10 | H | H | H | H | Ar15 | CN |
| Lₐ₉₈₅ | P6 | H | P10 | H | H | H | H | Ar16 | CN |
| Lₐ₉₈₆ | P6 | H | P10 | H | H | H | H | Ar17 | CN |
| Lₐ₉₈₇ | P6 | H | P10 | H | H | H | H | Ar18 | CN |
| Lₐ₉₈₈ | P6 | H | P10 | H | H | H | H | Ar19 | CN |
| Lₐ₉₈₉ | P6 | H | P10 | H | H | H | H | Ar20 | CN |
| Lₐ₉₉₀ | P6 | H | P10 | H | H | H | H | Ar21 | CN |
| Lₐ₉₉₁ | P6 | H | P10 | H | H | H | H | Ar22 | CN |
| Lₐ₉₉₂ | P6 | H | P10 | H | H | H | H | Ar23 | CN |
| Lₐ₉₉₃ | P6 | H | P10 | H | H | H | H | Ar24 | CN |
| Lₐ₉₉₄ | P6 | H | P10 | H | H | H | H | Ar25 | CN |
| Lₐ₉₉₅ | P6 | H | P10 | H | H | H | H | Ar26 | CN |
| Lₐ₉₉₆ | P6 | H | P10 | H | H | H | H | Ar27 | CN |
| Lₐ₉₉₇ | P6 | H | P10 | H | H | H | H | Ar28 | CN |
| Lₐ₉₉₈ | P6 | H | P10 | H | H | H | H | Ar29 | CN |
| Lₐ₉₉₉ | P6 | H | P10 | H | H | H | H | Ar30 | CN |
| Lₐ₁₀₀₀ | P6 | H | P10 | H | H | H | H | Ar31 | CN |
| Lₐ₁₀₀₁ | P6 | H | P10 | H | H | H | H | Ar32 | CN |
| Lₐ₁₀₀₂ | P6 | H | P10 | H | H | H | H | Ar33 | CN |
| Lₐ₁₀₀₃ | P6 | H | P10 | H | H | H | H | Ar34 | CN |
| Lₐ₁₀₀₄ | P6 | H | P10 | H | H | H | H | Ar35 | CN |
| Lₐ₁₀₀₅ | P6 | H | P10 | H | H | H | H | Ar36 | CN |
| Lₐ₁₀₀₆ | P6 | H | P10 | H | H | H | H | Ar37 | CN |
| Lₐ₁₀₀₇ | P6 | H | P10 | H | H | H | H | Ar38 | CN |
| Lₐ₁₀₀₈ | P6 | H | P10 | H | H | H | H | Ar39 | CN |
| Lₐ₁₀₀₉ | P6 | H | P10 | H | H | H | H | Ar40 | CN |
| Lₐ₁₀₁₀ | P6 | H | P10 | H | H | H | H | Ar41 | CN |
| Lₐ₁₀₁₁ | P6 | H | P10 | H | H | H | H | Ar42 | CN |
| Lₐ₁₀₁₂ | P6 | H | P10 | H | H | H | H | Ar43 | CN |
| Lₐ₁₀₁₃ | P6 | H | P10 | H | H | H | H | Ar44 | CN |
| Lₐ₁₀₁₄ | P6 | H | P10 | H | H | H | H | Ar45 | CN |
| Lₐ₁₀₁₅ | P6 | H | P10 | H | H | H | H | Ar46 | CN |
| Lₐ₁₀₁₆ | P6 | H | P10 | H | H | H | H | Ar47 | CN |
| Lₐ₁₀₁₇ | P6 | H | P10 | H | H | H | H | Ar48 | CN |
| Lₐ₁₀₁₈ | P6 | H | P10 | H | H | H | H | Ar49 | CN |
| Lₐ₁₀₁₉ | P6 | H | P10 | H | H | H | H | Ar50 | CN |
| Lₐ₁₀₂₀ | P6 | H | P10 | H | H | H | H | Ar51 | CN |
| Lₐ₁₀₂₁ | P6 | H | P10 | H | H | H | H | Ar52 | CN |
| Lₐ₁₀₂₂ | P6 | H | P10 | H | H | H | H | Ar53 | CN |
| Lₐ₁₀₂₃ | P6 | H | P10 | H | H | H | H | Ar54 | CN |
| Lₐ₁₀₂₄ | P6 | H | P10 | H | H | H | H | Ar55 | CN |
| Lₐ₁₀₂₅ | P6 | H | P10 | H | H | H | H | Ar56 | CN |
| Lₐ₁₀₂₆ | P6 | H | P10 | H | H | H | H | Ar57 | CN |
| Lₐ₁₀₂₇ | P6 | H | P10 | H | H | H | H | Ar58 | CN |
| Lₐ₁₀₂₈ | P6 | H | P10 | H | H | H | H | Ar59 | CN |
| Lₐ₁₀₂₉ | P6 | H | P10 | H | H | H | H | Ar60 | CN |
| Lₐ₁₀₃₀ | P6 | H | P10 | H | H | H | H | Ar61 | CN |
| Lₐ₁₀₃₁ | P6 | H | P10 | H | H | H | H | Ar62 | CN |
| Lₐ₁₀₃₂ | P6 | H | P10 | H | H | H | H | Ar63 | CN |
| Lₐ₁₀₃₃ | P6 | H | P10 | H | H | H | H | Ar64 | CN |
| Lₐ₁₀₃₄ | P6 | H | P10 | H | H | H | H | Ar65 | CN |
| Lₐ₁₀₃₅ | P6 | H | P10 | H | H | H | H | Ar66 | CN |
| Lₐ₁₀₃₆ | P6 | D | P11 | D | D | D | D | Ar16 | CN |
| Lₐ₁₀₃₇ | P6 | H | P6 | P1 | H | H | H | Ar1 | CN |
| Lₐ₁₀₃₈ | P6 | H | P6 | P1 | H | H | H | Ar2 | CN |
| Lₐ₁₀₃₉ | P6 | H | P6 | P1 | H | H | H | Ar3 | CN |
| Lₐ₁₀₄₀ | P6 | H | P6 | P1 | H | H | H | Ar4 | CN |
| Lₐ₁₀₄₁ | P6 | H | P6 | P1 | H | H | H | Ar5 | CN |
| Lₐ₁₀₄₂ | P6 | H | P6 | P1 | H | H | H | Ar6 | CN |
| Lₐ₁₀₄₃ | P6 | H | P6 | P1 | H | H | H | Ar7 | CN |
| Lₐ₁₀₄₄ | P6 | H | P6 | P1 | H | H | H | Ar8 | CN |
| Lₐ₁₀₄₅ | P6 | H | P6 | P1 | H | H | H | Ar9 | CN |
| Lₐ₁₀₄₆ | P6 | H | P6 | P1 | H | H | H | Ar10 | CN |
| Lₐ₁₀₄₇ | P6 | H | P6 | P1 | H | H | H | Ar11 | CN |
| Lₐ₁₀₄₈ | P6 | H | P6 | P1 | H | H | H | Ar12 | CN |
| Lₐ₁₀₄₉ | P6 | H | P6 | P1 | H | H | H | Ar13 | CN |
| Lₐ₁₀₅₀ | P6 | H | P6 | P1 | H | H | H | Ar14 | CN |
| Lₐ₁₀₅₁ | P6 | H | P6 | P1 | H | H | H | Ar15 | CN |
| Lₐ₁₀₅₂ | P6 | H | P6 | P1 | H | H | H | Ar16 | CN |
| Lₐ₁₀₅₃ | P6 | H | P6 | P1 | H | H | H | Ar17 | CN |
| Lₐ₁₀₅₄ | P6 | H | P6 | P1 | H | H | H | Ar18 | CN |
| Lₐ₁₀₅₅ | P6 | H | P6 | P1 | H | H | H | Ar19 | CN |
| Lₐ₁₀₅₆ | P6 | H | P6 | P1 | H | H | H | Ar20 | CN |
| Lₐ₁₀₅₇ | P6 | H | P6 | P1 | H | H | H | Ar21 | CN |
| Lₐ₁₀₅₈ | P6 | H | P6 | P1 | H | H | H | Ar22 | CN |
| Lₐ₁₀₅₉ | P6 | H | P6 | P1 | H | H | H | Ar23 | CN |
| Lₐ₁₀₆₀ | P6 | H | P6 | P1 | H | H | H | Ar24 | CN |
| Lₐ₁₀₆₁ | P6 | H | P6 | P1 | H | H | H | Ar25 | CN |
| Lₐ₁₀₆₂ | P6 | H | P6 | P1 | H | H | H | Ar26 | CN |
| Lₐ₁₀₆₃ | P6 | H | P6 | P1 | H | H | H | Ar27 | CN |
| Lₐ₁₀₆₄ | P6 | H | P6 | P1 | H | H | H | Ar28 | CN |
| Lₐ₁₀₆₅ | P6 | H | P6 | P1 | H | H | H | Ar29 | CN |
| Lₐ₁₀₆₆ | P6 | H | P6 | P1 | H | H | H | Ar30 | CN |
| Lₐ₁₀₆₇ | P6 | H | P6 | P1 | H | H | H | Ar31 | CN |
| Lₐ₁₀₆₈ | P6 | H | P6 | P1 | H | H | H | Ar32 | CN |
| Lₐ₁₀₆₉ | P6 | H | P6 | P1 | H | H | H | Ar33 | CN |
| Lₐ₁₀₇₀ | P6 | H | P6 | P1 | H | H | H | Ar34 | CN |
| Lₐ₁₀₇₁ | P6 | H | P6 | P1 | H | H | H | Ar35 | CN |
| Lₐ₁₀₇₂ | P6 | H | P6 | P1 | H | H | H | Ar36 | CN |
| Lₐ₁₀₇₃ | P6 | H | P6 | P1 | H | H | H | Ar37 | CN |
| Lₐ₁₀₇₄ | P6 | H | P6 | P1 | H | H | H | Ar38 | CN |
| Lₐ₁₀₇₅ | P6 | H | P6 | P1 | H | H | H | Ar39 | CN |
| Lₐ₁₀₇₆ | P6 | H | P6 | P1 | H | H | H | Ar40 | CN |
| Lₐ₁₀₇₇ | P6 | H | P6 | P1 | H | H | H | Ar41 | CN |
| Lₐ₁₀₇₈ | P6 | H | P6 | P1 | H | H | H | Ar42 | CN |
| Lₐ₁₀₇₉ | P6 | H | P6 | P1 | H | H | H | Ar43 | CN |
| Lₐ₁₀₈₀ | P6 | H | P6 | P1 | H | H | H | Ar44 | CN |
| Lₐ₁₀₈₁ | P6 | H | P6 | P1 | H | H | H | Ar45 | CN |
| Lₐ₁₀₈₂ | P6 | H | P6 | P1 | H | H | H | Ar46 | CN |
| Lₐ₁₀₈₃ | P6 | H | P6 | P1 | H | H | H | Ar47 | CN |
| Lₐ₁₀₈₄ | P6 | H | P6 | P1 | H | H | H | Ar48 | CN |
| Lₐ₁₀₈₅ | P6 | H | P6 | P1 | H | H | H | Ar49 | CN |
| Lₐ₁₀₈₆ | P6 | H | P6 | P1 | H | H | H | Ar50 | CN |
| Lₐ₁₀₈₇ | P6 | H | P6 | P1 | H | H | H | Ar51 | CN |
| Lₐ₁₀₈₈ | P6 | H | P6 | P1 | H | H | H | Ar52 | CN |
| Lₐ₁₀₈₉ | P6 | H | P6 | P1 | H | H | H | Ar53 | CN |
| Lₐ₁₀₉₀ | P6 | H | P6 | P1 | H | H | H | Ar54 | CN |
| Lₐ₁₀₉₁ | P6 | H | P6 | P1 | H | H | H | Ar55 | CN |
| Lₐ₁₀₉₂ | P6 | H | P6 | P1 | H | H | H | Ar56 | CN |
| Lₐ₁₀₉₃ | P6 | H | P6 | P1 | H | H | H | Ar57 | CN |
| Lₐ₁₀₉₄ | P6 | H | P6 | P1 | H | H | H | Ar58 | CN |
| Lₐ₁₀₉₅ | P6 | H | P6 | P1 | H | H | H | Ar59 | CN |
| Lₐ₁₀₉₆ | P6 | H | P6 | P1 | H | H | H | Ar60 | CN |
| Lₐ₁₀₉₇ | P6 | H | P6 | P1 | H | H | H | Ar61 | CN |
| Lₐ₁₀₉₈ | P6 | H | P6 | P1 | H | H | H | Ar62 | CN |
| Lₐ₁₀₉₉ | P6 | H | P6 | P1 | H | H | H | Ar63 | CN |
| Lₐ₁₁₀₀ | P6 | H | P6 | P1 | H | H | H | Ar64 | CN |
| Lₐ₁₁₀₁ | P6 | H | P6 | P1 | H | H | H | Ar65 | CN |
| Lₐ₁₁₀₂ | P6 | H | P6 | P1 | H | H | H | Ar66 | CN |
| Lₐ₁₁₀₃ | P6 | D | P6 | P2 | D | D | D | Ar16 | CN |
| Lₐ₁₁₀₄ | P6 | H | P10 | P1 | H | H | H | Ar1 | CN |
| Lₐ₁₁₀₅ | P6 | H | P10 | P1 | H | H | H | Ar | CN |
| Lₐ₁₁₀₆ | P6 | H | P10 | P1 | H | H | H | Ar3 | CN |
| Lₐ₁₁₀₇ | P6 | H | P10 | P1 | H | H | H | Ar4 | CN |
| Lₐ₁₁₀₈ | P6 | H | P10 | P1 | H | H | H | Ar5 | CN |
| Lₐ₁₁₀₉ | P6 | H | P10 | P1 | H | H | H | Ar6 | CN |
| Lₐ₁₁₁₀ | P6 | H | P10 | P1 | H | H | H | Ar7 | CN |
| Lₐ₁₁₁₁ | P6 | H | P10 | P1 | H | H | H | Ar8 | CN |
| Lₐ₁₁₁₂ | P6 | H | P10 | P1 | H | H | H | Ar9 | CN |
| Lₐ₁₁₁₃ | P6 | H | P10 | P1 | H | H | H | Ar10 | CN |
| Lₐ₁₁₁₄ | P6 | H | P10 | P1 | H | H | H | Ar11 | CN |
| Lₐ₁₁₁₅ | P6 | H | P10 | P1 | H | H | H | Ar12 | CN |
| Lₐ₁₁₁₆ | P6 | H | P10 | P1 | H | H | H | Ar13 | CN |
| Lₐ₁₁₁₇ | P6 | H | P10 | P1 | H | H | H | Ar14 | CN |
| Lₐ₁₁₁₈ | P6 | H | P10 | P1 | H | H | H | Ar15 | CN |
| Lₐ₁₁₁₉ | P6 | H | P10 | P1 | H | H | H | Ar16 | CN |
| Lₐ₁₁₂₀ | P6 | H | P10 | P1 | H | H | H | Ar17 | CN |
| Lₐ₁₁₂₁ | P6 | H | P10 | P1 | H | H | H | Ar18 | CN |
| Lₐ₁₁₂₂ | P6 | H | P10 | P1 | H | H | H | Ar19 | CN |
| Lₐ₁₁₂₃ | P6 | H | P10 | P1 | H | H | H | Ar20 | CN |
| Lₐ₁₁₂₄ | P6 | H | P10 | P1 | H | H | H | Ar21 | CN |
| Lₐ₁₁₂₅ | P6 | H | P10 | P1 | H | H | H | Ar22 | CN |
| Lₐ₁₁₂₆ | P6 | H | P10 | P1 | H | H | H | Ar23 | CN |
| Lₐ₁₁₂₇ | P6 | H | P10 | P1 | H | H | H | Ar24 | CN |
| Lₐ₁₁₂₈ | P6 | H | P10 | P1 | H | H | H | Ar25 | CN |
| Lₐ₁₁₂₉ | P6 | H | P10 | P1 | H | H | H | Ar26 | CN |
| Lₐ₁₁₃₀ | P6 | H | P10 | P1 | H | H | H | Ar27 | CN |
| Lₐ₁₁₃₁ | P6 | H | P10 | P1 | H | H | H | Ar28 | CN |
| Lₐ₁₁₃₂ | P6 | H | P10 | P1 | H | H | H | Ar29 | CN |
| Lₐ₁₁₃₃ | P6 | H | P10 | P1 | H | H | H | Ar30 | CN |
| Lₐ₁₁₃₄ | P6 | H | P10 | P1 | H | H | H | Ar31 | CN |
| Lₐ₁₁₃₅ | P6 | H | P10 | P1 | H | H | H | Ar32 | CN |
| Lₐ₁₁₃₆ | P6 | H | P10 | P1 | H | H | H | Ar33 | CN |
| Lₐ₁₁₃₇ | P6 | H | P10 | P1 | H | H | H | Ar34 | CN |
| Lₐ₁₁₃₈ | P6 | H | P10 | P1 | H | H | H | Ar35 | CN |
| Lₐ₁₁₃₉ | P6 | H | P10 | P1 | H | H | H | Ar36 | CN |
| Lₐ₁₁₄₀ | P6 | H | P10 | P1 | H | H | H | Ar37 | CN |
| Lₐ₁₁₄₁ | P6 | H | P10 | P1 | H | H | H | Ar38 | CN |
| Lₐ₁₁₄₂ | P6 | H | P10 | P1 | H | H | H | Ar39 | CN |
| Lₐ₁₁₄₃ | P6 | H | P10 | P1 | H | H | H | Ar40 | CN |
| Lₐ₁₁₄₄ | P6 | H | P10 | P1 | H | H | H | Ar41 | CN |
| Lₐ₁₁₄₅ | P6 | H | P10 | P1 | H | H | H | Ar42 | CN |
| Lₐ₁₁₄₆ | P6 | H | P10 | P1 | H | H | H | Ar43 | CN |
| Lₐ₁₁₄₇ | P6 | H | P10 | P1 | H | H | H | Ar44 | CN |
| Lₐ₁₁₄₈ | P6 | H | P10 | P1 | H | H | H | Ar45 | CN |
| Lₐ₁₁₄₉ | P6 | H | P10 | P1 | H | H | H | Ar46 | CN |
| Lₐ₁₁₅₀ | P6 | H | P10 | P1 | H | H | H | Ar47 | CN |
| Lₐ₁₁₅₁ | P6 | H | P10 | P1 | H | H | H | Ar48 | CN |
| Lₐ₁₁₅₂ | P6 | H | P10 | P1 | H | H | H | Ar49 | CN |
| Lₐ₁₁₅₃ | P6 | H | P10 | P1 | H | H | H | Ar50 | CN |
| Lₐ₁₁₅₄ | P6 | H | P10 | P1 | H | H | H | Ar51 | CN |
| Lₐ₁₁₅₅ | P6 | H | P10 | P1 | H | H | H | Ar52 | CN |
| Lₐ₁₁₅₆ | P6 | H | P10 | P1 | H | H | H | Ar53 | CN |
| Lₐ₁₁₅₇ | P6 | H | P10 | P1 | H | H | H | Ar54 | CN |
| Lₐ₁₁₅₈ | P6 | H | P10 | P1 | H | H | H | Ar55 | CN |
| Lₐ₁₁₅₉ | P6 | H | P10 | P1 | H | H | H | Ar56 | CN |
| Lₐ₁₁₆₀ | P6 | H | P10 | P1 | H | H | H | Ar57 | CN |
| Lₐ₁₁₆₁ | P6 | H | P10 | P1 | H | H | H | Ar58 | CN |
| Lₐ₁₁₆₂ | P6 | H | P10 | P1 | H | H | H | Ar59 | CN |
| Lₐ₁₁₆₃ | P6 | H | P10 | P1 | H | H | H | Ar60 | CN |
| Lₐ₁₁₆₄ | P6 | H | P10 | P1 | H | H | H | Ar61 | CN |
| Lₐ₁₁₆₅ | P6 | H | P10 | P1 | H | H | H | Ar62 | CN |
| Lₐ₁₁₆₆ | P6 | H | P10 | P1 | H | H | H | Ar63 | CN |
| Lₐ₁₁₆₇ | P6 | H | P10 | P1 | H | H | H | Ar64 | CN |
| Lₐ₁₁₆₈ | P6 | H | P10 | P1 | H | H | H | Ar65 | CN |
| Lₐ₁₁₆₉ | P6 | H | P10 | P1 | H | H | H | Ar66 | CN |
| Lₐ₁₁₇₀ | P6 | D | P11 | P2 | D | D | D | Ar16 | CN |
| Lₐ₁₁₇₁ | P6 | H | P3 | H | H | H | H | Ar16 | CN |
| Lₐ₁₁₇₂ | P6 | H | P4 | H | H | H | H | Ar16 | CN |
| Lₐ₁₁₇₃ | P6 | H | P5 | H | H | H | H | Ar16 | CN |
| Lₐ₁₁₇₄ | P6 | H | P7 | H | H | H | H | Ar16 | CN |
| Lₐ₁₁₇₅ | P6 | H | P8 | H | H | H | H | Ar16 | CN |
| Lₐ₁₁₇₆ | P6 | H | P9 | H | H | H | H | Ar16 | CN |
| Lₐ₁₁₇₇ | P6 | H | P12 | H | H | H | H | Ar16 | CN |
| Lₐ₁₁₇₈ | P6 | H | P13 | H | H | H | H | Ar16 | CN |
| Lₐ₁₁₇₉ | P6 | H | P14 | H | H | H | H | Ar16 | CN |
| Lₐ₁₁₈₀ | P6 | H | P15 | H | H | H | H | Ar16 | CN |
| Lₐ₁₁₈₁ | P6 | H | P16 | H | H | H | H | Ar16 | CN |
| Lₐ₁₁₈₂ | P6 | H | P17 | H | H | H | H | Ar16 | CN |
| Lₐ₁₁₈₃ | P6 | H | P18 | H | H | H | H | Ar16 | CN |
| Lₐ₁₁₈₄ | P6 | H | P19 | H | H | H | H | Ar16 | CN |
| Lₐ₁₁₈₅ | P6 | H | P20 | H | H | H | H | Ar16 | CN |
| Lₐ₁₁₈₆ | P6 | H | P21 | H | H | H | H | Ar16 | CN |
| Lₐ₁₁₈₇ | P6 | H | P22 | H | H | H | H | Ar16 | CN |
| Lₐ₁₁₈₈ | P6 | H | P23 | H | H | H | H | Ar16 | CN |
| Lₐ₁₁₈₉ | P6 | H | P24 | H | H | H | H | Ar16 | CN |
| Lₐ₁₁₉₀ | P6 | H | P25 | H | H | H | H | Ar16 | CN |
| Lₐ₁₁₉₁ | P6 | H | P26 | H | H | H | H | Ar16 | CN |
| Lₐ₁₁₉₂ | P6 | H | P27 | H | H | H | H | Ar16 | CN |
| Lₐ₁₁₉₃ | P6 | H | P28 | H | H | H | H | Ar16 | CN |
| Lₐ₁₁₉₄ | P6 | H | P29 | H | H | H | H | Ar16 | CN |
| Lₐ₁₁₉₅ | P6 | H | P30 | H | H | H | H | Ar16 | CN |
| Lₐ₁₁₉₆ | P6 | H | P31 | H | H | H | H | Ar16 | CN |
| Lₐ₁₁₉₇ | P6 | H | P32 | H | H | H | H | Ar16 | CN |
| Lₐ₁₁₉₈ | P6 | H | P33 | H | H | H | H | Ar16 | CN |
| Lₐ₁₁₉₉ | P6 | H | P34 | H | H | H | H | Ar16 | CN |
| Lₐ₁₂₀₀ | P6 | H | P35 | H | H | H | H | Ar16 | CN |
| Lₐ₁₂₀₁ | P6 | H | P36 | H | H | H | H | Ar16 | CN |
| Lₐ₁₂₀₂ | P6 | H | P37 | H | H | H | H | Ar16 | CN |
| Lₐ₁₂₀₃ | P6 | H | P38 | H | H | H | H | Ar16 | CN |
| Lₐ₁₂₀₄ | P6 | H | P39 | H | H | H | H | Ar16 | CN |
| Lₐ₁₂₀₅ | P6 | H | P40 | H | H | H | H | Ar16 | CN |
| Lₐ₁₂₀₆ | P6 | H | P41 | H | H | H | H | Ar16 | CN |
| Lₐ₁₂₀₇ | P6 | H | P42 | H | H | H | H | Ar16 | CN |
| Lₐ₁₂₀₈ | P6 | H | P43 | H | H | H | H | Ar16 | CN |
| Lₐ₁₂₀₉ | P6 | H | P44 | H | H | H | H | Ar16 | CN |
| Lₐ₁₂₁₀ | P6 | H | P45 | H | H | H | H | Ar16 | CN |
| Lₐ₁₂₁₁ | P6 | H | P46 | H | H | H | H | Ar16 | CN |
| Lₐ₁₂₁₂ | P6 | H | P47 | H | H | H | H | Ar16 | CN |
| Lₐ₁₂₁₃ | P6 | H | P48 | H | H | H | H | Ar16 | CN |
| Lₐ₁₂₁₄ | P6 | H | P49 | H | H | H | H | Ar16 | CN |
| Lₐ₁₂₁₅ | P6 | H | P50 | H | H | H | H | Ar16 | CN |
| Lₐ₁₂₁₆ | P6 | H | P51 | H | H | H | H | Ar16 | CN |
| Lₐ₁₂₁₇ | P6 | H | P52 | H | H | H | H | Ar16 | CN |
| Lₐ₁₂₁₈ | P6 | H | P53 | H | H | H | H | Ar16 | CN |
| Lₐ₁₂₁₉ | P6 | H | P54 | H | H | H | H | Ar16 | CN |
| Lₐ₁₂₂₀ | P6 | H | H | P3 | H | H | H | Ar16 | CN |
| Lₐ₁₂₂₁ | P6 | H | H | P4 | H | H | H | Ar16 | CN |
| Lₐ₁₂₂₂ | P6 | H | H | P5 | H | H | H | Ar16 | CN |
| Lₐ₁₂₂₃ | P6 | H | H | P7 | H | H | H | Ar16 | CN |
| Lₐ₁₂₂₄ | P6 | H | H | P8 | H | H | H | Ar16 | CN |
| Lₐ₁₂₂₅ | P6 | H | H | P9 | H | H | H | Ar16 | CN |
| Lₐ₁₂₂₆ | P6 | H | H | P12 | H | H | H | Ar16 | CN |
| Lₐ₁₂₂₇ | P6 | H | H | P13 | H | H | H | Ar16 | CN |
| Lₐ₁₂₂₈ | P6 | H | H | P14 | H | H | H | Ar16 | CN |
| Lₐ₁₂₂₉ | P6 | H | H | P15 | H | H | H | Ar16 | CN |
| Lₐ₁₂₃₀ | P6 | H | H | P16 | H | H | H | Ar16 | CN |
| Lₐ₁₂₃₁ | P6 | H | H | P17 | H | H | H | Ar16 | CN |
| Lₐ₁₂₃₂ | P6 | H | H | P18 | H | H | H | Ar16 | CN |
| Lₐ₁₂₃₃ | P6 | H | H | P19 | H | H | H | Ar16 | CN |
| Lₐ₁₂₃₄ | P6 | H | H | P20 | H | H | H | Ar16 | CN |
| Lₐ₁₂₃₅ | P6 | H | H | P21 | H | H | H | Ar16 | CN |
| Lₐ₁₂₃₆ | P6 | H | H | P22 | H | H | H | Ar16 | CN |
| Lₐ₁₂₃₇ | P6 | H | H | P23 | H | H | H | Ar16 | CN |
| Lₐ₁₂₃₈ | P6 | H | H | P24 | H | H | H | Ar16 | CN |
| Lₐ₁₂₃₉ | P6 | H | H | P25 | H | H | H | Ar16 | CN |
| Lₐ₁₂₄₀ | P6 | H | H | P26 | H | H | H | Ar16 | CN |
| Lₐ₁₂₄₁ | P6 | H | H | P27 | H | H | H | Ar16 | CN |
| Lₐ₁₂₄₂ | P6 | H | H | P28 | H | H | H | Ar16 | CN |
| Lₐ₁₂₄₃ | P6 | H | H | P29 | H | H | H | Ar16 | CN |
| Lₐ₁₂₄₄ | P6 | H | H | P30 | H | H | H | Ar16 | CN |
| Lₐ₁₂₄₅ | P6 | H | H | P31 | H | H | H | Ar16 | CN |
| Lₐ₁₂₄₆ | P6 | H | H | P32 | H | H | H | Ar16 | CN |
| Lₐ₁₂₄₇ | P6 | H | H | P33 | H | H | H | Ar16 | CN |
| Lₐ₁₂₄₈ | P6 | H | H | P34 | H | H | H | Ar16 | CN |
| Lₐ₁₂₄₉ | P6 | H | H | P35 | H | H | H | Ar16 | CN |
| Lₐ₁₂₅₀ | P6 | H | H | P36 | H | H | H | Ar16 | CN |
| Lₐ₁₂₅₁ | P6 | H | H | P37 | H | H | H | Ar16 | CN |
| Lₐ₁₂₅₂ | P6 | H | H | P38 | H | H | H | Ar16 | CN |
| Lₐ₁₂₅₃ | P6 | H | H | P39 | H | H | H | Ar16 | CN |
| Lₐ₁₂₅₄ | P6 | H | H | P40 | H | H | H | Ar16 | CN |
| Lₐ₁₂₅₅ | P6 | H | H | P41 | H | H | H | Ar16 | CN |
| Lₐ₁₂₅₆ | P6 | H | H | P42 | H | H | H | Ar16 | CN |
| Lₐ₁₂₅₇ | P6 | H | H | P43 | H | H | H | Ar16 | CN |
| Lₐ₁₂₅₈ | P6 | H | H | P44 | H | H | H | Ar16 | CN |
| Lₐ₁₂₅₉ | P6 | H | H | P45 | H | H | H | Ar16 | CN |
| Lₐ₁₂₆₀ | P6 | H | H | P46 | H | H | H | Ar16 | CN |
| Lₐ₁₂₆₁ | P6 | H | H | P47 | H | H | H | Ar16 | CN |
| Lₐ₁₂₆₂ | P6 | H | H | P48 | H | H | H | Ar16 | CN |
| Lₐ₁₂₆₃ | P6 | H | H | P49 | H | H | H | Ar16 | CN |
| Lₐ₁₂₆₄ | P6 | H | H | P50 | H | H | H | Ar16 | CN |
| Lₐ₁₂₆₅ | P6 | H | H | P51 | H | H | H | Ar16 | CN |
| Lₐ₁₂₆₆ | P6 | H | H | P52 | H | H | H | Ar16 | CN |
| Lₐ₁₂₆₇ | P6 | H | H | P53 | H | H | H | Ar16 | CN |
| Lₐ₁₂₆₈ | P6 | H | H | P54 | H | H | H | Ar16 | CN |
| Lₐ₁₂₆₉ | P6 | H | H | P6 | H | H | H | F | Ar1 |
| Lₐ₁₂₇₀ | P6 | H | H | P6 | H | H | H | F | Ar2 |
| Lₐ₁₂₇₁ | P6 | H | H | P6 | H | H | H | F | Ar3 |
| Lₐ₁₂₇₂ | P6 | H | H | P6 | H | H | H | F | Ar4 |
| Lₐ₁₂₇₃ | P6 | H | H | P6 | H | H | H | F | Ar5 |
| Lₐ₁₂₇₄ | P6 | H | H | P6 | H | H | H | F | Ar6 |
| Lₐ₁₂₇₅ | P6 | H | H | P6 | H | H | H | F | Ar7 |
| Lₐ₁₂₇₆ | P6 | H | H | P6 | H | H | H | F | Ar8 |
| Lₐ₁₂₇₇ | P6 | H | H | P6 | H | H | H | F | Ar9 |
| Lₐ₁₂₇₈ | P6 | H | H | P6 | H | H | H | F | Ar10 |
| Lₐ₁₂₇₉ | P6 | H | H | P6 | H | H | H | F | Ar11 |
| Lₐ₁₂₈₀ | P6 | H | H | P6 | H | H | H | F | Ar12 |
| Lₐ₁₂₈₁ | P6 | H | H | P6 | H | H | H | F | Ar13 |
| Lₐ₁₂₈₂ | P6 | H | H | P6 | H | H | H | F | Ar14 |
| Lₐ₁₂₈₃ | P6 | H | H | P6 | H | H | H | F | Ar15 |
| Lₐ₁₂₈₄ | P6 | H | H | P6 | H | H | H | F | Ar16 |
| Lₐ₁₂₈₅ | P6 | H | H | P6 | H | H | H | F | Ar17 |
| Lₐ₁₂₈₆ | P6 | H | H | P6 | H | H | H | F | Ar18 |
| Lₐ₁₂₈₇ | P6 | H | H | P6 | H | H | H | F | Ar19 |
| Lₐ₁₂₈₈ | P6 | H | H | P6 | H | H | H | F | Ar20 |
| Lₐ₁₂₈₉ | P6 | H | H | P6 | H | H | H | F | Ar21 |
| Lₐ₁₂₉₀ | P6 | H | H | P6 | H | H | H | F | Ar22 |
| Lₐ₁₂₉₁ | P6 | H | H | P6 | H | H | H | F | Ar23 |
| Lₐ₁₂₉₂ | P6 | H | H | P6 | H | H | H | F | Ar24 |
| Lₐ₁₂₉₃ | P6 | H | H | P6 | H | H | H | F | Ar25 |
| Lₐ₁₂₉₄ | P6 | H | H | P6 | H | H | H | F | Ar26 |
| Lₐ₁₂₉₅ | P6 | H | H | P6 | H | H | H | F | Ar27 |
| Lₐ₁₂₉₆ | P6 | H | H | P6 | H | H | H | F | Ar28 |
| Lₐ₁₂₉₇ | P6 | H | H | P6 | H | H | H | F | Ar29 |
| Lₐ₁₂₉₈ | P6 | H | H | P6 | H | H | H | F | Ar30 |
| Lₐ₁₂₉₉ | P6 | H | H | P6 | H | H | H | F | Ar31 |
| Lₐ₁₃₀₀ | P6 | H | H | P6 | H | H | H | F | Ar32 |
| Lₐ₁₃₀₁ | P6 | H | H | P6 | H | H | H | F | Ar33 |
| Lₐ₁₃₀₂ | P6 | H | H | P6 | H | H | H | F | Ar34 |
| Lₐ₁₃₀₃ | P6 | H | H | P6 | H | H | H | F | Ar35 |
| Lₐ₁₃₀₄ | P6 | H | H | P6 | H | H | H | F | Ar36 |
| Lₐ₁₃₀₅ | P6 | H | H | P6 | H | H | H | F | Ar37 |
| Lₐ₁₃₀₆ | P6 | H | H | P6 | H | H | H | F | Ar38 |
| Lₐ₁₃₀₇ | P6 | H | H | P6 | H | H | H | F | Ar39 |
| Lₐ₁₃₀₈ | P6 | H | H | P6 | H | H | H | F | Ar40 |
| Lₐ₁₃₀₉ | P6 | H | H | P6 | H | H | H | F | Ar41 |
| Lₐ₁₃₁₀ | P6 | H | H | P6 | H | H | H | F | Ar42 |
| Lₐ₁₃₁₁ | P6 | H | H | P6 | H | H | H | F | Ar43 |
| Lₐ₁₃₁₂ | P6 | H | H | P6 | H | H | H | F | Ar44 |
| Lₐ₁₃₁₃ | P6 | H | H | P6 | H | H | H | F | Ar45 |
| Lₐ₁₃₁₄ | P6 | H | H | P6 | H | H | H | F | Ar46 |
| Lₐ₁₃₁₅ | P6 | H | H | P6 | H | H | H | F | Ar47 |
| Lₐ₁₃₁₆ | P6 | H | H | P6 | H | H | H | F | Ar48 |
| Lₐ₁₃₁₇ | P6 | H | H | P6 | H | H | H | F | Ar49 |
| Lₐ₁₃₁₈ | P6 | H | H | P6 | H | H | H | F | Ar50 |
| Lₐ₁₃₁₉ | P6 | H | H | P6 | H | H | H | F | Ar51 |
| Lₐ₁₃₂₀ | P6 | H | H | P6 | H | H | H | F | Ar52 |
| Lₐ₁₃₂₁ | P6 | H | H | P6 | H | H | H | F | Ar53 |
| Lₐ₁₃₂₂ | P6 | H | H | P6 | H | H | H | F | Ar54 |
| Lₐ₁₃₂₃ | P6 | H | H | P6 | H | H | H | F | Ar55 |
| Lₐ₁₃₂₄ | P6 | H | H | P6 | H | H | H | F | Ar56 |
| Lₐ₁₃₂₅ | P6 | H | H | P6 | H | H | H | F | Ar57 |
| Lₐ₁₃₂₆ | P6 | H | H | P6 | H | H | H | F | Ar58 |
| Lₐ₁₃₂₇ | P6 | H | H | P6 | H | H | H | F | Ar59 |
| Lₐ₁₃₂₈ | P6 | H | H | P6 | H | H | H | F | Ar60 |
| Lₐ₁₃₂₉ | P6 | H | H | P6 | H | H | H | F | Ar61 |
| Lₐ₁₃₃₀ | P6 | H | H | P6 | H | H | H | F | Ar62 |
| Lₐ₁₃₃₁ | P6 | H | H | P6 | H | H | H | F | Ar63 |
| Lₐ₁₃₃₂ | P6 | H | H | P6 | H | H | H | F | Ar64 |
| Lₐ₁₃₃₃ | P6 | H | H | P6 | H | H | H | F | Ar65 |
| Lₐ₁₃₃₄ | P6 | H | H | P6 | H | H | H | F | Ar66 |
| Lₐ₁₃₃₅ | P6 | D | D | P6 | D | D | D | F | Ar16 |
| Lₐ₁₃₃₆ | P6 | H | H | P10 | H | H | H | F | Ar1 |
| Lₐ₁₃₃₇ | P6 | H | H | P10 | H | H | H | F | Ar2 |
| Lₐ₁₃₃₈ | P6 | H | H | P10 | H | H | H | F | Ar3 |
| Lₐ₁₃₃₉ | P6 | H | H | P10 | H | H | H | F | Ar4 |
| Lₐ₁₃₄₀ | P6 | H | H | P10 | H | H | H | F | Ar5 |
| Lₐ₁₃₄₁ | P6 | H | H | P10 | H | H | H | F | Ar6 |
| Lₐ₁₃₄₂ | P6 | H | H | P10 | H | H | H | F | Ar7 |
| Lₐ₁₃₄₃ | P6 | H | H | P10 | H | H | H | F | Ar8 |
| Lₐ₁₃₄₄ | P6 | H | H | P10 | H | H | H | F | Ar9 |
| Lₐ₁₃₄₅ | P6 | H | H | P10 | H | H | H | F | Ar10 |
| Lₐ₁₃₄₆ | P6 | H | H | P10 | H | H | H | F | Ar11 |
| Lₐ₁₃₄₇ | P6 | H | H | P10 | H | H | H | F | Ar12 |
| Lₐ₁₃₄₈ | P6 | H | H | P10 | H | H | H | F | Ar13 |
| Lₐ₁₃₄₉ | P6 | H | H | P10 | H | H | H | F | Ar14 |
| Lₐ₁₃₅₀ | P6 | H | H | P10 | H | H | H | F | Ar15 |
| Lₐ₁₃₅₁ | P6 | H | H | P10 | H | H | H | F | Ar16 |
| Lₐ₁₃₅₂ | P6 | H | H | P10 | H | H | H | F | Ar17 |
| Lₐ₁₃₅₃ | P6 | H | H | P10 | H | H | H | F | Ar18 |
| Lₐ₁₃₅₄ | P6 | H | H | P10 | H | H | H | F | Ar19 |
| Lₐ₁₃₅₅ | P6 | H | H | P10 | H | H | H | F | Ar20 |
| Lₐ₁₃₅₆ | P6 | H | H | P10 | H | H | H | F | Ar21 |
| Lₐ₁₃₅₇ | P6 | H | H | P10 | H | H | H | F | Ar22 |
| Lₐ₁₃₅₈ | P6 | H | H | P10 | H | H | H | F | Ar23 |
| Lₐ₁₃₅₉ | P6 | H | H | P10 | H | H | H | F | Ar24 |
| Lₐ₁₃₆₀ | P6 | H | H | P10 | H | H | H | F | Ar25 |
| Lₐ₁₃₆₁ | P6 | H | H | P10 | H | H | H | F | Ar26 |
| Lₐ₁₃₆₂ | P6 | H | H | P10 | H | H | H | F | Ar27 |
| Lₐ₁₃₆₃ | P6 | H | H | P10 | H | H | H | F | Ar28 |
| Lₐ₁₃₆₄ | P6 | H | H | P10 | H | H | H | F | Ar29 |
| Lₐ₁₃₆₅ | P6 | H | H | P10 | H | H | H | F | Ar30 |
| Lₐ₁₃₆₆ | P6 | H | H | P10 | H | H | H | F | Ar31 |
| Lₐ₁₃₆₇ | P6 | H | H | P10 | H | H | H | F | Ar32 |
| Lₐ₁₃₆₈ | P6 | H | H | P10 | H | H | H | F | Ar33 |
| Lₐ₁₃₆₉ | P6 | H | H | P10 | H | H | H | F | Ar34 |
| Lₐ₁₃₇₀ | P6 | H | H | P10 | H | H | H | F | Ar35 |
| Lₐ₁₃₇₁ | P6 | H | H | P10 | H | H | H | F | Ar36 |
| Lₐ₁₃₇₂ | P6 | H | H | P10 | H | H | H | F | Ar37 |
| Lₐ₁₃₇₃ | P6 | H | H | P10 | H | H | H | F | Ar38 |
| Lₐ₁₃₇₄ | P6 | H | H | P10 | H | H | H | F | Ar39 |
| Lₐ₁₃₇₅ | P6 | H | H | P10 | H | H | H | F | Ar40 |
| Lₐ₁₃₇₆ | P6 | H | H | P10 | H | H | H | F | Ar41 |
| Lₐ₁₃₇₇ | P6 | H | H | P10 | H | H | H | F | Ar42 |
| Lₐ₁₃₇₈ | P6 | H | H | P10 | H | H | H | F | Ar43 |
| Lₐ₁₃₇₉ | P6 | H | H | P10 | H | H | H | F | Ar44 |
| Lₐ₁₃₈₀ | P6 | H | H | P10 | H | H | H | F | Ar45 |
| Lₐ₁₃₈₁ | P6 | H | H | P10 | H | H | H | F | Ar46 |
| Lₐ₁₃₈₂ | P6 | H | H | P10 | H | H | H | F | Ar47 |
| Lₐ₁₃₈₃ | P6 | H | H | P10 | H | H | H | F | Ar48 |
| Lₐ₁₃₈₄ | P6 | H | H | P10 | H | H | H | F | Ar49 |
| Lₐ₁₃₈₅ | P6 | H | H | P10 | H | H | H | F | Ar50 |
| Lₐ₁₃₈₆ | P6 | H | H | P10 | H | H | H | F | Ar51 |
| Lₐ₁₃₈₇ | P6 | H | H | P10 | H | H | H | F | Ar52 |
| Lₐ₁₃₈₈ | P6 | H | H | P10 | H | H | H | F | Ar53 |
| Lₐ₁₃₈₉ | P6 | H | H | P10 | H | H | H | F | Ar54 |
| Lₐ₁₃₉₀ | P6 | H | H | P10 | H | H | H | F | Ar55 |
| Lₐ₁₃₉₁ | P6 | H | H | P10 | H | H | H | F | Ar56 |
| Lₐ₁₃₉₂ | P6 | H | H | P10 | H | H | H | F | Ar57 |
| Lₐ₁₃₉₃ | P6 | H | H | P10 | H | H | H | F | Ar58 |
| Lₐ₁₃₉₄ | P6 | H | H | P10 | H | H | H | F | Ar59 |
| Lₐ₁₃₉₅ | P6 | H | H | P10 | H | H | H | F | Ar60 |
| Lₐ₁₃₉₆ | P6 | H | H | P10 | H | H | H | F | Ar61 |
| Lₐ₁₃₉₇ | P6 | H | H | P10 | H | H | H | F | Ar62 |
| Lₐ₁₃₉₈ | P6 | H | H | P10 | H | H | H | F | Ar63 |
| Lₐ₁₃₉₉ | P6 | H | H | P10 | H | H | H | F | Ar64 |
| Lₐ₁₄₀₀ | P6 | H | H | P10 | H | H | H | F | Ar65 |
| Lₐ₁₄₀₁ | P6 | H | H | P10 | H | H | H | F | Ar66 |
| Lₐ₁₄₀₂ | P6 | D | D | P11 | D | D | D | F | Ar16 |
| Lₐ₁₄₀₃ | P6 | H | P1 | P6 | H | H | H | F | Ar1 |
| Lₐ₁₄₀₄ | P6 | H | P1 | P6 | H | H | H | F | Ar2 |
| Lₐ₁₄₀₅ | P6 | H | P1 | P6 | H | H | H | F | Ar3 |
| Lₐ₁₄₀₆ | P6 | H | P1 | P6 | H | H | H | F | Ar4 |
| Lₐ₁₄₀₇ | P6 | H | P1 | P6 | H | H | H | F | Ar5 |
| Lₐ₁₄₀₈ | P6 | H | P1 | P6 | H | H | H | F | Ar6 |
| Lₐ₁₄₀₉ | P6 | H | P1 | P6 | H | H | H | F | Ar7 |
| Lₐ₁₄₁₀ | P6 | H | P1 | P6 | H | H | H | F | Ar8 |
| Lₐ₁₄₁₁ | P6 | H | P1 | P6 | H | H | H | F | Ar9 |
| Lₐ₁₄₁₂ | P6 | H | P1 | P6 | H | H | H | F | Ar10 |
| Lₐ₁₄₁₃ | P6 | H | P1 | P6 | H | H | H | F | Ar11 |
| Lₐ₁₄₁₄ | P6 | H | P1 | P6 | H | H | H | F | Ar12 |
| Lₐ₁₄₁₅ | P6 | H | P1 | P6 | H | H | H | F | Ar13 |
| Lₐ₁₄₁₆ | P6 | H | P1 | P6 | H | H | H | F | Ar14 |
| Lₐ₁₄₁₇ | P6 | H | P1 | P6 | H | H | H | F | Ar15 |
| Lₐ₁₄₁₈ | P6 | H | P1 | P6 | H | H | H | F | Ar16 |
| Lₐ₁₄₁₉ | P6 | H | P1 | P6 | H | H | H | F | Ar17 |
| Lₐ₁₄₂₀ | P6 | H | P1 | P6 | H | H | H | F | Ar18 |
| Lₐ₁₄₂₁ | P6 | H | P1 | P6 | H | H | H | F | Ar19 |
| Lₐ₁₄₂₂ | P6 | H | P1 | P6 | H | H | H | F | Ar20 |
| Lₐ₁₄₂₃ | P6 | H | P1 | P6 | H | H | H | F | Ar21 |
| Lₐ₁₄₂₄ | P6 | H | P1 | P6 | H | H | H | F | Ar22 |
| Lₐ₁₄₂₅ | P6 | H | P1 | P6 | H | H | H | F | Ar23 |
| Lₐ₁₄₂₆ | P6 | H | P1 | P6 | H | H | H | F | Ar24 |
| Lₐ₁₄₂₇ | P6 | H | P1 | P6 | H | H | H | F | Ar25 |
| Lₐ₁₄₂₈ | P6 | H | P1 | P6 | H | H | H | F | Ar26 |
| Lₐ₁₄₂₉ | P6 | H | P1 | P6 | H | H | H | F | Ar27 |
| Lₐ₁₄₃₀ | P6 | H | P1 | P6 | H | H | H | F | Ar28 |
| Lₐ₁₄₃₁ | P6 | H | P1 | P6 | H | H | H | F | Ar29 |
| Lₐ₁₄₃₂ | P6 | H | P1 | P6 | H | H | H | F | Ar30 |
| Lₐ₁₄₃₃ | P6 | H | P1 | P6 | H | H | H | F | Ar31 |
| Lₐ₁₄₃₄ | P6 | H | P1 | P6 | H | H | H | F | Ar32 |
| Lₐ₁₄₃₅ | P6 | H | P1 | P6 | H | H | H | F | Ar33 |
| Lₐ₁₄₃₆ | P6 | H | P1 | P6 | H | H | H | F | Ar34 |
| Lₐ₁₄₃₇ | P6 | H | P1 | P6 | H | H | H | F | Ar35 |
| Lₐ₁₄₃₈ | P6 | H | P1 | P6 | H | H | H | F | Ar36 |
| Lₐ₁₄₃₉ | P6 | H | P1 | P6 | H | H | H | F | Ar37 |
| Lₐ₁₄₄₀ | P6 | H | P1 | P6 | H | H | H | F | Ar38 |
| Lₐ₁₄₄₁ | P6 | H | P1 | P6 | H | H | H | F | Ar39 |
| Lₐ₁₄₄₂ | P6 | H | P1 | P6 | H | H | H | F | Ar40 |
| Lₐ₁₄₄₃ | P6 | H | P1 | P6 | H | H | H | F | Ar41 |
| Lₐ₁₄₄₄ | P6 | H | P1 | P6 | H | H | H | F | Ar42 |
| Lₐ₁₄₄₅ | P6 | H | P1 | P6 | H | H | H | F | Ar43 |
| Lₐ₁₄₄₆ | P6 | H | P1 | P6 | H | H | H | F | Ar44 |
| Lₐ₁₄₄₇ | P6 | H | P1 | P6 | H | H | H | F | Ar45 |
| Lₐ₁₄₄₈ | P6 | H | P1 | P6 | H | H | H | F | Ar46 |
| Lₐ₁₄₄₉ | P6 | H | P1 | P6 | H | H | H | F | Ar47 |
| Lₐ₁₄₅₀ | P6 | H | P1 | P6 | H | H | H | F | Ar48 |
| Lₐ₁₄₅₁ | P6 | H | P1 | P6 | H | H | H | F | Ar49 |
| Lₐ₁₄₅₂ | P6 | H | P1 | P6 | H | H | H | F | Ar50 |
| Lₐ₁₄₅₃ | P6 | H | P1 | P6 | H | H | H | F | Ar51 |
| Lₐ₁₄₅₄ | P6 | H | P1 | P6 | H | H | H | F | Ar52 |
| Lₐ₁₄₅₅ | P6 | H | P1 | P6 | H | H | H | F | Ar53 |
| Lₐ₁₄₅₆ | P6 | H | P1 | P6 | H | H | H | F | Ar54 |
| Lₐ₁₄₅₇ | P6 | H | P1 | P6 | H | H | H | F | Ar55 |
| Lₐ₁₄₅₈ | P6 | H | P1 | P6 | H | H | H | F | Ar56 |
| Lₐ₁₄₅₉ | P6 | H | P1 | P6 | H | H | H | F | Ar57 |
| Lₐ₁₄₆₀ | P6 | H | P1 | P6 | H | H | H | F | Ar58 |
| Lₐ₁₄₆₁ | P6 | H | P1 | P6 | H | H | H | F | Ar59 |
| Lₐ₁₄₆₂ | P6 | H | P1 | P6 | H | H | H | F | Ar60 |
| Lₐ₁₄₆₃ | P6 | H | P1 | P6 | H | H | H | F | Ar61 |
| Lₐ₁₄₆₄ | P6 | H | P1 | P6 | H | H | H | F | Ar62 |
| Lₐ₁₄₆₅ | P6 | H | P1 | P6 | H | H | H | F | Ar63 |
| Lₐ₁₄₆₆ | P6 | H | P1 | P6 | H | H | H | F | Ar64 |
| Lₐ₁₄₆₇ | P6 | H | P1 | P6 | H | H | H | F | Ar65 |
| Lₐ₁₄₆₈ | P6 | H | P1 | P6 | H | H | H | F | Ar66 |
| Lₐ₁₄₆₉ | P6 | D | P2 | P6 | D | D | D | F | Ar16 |
| Lₐ₁₄₇₀ | P6 | H | P1 | P10 | H | H | H | F | Ar1 |
| Lₐ₁₄₇₁ | P6 | H | P1 | P10 | H | H | H | F | Ar2 |
| Lₐ₁₄₇₂ | P6 | H | P1 | P10 | H | H | H | F | Ar3 |
| Lₐ₁₄₇₃ | P6 | H | P1 | P10 | H | H | H | F | Ar4 |
| Lₐ₁₄₇₄ | P6 | H | P1 | P10 | H | H | H | F | Ar5 |
| Lₐ₁₄₇₅ | P6 | H | P1 | P10 | H | H | H | F | Ar6 |
| Lₐ₁₄₇₆ | P6 | H | P1 | P10 | H | H | H | F | Ar7 |
| Lₐ₁₄₇₇ | P6 | H | P1 | P10 | H | H | H | F | Ar8 |
| Lₐ₁₄₇₈ | P6 | H | P1 | P10 | H | H | H | F | Ar9 |
| Lₐ₁₄₇₉ | P6 | H | P1 | P10 | H | H | H | F | Ar10 |
| Lₐ₁₄₈₀ | P6 | H | P1 | P10 | H | H | H | F | Ar11 |
| Lₐ₁₄₈₁ | P6 | H | P1 | P10 | H | H | H | F | Ar12 |
| Lₐ₁₄₈₂ | P6 | H | P1 | P10 | H | H | H | F | Ar13 |
| Lₐ₁₄₈₃ | P6 | H | P1 | P10 | H | H | H | F | Ar14 |
| Lₐ₁₄₈₄ | P6 | H | P1 | P10 | H | H | H | F | Ar15 |
| Lₐ₁₄₈₅ | P6 | H | P1 | P10 | H | H | H | F | Ar16 |
| Lₐ₁₄₈₆ | P6 | H | P1 | P10 | H | H | H | F | Ar17 |
| Lₐ₁₄₈₇ | P6 | H | P1 | P10 | H | H | H | F | Ar18 |
| Lₐ₁₄₈₈ | P6 | H | P1 | P10 | H | H | H | F | Ar19 |
| Lₐ₁₄₈₉ | P6 | H | P1 | P10 | H | H | H | F | Ar20 |
| Lₐ₁₄₉₀ | P6 | H | P1 | P10 | H | H | H | F | Ar21 |
| Lₐ₁₄₉₁ | P6 | H | P1 | P10 | H | H | H | F | Ar22 |
| Lₐ₁₄₉₂ | P6 | H | P1 | P10 | H | H | H | F | Ar23 |
| Lₐ₁₄₉₃ | P6 | H | P1 | P10 | H | H | H | F | Ar24 |
| Lₐ₁₄₉₄ | P6 | H | P1 | P10 | H | H | H | F | Ar25 |
| Lₐ₁₄₉₅ | P6 | H | P1 | P10 | H | H | H | F | Ar26 |
| Lₐ₁₄₉₆ | P6 | H | P1 | P10 | H | H | H | F | Ar27 |
| Lₐ₁₄₉₇ | P6 | H | P1 | P10 | H | H | H | F | Ar28 |
| Lₐ₁₄₉₈ | P6 | H | P1 | P10 | H | H | H | F | Ar29 |
| Lₐ₁₄₉₉ | P6 | H | P1 | P10 | H | H | H | F | Ar30 |
| Lₐ₁₅₀₀ | P6 | H | P1 | P10 | H | H | H | F | Ar31 |
| Lₐ₁₅₀₁ | P6 | H | P1 | P10 | H | H | H | F | Ar32 |
| Lₐ₁₅₀₂ | P6 | H | P1 | P10 | H | H | H | F | Ar33 |
| Lₐ₁₅₀₃ | P6 | H | P1 | P10 | H | H | H | F | Ar34 |
| Lₐ₁₅₀₄ | P6 | H | P1 | P10 | H | H | H | F | Ar35 |
| Lₐ₁₅₀₅ | P6 | H | P1 | P10 | H | H | H | F | Ar36 |
| Lₐ₁₅₀₆ | P6 | H | P1 | P10 | H | H | H | F | Ar37 |
| Lₐ₁₅₀₇ | P6 | H | P1 | P10 | H | H | H | F | Ar38 |
| Lₐ₁₅₀₈ | P6 | H | P1 | P10 | H | H | H | F | Ar39 |
| Lₐ₁₅₀₉ | P6 | H | P1 | P10 | H | H | H | F | Ar40 |
| Lₐ₁₅₁₀ | P6 | H | P1 | P10 | H | H | H | F | Ar41 |
| Lₐ₁₅₁₁ | P6 | H | P1 | P10 | H | H | H | F | Ar42 |
| Lₐ₁₅₁₂ | P6 | H | P1 | P10 | H | H | H | F | Ar43 |
| Lₐ₁₅₁₃ | P6 | H | P1 | P10 | H | H | H | F | Ar44 |
| Lₐ₁₅₁₄ | P6 | H | P1 | P10 | H | H | H | F | Ar45 |
| Lₐ₁₅₁₅ | P6 | H | P1 | P10 | H | H | H | F | Ar46 |
| Lₐ₁₅₁₆ | P6 | H | P1 | P10 | H | H | H | F | Ar47 |
| Lₐ₁₅₁₇ | P6 | H | P1 | P10 | H | H | H | F | Ar48 |
| Lₐ₁₅₁₈ | P6 | H | P1 | P10 | H | H | H | F | Ar49 |
| Lₐ₁₅₁₉ | P6 | H | P1 | P10 | H | H | H | F | Ar50 |
| Lₐ₁₅₂₀ | P6 | H | P1 | P10 | H | H | H | F | Ar51 |
| Lₐ₁₅₂₁ | P6 | H | P1 | P10 | H | H | H | F | Ar52 |
| Lₐ₁₅₂₂ | P6 | H | P1 | P10 | H | H | H | F | Ar53 |
| Lₐ₁₅₂₃ | P6 | H | P1 | P10 | H | H | H | F | Ar54 |
| Lₐ₁₅₂₄ | P6 | H | P1 | P10 | H | H | H | F | Ar55 |
| Lₐ₁₅₂₅ | P6 | H | P1 | P10 | H | H | H | F | Ar56 |
| Lₐ₁₅₂₆ | P6 | H | P1 | P10 | H | H | H | F | Ar57 |
| Lₐ₁₅₂₇ | P6 | H | P1 | P10 | H | H | H | F | Ar58 |
| Lₐ₁₅₂₈ | P6 | H | P1 | P10 | H | H | H | F | Ar59 |
| Lₐ₁₅₂₉ | P6 | H | P1 | P10 | H | H | H | F | Ar60 |
| Lₐ₁₅₃₀ | P6 | H | P1 | P10 | H | H | H | F | Ar61 |
| Lₐ₁₅₃₁ | P6 | H | P1 | P10 | H | H | H | F | Ar62 |
| Lₐ₁₅₃₂ | P6 | H | P1 | P10 | H | H | H | F | Ar63 |
| Lₐ₁₅₃₃ | P6 | H | P1 | P10 | H | H | H | F | Ar64 |
| Lₐ₁₅₃₄ | P6 | H | P1 | P10 | H | H | H | F | Ar65 |
| Lₐ₁₅₃₅ | P6 | H | P1 | P10 | H | H | H | F | Ar66 |
| Lₐ₁₅₃₆ | P6 | D | P2 | P11 | D | D | D | F | Ar16 |
| Lₐ₁₅₃₇ | P6 | H | P6 | H | H | H | H | F | Ar1 |
| Lₐ₁₅₃₈ | P6 | H | P6 | H | H | H | H | F | Ar2 |
| Lₐ₁₅₃₉ | P6 | H | P6 | H | H | H | H | F | Ar3 |
| Lₐ₁₅₄₀ | P6 | H | P6 | H | H | H | H | F | Ar4 |
| Lₐ₁₅₄₁ | P6 | H | P6 | H | H | H | H | F | Ar5 |
| Lₐ₁₅₄₂ | P6 | H | P6 | H | H | H | H | F | Ar6 |
| Lₐ₁₅₄₃ | P6 | H | P6 | H | H | H | H | F | Ar7 |
| Lₐ₁₅₄₄ | P6 | H | P6 | H | H | H | H | F | Ar8 |
| Lₐ₁₅₄₅ | P6 | H | P6 | H | H | H | H | F | Ar9 |
| Lₐ₁₅₄₆ | P6 | H | P6 | H | H | H | H | F | Ar10 |
| Lₐ₁₅₄₇ | P6 | H | P6 | H | H | H | H | F | Ar11 |
| Lₐ₁₅₄₈ | P6 | H | P6 | H | H | H | H | F | Ar12 |
| Lₐ₁₅₄₉ | P6 | H | P6 | H | H | H | H | F | Ar13 |
| Lₐ₁₅₅₀ | P6 | H | P6 | H | H | H | H | F | Ar14 |
| Lₐ₁₅₅₁ | P6 | H | P6 | H | H | H | H | F | Ar15 |
| Lₐ₁₅₅₂ | P6 | H | P6 | H | H | H | H | F | Ar16 |
| Lₐ₁₅₅₃ | P6 | H | P6 | H | H | H | H | F | Ar17 |
| Lₐ₁₅₅₄ | P6 | H | P6 | H | H | H | H | F | Ar18 |
| Lₐ₁₅₅₅ | P6 | H | P6 | H | H | H | H | F | Ar19 |
| Lₐ₁₅₅₆ | P6 | H | P6 | H | H | H | H | F | Ar20 |
| Lₐ₁₅₅₇ | P6 | H | P6 | H | H | H | H | F | Ar21 |
| Lₐ₁₅₅₈ | P6 | H | P6 | H | H | H | H | F | Ar22 |
| Lₐ₁₅₅₉ | P6 | H | P6 | H | H | H | H | F | Ar23 |
| Lₐ₁₅₆₀ | P6 | H | P6 | H | H | H | H | F | Ar24 |
| Lₐ₁₅₆₁ | P6 | H | P6 | H | H | H | H | F | Ar25 |
| Lₐ₁₅₆₂ | P6 | H | P6 | H | H | H | H | F | Ar26 |
| Lₐ₁₅₆₃ | P6 | H | P6 | H | H | H | H | F | Ar27 |
| Lₐ₁₅₆₄ | P6 | H | P6 | H | H | H | H | F | Ar28 |
| Lₐ₁₅₆₅ | P6 | H | P6 | H | H | H | H | F | Ar29 |
| Lₐ₁₅₆₆ | P6 | H | P6 | H | H | H | H | F | Ar30 |
| Lₐ₁₅₆₇ | P6 | H | P6 | H | H | H | H | F | Ar31 |
| Lₐ₁₅₆₈ | P6 | H | P6 | H | H | H | H | F | Ar32 |
| Lₐ₁₅₆₉ | P6 | H | P6 | H | H | H | H | F | Ar33 |
| Lₐ₁₅₇₀ | P6 | H | P6 | H | H | H | H | F | Ar34 |
| Lₐ₁₅₇₁ | P6 | H | P6 | H | H | H | H | F | Ar35 |
| Lₐ₁₅₇₂ | P6 | H | P6 | H | H | H | H | F | Ar36 |
| Lₐ₁₅₇₃ | P6 | H | P6 | H | H | H | H | F | Ar37 |
| Lₐ₁₅₇₄ | P6 | H | P6 | H | H | H | H | F | Ar38 |
| Lₐ₁₅₇₅ | P6 | H | P6 | H | H | H | H | F | Ar39 |
| Lₐ₁₅₇₆ | P6 | H | P6 | H | H | H | H | F | Ar40 |
| Lₐ₁₅₇₇ | P6 | H | P6 | H | H | H | H | F | Ar41 |
| Lₐ₁₅₇₈ | P6 | H | P6 | H | H | H | H | F | Ar42 |
| Lₐ₁₅₇₉ | P6 | H | P6 | H | H | H | H | F | Ar43 |
| Lₐ₁₅₈₀ | P6 | H | P6 | H | H | H | H | F | Ar44 |
| Lₐ₁₅₈₁ | P6 | H | P6 | H | H | H | H | F | Ar45 |
| Lₐ₁₅₈₂ | P6 | H | P6 | H | H | H | H | F | Ar46 |
| Lₐ₁₅₈₃ | P6 | H | P6 | H | H | H | H | F | Ar47 |
| Lₐ₁₅₈₄ | P6 | H | P6 | H | H | H | H | F | Ar48 |
| Lₐ₁₅₈₅ | P6 | H | P6 | H | H | H | H | F | Ar49 |
| Lₐ₁₅₈₆ | P6 | H | P6 | H | H | H | H | F | Ar50 |
| Lₐ₁₅₈₇ | P6 | H | P6 | H | H | H | H | F | Ar51 |
| Lₐ₁₅₈₈ | P6 | H | P6 | H | H | H | H | F | Ar52 |
| Lₐ₁₅₈₉ | P6 | H | P6 | H | H | H | H | F | Ar53 |
| Lₐ₁₅₉₀ | P6 | H | P6 | H | H | H | H | F | Ar54 |
| Lₐ₁₅₉₁ | P6 | H | P6 | H | H | H | H | F | Ar55 |
| Lₐ₁₅₉₂ | P6 | H | P6 | H | H | H | H | F | Ar56 |
| Lₐ₁₅₉₃ | P6 | H | P6 | H | H | H | H | F | Ar57 |
| Lₐ₁₅₉₄ | P6 | H | P6 | H | H | H | H | F | Ar58 |
| Lₐ₁₅₉₅ | P6 | H | P6 | H | H | H | H | F | Ar59 |
| Lₐ₁₅₉₆ | P6 | H | P6 | H | H | H | H | F | Ar60 |
| Lₐ₁₅₉₇ | P6 | H | P6 | H | H | H | H | F | Ar61 |
| Lₐ₁₅₉₈ | P6 | H | P6 | H | H | H | H | F | Ar62 |
| Lₐ₁₅₉₉ | P6 | H | P6 | H | H | H | H | F | Ar63 |
| Lₐ₁₆₀₀ | P6 | H | P6 | H | H | H | H | F | Ar64 |
| Lₐ₁₆₀₁ | P6 | H | P6 | H | H | H | H | F | Ar65 |
| Lₐ₁₆₀₂ | P6 | H | P6 | H | H | H | H | F | Ar66 |
| Lₐ₁₆₀₃ | P6 | D | P6 | D | D | D | D | F | Ar16 |
| Lₐ₁₆₀₄ | P6 | H | P10 | H | H | H | H | F | Ar1 |
| Lₐ₁₆₀₅ | P6 | H | P10 | H | H | H | H | F | Ar2 |
| Lₐ₁₆₀₆ | P6 | H | P10 | H | H | H | H | F | Ar3 |
| Lₐ₁₆₀₇ | P6 | H | P10 | H | H | H | H | F | Ar4 |
| Lₐ₁₆₀₈ | P6 | H | P10 | H | H | H | H | F | Ar5 |
| Lₐ₁₆₀₉ | P6 | H | P10 | H | H | H | H | F | Ar6 |
| Lₐ₁₆₁₀ | P6 | H | P10 | H | H | H | H | F | Ar7 |
| Lₐ₁₆₁₁ | P6 | H | P10 | H | H | H | H | F | Ar8 |
| Lₐ₁₆₁₂ | P6 | H | P10 | H | H | H | H | F | Ar9 |
| Lₐ₁₆₁₃ | P6 | H | P10 | H | H | H | H | F | Ar10 |
| Lₐ₁₆₁₄ | P6 | H | P10 | H | H | H | H | F | Ar11 |
| Lₐ₁₆₁₅ | P6 | H | P10 | H | H | H | H | F | Ar12 |
| Lₐ₁₆₁₆ | P6 | H | P10 | H | H | H | H | F | Ar13 |
| Lₐ₁₆₁₇ | P6 | H | P10 | H | H | H | H | F | Ar14 |
| Lₐ₁₆₁₈ | P6 | H | P10 | H | H | H | H | F | Ar15 |
| Lₐ₁₆₁₉ | P6 | H | P10 | H | H | H | H | F | Ar16 |
| Lₐ₁₆₂₀ | P6 | H | P10 | H | H | H | H | F | Ar17 |
| Lₐ₁₆₂₁ | P6 | H | P10 | H | H | H | H | F | Ar18 |
| Lₐ₁₆₂₂ | P6 | H | P10 | H | H | H | H | F | Ar19 |
| Lₐ₁₆₂₃ | P6 | H | P10 | H | H | H | H | F | Ar20 |
| Lₐ₁₆₂₄ | P6 | H | P10 | H | H | H | H | F | Ar21 |
| Lₐ₁₆₂₅ | P6 | H | P10 | H | H | H | H | F | Ar22 |
| Lₐ₁₆₂₆ | P6 | H | P10 | H | H | H | H | F | Ar23 |
| Lₐ₁₆₂₇ | P6 | H | P10 | H | H | H | H | F | Ar24 |
| Lₐ₁₆₂₈ | P6 | H | P10 | H | H | H | H | F | Ar25 |
| Lₐ₁₆₂₉ | P6 | H | P10 | H | H | H | H | F | Ar26 |
| Lₐ₁₆₃₀ | P6 | H | P10 | H | H | H | H | F | Ar27 |
| Lₐ₁₆₃₁ | P6 | H | P10 | H | H | H | H | F | Ar28 |
| Lₐ₁₆₃₂ | P6 | H | P10 | H | H | H | H | F | Ar29 |
| Lₐ₁₆₃₃ | P6 | H | P10 | H | H | H | H | F | Ar30 |
| Lₐ₁₆₃₄ | P6 | H | P10 | H | H | H | H | F | Ar31 |
| Lₐ₁₆₃₅ | P6 | H | P10 | H | H | H | H | F | Ar32 |
| Lₐ₁₆₃₆ | P6 | H | P10 | H | H | H | H | F | Ar33 |
| Lₐ₁₆₃₇ | P6 | H | P10 | H | H | H | H | F | Ar34 |
| Lₐ₁₆₃₈ | P6 | H | P10 | H | H | H | H | F | Ar35 |
| Lₐ₁₆₃₉ | P6 | H | P10 | H | H | H | H | F | Ar36 |
| Lₐ₁₆₄₀ | P6 | H | P10 | H | H | H | H | F | Ar37 |
| Lₐ₁₆₄₁ | P6 | H | P10 | H | H | H | H | F | Ar38 |
| Lₐ₁₆₄₂ | P6 | H | P10 | H | H | H | H | F | Ar39 |
| Lₐ₁₆₄₃ | P6 | H | P10 | H | H | H | H | F | Ar40 |
| Lₐ₁₆₄₄ | P6 | H | P10 | H | H | H | H | F | Ar41 |
| Lₐ₁₆₄₅ | P6 | H | P10 | H | H | H | H | F | Ar42 |
| Lₐ₁₆₄₆ | P6 | H | P10 | H | H | H | H | F | Ar43 |
| Lₐ₁₆₄₇ | P6 | H | P10 | H | H | H | H | F | Ar44 |
| Lₐ₁₆₄₈ | P6 | H | P10 | H | H | H | H | F | Ar45 |
| Lₐ₁₆₄₉ | P6 | H | P10 | H | H | H | H | F | Ar46 |
| Lₐ₁₆₅₀ | P6 | H | P10 | H | H | H | H | F | Ar47 |
| Lₐ₁₆₅₁ | P6 | H | P10 | H | H | H | H | F | Ar48 |
| Lₐ₁₆₅₂ | P6 | H | P10 | H | H | H | H | F | Ar49 |
| Lₐ₁₆₅₃ | P6 | H | P10 | H | H | H | H | F | Ar50 |
| Lₐ₁₆₅₄ | P6 | H | P10 | H | H | H | H | F | Ar51 |
| Lₐ₁₆₅₅ | P6 | H | P10 | H | H | H | H | F | Ar52 |
| Lₐ₁₆₅₆ | P6 | H | P10 | H | H | H | H | F | Ar53 |
| Lₐ₁₆₅₇ | P6 | H | P10 | H | H | H | H | F | Ar54 |
| Lₐ₁₆₅₈ | P6 | H | P10 | H | H | H | H | F | Ar55 |
| Lₐ₁₆₅₉ | P6 | H | P10 | H | H | H | H | F | Ar56 |
| Lₐ₁₆₆₀ | P6 | H | P10 | H | H | H | H | F | Ar57 |
| Lₐ₁₆₆₁ | P6 | H | P10 | H | H | H | H | F | Ar58 |
| Lₐ₁₆₆₂ | P6 | H | P10 | H | H | H | H | F | Ar59 |
| Lₐ₁₆₆₃ | P6 | H | P10 | H | H | H | H | F | Ar60 |
| Lₐ₁₆₆₄ | P6 | H | P10 | H | H | H | H | F | Ar61 |
| Lₐ₁₆₆₅ | P6 | H | P10 | H | H | H | H | F | Ar62 |
| Lₐ₁₆₆₆ | P6 | H | P10 | H | H | H | H | F | Ar63 |
| Lₐ₁₆₆₇ | P6 | H | P10 | H | H | H | H | F | Ar64 |
| Lₐ₁₆₆₈ | P6 | H | P10 | H | H | H | H | F | Ar65 |
| Lₐ₁₆₆₉ | P6 | H | P10 | H | H | H | H | F | Ar66 |
| Lₐ₁₆₇₀ | P6 | D | P11 | D | D | D | D | F | Ar16 |
| Lₐ₁₆₇₁ | P6 | H | P6 | P1 | H | H | H | F | Ar1 |
| Lₐ₁₆₇₂ | P6 | H | P6 | P1 | H | H | H | F | Ar2 |
| Lₐ₁₆₇₃ | P6 | H | P6 | P1 | H | H | H | F | Ar3 |
| Lₐ₁₆₇₄ | P6 | H | P6 | P1 | H | H | H | F | Ar4 |
| Lₐ₁₆₇₅ | P6 | H | P6 | P1 | H | H | H | F | Ar5 |
| Lₐ₁₆₇₆ | P6 | H | P6 | P1 | H | H | H | F | Ar6 |
| Lₐ₁₆₇₇ | P6 | H | P6 | P1 | H | H | H | F | Ar7 |
| Lₐ₁₆₇₈ | P6 | H | P6 | P1 | H | H | H | F | Ar8 |
| Lₐ₁₆₇₉ | P6 | H | P6 | P1 | H | H | H | F | Ar9 |
| Lₐ₁₆₈₀ | P6 | H | P6 | P1 | H | H | H | F | Ar10 |
| Lₐ₁₆₈₁ | P6 | H | P6 | P1 | H | H | H | F | Ar11 |
| Lₐ₁₆₈₂ | P6 | H | P6 | P1 | H | H | H | F | Ar12 |
| Lₐ₁₆₈₃ | P6 | H | P6 | P1 | H | H | H | F | Ar13 |
| Lₐ₁₆₈₄ | P6 | H | P6 | P1 | H | H | H | F | Ar14 |
| Lₐ₁₆₈₅ | P6 | H | P6 | P1 | H | H | H | F | Ar15 |
| Lₐ₁₆₈₆ | P6 | H | P6 | P1 | H | H | H | F | Ar16 |
| Lₐ₁₆₈₇ | P6 | H | P6 | P1 | H | H | H | F | Ar17 |
| Lₐ₁₆₈₈ | P6 | H | P6 | P1 | H | H | H | F | Ar18 |
| Lₐ₁₆₈₉ | P6 | H | P6 | P1 | H | H | H | F | Ar19 |
| Lₐ₁₆₉₀ | P6 | H | P6 | P1 | H | H | H | F | Ar20 |
| Lₐ₁₆₉₁ | P6 | H | P6 | P1 | H | H | H | F | Ar21 |
| Lₐ₁₆₉₂ | P6 | H | P6 | P1 | H | H | H | F | Ar22 |
| Lₐ₁₆₉₃ | P6 | H | P6 | P1 | H | H | H | F | Ar23 |
| Lₐ₁₆₉₄ | P6 | H | P6 | P1 | H | H | H | F | Ar24 |
| Lₐ₁₆₉₅ | P6 | H | P6 | P1 | H | H | H | F | Ar25 |
| Lₐ₁₆₉₆ | P6 | H | P6 | P1 | H | H | H | F | Ar26 |
| Lₐ₁₆₉₇ | P6 | H | P6 | P1 | H | H | H | F | Ar27 |
| Lₐ₁₆₉₈ | P6 | H | P6 | P1 | H | H | H | F | Ar28 |
| Lₐ₁₆₉₉ | P6 | H | P6 | P1 | H | H | H | F | Ar29 |
| Lₐ₁₇₀₀ | P6 | H | P6 | P1 | H | H | H | F | Ar30 |
| Lₐ₁₇₀₁ | P6 | H | P6 | P1 | H | H | H | F | Ar31 |
| Lₐ₁₇₀₂ | P6 | H | P6 | P1 | H | H | H | F | Ar32 |
| Lₐ₁₇₀₃ | P6 | H | P6 | P1 | H | H | H | F | Ar33 |
| Lₐ₁₇₀₄ | P6 | H | P6 | P1 | H | H | H | F | Ar34 |
| Lₐ₁₇₀₅ | P6 | H | P6 | P1 | H | H | H | F | Ar35 |
| Lₐ₁₇₀₆ | P6 | H | P6 | P1 | H | H | H | F | Ar36 |
| Lₐ₁₇₀₇ | P6 | H | P6 | P1 | H | H | H | F | Ar37 |
| Lₐ₁₇₀₈ | P6 | H | P6 | P1 | H | H | H | F | Ar38 |
| Lₐ₁₇₀₉ | P6 | H | P6 | P1 | H | H | H | F | Ar39 |
| Lₐ₁₇₁₀ | P6 | H | P6 | P1 | H | H | H | F | Ar40 |
| Lₐ₁₇₁₁ | P6 | H | P6 | P1 | H | H | H | F | Ar41 |
| Lₐ₁₇₁₂ | P6 | H | P6 | P1 | H | H | H | F | Ar42 |
| Lₐ₁₇₁₃ | P6 | H | P6 | P1 | H | H | H | F | Ar43 |
| Lₐ₁₇₁₄ | P6 | H | P6 | P1 | H | H | H | F | Ar44 |
| Lₐ₁₇₁₅ | P6 | H | P6 | P1 | H | H | H | F | Ar45 |
| Lₐ₁₇₁₆ | P6 | H | P6 | P1 | H | H | H | F | Ar46 |
| Lₐ₁₇₁₇ | P6 | H | P6 | P1 | H | H | H | F | Ar47 |
| Lₐ₁₇₁₈ | P6 | H | P6 | P1 | H | H | H | F | Ar48 |
| Lₐ₁₇₁₉ | P6 | H | P6 | P1 | H | H | H | F | Ar49 |
| Lₐ₁₇₂₀ | P6 | H | P6 | P1 | H | H | H | F | Ar50 |
| Lₐ₁₇₂₁ | P6 | H | P6 | P1 | H | H | H | F | Ar51 |
| Lₐ₁₇₂₂ | P6 | H | P6 | P1 | H | H | H | F | Ar52 |
| Lₐ₁₇₂₃ | P6 | H | P6 | P1 | H | H | H | F | Ar53 |
| Lₐ₁₇₂₄ | P6 | H | P6 | P1 | H | H | H | F | Ar54 |
| Lₐ₁₇₂₅ | P6 | H | P6 | P1 | H | H | H | F | Ar55 |
| Lₐ₁₇₂₆ | P6 | H | P6 | P1 | H | H | H | F | Ar56 |
| Lₐ₁₇₂₇ | P6 | H | P6 | P1 | H | H | H | F | Ar57 |
| Lₐ₁₇₂₈ | P6 | H | P6 | P1 | H | H | H | F | Ar58 |
| Lₐ₁₇₂₉ | P6 | H | P6 | P1 | H | H | H | F | Ar59 |
| Lₐ₁₇₃₀ | P6 | H | P6 | P1 | H | H | H | F | Ar60 |
| Lₐ₁₇₃₁ | P6 | H | P6 | P1 | H | H | H | F | Ar61 |
| Lₐ₁₇₃₂ | P6 | H | P6 | P1 | H | H | H | F | Ar62 |
| Lₐ₁₇₃₃ | P6 | H | P6 | P1 | H | H | H | F | Ar63 |
| Lₐ₁₇₃₄ | P6 | H | P6 | P1 | H | H | H | F | Ar64 |
| Lₐ₁₇₃₅ | P6 | H | P6 | P1 | H | H | H | F | Ar65 |
| Lₐ₁₇₃₆ | P6 | H | P6 | P1 | H | H | H | F | Ar66 |
| Lₐ₁₇₃₇ | P6 | D | P6 | P2 | D | D | D | F | Ar16 |
| Lₐ₁₇₃₈ | P6 | H | P10 | P1 | H | H | H | F | Ar1 |
| Lₐ₁₇₃₉ | P6 | H | P10 | P1 | H | H | H | F | Ar2 |
| Lₐ₁₇₄₀ | P6 | H | P10 | P1 | H | H | H | F | Ar3 |
| Lₐ₁₇₄₁ | P6 | H | P10 | P1 | H | H | H | F | Ar4 |
| Lₐ₁₇₄₂ | P6 | H | P10 | P1 | H | H | H | F | Ar5 |
| Lₐ₁₇₄₃ | P6 | H | P10 | P1 | H | H | H | F | Ar6 |
| Lₐ₁₇₄₄ | P6 | H | P10 | P1 | H | H | H | F | Ar7 |
| Lₐ₁₇₄₅ | P6 | H | P10 | P1 | H | H | H | F | Ar8 |
| Lₐ₁₇₄₆ | P6 | H | P10 | P1 | H | H | H | F | Ar9 |
| Lₐ₁₇₄₇ | P6 | H | P10 | P1 | H | H | H | F | Ar10 |
| Lₐ₁₇₄₈ | P6 | H | P10 | P1 | H | H | H | F | Ar11 |
| Lₐ₁₇₄₉ | P6 | H | P10 | P1 | H | H | H | F | Ar12 |
| Lₐ₁₇₅₀ | P6 | H | P10 | P1 | H | H | H | F | Ar13 |
| Lₐ₁₇₅₁ | P6 | H | P10 | P1 | H | H | H | F | Ar14 |
| Lₐ₁₇₅₂ | P6 | H | P10 | P1 | H | H | H | F | Ar15 |
| Lₐ₁₇₅₃ | P6 | H | P10 | P1 | H | H | H | F | Ar16 |
| Lₐ₁₇₅₄ | P6 | H | P10 | P1 | H | H | H | F | Ar17 |
| Lₐ₁₇₅₅ | P6 | H | P10 | P1 | H | H | H | F | Ar18 |
| Lₐ₁₇₅₆ | P6 | H | P10 | P1 | H | H | H | F | Ar19 |
| Lₐ₁₇₅₇ | P6 | H | P10 | P1 | H | H | H | F | Ar20 |
| Lₐ₁₇₅₈ | P6 | H | P10 | P1 | H | H | H | F | Ar21 |
| Lₐ₁₇₅₉ | P6 | H | P10 | P1 | H | H | H | F | Ar22 |
| Lₐ₁₇₆₀ | P6 | H | P10 | P1 | H | H | H | F | Ar23 |
| Lₐ₁₇₆₁ | P6 | H | P10 | P1 | H | H | H | F | Ar24 |
| Lₐ₁₇₆₂ | P6 | H | P10 | P1 | H | H | H | F | Ar25 |
| Lₐ₁₇₆₃ | P6 | H | P10 | P1 | H | H | H | F | Ar26 |
| Lₐ₁₇₆₄ | P6 | H | P10 | P1 | H | H | H | F | Ar27 |
| Lₐ₁₇₆₅ | P6 | H | P10 | P1 | H | H | H | F | Ar28 |
| Lₐ₁₇₆₆ | P6 | H | P10 | P1 | H | H | H | F | Ar29 |
| Lₐ₁₇₆₇ | P6 | H | P10 | P1 | H | H | H | F | Ar30 |
| Lₐ₁₇₆₈ | P6 | H | P10 | P1 | H | H | H | F | Ar31 |
| Lₐ₁₇₆₉ | P6 | H | P10 | P1 | H | H | H | F | Ar32 |
| Lₐ₁₇₇₀ | P6 | H | P10 | P1 | H | H | H | F | Ar33 |
| Lₐ₁₇₇₁ | P6 | H | P10 | P1 | H | H | H | F | Ar34 |
| Lₐ₁₇₇₂ | P6 | H | P10 | P1 | H | H | H | F | Ar35 |
| Lₐ₁₇₇₃ | P6 | H | P10 | P1 | H | H | H | F | Ar36 |
| Lₐ₁₇₇₄ | P6 | H | P10 | P1 | H | H | H | F | Ar37 |
| Lₐ₁₇₇₅ | P6 | H | P10 | P1 | H | H | H | F | Ar38 |
| Lₐ₁₇₇₆ | P6 | H | P10 | P1 | H | H | H | F | Ar39 |
| Lₐ₁₇₇₇ | P6 | H | P10 | P1 | H | H | H | F | Ar40 |
| Lₐ₁₇₇₈ | P6 | H | P10 | P1 | H | H | H | F | Ar41 |
| Lₐ₁₇₇₉ | P6 | H | P10 | P1 | H | H | H | F | Ar42 |
| Lₐ₁₇₈₀ | P6 | H | P10 | P1 | H | H | H | F | Ar43 |
| Lₐ₁₇₈₁ | P6 | H | P10 | P1 | H | H | H | F | Ar44 |
| Lₐ₁₇₈₂ | P6 | H | P10 | P1 | H | H | H | F | Ar45 |
| Lₐ₁₇₈₃ | P6 | H | P10 | P1 | H | H | H | F | Ar46 |
| Lₐ₁₇₈₄ | P6 | H | P10 | P1 | H | H | H | F | Ar47 |
| Lₐ₁₇₈₅ | P6 | H | P10 | P1 | H | H | H | F | Ar48 |
| Lₐ₁₇₈₆ | P6 | H | P10 | P1 | H | H | H | F | Ar49 |
| Lₐ₁₇₈₇ | P6 | H | P10 | P1 | H | H | H | F | Ar50 |
| Lₐ₁₇₈₈ | P6 | H | P10 | P1 | H | H | H | F | Ar51 |
| Lₐ₁₇₈₉ | P6 | H | P10 | P1 | H | H | H | F | Ar52 |
| Lₐ₁₇₉₀ | P6 | H | P10 | P1 | H | H | H | F | Ar53 |
| Lₐ₁₇₉₁ | P6 | H | P10 | P1 | H | H | H | F | Ar54 |
| Lₐ₁₇₉₂ | P6 | H | P10 | P1 | H | H | H | F | Ar55 |
| Lₐ₁₇₉₃ | P6 | H | P10 | P1 | H | H | H | F | Ar56 |
| Lₐ₁₇₉₄ | P6 | H | P10 | P1 | H | H | H | F | Ar57 |
| Lₐ₁₇₉₅ | P6 | H | P10 | P1 | H | H | H | F | Ar58 |
| Lₐ₁₇₉₆ | P6 | H | P10 | P1 | H | H | H | F | Ar59 |
| Lₐ₁₇₉₇ | P6 | H | P10 | P1 | H | H | H | F | Ar60 |
| Lₐ₁₇₉₈ | P6 | H | P10 | P1 | H | H | H | F | Ar61 |
| Lₐ₁₇₉₉ | P6 | H | P10 | P1 | H | H | H | F | Ar62 |
| Lₐ₁₈₀₀ | P6 | H | P10 | P1 | H | H | H | F | Ar63 |
| Lₐ₁₈₀₁ | P6 | H | P10 | P1 | H | H | H | F | Ar64 |
| Lₐ₁₈₀₂ | P6 | H | P10 | P1 | H | H | H | F | Ar65 |
| Lₐ₁₈₀₃ | P6 | H | P10 | P1 | H | H | H | F | Ar66 |
| Lₐ₁₈₀₄ | P6 | D | P11 | P2 | D | D | D | F | Ar16 |
| Lₐ₁₈₀₅ | P6 | H | P3 | H | H | H | H | F | Ar16 |
| Lₐ₁₈₀₆ | P6 | H | P4 | H | H | H | H | F | Ar16 |
| Lₐ₁₈₀₇ | P6 | H | P5 | H | H | H | H | F | Ar16 |
| Lₐ₁₈₀₈ | P6 | H | P7 | H | H | H | H | F | Ar16 |
| Lₐ₁₈₀₉ | P6 | H | P8 | H | H | H | H | F | Ar16 |
| Lₐ₁₈₁₀ | P6 | H | P9 | H | H | H | H | F | Ar16 |
| Lₐ₁₈₁₁ | P6 | H | P12 | H | H | H | H | F | Ar16 |
| Lₐ₁₈₁₂ | P6 | H | P13 | H | H | H | H | F | Ar16 |
| Lₐ₁₈₁₃ | P6 | H | P14 | H | H | H | H | F | Ar16 |
| Lₐ₁₈₁₄ | P6 | H | P15 | H | H | H | H | F | Ar16 |
| Lₐ₁₈₁₅ | P6 | H | P16 | H | H | H | H | F | Ar16 |
| Lₐ₁₈₁₆ | P6 | H | P17 | H | H | H | H | F | Ar16 |
| Lₐ₁₈₁₇ | P6 | H | P18 | H | H | H | H | F | Ar16 |
| Lₐ₁₈₁₈ | P6 | H | P19 | H | H | H | H | F | Ar16 |
| Lₐ₁₈₁₉ | P6 | H | P20 | H | H | H | H | F | Ar16 |
| Lₐ₁₈₂₀ | P6 | H | P21 | H | H | H | H | F | Ar16 |
| Lₐ₁₈₂₁ | P6 | H | P22 | H | H | H | H | F | Ar16 |
| Lₐ₁₈₂₂ | P6 | H | P23 | H | H | H | H | F | Ar16 |
| Lₐ₁₈₂₃ | P6 | H | P24 | H | H | H | H | F | Ar16 |
| Lₐ₁₈₂₄ | P6 | H | P25 | H | H | H | H | F | Ar16 |
| Lₐ₁₈₂₅ | P6 | H | P26 | H | H | H | H | F | Ar16 |
| Lₐ₁₈₂₆ | P6 | H | P27 | H | H | H | H | F | Ar16 |
| Lₐ₁₈₂₇ | P6 | H | P28 | H | H | H | H | F | Ar16 |
| Lₐ₁₈₂₈ | P6 | H | P29 | H | H | H | H | F | Ar16 |
| Lₐ₁₈₂₉ | P6 | H | P30 | H | H | H | H | F | Ar16 |
| Lₐ₁₈₃₀ | P6 | H | P31 | H | H | H | H | F | Ar16 |
| Lₐ₁₈₃₁ | P6 | H | P32 | H | H | H | H | F | Ar16 |
| Lₐ₁₈₃₂ | P6 | H | P33 | H | H | H | H | F | Ar16 |
| Lₐ₁₈₃₃ | P6 | H | P34 | H | H | H | H | F | Ar16 |
| Lₐ₁₈₃₄ | P6 | H | P35 | H | H | H | H | F | Ar16 |
| Lₐ₁₈₃₅ | P6 | H | P36 | H | H | H | H | F | Ar16 |
| Lₐ₁₈₃₆ | P6 | H | P37 | H | H | H | H | F | Ar16 |
| Lₐ₁₈₃₇ | P6 | H | P38 | H | H | H | H | F | Ar16 |
| Lₐ₁₈₃₈ | P6 | H | P39 | H | H | H | H | F | Ar16 |
| Lₐ₁₈₃₉ | P6 | H | P40 | H | H | H | H | F | Ar16 |
| Lₐ₁₈₄₀ | P6 | H | P41 | H | H | H | H | F | Ar16 |
| Lₐ₁₈₄₁ | P6 | H | P42 | H | H | H | H | F | Ar16 |
| Lₐ₁₈₄₂ | P6 | H | P43 | H | H | H | H | F | Ar16 |
| Lₐ₁₈₄₃ | P6 | H | P44 | H | H | H | H | F | Ar16 |
| Lₐ₁₈₄₄ | P6 | H | P45 | H | H | H | H | F | Ar16 |
| Lₐ₁₈₄₅ | P6 | H | P46 | H | H | H | H | F | Ar16 |
| Lₐ₁₈₄₆ | P6 | H | P47 | H | H | H | H | F | Ar16 |
| Lₐ₁₈₄₇ | P6 | H | P48 | H | H | H | H | F | Ar16 |
| Lₐ₁₈₄₈ | P6 | H | P49 | H | H | H | H | F | Ar16 |
| Lₐ₁₈₄₉ | P6 | H | P50 | H | H | H | H | F | Ar16 |
| Lₐ₁₈₅₀ | P6 | H | P51 | H | H | H | H | F | Ar16 |
| Lₐ₁₈₅₁ | P6 | H | P52 | H | H | H | H | F | Ar16 |
| Lₐ₁₈₅₂ | P6 | H | P53 | H | H | H | H | F | Ar16 |
| Lₐ₁₈₅₃ | P6 | H | P54 | H | H | H | H | F | Ar16 |
| Lₐ₁₈₅₄ | P6 | H | H | P3 | H | H | H | F | Ar16 |
| Lₐ₁₈₅₅ | P6 | H | H | P4 | H | H | H | F | Ar16 |
| Lₐ₁₈₅₆ | P6 | H | H | P5 | H | H | H | F | Ar16 |
| Lₐ₁₈₅₇ | P6 | H | H | P7 | H | H | H | F | Ar16 |
| Lₐ₁₈₅₈ | P6 | H | H | P8 | H | H | H | F | Ar16 |
| Lₐ₁₈₅₉ | P6 | H | H | P9 | H | H | H | F | Ar16 |
| Lₐ₁₈₆₀ | P6 | H | H | P12 | H | H | H | F | Ar16 |
| Lₐ₁₈₆₁ | P6 | H | H | P13 | H | H | H | F | Ar16 |
| Lₐ₁₈₆₂ | P6 | H | H | P14 | H | H | H | F | Ar16 |
| Lₐ₁₈₆₃ | P6 | H | H | P15 | H | H | H | F | Ar16 |
| Lₐ₁₈₆₄ | P6 | H | H | P16 | H | H | H | F | Ar16 |
| Lₐ₁₈₆₅ | P6 | H | H | P17 | H | H | H | F | Ar16 |
| Lₐ₁₈₆₆ | P6 | H | H | P18 | H | H | H | F | Ar16 |
| Lₐ₁₈₆₇ | P6 | H | H | P19 | H | H | H | F | Ar16 |
| Lₐ₁₈₆₈ | P6 | H | H | P20 | H | H | H | F | Ar16 |
| Lₐ₁₈₆₉ | P6 | H | H | P21 | H | H | H | F | Ar16 |
| Lₐ₁₈₇₀ | P6 | H | H | P22 | H | H | H | F | Ar16 |
| Lₐ₁₈₇₁ | P6 | H | H | P23 | H | H | H | F | Ar16 |
| Lₐ₁₈₇₂ | P6 | H | H | P24 | H | H | H | F | Ar16 |
| Lₐ₁₈₇₃ | P6 | H | H | P25 | H | H | H | F | Ar16 |
| Lₐ₁₈₇₄ | P6 | H | H | P26 | H | H | H | F | Ar16 |
| Lₐ₁₈₇₅ | P6 | H | H | P27 | H | H | H | F | Ar16 |
| Lₐ₁₈₇₆ | P6 | H | H | P28 | H | H | H | F | Ar16 |
| Lₐ₁₈₇₇ | P6 | H | H | P29 | H | H | H | F | Ar16 |
| Lₐ₁₈₇₈ | P6 | H | H | P30 | H | H | H | F | Ar16 |
| Lₐ₁₈₇₉ | P6 | H | H | P31 | H | H | H | F | Ar16 |
| Lₐ₁₈₈₀ | P6 | H | H | P32 | H | H | H | F | Ar16 |
| Lₐ₁₈₈₁ | P6 | H | H | P33 | H | H | H | F | Ar16 |
| Lₐ₁₈₈₂ | P6 | H | H | P34 | H | H | H | F | Ar16 |
| Lₐ₁₈₈₃ | P6 | H | H | P35 | H | H | H | F | Ar16 |
| Lₐ₁₈₈₄ | P6 | H | H | P36 | H | H | H | F | Ar16 |
| Lₐ₁₈₈₅ | P6 | H | H | P37 | H | H | H | F | Ar16 |
| Lₐ₁₈₈₆ | P6 | H | H | P38 | H | H | H | F | Ar16 |
| Lₐ₁₈₈₇ | P6 | H | H | P39 | H | H | H | F | Ar16 |
| Lₐ₁₈₈₈ | P6 | H | H | P40 | H | H | H | F | Ar16 |
| Lₐ₁₈₈₉ | P6 | H | H | P41 | H | H | H | F | Ar16 |
| Lₐ₁₈₉₀ | P6 | H | H | P42 | H | H | H | F | Ar16 |
| Lₐ₁₈₉₁ | P6 | H | H | P43 | H | H | H | F | Ar16 |
| Lₐ₁₈₉₂ | P6 | H | H | P44 | H | H | H | F | Ar16 |
| Lₐ₁₈₉₃ | P6 | H | H | P45 | H | H | H | F | Ar16 |
| Lₐ₁₈₉₄ | P6 | H | H | P46 | H | H | H | F | Ar16 |
| Lₐ₁₈₉₅ | P6 | H | H | P47 | H | H | H | F | Ar16 |
| Lₐ₁₈₉₆ | P6 | H | H | P48 | H | H | H | F | Ar16 |
| Lₐ₁₈₉₇ | P6 | H | H | P49 | H | H | H | F | Ar16 |
| Lₐ₁₈₉₈ | P6 | H | H | P50 | H | H | H | F | Ar16 |
| Lₐ₁₈₉₉ | P6 | H | H | P51 | H | H | H | F | Ar16 |
| Lₐ₁₉₀₀ | P6 | H | H | P52 | H | H | H | F | Ar16 |
| Lₐ₁₉₀₁ | P6 | H | H | P53 | H | H | H | F | Ar16 |
| Lₐ₁₉₀₂ | P6 | H | H | P54 | H | H | H | F | Ar16 |
| Lₐ₁₉₀₃ | P11 | H | H | P6 | H | H | H | F | Ar16 |
| Lₐ₁₉₀₄ | P11 | H | P1 | P6 | H | H | H | F | Ar16 |
| Lₐ₁₉₀₅ | P11 | D | P2 | P6 | D | D | D | F | Ar16 |
| Lₐ₁₉₀₆ | P11 | D | P21 | H | H | H | H | F | Ar16 |
| Lₐ₁₉₀₇ | P11 | H | H | P21 | H | H | H | F | Ar16 |
| Lₐ₁₉₀₈ | P11 | H | P6 | H | H | H | H | F | Ar16 |
| Lₐ₁₉₀₉ | P11 | H | P6 | P1 | H | H | H | F | Ar16 |
| Lₐ₁₉₁₀ | P11 | D | P6 | P2 | D | D | D | F | Ar16 |
| Lₐ₁₉₁₁ | P11 | H | P17 | H | H | H | H | F | Ar16 |
| Lₐ₁₉₁₂ | P11 | H | H | P17 | H | H | H | F | Ar16 |
| Lₐ₁₉₁₃ | P11 | H | P23 | H | H | H | H | F | Ar16 |
| Lₐ₁₉₁₄ | P11 | H | H | P23 | H | H | H | F | Ar16 |
| Lₐ₁₉₁₅ | P11 | H | P29 | H | H | H | H | F | Ar16 |
| Lₐ₁₉₁₆ | P11 | H | H | P29 | H | H | H | F | Ar16 |
| Lₐ₁₉₁₇ | P11 | H | H | P6 | H | H | H | CN | Ar16 |
| Lₐ₁₉₁₈ | P11 | H | P1 | P6 | H | H | H | CN | Ar16 |
| Lₐ₁₉₁₉ | P11 | D | P2 | P6 | D | D | D | CN | Ar16 |
| Lₐ₁₉₂₀ | P11 | D | P21 | H | H | H | H | CN | Ar16 |
| Lₐ₁₉₂₁ | P11 | H | H | P21 | H | H | H | CN | Ar16 |
| Lₐ₁₉₂₂ | P11 | H | P6 | H | H | H | H | CN | Ar16 |
| Lₐ₁₉₂₃ | P11 | H | P6 | P1 | H | H | H | CN | Ar16 |
| Lₐ₁₉₂₄ | P11 | D | P6 | P2 | D | D | D | CN | Ar16 |
| Lₐ₁₉₂₅ | P11 | H | P17 | H | H | H | H | CN | Ar16 |
| Lₐ₁₉₂₆ | P11 | H | H | P17 | H | H | H | CN | Ar16 |
| Lₐ₁₉₂₇ | P11 | H | P23 | H | H | H | H | CN | Ar16 |
| Lₐ₁₉₂₈ | P11 | H | H | P23 | H | H | H | CN | Ar16 |
| Lₐ₁₉₂₉ | P11 | H | P29 | H | H | H | H | CN | Ar16 |
| Lₐ₁₉₃₀ | P11 | H | H | P29 | H | H | H | CN | Ar16 |
| Lₐ₁₉₃₁ | P11 | H | H | P6 | H | H | H | Ar16 | CN |

wherein P1 to P54 are selected from the group consisting of the following structures: 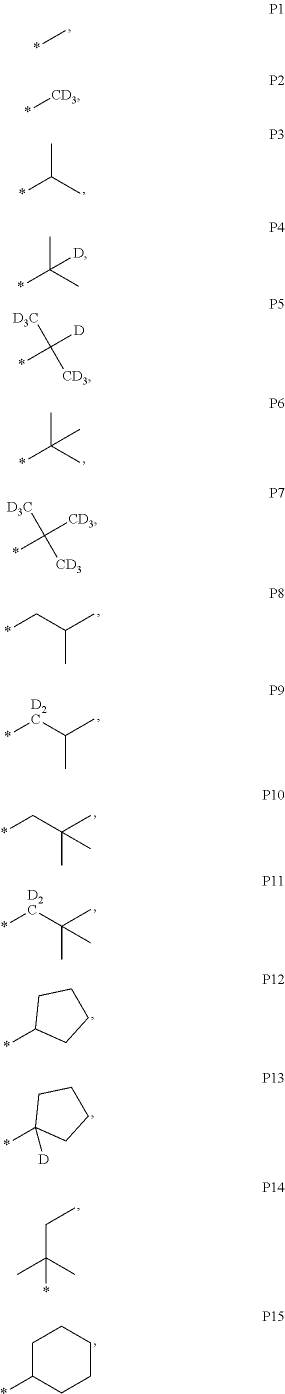 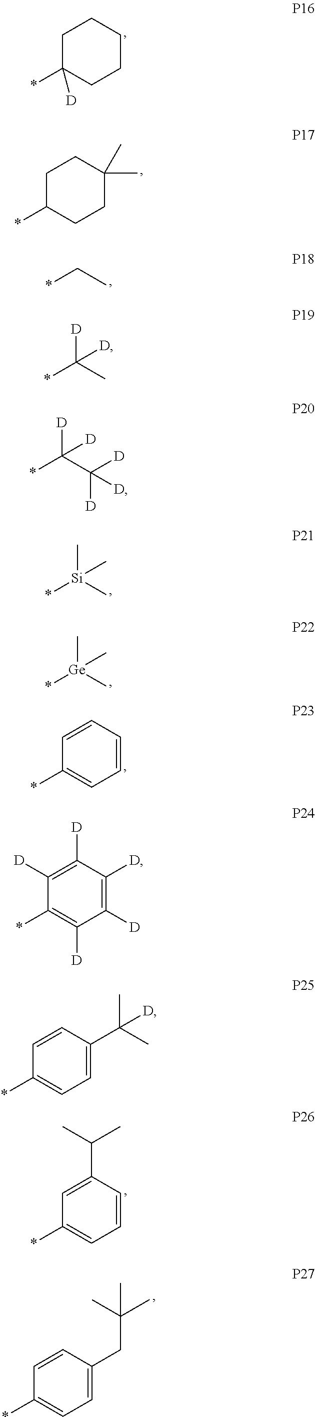 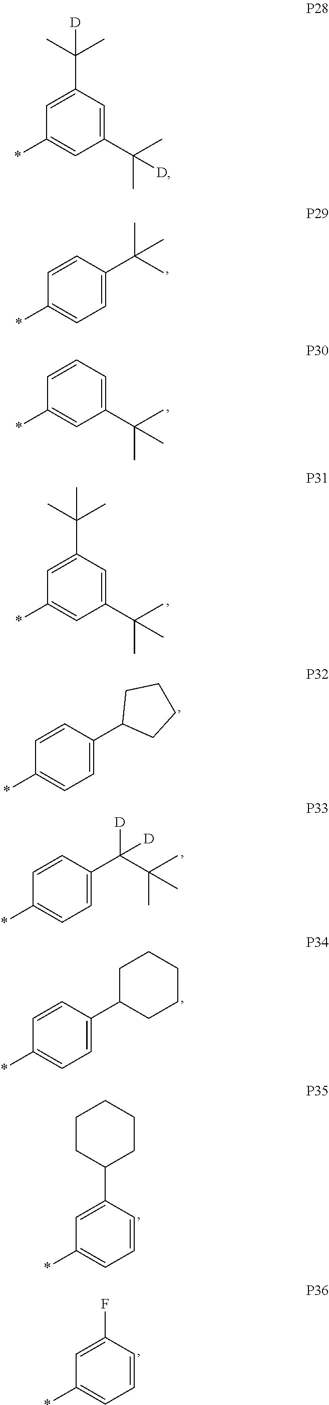 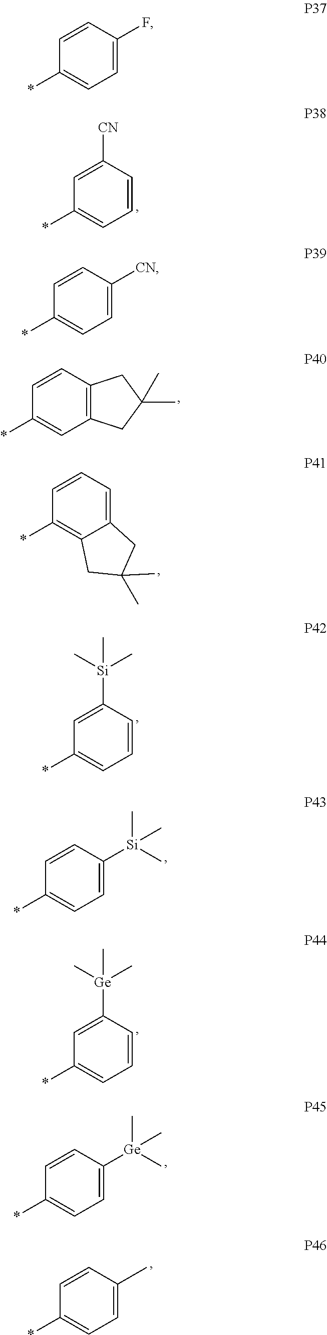 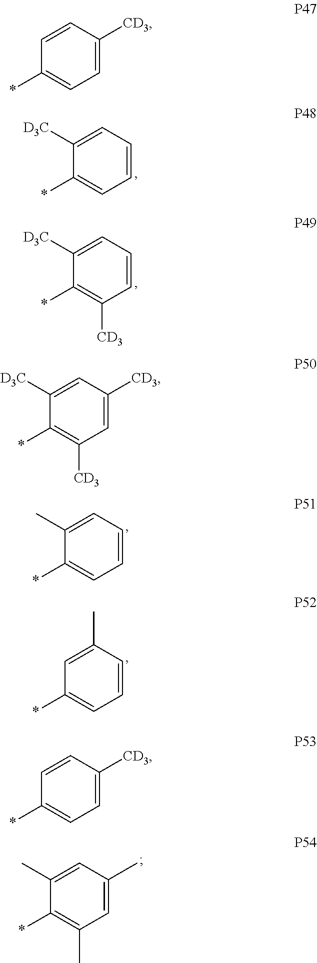
wherein “*” represents a position where P1 to P54 are each joined in the ligand Lₐ.

21. The metal complex according to claim 3, wherein R₁ and R₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, cyano, isocyano, and combinations thereof;
preferably, R₁ and R₂ are, at each occurrence identically or differently, selected from the group consisting of: hydrogen, deuterium, halogen, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, cyano, and combinations thereof;
more preferably, R₁ and R₂ are, at each occurrence identically or differently, selected from the group consisting of: hydrogen, deuterium, fluorine, cyano, methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, phenyl, pyridyl, trimethylsilyl, trimethylgermanyl, and combinations thereof.

22. The metal complex according to claim 20, wherein L_{b} is, at each occurrence identically or differently, selected from the group consisting of L_{b1} to L_{b160} whose structures are as follows: 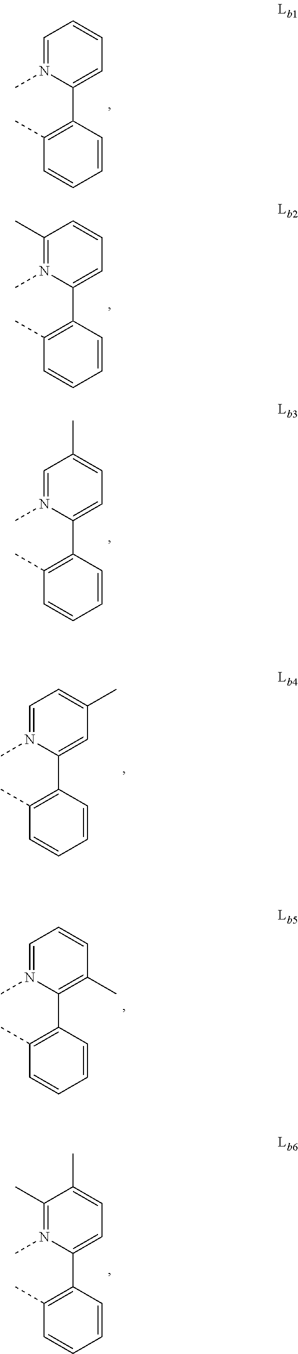 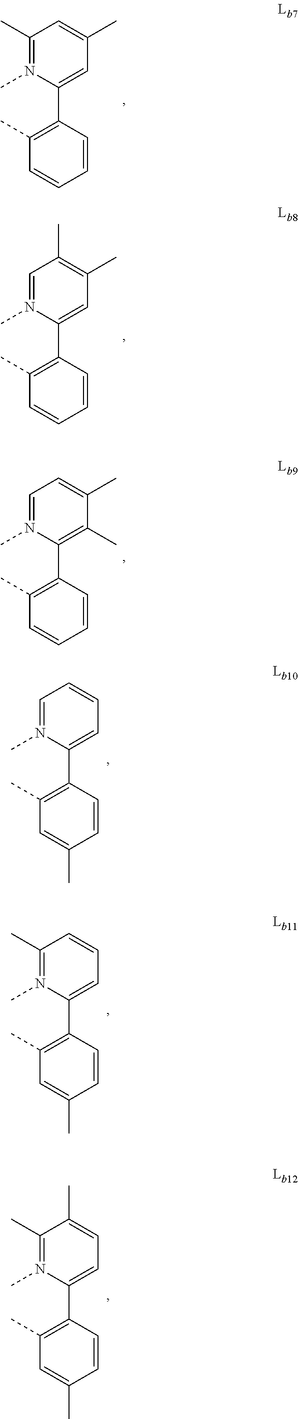 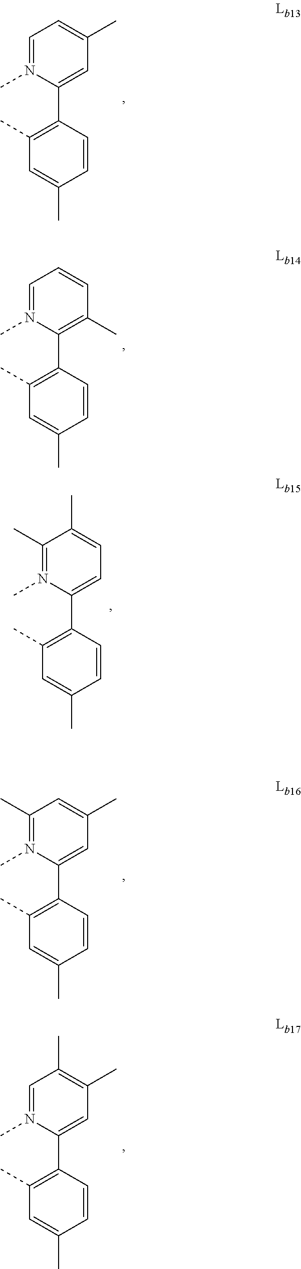 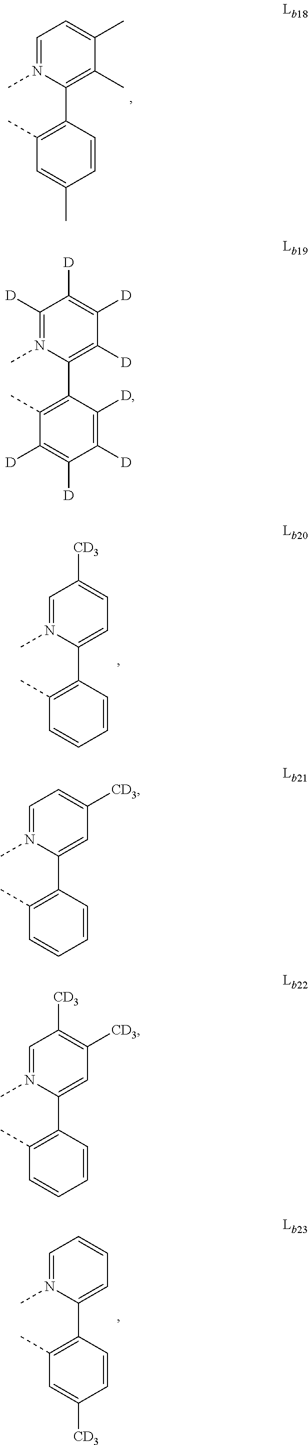 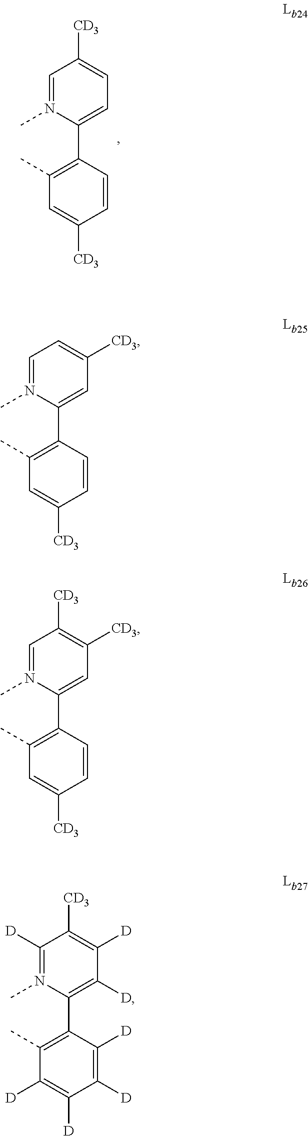 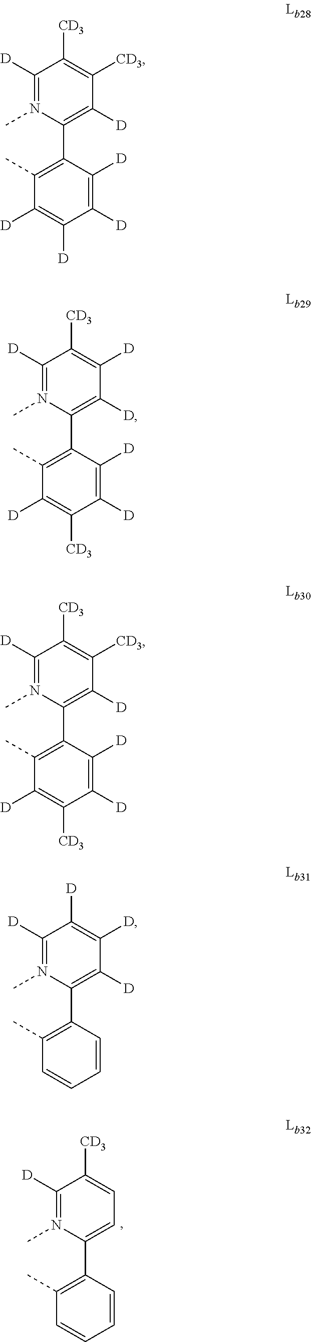 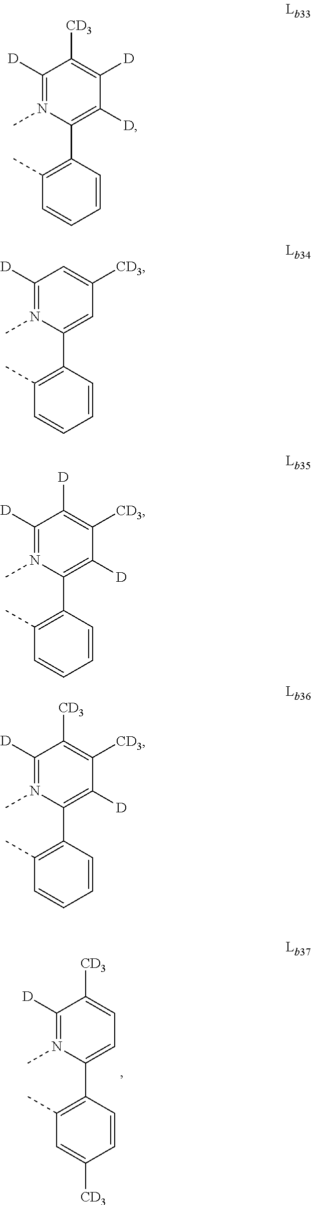 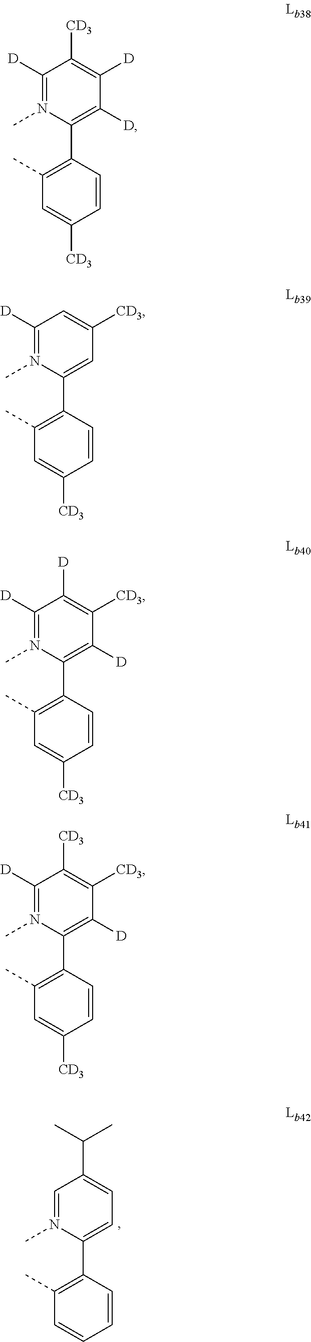 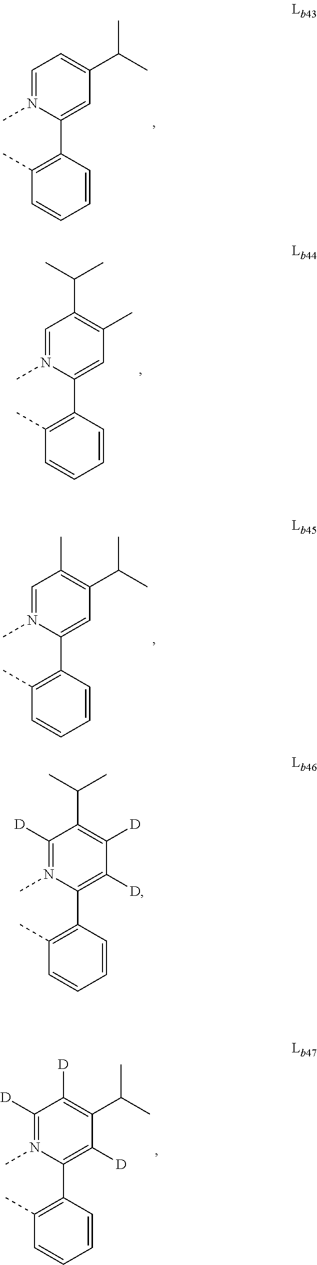 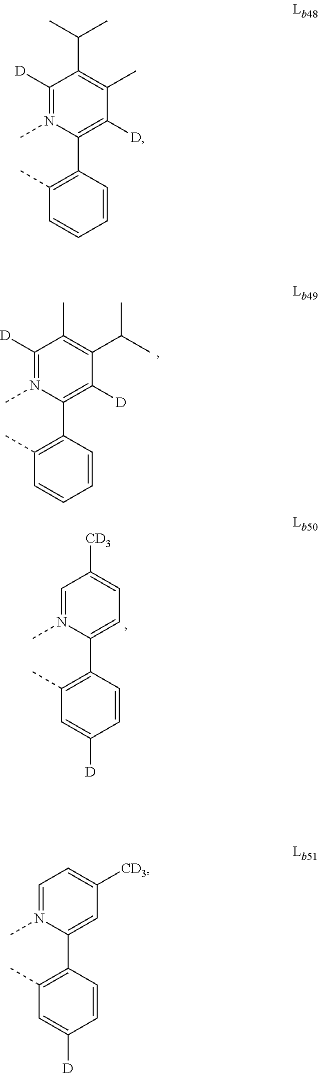 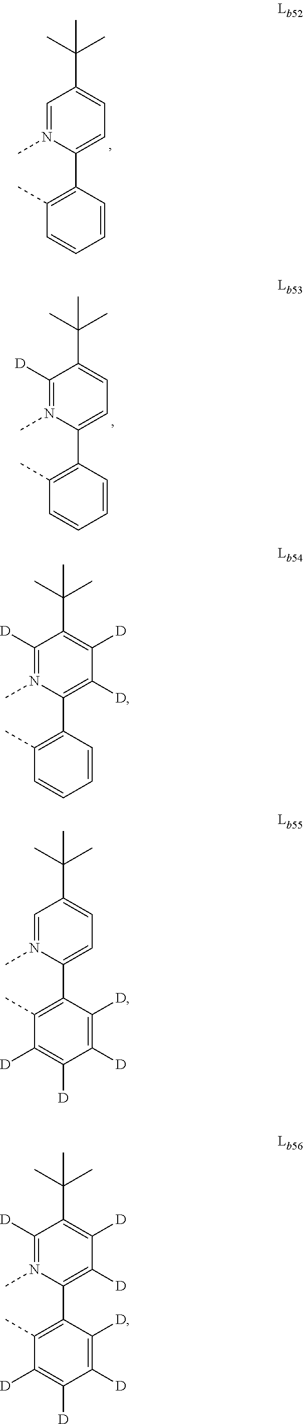 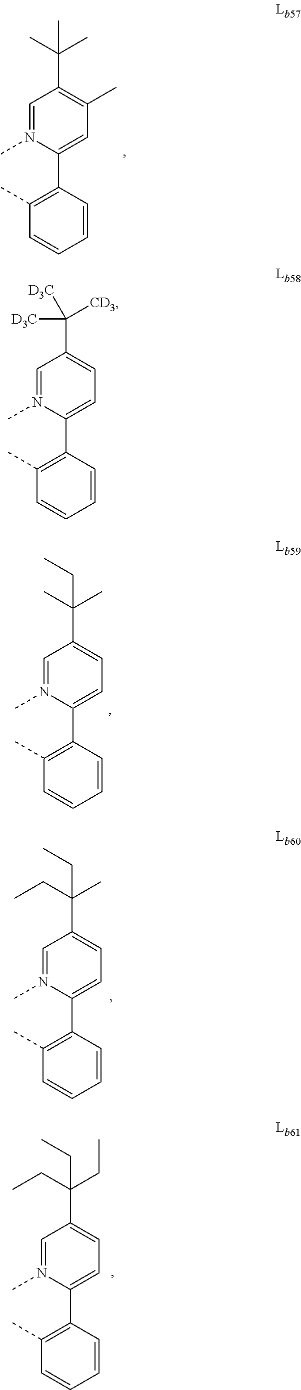 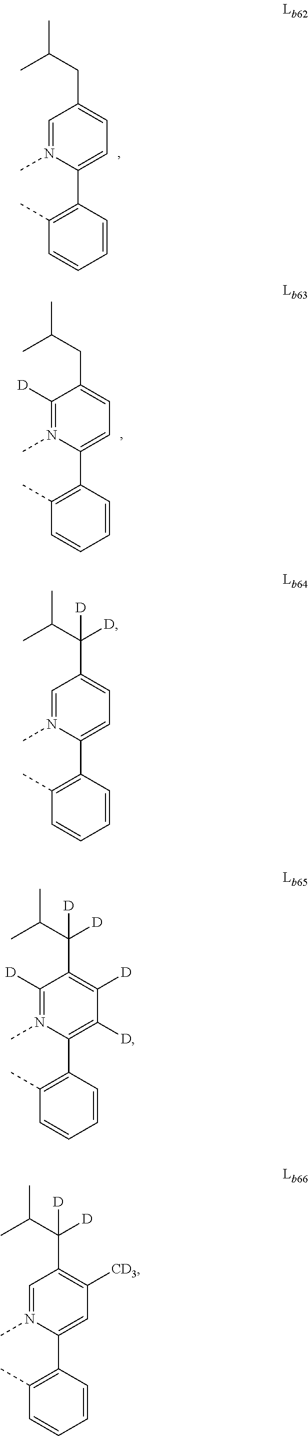 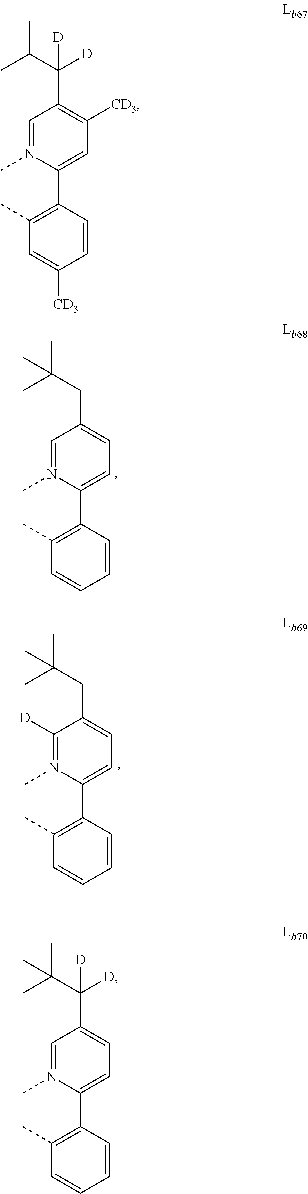 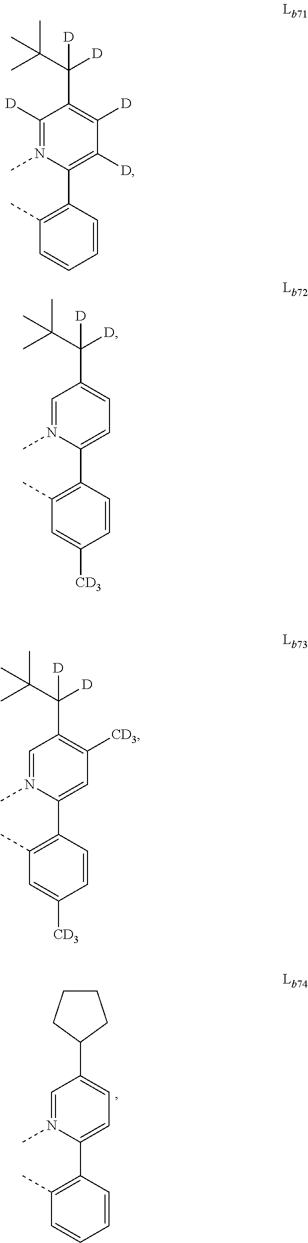 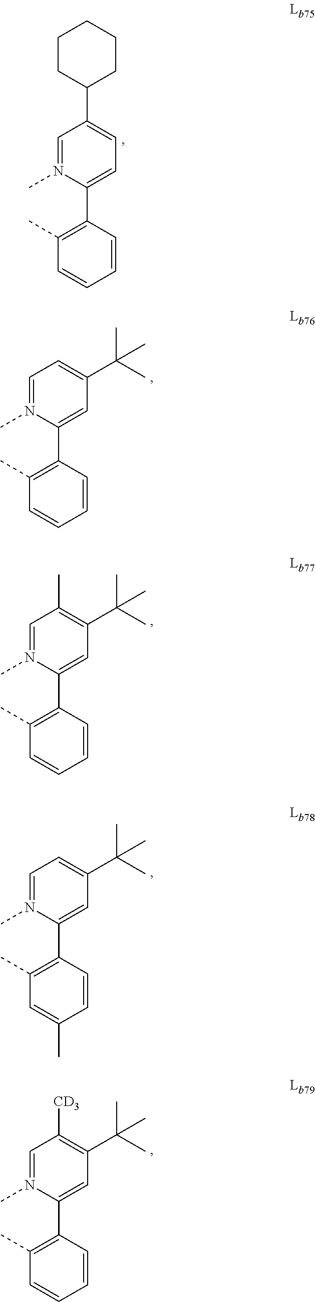 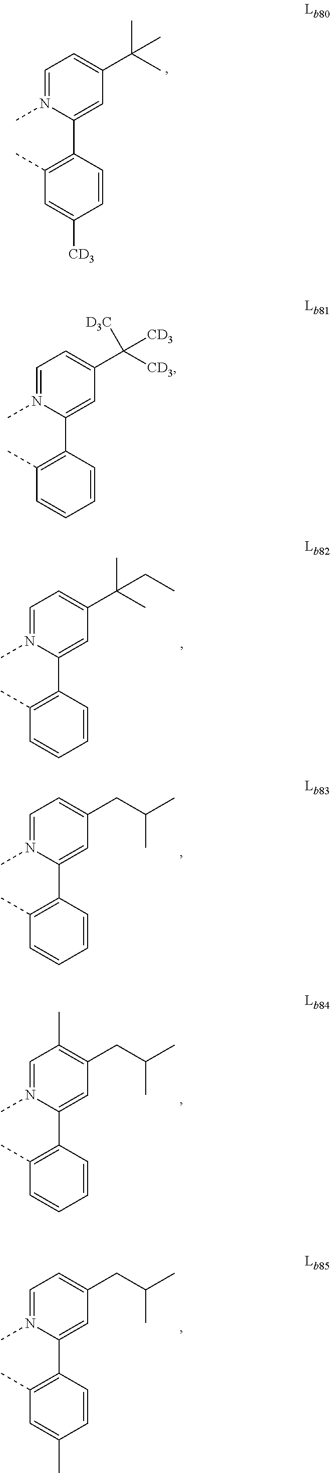 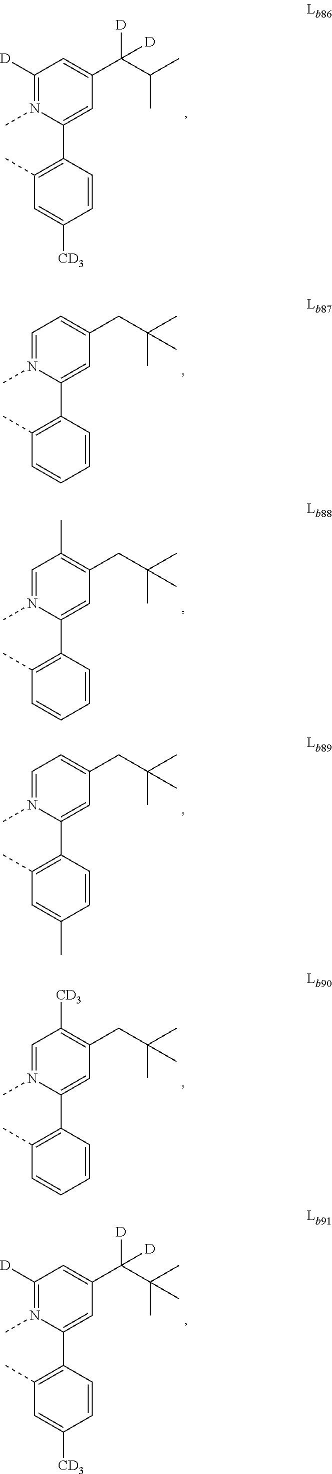 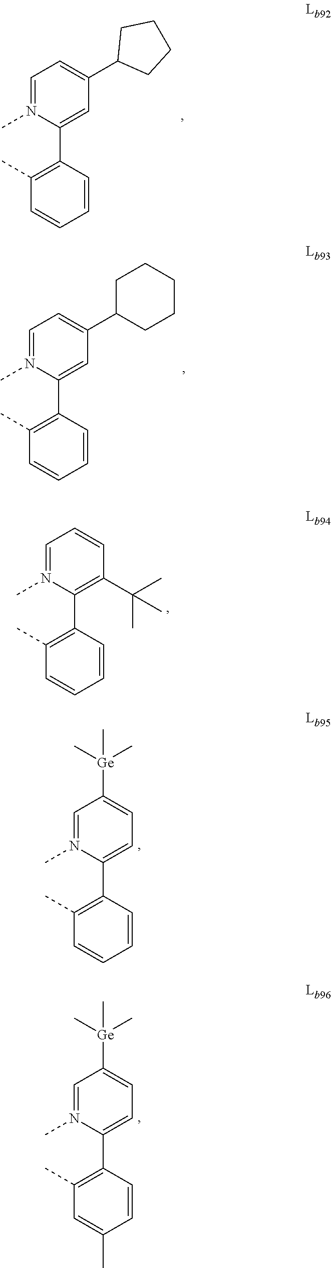 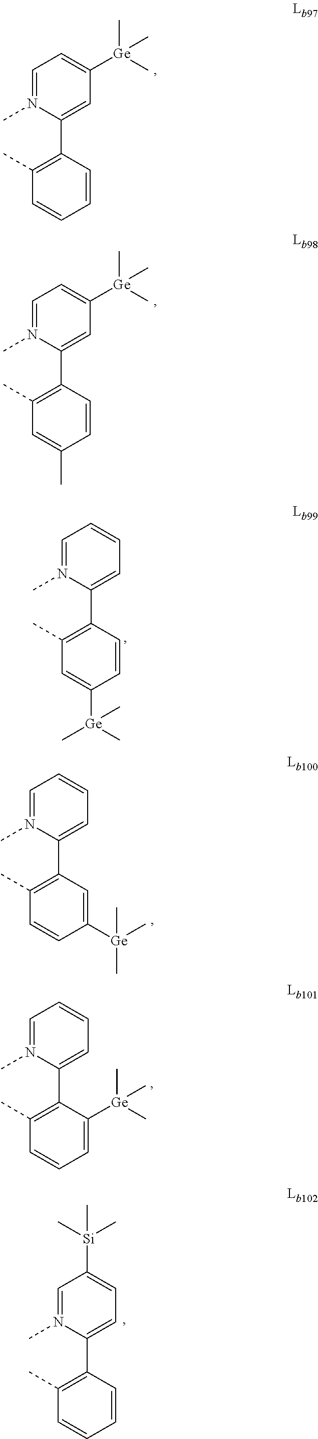 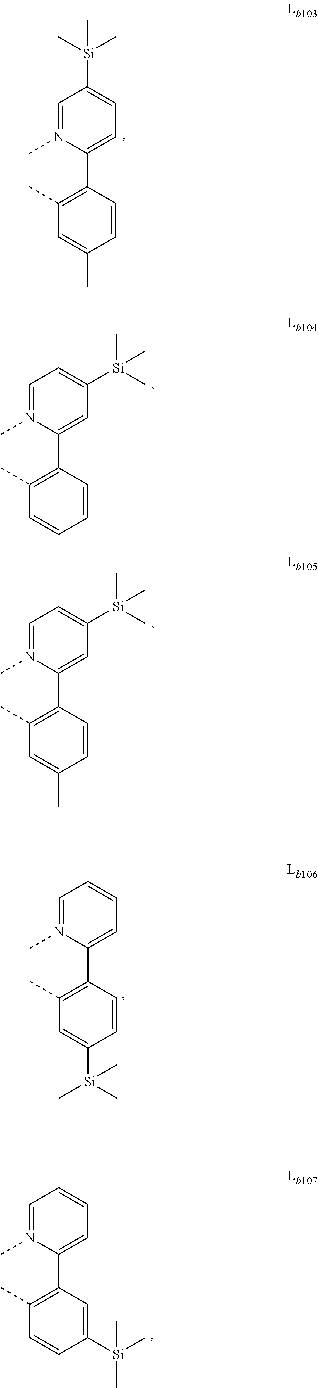 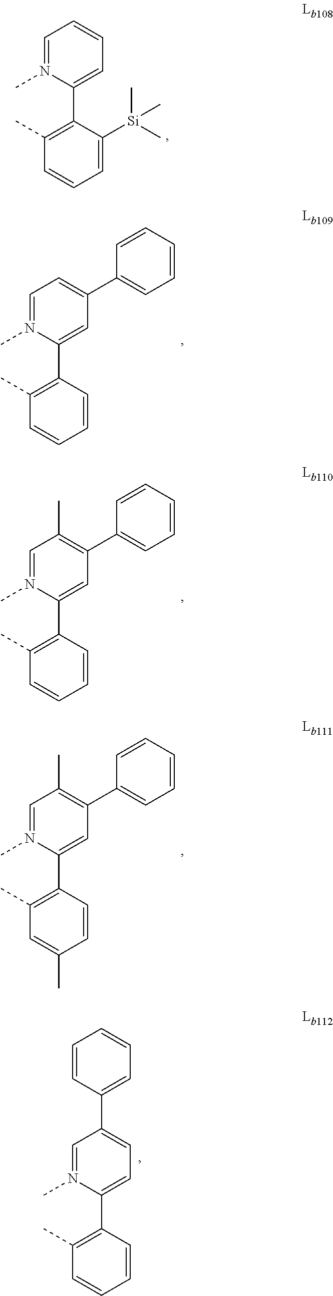 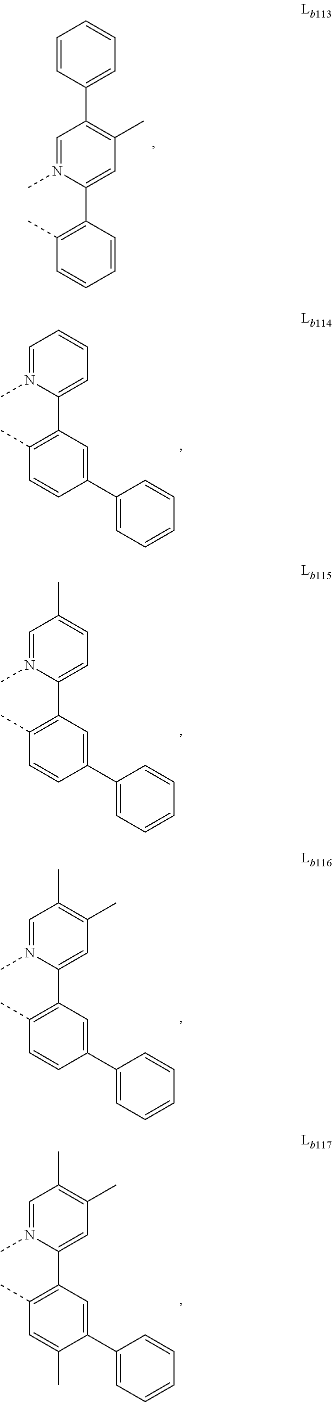 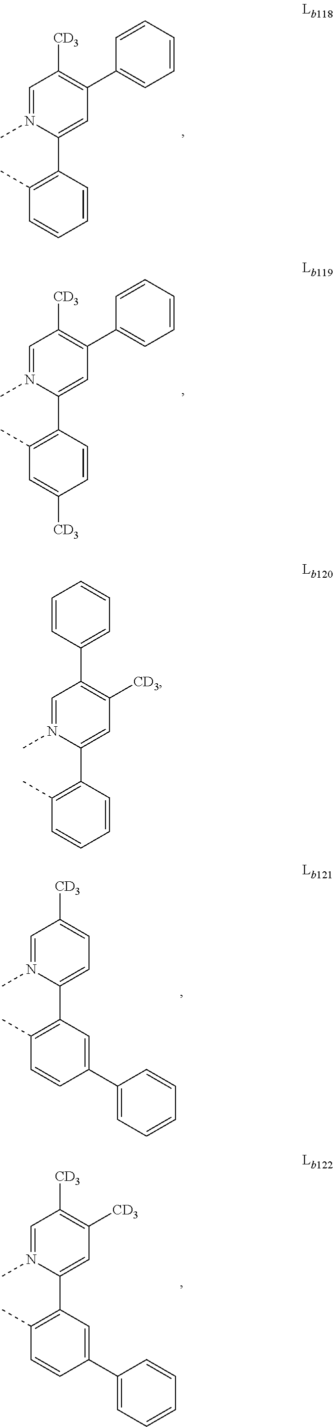 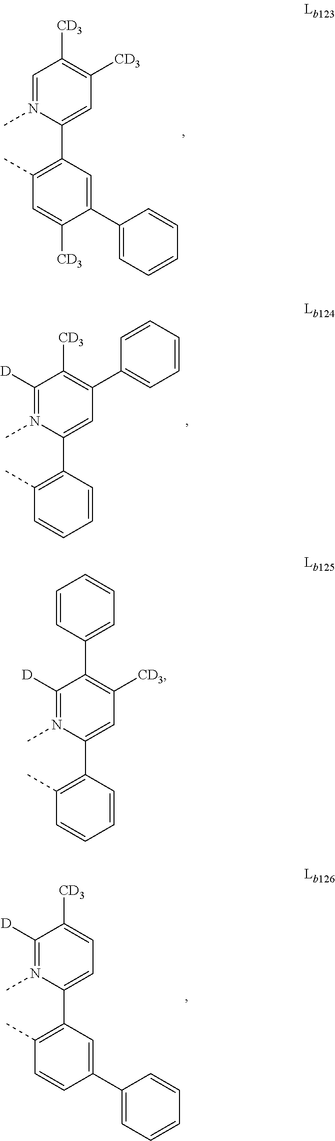 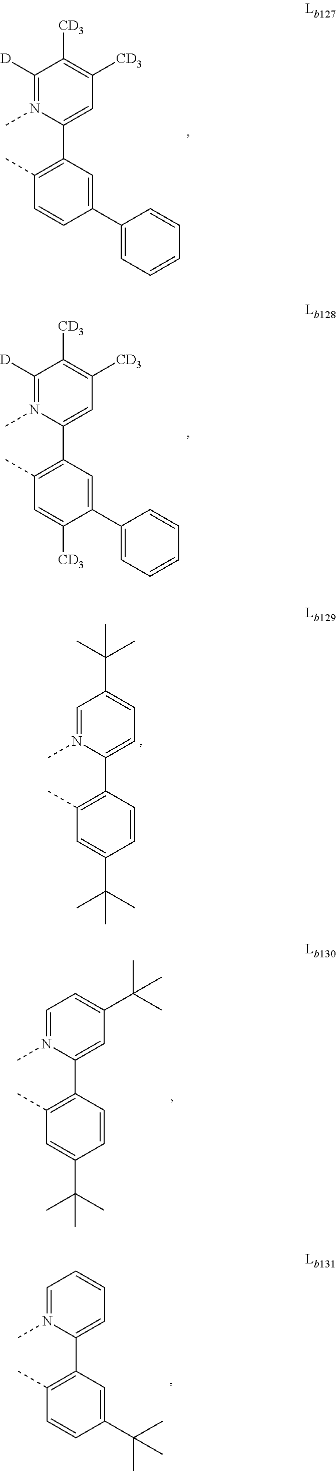 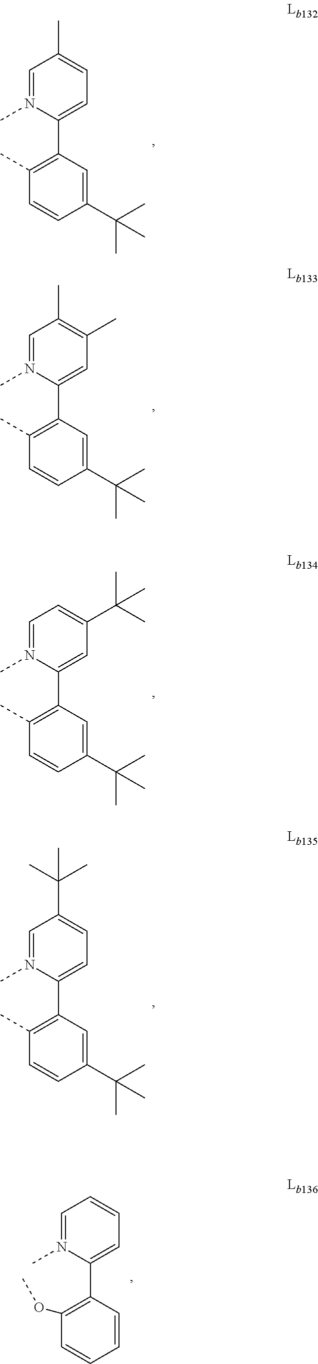 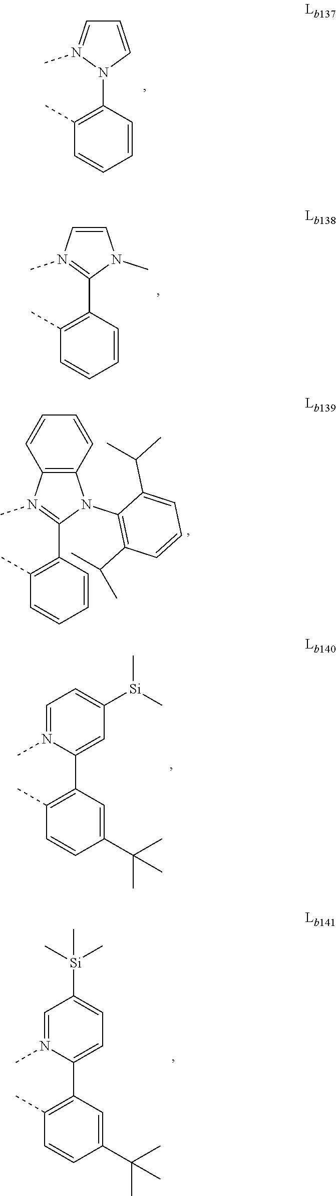 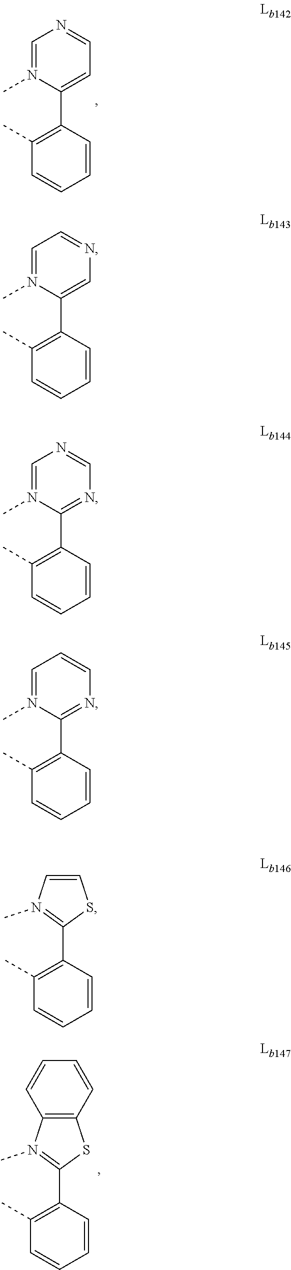 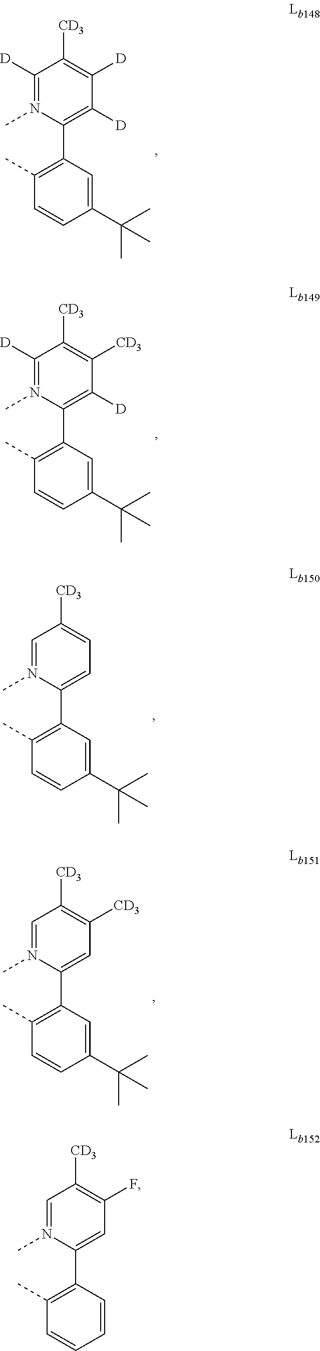 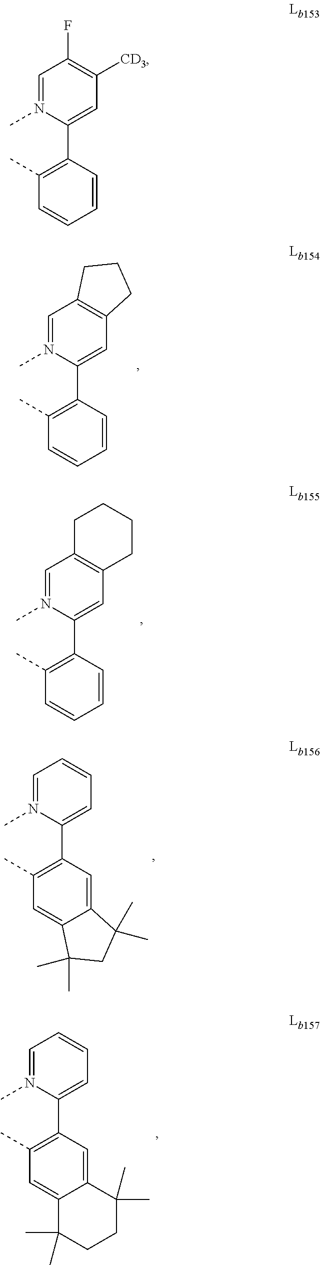 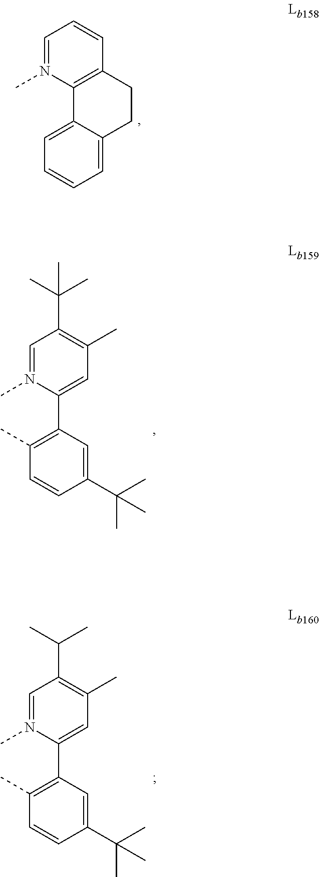
wherein optionally, hydrogens in the above L_{b1} to L_{b18}, L_{b20} to L_{b26}, and L_{b31} to L_{b160} can be partially or fully substituted with deuterium.

23. The metal complex according to claim 22, wherein the metal complex has a structure of Ir(Lₐ)(L_{b})₂, wherein the two L_{b} are identical, Lₐ is selected from the group consisting of Lₐ₁ to Lₐ₁₉₃₁, and L_{b} is selected from the group consisting of L_{b1} to L_{b160};
preferably, the metal complex is selected from the group consisting of Metal Complex 1 to Metal Complex 4074 which are as follows:

| Metal | | | Metal | | | Metal | | |
|---|---|---|---|---|---|---|---|---|
| Com- | | | Com- | | | Com- | | |
| plex | Lₐ | L_{b} | plex | Lₐ | L_{b} | plex | Lₐ | L_{b} |
| 1 | Lₐ₁ | L_{b52} | 2 | Lₐ₂ | L_{b52} | 3 | Lₐ₃ | L_{b52} |
| 4 | Lₐ₄ | L_{b52} | 5 | Lₐ₅ | L_{b52} | 6 | Lₐ₆ | L_{b52} |
| 7 | Lₐ₇ | L_{b52} | 8 | Lₐ₈ | L_{b52} | 9 | Lₐ₉ | L_{b52} |
| 10 | Lₐ₁₀ | L_{b52} | 11 | Lₐ₁₁ | L_{b52} | 12 | Lₐ₁₂ | L_{b52} |
| 13 | Lₐ₁₃ | L_{b52} | 14 | Lₐ₁₄ | L_{b52} | 15 | Lₐ₁₅ | L_{b52} |
| 16 | Lₐ₁₆ | L_{b52} | 17 | Lₐ₁₇ | L_{b52} | 18 | Lₐ₁₈ | L_{b52} |
| 19 | Lₐ₁₉ | L_{b52} | 20 | Lₐ₂₀ | L_{b52} | 21 | Lₐ₂₁ | L_{b52} |
| 22 | Lₐ₂₂ | L_{b52} | 23 | Lₐ₂₃ | L_{b52} | 24 | Lₐ₂₄ | L_{b52} |
| 25 | Lₐ₂₅ | L_{b52} | 26 | Lₐ₂₆ | L_{b52} | 27 | Lₐ₂₇ | L_{b52} |
| 28 | Lₐ₂₈ | L_{b52} | 29 | Lₐ₂₉ | L_{b52} | 30 | Lₐ₃₀ | L_{b52} |
| 31 | Lₐ₃₁ | L_{b52} | 32 | Lₐ₃₂ | L_{b52} | 33 | Lₐ₃₃ | L_{b52} |
| 34 | Lₐ₃₄ | L_{b52} | 35 | Lₐ₃₅ | L_{b52} | 36 | Lₐ₃₆ | L_{b52} |
| 37 | Lₐ₃₇ | L_{b52} | 38 | Lₐ₃₈ | L_{b52} | 39 | Lₐ₃₉ | L_{b52} |
| 40 | Lₐ₄₀ | L_{b52} | 41 | Lₐ₄₁ | L_{b52} | 42 | Lₐ₄₂ | L_{b52} |
| 43 | Lₐ₄₃ | L_{b52} | 44 | Lₐ₄₄ | L_{b52} | 45 | Lₐ₄₅ | L_{b52} |
| 46 | Lₐ₄₆ | L_{b52} | 47 | Lₐ₄₇ | L_{b52} | 48 | Lₐ₄₈ | L_{b52} |
| 49 | Lₐ₄₉ | L_{b52} | 50 | Lₐ₅₀ | L_{b52} | 51 | Lₐ₅₁ | L_{b52} |
| 52 | Lₐ₅₂ | L_{b52} | 53 | Lₐ₅₃ | L_{b52} | 54 | Lₐ₅₄ | L_{b52} |
| 55 | Lₐ₅₅ | L_{b52} | 56 | Lₐ₅₆ | L_{b52} | 57 | Lₐ₅₇ | L_{b52} |
| 58 | Lₐ₅₈ | L_{b52} | 59 | Lₐ₅₉ | L_{b52} | 60 | Lₐ₆₀ | L_{b52} |
| 61 | Lₐ₆₁ | L_{b52} | 62 | Lₐ₆₂ | L_{b52} | 63 | Lₐ₆₃ | L_{b52} |
| 64 | Lₐ₆₄ | L_{b52} | 65 | Lₐ₆₅ | L_{b52} | 66 | Lₐ₆₆ | L_{b52} |
| 67 | Lₐ₆₇ | L_{b52} | 68 | Lₐ₆₈ | L_{b52} | 69 | Lₐ₆₉ | L_{b52} |
| 70 | Lₐ₇₀ | L_{b52} | 71 | Lₐ₇₁ | L_{b52} | 72 | Lₐ₇₂ | L_{b52} |
| 73 | Lₐ₇₃ | L_{b52} | 74 | Lₐ₇₄ | L_{b52} | 75 | Lₐ₇₅ | L_{b52} |
| 76 | Lₐ₇₆ | L_{b52} | 77 | Lₐ₇₇ | L_{b52} | 78 | Lₐ₇₈ | L_{b52} |
| 79 | Lₐ₇₉ | L_{b52} | 80 | Lₐ₈₀ | L_{b52} | 81 | Lₐ₈₁ | L_{b52} |
| 82 | Lₐ₈₂ | L_{b52} | 83 | Lₐ₈₃ | L_{b52} | 84 | Lₐ₈₄ | L_{b52} |
| 85 | Lₐ₈₅ | L_{b52} | 86 | Lₐ₈₆ | L_{b52} | 87 | Lₐ₈₇ | L_{b52} |
| 88 | Lₐ₈₈ | L_{b52} | 89 | Lₐ₈₉ | L_{b52} | 90 | Lₐ₉₀ | L_{b52} |
| 91 | Lₐ₉₁ | L_{b52} | 92 | Lₐ₉₂ | L_{b52} | 93 | Lₐ₉₃ | L_{b52} |
| 94 | Lₐ₉₄ | L_{b52} | 95 | Lₐ₉₅ | L_{b52} | 96 | Lₐ₉₆ | L_{b52} |
| 97 | Lₐ₉₇ | L_{b52} | 98 | Lₐ₉₈ | L_{b52} | 99 | Lₐ₉₉ | L_{b52} |
| 100 | Lₐ₁₀₀ | L_{b52} | 101 | Lₐ₁₀₁ | L_{b52} | 102 | Lₐ₁₀₂ | L_{b52} |
| 103 | Lₐ₁₀₃ | L_{b52} | 104 | Lₐ₁₀₄ | L_{b52} | 105 | Lₐ₁₀₅ | L_{b52} |
| 106 | Lₐ₁₀₆ | L_{b52} | 107 | Lₐ₁₀₇ | L_{b52} | 108 | Lₐ₁₀₈ | L_{b52} |
| 109 | Lₐ₁₀₉ | L_{b52} | 110 | Lₐ₁₁₀ | L_{b52} | 111 | Lₐ₁₁₁ | L_{b52} |
| 112 | Lₐ₁₁₂ | L_{b52} | 113 | Lₐ₁₁₃ | L_{b52} | 114 | Lₐ₁₁₄ | L_{b52} |
| 115 | Lₐ₁₁₅ | L_{b52} | 116 | Lₐ₁₁₆ | L_{b52} | 117 | Lₐ₁₁₇ | L_{b52} |
| 118 | Lₐ₁₁₈ | L_{b52} | 119 | Lₐ₁₁₉ | L_{b52} | 120 | Lₐ₁₂₀ | L_{b52} |
| 121 | Lₐ₁₂₁ | L_{b52} | 122 | Lₐ₁₂₂ | L_{b52} | 123 | Lₐ₁₂₃ | L_{b52} |
| 124 | Lₐ₁₂₄ | L_{b52} | 125 | Lₐ₁₂₅ | L_{b52} | 126 | Lₐ₁₂₆ | L_{b52} |
| 127 | Lₐ₁₂₇ | L_{b52} | 128 | Lₐ₁₂₈ | L_{b52} | 129 | Lₐ₁₂₉ | L_{b52} |
| 130 | Lₐ₁₃₀ | L_{b52} | 131 | Lₐ₁₃₁ | L_{b52} | 132 | Lₐ₁₃₂ | L_{b52} |
| 133 | Lₐ₁₃₃ | L_{b52} | 134 | Lₐ₁₃₄ | L_{b52} | 135 | Lₐ₁₃₅ | L_{b52} |
| 136 | Lₐ₁₃₆ | L_{b52} | 137 | Lₐ₁₃₇ | L_{b52} | 138 | Lₐ₁₃₈ | L_{b52} |
| 139 | Lₐ₁₃₉ | L_{b52} | 140 | Lₐ₁₄₀ | L_{b52} | 141 | Lₐ₁₄₁ | L_{b52} |
| 142 | Lₐ₁₄₂ | L_{b52} | 143 | Lₐ₁₄₃ | L_{b52} | 144 | Lₐ₁₄₄ | L_{b52} |
| 145 | Lₐ₁₄₅ | L_{b52} | 146 | Lₐ₁₄₆ | L_{b52} | 147 | Lₐ₁₄₇ | L_{b52} |
| 148 | Lₐ₁₄₈ | L_{b52} | 149 | Lₐ₁₄₉ | L_{b52} | 150 | Lₐ₁₅₀ | L_{b52} |
| 151 | Lₐ₁₅₁ | L_{b52} | 152 | Lₐ₁₅₂ | L_{b52} | 153 | Lₐ₁₅₃ | L_{b52} |
| 154 | Lₐ₁₅₄ | L_{b52} | 155 | Lₐ₁₅₅ | L_{b52} | 156 | Lₐ₁₅₆ | L_{b52} |
| 157 | Lₐ₁₅₇ | L_{b52} | 158 | Lₐ₁₅₈ | L_{b52} | 159 | Lₐ₁₅₉ | L_{b52} |
| 160 | Lₐ₁₆₀ | L_{b52} | 161 | Lₐ₁₆₁ | L_{b52} | 162 | Lₐ₁₆₂ | L_{b52} |
| 163 | Lₐ₁₆₃ | L_{b52} | 164 | Lₐ₁₆₄ | L_{b52} | 165 | Lₐ₁₆₅ | L_{b52} |
| 166 | Lₐ₁₆₆ | L_{b52} | 167 | Lₐ₁₆₇ | L_{b52} | 168 | Lₐ₁₆₈ | L_{b52} |
| 169 | Lₐ₁₆₉ | L_{b52} | 170 | Lₐ₁₇₀ | L_{b52} | 171 | Lₐ₁₇₁ | L_{b52} |
| 172 | Lₐ₁₇₂ | L_{b52} | 173 | Lₐ₁₇₃ | L_{b52} | 174 | Lₐ₁₇₄ | L_{b52} |
| 175 | Lₐ₁₇₅ | L_{b52} | 176 | Lₐ₁₇₆ | L_{b52} | 177 | Lₐ₁₇₇ | L_{b52} |
| 178 | Lₐ₁₇₈ | L_{b52} | 179 | Lₐ₁₇₉ | L_{b52} | 180 | Lₐ₁₈₀ | L_{b52} |
| 181 | Lₐ₁₈₁ | L_{b52} | 182 | Lₐ₁₈₂ | L_{b52} | 183 | Lₐ₁₈₃ | L_{b52} |
| 184 | Lₐ₁₈₄ | L_{b52} | 185 | Lₐ₁₈₅ | L_{b52} | 186 | Lₐ₁₈₆ | L_{b52} |
| 187 | Lₐ₁₈₇ | L_{b52} | 188 | Lₐ₁₈₈ | L_{b52} | 189 | Lₐ₁₈₉ | L_{b52} |
| 190 | Lₐ₁₉₀ | L_{b52} | 191 | Lₐ₁₉₁ | L_{b52} | 192 | Lₐ₁₉₂ | L_{b52} |
| 193 | Lₐ₁₉₃ | L_{b52} | 194 | Lₐ₁₉₄ | L_{b52} | 195 | Lₐ₁₉₅ | L_{b52} |
| 196 | Lₐ₁₉₆ | L_{b52} | 197 | Lₐ₁₉₇ | L_{b52} | 198 | Lₐ₁₉₈ | L_{b52} |
| 199 | Lₐ₁₉₉ | L_{b52} | 200 | Lₐ₂₀₀ | L_{b52} | 201 | Lₐ₂₀₁ | L_{b52} |
| 202 | Lₐ₂₀₂ | L_{b52} | 203 | Lₐ₂₀₃ | L_{b52} | 204 | Lₐ₂₀₄ | L_{b52} |
| 205 | Lₐ₂₀₅ | L_{b52} | 206 | Lₐ₂₀₆ | L_{b52} | 207 | Lₐ₂₀₇ | L_{b52} |
| 208 | Lₐ₂₀₈ | L_{b52} | 209 | Lₐ₂₀₉ | L_{b52} | 210 | Lₐ₂₁₀ | L_{b52} |
| 211 | Lₐ₂₁₁ | L_{b52} | 212 | Lₐ₂₁₂ | L_{b52} | 213 | Lₐ₂₁₃ | L_{b52} |
| 214 | Lₐ₂₁₄ | L_{b52} | 215 | Lₐ₂₁₅ | L_{b52} | 216 | Lₐ₂₁₆ | L_{b52} |
| 217 | Lₐ₂₁₇ | L_{b52} | 218 | Lₐ₂₁₈ | L_{b52} | 219 | Lₐ₂₁₉ | L_{b52} |
| 220 | Lₐ₂₂₀ | L_{b52} | 221 | Lₐ₂₂₁ | L_{b52} | 222 | Lₐ₂₂₂ | L_{b52} |
| 223 | Lₐ₂₂₃ | L_{b52} | 224 | Lₐ₂₂₄ | L_{b52} | 225 | Lₐ₂₂₅ | L_{b52} |
| 226 | Lₐ₂₂₆ | L_{b52} | 227 | Lₐ₂₂₇ | L_{b52} | 228 | Lₐ₂₂₈ | L_{b52} |
| 229 | Lₐ₂₂₉ | L_{b52} | 230 | Lₐ₂₃₀ | L_{b52} | 231 | Lₐ₂₃₁ | L_{b52} |
| 232 | Lₐ₂₃₂ | L_{b52} | 233 | Lₐ₂₃₃ | L_{b52} | 234 | Lₐ₂₃₄ | L_{b52} |
| 235 | Lₐ₂₃₅ | L_{b52} | 236 | Lₐ₂₃₆ | L_{b52} | 237 | Lₐ₂₃₇ | L_{b52} |
| 238 | Lₐ₂₃₈ | L_{b52} | 239 | Lₐ₂₃₉ | L_{b52} | 240 | Lₐ₂₄₀ | L_{b52} |
| 241 | Lₐ₂₄₁ | L_{b52} | 242 | Lₐ₂₄₂ | L_{b52} | 243 | Lₐ₂₄₃ | L_{b52} |
| 244 | Lₐ₂₄₄ | L_{b52} | 245 | Lₐ₂₄₅ | L_{b52} | 246 | Lₐ₂₄₆ | L_{b52} |
| 247 | Lₐ₂₄₇ | L_{b52} | 248 | Lₐ₂₄₈ | L_{b52} | 249 | Lₐ₂₄₉ | L_{b52} |
| 250 | Lₐ₂₅₀ | L_{b52} | 251 | Lₐ₂₅₁ | L_{b52} | 252 | Lₐ₂₅₂ | L_{b52} |
| 253 | Lₐ₂₅₃ | L_{b52} | 254 | Lₐ₂₅₄ | L_{b52} | 255 | Lₐ₂₅₅ | L_{b52} |
| 256 | Lₐ₂₅₆ | L_{b52} | 257 | Lₐ₂₅₇ | L_{b52} | 258 | Lₐ₂₅₈ | L_{b52} |
| 259 | Lₐ₂₅₉ | L_{b52} | 260 | Lₐ₂₆₀ | L_{b52} | 261 | Lₐ₂₆₁ | L_{b52} |
| 262 | Lₐ₂₆₂ | L_{b52} | 263 | Lₐ₂₆₃ | L_{b52} | 264 | Lₐ₂₆₄ | L_{b52} |
| 265 | Lₐ₂₆₅ | L_{b52} | 266 | Lₐ₂₆₆ | L_{b52} | 267 | Lₐ₂₆₇ | L_{b52} |
| 268 | Lₐ₂₆₈ | L_{b52} | 269 | Lₐ₂₆₉ | L_{b52} | 270 | Lₐ₂₇₀ | L_{b52} |
| 271 | Lₐ₂₇₁ | L_{b52} | 272 | Lₐ₂₇₂ | L_{b52} | 273 | Lₐ₂₇₃ | L_{b52} |
| 274 | Lₐ₂₇₄ | L_{b52} | 275 | Lₐ₂₇₅ | L_{b52} | 276 | Lₐ₂₇₆ | L_{b52} |
| 277 | Lₐ₂₇₇ | L_{b52} | 278 | Lₐ₂₇₈ | L_{b52} | 279 | Lₐ₂₇₉ | L_{b52} |
| 280 | Lₐ₂₈₀ | L_{b52} | 281 | Lₐ₂₈₁ | L_{b52} | 282 | Lₐ₂₈₂ | L_{b52} |
| 283 | Lₐ₂₈₃ | L_{b52} | 284 | Lₐ₂₈₄ | L_{b52} | 285 | Lₐ₂₈₅ | L_{b52} |
| 286 | Lₐ₂₈₆ | L_{b52} | 287 | Lₐ₂₈₇ | L_{b52} | 288 | Lₐ₂₈₈ | L_{b52} |
| 289 | Lₐ₂₈₉ | L_{b52} | 290 | Lₐ₂₉₀ | L_{b52} | 291 | Lₐ₂₉₁ | L_{b52} |
| 292 | Lₐ₂₉₂ | L_{b52} | 293 | Lₐ₂₉₃ | L_{b52} | 294 | Lₐ₂₉₄ | L_{b52} |
| 295 | Lₐ₂₉₅ | L_{b52} | 296 | Lₐ₂₉₆ | L_{b52} | 297 | Lₐ₂₉₇ | L_{b52} |
| 298 | Lₐ₂₉₈ | L_{b52} | 299 | Lₐ₂₉₉ | L_{b52} | 300 | Lₐ₃₀₀ | L_{b52} |
| 301 | Lₐ₃₀₁ | L_{b52} | 302 | Lₐ₃₀₂ | L_{b52} | 303 | Lₐ₃₀₃ | L_{b52} |
| 304 | Lₐ₃₀₄ | L_{b52} | 305 | Lₐ₃₀₅ | L_{b52} | 306 | Lₐ₃₀₆ | L_{b52} |
| 307 | Lₐ₃₀₇ | L_{b52} | 308 | Lₐ₃₀₈ | L_{b52} | 309 | Lₐ₃₀₉ | L_{b52} |
| 310 | Lₐ₃₁₀ | L_{b52} | 311 | Lₐ₃₁₁ | L_{b52} | 312 | Lₐ₃₁₂ | L_{b52} |
| 313 | Lₐ₃₁₃ | L_{b52} | 314 | Lₐ₃₁₄ | L_{b52} | 315 | Lₐ₃₁₅ | L_{b52} |
| 316 | Lₐ₃₁₆ | L_{b52} | 317 | Lₐ₃₁₇ | L_{b52} | 318 | Lₐ₃₁₈ | L_{b52} |
| 319 | Lₐ₃₁₉ | L_{b52} | 320 | Lₐ₃₂₀ | L_{b52} | 321 | Lₐ₃₂₁ | L_{b52} |
| 322 | Lₐ₃₂₂ | L_{b52} | 323 | Lₐ₃₂₃ | L_{b52} | 324 | Lₐ₃₂₄ | L_{b52} |
| 325 | Lₐ₃₂₅ | L_{b52} | 326 | Lₐ₃₂₆ | L_{b52} | 327 | Lₐ₃₂₇ | L_{b52} |
| 328 | Lₐ₃₂₈ | L_{b52} | 329 | Lₐ₃₂₉ | L_{b52} | 330 | Lₐ₃₃₀ | L_{b52} |
| 331 | Lₐ₃₃₁ | L_{b52} | 332 | Lₐ₃₃₂ | L_{b52} | 333 | Lₐ₃₃₃ | L_{b52} |
| 334 | Lₐ₃₃₄ | L_{b52} | 335 | Lₐ₃₃₅ | L_{b52} | 336 | Lₐ₃₃₆ | L_{b52} |
| 337 | Lₐ₃₃₇ | L_{b52} | 338 | Lₐ₃₃₈ | L_{b52} | 339 | Lₐ₃₃₉ | L_{b52} |
| 340 | Lₐ₃₄₀ | L_{b52} | 341 | Lₐ₃₄₁ | L_{b52} | 342 | Lₐ₃₄₂ | L_{b52} |
| 343 | Lₐ₃₄₃ | L_{b52} | 344 | Lₐ₃₄₄ | L_{b52} | 345 | Lₐ₃₄₅ | L_{b52} |
| 346 | Lₐ₃₄₆ | L_{b52} | 347 | Lₐ₃₄₇ | L_{b52} | 348 | Lₐ₃₄₈ | L_{b52} |
| 349 | Lₐ₃₄₉ | L_{b52} | 350 | Lₐ₃₅₀ | L_{b52} | 351 | Lₐ₃₅₁ | L_{b52} |
| 352 | Lₐ₃₅₂ | L_{b52} | 353 | Lₐ₃₅₃ | L_{b52} | 354 | Lₐ₃₅₄ | L_{b52} |
| 355 | Lₐ₃₅₅ | L_{b52} | 356 | Lₐ₃₅₆ | L_{b52} | 357 | Lₐ₃₅₇ | L_{b52} |
| 358 | Lₐ₃₅₈ | L_{b52} | 359 | Lₐ₃₅₉ | L_{b52} | 360 | Lₐ₃₆₀ | L_{b52} |
| 361 | Lₐ₃₆₁ | L_{b52} | 362 | Lₐ₃₆₂ | L_{b52} | 363 | Lₐ₃₆₃ | L_{b52} |
| 364 | Lₐ₃₆₄ | L_{b52} | 365 | Lₐ₃₆₅ | L_{b52} | 366 | Lₐ₃₆₆ | L_{b52} |
| 367 | Lₐ₃₆₇ | L_{b52} | 368 | Lₐ₃₆₈ | L_{b52} | 369 | Lₐ₃₆₉ | L_{b52} |
| 370 | Lₐ₃₇₀ | L_{b52} | 371 | Lₐ₃₇₁ | L_{b52} | 372 | Lₐ₃₇₂ | L_{b52} |
| 373 | Lₐ₃₇₃ | L_{b52} | 374 | Lₐ₃₇₄ | L_{b52} | 375 | Lₐ₃₇₅ | L_{b52} |
| 376 | Lₐ₃₇₆ | L_{b52} | 377 | Lₐ₃₇₇ | L_{b52} | 378 | Lₐ₃₇₈ | L_{b52} |
| 379 | Lₐ₃₇₉ | L_{b52} | 380 | Lₐ₃₈₀ | L_{b52} | 381 | Lₐ₃₈₁ | L_{b52} |
| 382 | Lₐ₃₈₂ | L_{b52} | 383 | Lₐ₃₈₃ | L_{b52} | 384 | Lₐ₃₈₄ | L_{b52} |
| 385 | Lₐ₃₈₅ | L_{b52} | 386 | Lₐ₃₈₆ | L_{b52} | 387 | Lₐ₃₈₇ | L_{b52} |
| 388 | Lₐ₃₈₈ | L_{b52} | 389 | Lₐ₃₈₉ | L_{b52} | 390 | Lₐ₃₉₀ | L_{b52} |
| 391 | Lₐ₃₉₁ | L_{b52} | 392 | Lₐ₃₉₂ | L_{b52} | 393 | Lₐ₃₉₃ | L_{b52} |
| 394 | Lₐ₃₉₄ | L_{b52} | 395 | Lₐ₃₉₅ | L_{b52} | 396 | Lₐ₃₉₆ | L_{b52} |
| 397 | Lₐ₃₉₇ | L_{b52} | 398 | Lₐ₃₉₈ | L_{b52} | 399 | Lₐ₃₉₉ | L_{b52} |
| 400 | Lₐ₄₀₀ | L_{b52} | 401 | Lₐ₄₀₁ | L_{b52} | 402 | Lₐ₄₀₂ | L_{b52} |
| 403 | Lₐ₄₀₃ | L_{b52} | 404 | Lₐ₄₀₄ | L_{b52} | 405 | Lₐ₄₀₅ | L_{b52} |
| 406 | Lₐ₄₀₆ | L_{b52} | 407 | Lₐ₄₀₇ | L_{b52} | 408 | Lₐ₄₀₈ | L_{b52} |
| 409 | Lₐ₄₀₉ | L_{b52} | 410 | Lₐ₄₁₀ | L_{b52} | 411 | Lₐ₄₁₁ | L_{b52} |
| 412 | Lₐ₄₁₂ | L_{b52} | 413 | Lₐ₄₁₃ | L_{b52} | 414 | Lₐ₄₁₄ | L_{b52} |
| 415 | Lₐ₄₁₅ | L_{b52} | 416 | Lₐ₄₁₆ | L_{b52} | 417 | Lₐ₄₁₇ | L_{b52} |
| 418 | Lₐ₄₁₈ | L_{b52} | 419 | Lₐ₄₁₉ | L_{b52} | 420 | Lₐ₄₂₀ | L_{b52} |
| 421 | Lₐ₄₂₁ | L_{b52} | 422 | Lₐ₄₂₂ | L_{b52} | 423 | Lₐ₄₂₃ | L_{b52} |
| 424 | Lₐ₄₂₄ | L_{b52} | 425 | Lₐ₄₂₅ | L_{b52} | 426 | Lₐ₄₂₆ | L_{b52} |
| 427 | Lₐ₄₂₇ | L_{b52} | 428 | Lₐ₄₂₈ | L_{b52} | 429 | Lₐ₄₂₉ | L_{b52} |
| 430 | Lₐ₄₃₀ | L_{b52} | 431 | Lₐ₄₃₁ | L_{b52} | 432 | Lₐ₄₃₂ | L_{b52} |
| 433 | Lₐ₄₃₃ | L_{b52} | 434 | Lₐ₄₃₄ | L_{b52} | 435 | Lₐ₄₃₅ | L_{b52} |
| 436 | Lₐ₄₃₆ | L_{b52} | 437 | Lₐ₄₃₇ | L_{b52} | 438 | Lₐ₄₃₈ | L_{b52} |
| 439 | Lₐ₄₃₉ | L_{b52} | 440 | Lₐ₄₄₀ | L_{b52} | 441 | Lₐ₄₄₁ | L_{b52} |
| 442 | Lₐ₄₄₂ | L_{b52} | 443 | Lₐ₄₄₃ | L_{b52} | 444 | Lₐ₄₄₄ | L_{b52} |
| 445 | Lₐ₄₄₅ | L_{b52} | 446 | Lₐ₄₄₆ | L_{b52} | 447 | Lₐ₄₄₇ | L_{b52} |
| 448 | Lₐ₄₄₈ | L_{b52} | 449 | Lₐ₄₄₉ | L_{b52} | 450 | Lₐ₄₅₀ | L_{b52} |
| 451 | Lₐ₄₅₁ | L_{b52} | 452 | Lₐ₄₅₂ | L_{b52} | 453 | Lₐ₄₅₃ | L_{b52} |
| 454 | Lₐ₄₅₄ | L_{b52} | 455 | Lₐ₄₅₅ | L_{b52} | 456 | Lₐ₄₅₆ | L_{b52} |
| 457 | Lₐ₄₅₇ | L_{b52} | 458 | Lₐ₄₅₈ | L_{b52} | 459 | Lₐ₄₅₉ | L_{b52} |
| 460 | Lₐ₄₆₀ | L_{b52} | 461 | Lₐ₄₆₁ | L_{b52} | 462 | Lₐ₄₆₂ | L_{b52} |
| 463 | Lₐ₄₆₃ | L_{b52} | 464 | Lₐ₄₆₄ | L_{b52} | 465 | Lₐ₄₆₅ | L_{b52} |
| 466 | Lₐ₄₆₆ | L_{b52} | 467 | Lₐ₄₆₇ | L_{b52} | 468 | Lₐ₄₆₈ | L_{b52} |
| 469 | Lₐ₄₆₉ | L_{b52} | 470 | Lₐ₄₇₀ | L_{b52} | 471 | Lₐ₄₇₁ | L_{b52} |
| 472 | Lₐ₄₇₂ | L_{b52} | 473 | Lₐ₄₇₃ | L_{b52} | 474 | Lₐ₄₇₄ | L_{b52} |
| 475 | Lₐ₄₇₅ | L_{b52} | 476 | Lₐ₄₇₆ | L_{b52} | 477 | Lₐ₄₇₇ | L_{b52} |
| 478 | Lₐ₄₇₈ | L_{b52} | 479 | Lₐ₄₇₉ | L_{b52} | 480 | Lₐ₄₈₀ | L_{b52} |
| 481 | Lₐ₄₈₁ | L_{b52} | 482 | Lₐ₄₈₂ | L_{b52} | 483 | Lₐ₄₈₃ | L_{b52} |
| 484 | Lₐ₄₈₄ | L_{b52} | 485 | Lₐ₄₈₅ | L_{b52} | 486 | Lₐ₄₈₆ | L_{b52} |
| 487 | Lₐ₄₈₇ | L_{b52} | 488 | Lₐ₄₈₈ | L_{b52} | 489 | Lₐ₄₈₉ | L_{b52} |
| 490 | Lₐ₄₉₀ | L_{b52} | 491 | Lₐ₄₉₁ | L_{b52} | 492 | Lₐ₄₉₂ | L_{b52} |
| 493 | Lₐ₄₉₃ | L_{b52} | 494 | Lₐ₄₉₄ | L_{b52} | 495 | Lₐ₄₉₅ | L_{b52} |
| 496 | Lₐ₄₉₆ | L_{b52} | 497 | Lₐ₄₉₇ | L_{b52} | 498 | Lₐ₄₉₈ | L_{b52} |
| 499 | Lₐ₄₉₉ | L_{b52} | 500 | Lₐ₅₀₀ | L_{b52} | 501 | Lₐ₅₀₁ | L_{b52} |
| 502 | Lₐ₅₀₂ | L_{b52} | 503 | Lₐ₅₀₃ | L_{b52} | 504 | Lₐ₅₀₄ | L_{b52} |
| 505 | Lₐ₅₀₅ | L_{b52} | 506 | Lₐ₅₀₆ | L_{b52} | 507 | Lₐ₅₀₇ | L_{b52} |
| 508 | Lₐ₅₀₈ | L_{b52} | 509 | Lₐ₅₀₉ | L_{b52} | 510 | Lₐ₅₁₀ | L_{b52} |
| 511 | Lₐ₅₁₁ | L_{b52} | 512 | Lₐ₅₁₂ | L_{b52} | 513 | Lₐ₅₁₃ | L_{b52} |
| 514 | Lₐ₅₁₄ | L_{b52} | 515 | Lₐ₅₁₅ | L_{b52} | 516 | Lₐ₅₁₆ | L_{b52} |
| 517 | Lₐ₅₁₇ | L_{b52} | 518 | Lₐ₅₁₈ | L_{b52} | 519 | Lₐ₅₁₉ | L_{b52} |
| 520 | Lₐ₅₂₀ | L_{b52} | 521 | Lₐ₅₂₁ | L_{b52} | 522 | Lₐ₅₂₂ | L_{b52} |
| 523 | Lₐ₅₂₃ | L_{b52} | 524 | Lₐ₅₂₄ | L_{b52} | 525 | Lₐ₅₂₅ | L_{b52} |
| 526 | Lₐ₅₂₆ | L_{b52} | 527 | Lₐ₅₂₇ | L_{b52} | 528 | Lₐ₅₂₈ | L_{b52} |
| 529 | Lₐ₅₂₉ | L_{b52} | 530 | Lₐ₅₃₀ | L_{b52} | 531 | Lₐ₅₃₁ | L_{b52} |
| 532 | Lₐ₅₃₂ | L_{b52} | 533 | Lₐ₅₃₃ | L_{b52} | 534 | Lₐ₅₃₄ | L_{b52} |
| 535 | Lₐ₅₃₅ | L_{b52} | 536 | Lₐ₅₃₆ | L_{b52} | 537 | Lₐ₅₃₇ | L_{b52} |
| 538 | Lₐ₅₃₈ | L_{b52} | 539 | Lₐ₅₃₉ | L_{b52} | 540 | Lₐ₅₄₀ | L_{b52} |
| 541 | Lₐ₅₄₁ | L_{b52} | 542 | Lₐ₅₄₂ | L_{b52} | 543 | Lₐ₅₄₃ | L_{b52} |
| 544 | Lₐ₅₄₄ | L_{b52} | 545 | Lₐ₅₄₅ | L_{b52} | 546 | Lₐ₅₄₆ | L_{b52} |
| 547 | Lₐ₅₄₇ | L_{b52} | 548 | Lₐ₅₄₈ | L_{b52} | 549 | Lₐ₅₄₉ | L_{b52} |
| 550 | Lₐ₅₅₀ | L_{b52} | 551 | Lₐ₅₅₁ | L_{b52} | 552 | Lₐ₅₅₂ | L_{b52} |
| 553 | Lₐ₅₅₃ | L_{b52} | 554 | Lₐ₅₅₄ | L_{b52} | 555 | Lₐ₅₅₅ | L_{b52} |
| 556 | Lₐ₅₅₆ | L_{b52} | 557 | Lₐ₅₅₇ | L_{b52} | 558 | Lₐ₅₅₈ | L_{b52} |
| 559 | Lₐ₅₅₉ | L_{b52} | 560 | Lₐ₅₆₀ | L_{b52} | 561 | Lₐ₅₆₁ | L_{b52} |
| 562 | Lₐ₅₆₂ | L_{b52} | 563 | Lₐ₅₆₃ | L_{b52} | 564 | Lₐ₅₆₄ | L_{b52} |
| 565 | Lₐ₅₆₅ | L_{b52} | 566 | Lₐ₅₆₆ | L_{b52} | 567 | Lₐ₅₆₇ | L_{b52} |
| 568 | Lₐ₅₆₈ | L_{b52} | 569 | Lₐ₅₆₉ | L_{b52} | 570 | Lₐ₅₇₀ | L_{b52} |
| 571 | Lₐ₅₇₁ | L_{b52} | 572 | Lₐ₅₇₂ | L_{b52} | 573 | Lₐ₅₇₃ | L_{b52} |
| 574 | Lₐ₅₇₄ | L_{b52} | 575 | Lₐ₅₇₅ | L_{b52} | 576 | Lₐ₅₇₆ | L_{b52} |
| 577 | Lₐ₅₇₇ | L_{b52} | 578 | Lₐ₅₇₈ | L_{b52} | 579 | Lₐ₅₇₉ | L_{b52} |
| 580 | Lₐ₅₈₀ | L_{b52} | 581 | Lₐ₅₈₁ | L_{b52} | 582 | Lₐ₅₈₂ | L_{b52} |
| 583 | Lₐ₅₈₃ | L_{b52} | 584 | Lₐ₅₈₄ | L_{b52} | 585 | Lₐ₅₈₅ | L_{b52} |
| 586 | Lₐ₅₈₆ | L_{b52} | 587 | Lₐ₅₈₇ | L_{b52} | 588 | Lₐ₅₈₈ | L_{b52} |
| 589 | Lₐ₅₈₉ | L_{b52} | 590 | Lₐ₅₉₀ | L_{b52} | 591 | Lₐ₅₉₁ | L_{b52} |
| 592 | Lₐ₅₉₂ | L_{b52} | 593 | Lₐ₅₉₃ | L_{b52} | 594 | Lₐ₅₉₄ | L_{b52} |
| 595 | Lₐ₅₉₅ | L_{b52} | 596 | Lₐ₅₉₆ | L_{b52} | 597 | Lₐ₅₉₇ | L_{b52} |
| 598 | Lₐ₅₉₈ | L_{b52} | 599 | Lₐ₅₉₉ | L_{b52} | 600 | Lₐ₆₀₀ | L_{b52} |
| 601 | Lₐ₆₀₁ | L_{b52} | 602 | Lₐ₆₀₂ | L_{b52} | 603 | Lₐ₆₀₃ | L_{b52} |
| 604 | Lₐ₆₀₄ | L_{b52} | 605 | Lₐ₆₀₅ | L_{b52} | 606 | Lₐ₆₀₆ | L_{b52} |
| 607 | Lₐ₆₀₇ | L_{b52} | 608 | Lₐ₆₀₈ | L_{b52} | 609 | Lₐ₆₀₉ | L_{b52} |
| 610 | Lₐ₆₁₀ | L_{b52} | 611 | Lₐ₆₁₁ | L_{b52} | 612 | Lₐ₆₁₂ | L_{b52} |
| 613 | Lₐ₆₁₃ | L_{b52} | 614 | Lₐ₆₁₄ | L_{b52} | 615 | Lₐ₆₁₅ | L_{b52} |
| 616 | Lₐ₆₁₆ | L_{b52} | 617 | Lₐ₆₁₇ | L_{b52} | 618 | Lₐ₆₁₈ | L_{b52} |
| 619 | Lₐ₆₁₉ | L_{b52} | 620 | Lₐ₆₂₀ | L_{b52} | 621 | Lₐ₆₂₁ | L_{b52} |
| 622 | Lₐ₆₂₂ | L_{b52} | 623 | Lₐ₆₂₃ | L_{b52} | 624 | Lₐ₆₂₄ | L_{b52} |
| 625 | Lₐ₆₂₅ | L_{b52} | 626 | Lₐ₆₂₆ | L_{b52} | 627 | Lₐ₆₂₇ | L_{b52} |
| 628 | Lₐ₆₂₈ | L_{b52} | 629 | Lₐ₆₂₉ | L_{b52} | 630 | Lₐ₆₃₀ | L_{b52} |
| 631 | Lₐ₆₃₁ | L_{b52} | 632 | Lₐ₆₃₂ | L_{b52} | 633 | Lₐ₆₃₃ | L_{b52} |
| 634 | Lₐ₆₃₄ | L_{b52} | 635 | Lₐ₆₃₅ | L_{b52} | 636 | Lₐ₆₃₆ | L_{b52} |
| 637 | Lₐ₆₃₇ | L_{b52} | 638 | Lₐ₆₃₈ | L_{b52} | 639 | Lₐ₆₃₉ | L_{b52} |
| 640 | Lₐ₆₄₀ | L_{b52} | 641 | Lₐ₆₄₁ | L_{b52} | 642 | Lₐ₆₄₂ | L_{b52} |
| 643 | Lₐ₆₄₃ | L_{b52} | 644 | Lₐ₆₄₄ | L_{b52} | 645 | Lₐ₆₄₅ | L_{b52} |
| 646 | Lₐ₆₄₆ | L_{b52} | 647 | Lₐ₆₄₇ | L_{b52} | 648 | Lₐ₆₄₈ | L_{b52} |
| 649 | Lₐ₆₄₉ | L_{b52} | 650 | Lₐ₆₅₀ | L_{b52} | 651 | Lₐ₆₅₁ | L_{b52} |
| 652 | Lₐ₆₅₂ | L_{b52} | 653 | Lₐ₆₅₃ | L_{b52} | 654 | Lₐ₆₅₄ | L_{b52} |
| 655 | Lₐ₆₅₅ | L_{b52} | 656 | Lₐ₆₅₆ | L_{b52} | 657 | Lₐ₆₅₇ | L_{b52} |
| 658 | Lₐ₆₅₈ | L_{b52} | 659 | Lₐ₆₅₉ | L_{b52} | 660 | Lₐ₆₆₀ | L_{b52} |
| 661 | Lₐ₆₆₁ | L_{b52} | 662 | Lₐ₆₆₂ | L_{b52} | 663 | Lₐ₆₆₃ | L_{b52} |
| 664 | Lₐ₆₆₄ | L_{b52} | 665 | Lₐ₆₆₅ | L_{b52} | 666 | Lₐ₆₆₆ | L_{b52} |
| 667 | Lₐ₆₆₇ | L_{b52} | 668 | Lₐ₆₆₈ | L_{b52} | 669 | Lₐ₆₆₉ | L_{b52} |
| 670 | Lₐ₆₇₀ | L_{b52} | 671 | Lₐ₆₇₁ | L_{b52} | 672 | Lₐ₆₇₂ | L_{b52} |
| 673 | Lₐ₆₇₃ | L_{b52} | 674 | Lₐ₆₇₄ | L_{b52} | 675 | Lₐ₆₇₅ | L_{b52} |
| 676 | Lₐ₆₇₆ | L_{b52} | 677 | Lₐ₆₇₇ | L_{b52} | 678 | Lₐ₆₇₈ | L_{b52} |
| 679 | Lₐ₆₇₉ | L_{b52} | 680 | Lₐ₆₈₀ | L_{b52} | 681 | Lₐ₆₈₁ | L_{b52} |
| 682 | Lₐ₆₈₂ | L_{b52} | 683 | Lₐ₆₈₃ | L_{b52} | 684 | Lₐ₆₈₄ | L_{b52} |
| 685 | Lₐ₆₈₅ | L_{b52} | 686 | Lₐ₆₈₆ | L_{b52} | 687 | Lₐ₆₈₇ | L_{b52} |
| 688 | Lₐ₆₈₈ | L_{b52} | 689 | Lₐ₆₈₉ | L_{b52} | 690 | Lₐ₆₉₀ | L_{b52} |
| 691 | Lₐ₆₉₁ | L_{b52} | 692 | Lₐ₆₉₂ | L_{b52} | 693 | Lₐ₆₉₃ | L_{b52} |
| 694 | Lₐ₆₉₄ | L_{b52} | 695 | Lₐ₆₉₅ | L_{b52} | 696 | Lₐ₆₉₆ | L_{b52} |
| 697 | Lₐ₆₉₇ | L_{b52} | 698 | Lₐ₆₉₈ | L_{b52} | 699 | Lₐ₆₉₉ | L_{b52} |
| 700 | Lₐ₇₀₀ | L_{b52} | 701 | Lₐ₇₀₁ | L_{b52} | 702 | Lₐ₇₀₂ | L_{b52} |
| 703 | Lₐ₇₀₃ | L_{b52} | 704 | Lₐ₇₀₄ | L_{b52} | 705 | Lₐ₇₀₅ | L_{b52} |
| 706 | Lₐ₇₀₆ | L_{b52} | 707 | Lₐ₇₀₇ | L_{b52} | 708 | Lₐ₇₀₈ | L_{b52} |
| 709 | Lₐ₇₀₉ | L_{b52} | 710 | Lₐ₇₁₀ | L_{b52} | 711 | Lₐ₇₁₁ | L_{b52} |
| 712 | Lₐ₇₁₂ | L_{b52} | 713 | Lₐ₇₁₃ | L_{b52} | 714 | Lₐ₇₁₄ | L_{b52} |
| 715 | Lₐ₇₁₅ | L_{b52} | 716 | Lₐ₇₁₆ | L_{b52} | 717 | Lₐ₇₁₇ | L_{b52} |
| 718 | Lₐ₇₁₈ | L_{b52} | 719 | Lₐ₇₁₉ | L_{b52} | 720 | Lₐ₇₂₀ | L_{b52} |
| 721 | Lₐ₇₂₁ | L_{b52} | 722 | Lₐ₇₂₂ | L_{b52} | 723 | Lₐ₇₂₃ | L_{b52} |
| 724 | Lₐ₇₂₄ | L_{b52} | 725 | Lₐ₇₂₅ | L_{b52} | 726 | Lₐ₇₂₆ | L_{b52} |
| 727 | Lₐ₇₂₇ | L_{b52} | 728 | Lₐ₇₂₈ | L_{b52} | 729 | Lₐ₇₂₉ | L_{b52} |
| 730 | Lₐ₇₃₀ | L_{b52} | 731 | Lₐ₇₃₁ | L_{b52} | 732 | Lₐ₇₃₂ | L_{b52} |
| 733 | Lₐ₇₃₃ | L_{b52} | 734 | Lₐ₇₃₄ | L_{b52} | 735 | Lₐ₇₃₅ | L_{b52} |
| 736 | Lₐ₇₃₆ | L_{b52} | 737 | Lₐ₇₃₇ | L_{b52} | 738 | Lₐ₇₃₈ | L_{b52} |
| 739 | Lₐ₇₃₉ | L_{b52} | 740 | Lₐ₇₄₀ | L_{b52} | 741 | Lₐ₇₄₁ | L_{b52} |
| 742 | Lₐ₇₄₂ | L_{b52} | 743 | Lₐ₇₄₃ | L_{b52} | 744 | Lₐ₇₄₄ | L_{b52} |
| 745 | Lₐ₇₄₅ | L_{b52} | 746 | Lₐ₇₄₆ | L_{b52} | 747 | Lₐ₇₄₇ | L_{b52} |
| 748 | Lₐ₇₄₈ | L_{b52} | 749 | Lₐ₇₄₉ | L_{b52} | 750 | Lₐ₇₅₀ | L_{b52} |
| 751 | Lₐ₇₅₁ | L_{b52} | 752 | Lₐ₇₅₂ | L_{b52} | 753 | Lₐ₇₅₃ | L_{b52} |
| 754 | Lₐ₇₅₄ | L_{b52} | 755 | Lₐ₇₅₅ | L_{b52} | 756 | Lₐ₇₅₆ | L_{b52} |
| 757 | Lₐ₇₅₇ | L_{b52} | 758 | Lₐ₇₅₈ | L_{b52} | 759 | Lₐ₇₅₉ | L_{b52} |
| 760 | Lₐ₇₆₀ | L_{b52} | 761 | Lₐ₇₆₁ | L_{b52} | 762 | Lₐ₇₆₂ | L_{b52} |
| 763 | Lₐ₇₆₃ | L_{b52} | 764 | Lₐ₇₆₄ | L_{b52} | 765 | Lₐ₇₆₅ | L_{b52} |
| 766 | Lₐ₇₆₆ | L_{b52} | 767 | Lₐ₇₆₇ | L_{b52} | 768 | Lₐ₇₆₈ | L_{b52} |
| 769 | Lₐ₇₆₉ | L_{b52} | 770 | Lₐ₇₇₀ | L_{b52} | 771 | Lₐ₇₇₁ | L_{b52} |
| 772 | Lₐ₇₇₂ | L_{b52} | 773 | Lₐ₇₇₃ | L_{b52} | 774 | Lₐ₇₇₄ | L_{b52} |
| 775 | Lₐ₇₇₅ | L_{b52} | 776 | Lₐ₇₇₆ | L_{b52} | 777 | Lₐ₇₇₇ | L_{b52} |
| 778 | Lₐ₇₇₈ | L_{b52} | 779 | Lₐ₇₇₉ | L_{b52} | 780 | Lₐ₇₈₀ | L_{b52} |
| 781 | Lₐ₇₈₁ | L_{b52} | 782 | Lₐ₇₈₂ | L_{b52} | 783 | Lₐ₇₈₃ | L_{b52} |
| 784 | Lₐ₇₈₄ | L_{b52} | 785 | Lₐ₇₈₅ | L_{b52} | 786 | Lₐ₇₈₆ | L_{b52} |
| 787 | Lₐ₇₈₇ | L_{b52} | 788 | Lₐ₇₈₈ | L_{b52} | 789 | Lₐ₇₈₉ | L_{b52} |
| 790 | Lₐ₇₉₀ | L_{b52} | 791 | Lₐ₇₉₁ | L_{b52} | 792 | Lₐ₇₉₂ | L_{b52} |
| 793 | Lₐ₇₉₃ | L_{b52} | 794 | Lₐ₇₉₄ | L_{b52} | 795 | Lₐ₇₉₅ | L_{b52} |
| 796 | Lₐ₇₉₆ | L_{b52} | 797 | Lₐ₇₉₇ | L_{b52} | 798 | Lₐ₇₉₈ | L_{b52} |
| 799 | Lₐ₇₉₉ | L_{b52} | 800 | Lₐ₈₀₀ | L_{b52} | 801 | Lₐ₈₀₁ | L_{b52} |
| 802 | Lₐ₈₀₂ | L_{b52} | 803 | Lₐ₈₀₃ | L_{b52} | 804 | Lₐ₈₀₄ | L_{b52} |
| 805 | Lₐ₈₀₅ | L_{b52} | 806 | Lₐ₈₀₆ | L_{b52} | 807 | Lₐ₈₀₇ | L_{b52} |
| 808 | Lₐ₈₀₈ | L_{b52} | 809 | Lₐ₈₀₉ | L_{b52} | 810 | Lₐ₈₁₀ | L_{b52} |
| 811 | Lₐ₈₁₁ | L_{b52} | 812 | Lₐ₈₁₂ | L_{b52} | 813 | Lₐ₈₁₃ | L_{b52} |
| 814 | Lₐ₈₁₄ | L_{b52} | 815 | Lₐ₈₁₅ | L_{b52} | 816 | Lₐ₈₁₆ | L_{b52} |
| 817 | Lₐ₈₁₇ | L_{b52} | 818 | Lₐ₈₁₈ | L_{b52} | 819 | Lₐ₈₁₉ | L_{b52} |
| 820 | Lₐ₈₂₀ | L_{b52} | 821 | Lₐ₈₂₁ | L_{b52} | 822 | Lₐ₈₂₂ | L_{b52} |
| 823 | Lₐ₈₂₃ | L_{b52} | 824 | Lₐ₈₂₄ | L_{b52} | 825 | Lₐ₈₂₅ | L_{b52} |
| 826 | Lₐ₈₂₆ | L_{b52} | 827 | Lₐ₈₂₇ | L_{b52} | 828 | Lₐ₈₂₈ | L_{b52} |
| 829 | Lₐ₈₂₉ | L_{b52} | 830 | Lₐ₈₃₀ | L_{b52} | 831 | Lₐ₈₃₁ | L_{b52} |
| 832 | Lₐ₈₃₂ | L_{b52} | 833 | Lₐ₈₃₃ | L_{b52} | 834 | Lₐ₈₃₄ | L_{b52} |
| 835 | Lₐ₈₃₅ | L_{b52} | 836 | Lₐ₈₃₆ | L_{b52} | 837 | Lₐ₈₃₇ | L_{b52} |
| 838 | Lₐ₈₃₈ | L_{b52} | 839 | Lₐ₈₃₉ | L_{b52} | 840 | Lₐ₈₄₀ | L_{b52} |
| 841 | Lₐ₈₄₁ | L_{b52} | 842 | Lₐ₈₄₂ | L_{b52} | 843 | Lₐ₈₄₃ | L_{b52} |
| 844 | Lₐ₈₄₄ | L_{b52} | 845 | Lₐ₈₄₅ | L_{b52} | 846 | Lₐ₈₄₆ | L_{b52} |
| 847 | Lₐ₈₄₇ | L_{b52} | 848 | Lₐ₈₄₈ | L_{b52} | 849 | Lₐ₈₄₉ | L_{b52} |
| 850 | Lₐ₈₅₀ | L_{b52} | 851 | Lₐ₈₅₁ | L_{b52} | 852 | Lₐ₈₅₂ | L_{b52} |
| 853 | Lₐ₈₅₃ | L_{b52} | 854 | Lₐ₈₅₄ | L_{b52} | 855 | Lₐ₈₅₅ | L_{b52} |
| 856 | Lₐ₈₅₆ | L_{b52} | 857 | Lₐ₈₅₇ | L_{b52} | 858 | Lₐ₈₅₈ | L_{b52} |
| 859 | Lₐ₈₅₉ | L_{b52} | 860 | Lₐ₈₆₀ | L_{b52} | 861 | Lₐ₈₆₁ | L_{b52} |
| 862 | Lₐ₈₆₂ | L_{b52} | 863 | Lₐ₈₆₃ | L_{b52} | 864 | Lₐ₈₆₄ | L_{b52} |
| 865 | Lₐ₈₆₅ | L_{b52} | 866 | Lₐ₈₆₆ | L_{b52} | 867 | Lₐ₈₆₇ | L_{b52} |
| 868 | Lₐ₈₆₈ | L_{b52} | 869 | Lₐ₈₆₉ | L_{b52} | 870 | Lₐ₈₇₀ | L_{b52} |
| 871 | Lₐ₈₇₁ | L_{b52} | 872 | Lₐ₈₇₂ | L_{b52} | 873 | Lₐ₈₇₃ | L_{b52} |
| 874 | Lₐ₈₇₄ | L_{b52} | 875 | Lₐ₈₇₅ | L_{b52} | 876 | Lₐ₈₇₆ | L_{b52} |
| 877 | Lₐ₈₇₇ | L_{b52} | 878 | Lₐ₈₇₈ | L_{b52} | 879 | Lₐ₈₇₉ | L_{b52} |
| 880 | Lₐ₈₈₀ | L_{b52} | 881 | Lₐ₈₈₁ | L_{b52} | 882 | Lₐ₈₈₂ | L_{b52} |
| 883 | Lₐ₈₈₃ | L_{b52} | 884 | Lₐ₈₈₄ | L_{b52} | 885 | Lₐ₈₈₅ | L_{b52} |
| 886 | Lₐ₈₈₆ | L_{b52} | 887 | Lₐ₈₈₇ | L_{b52} | 888 | Lₐ₈₈₈ | L_{b52} |
| 889 | Lₐ₈₈₉ | L_{b52} | 890 | Lₐ₈₉₀ | L_{b52} | 891 | Lₐ₈₉₁ | L_{b52} |
| 892 | Lₐ₈₉₂ | L_{b52} | 893 | Lₐ₈₉₃ | L_{b52} | 894 | Lₐ₈₉₄ | L_{b52} |
| 895 | Lₐ₈₉₅ | L_{b52} | 896 | Lₐ₈₉₆ | L_{b52} | 897 | Lₐ₈₉₇ | L_{b52} |
| 898 | Lₐ₈₉₈ | L_{b52} | 899 | Lₐ₈₉₉ | L_{b52} | 900 | Lₐ₉₀₀ | L_{b52} |
| 901 | Lₐ₉₀₁ | L_{b52} | 902 | Lₐ₉₀₂ | L_{b52} | 903 | Lₐ₉₀₃ | L_{b52} |
| 904 | Lₐ₉₀₄ | L_{b52} | 905 | Lₐ₉₀₅ | L_{b52} | 906 | Lₐ₉₀₆ | L_{b52} |
| 907 | Lₐ₉₀₇ | L_{b52} | 908 | Lₐ₉₀₈ | L_{b52} | 909 | Lₐ₉₀₉ | L_{b52} |
| 910 | Lₐ₉₁₀ | L_{b52} | 911 | Lₐ₉₁₁ | L_{b52} | 912 | Lₐ₉₁₂ | L_{b52} |
| 913 | Lₐ₉₁₃ | L_{b52} | 914 | Lₐ₉₁₄ | L_{b52} | 915 | Lₐ₉₁₅ | L_{b52} |
| 916 | Lₐ₉₁₆ | L_{b52} | 917 | Lₐ₉₁₇ | L_{b52} | 918 | Lₐ₉₁₈ | L_{b52} |
| 919 | Lₐ₉₁₉ | L_{b52} | 920 | Lₐ₉₂₀ | L_{b52} | 921 | Lₐ₉₂₁ | L_{b52} |
| 922 | Lₐ₉₂₂ | L_{b52} | 923 | Lₐ₉₂₃ | L_{b52} | 924 | Lₐ₉₂₄ | L_{b52} |
| 925 | Lₐ₉₂₅ | L_{b52} | 926 | Lₐ₉₂₆ | L_{b52} | 927 | Lₐ₉₂₇ | L_{b52} |
| 928 | Lₐ₉₂₈ | L_{b52} | 929 | Lₐ₉₂₉ | L_{b52} | 930 | Lₐ₉₃₀ | L_{b52} |
| 931 | Lₐ₉₃₁ | L_{b52} | 932 | Lₐ₉₃₂ | L_{b52} | 933 | Lₐ₉₃₃ | L_{b52} |
| 934 | Lₐ₉₃₄ | L_{b52} | 935 | Lₐ₉₃₅ | L_{b52} | 936 | Lₐ₉₃₆ | L_{b52} |
| 937 | Lₐ₉₃₇ | L_{b52} | 938 | Lₐ₉₃₈ | L_{b52} | 939 | Lₐ₉₃₉ | L_{b52} |
| 940 | Lₐ₉₄₀ | L_{b52} | 941 | Lₐ₉₄₁ | L_{b52} | 942 | Lₐ₉₄₂ | L_{b52} |
| 943 | Lₐ₉₄₃ | L_{b52} | 944 | Lₐ₉₄₄ | L_{b52} | 945 | Lₐ₉₄₅ | L_{b52} |
| 946 | Lₐ₉₄₆ | L_{b52} | 947 | Lₐ₉₄₇ | L_{b52} | 948 | Lₐ₉₄₈ | L_{b52} |
| 949 | Lₐ₉₄₉ | L_{b52} | 950 | Lₐ₉₅₀ | L_{b52} | 951 | Lₐ₉₅₁ | L_{b52} |
| 952 | Lₐ₉₅₂ | L_{b52} | 953 | Lₐ₉₅₃ | L_{b52} | 954 | Lₐ₉₅₄ | L_{b52} |
| 955 | Lₐ₉₅₅ | L_{b52} | 956 | Lₐ₉₅₆ | L_{b52} | 957 | Lₐ₉₅₇ | L_{b52} |
| 958 | Lₐ₉₅₈ | L_{b52} | 959 | Lₐ₉₅₉ | L_{b52} | 960 | Lₐ₉₆₀ | L_{b52} |
| 961 | Lₐ₉₆₁ | L_{b52} | 962 | Lₐ₉₆₂ | L_{b52} | 963 | Lₐ₉₆₃ | L_{b52} |
| 964 | Lₐ₉₆₄ | L_{b52} | 965 | Lₐ₉₆₅ | L_{b52} | 966 | Lₐ₉₆₆ | L_{b52} |
| 967 | Lₐ₉₆₇ | L_{b52} | 968 | Lₐ₉₆₈ | L_{b52} | 969 | Lₐ₉₆₉ | L_{b52} |
| 970 | Lₐ₉₇₀ | L_{b52} | 971 | Lₐ₉₇₁ | L_{b52} | 972 | Lₐ₉₇₂ | L_{b52} |
| 973 | Lₐ₉₇₃ | L_{b52} | 974 | Lₐ₉₇₄ | L_{b52} | 975 | Lₐ₉₇₅ | L_{b52} |
| 976 | Lₐ₉₇₆ | L_{b52} | 977 | Lₐ₉₇₇ | L_{b52} | 978 | Lₐ₉₇₈ | L_{b52} |
| 979 | Lₐ₉₇₉ | L_{b52} | 980 | Lₐ₉₈₀ | L_{b52} | 981 | Lₐ₉₈₁ | L_{b52} |
| 982 | Lₐ₉₈₂ | L_{b52} | 983 | Lₐ₉₈₃ | L_{b52} | 984 | Lₐ₉₈₄ | L_{b52} |
| 985 | Lₐ₉₈₅ | L_{b52} | 986 | Lₐ₉₈₆ | L_{b52} | 987 | Lₐ₉₈₇ | L_{b52} |
| 988 | Lₐ₉₈₈ | L_{b52} | 989 | Lₐ₉₈₉ | L_{b52} | 990 | Lₐ₉₉₀ | L_{b52} |
| 991 | Lₐ₉₉₁ | L_{b52} | 992 | Lₐ₉₉₂ | L_{b52} | 993 | Lₐ₉₉₃ | L_{b52} |
| 994 | Lₐ₉₉₄ | L_{b52} | 995 | Lₐ₉₉₅ | L_{b52} | 996 | Lₐ₉₉₆ | L_{b52} |
| 997 | Lₐ₉₉₇ | L_{b52} | 998 | Lₐ₉₉₈ | L_{b52} | 999 | Lₐ₉₉₉ | L_{b52} |
| 1000 | Lₐ₁₀₀₀ | L_{b52} | 1001 | Lₐ₁₀₀₁ | L_{b52} | 1002 | Lₐ₁₀₀₂ | L_{b52} |
| 1003 | Lₐ₁₀₀₃ | L_{b52} | 1004 | Lₐ₁₀₀₄ | L_{b52} | 1005 | Lₐ₁₀₀₅ | L_{b52} |
| 1006 | Lₐ₁₀₀₆ | L_{b52} | 1007 | Lₐ₁₀₀₇ | L_{b52} | 1008 | Lₐ₁₀₀₈ | L_{b52} |
| 1009 | Lₐ₁₀₀₉ | L_{b52} | 1010 | Lₐ₁₀₁₀ | L_{b52} | 1011 | Lₐ₁₀₁₁ | L_{b52} |
| 1012 | Lₐ₁₀₁₂ | L_{b52} | 1013 | Lₐ₁₀₁₃ | L_{b52} | 1014 | Lₐ₁₀₁₄ | L_{b52} |
| 1015 | Lₐ₁₀₁₅ | L_{b52} | 1016 | Lₐ₁₀₁₆ | L_{b52} | 1017 | Lₐ₁₀₁₇ | L_{b52} |
| 1018 | Lₐ₁₀₁₈ | L_{b52} | 1019 | Lₐ₁₀₁₉ | L_{b52} | 1020 | Lₐ₁₀₂₀ | L_{b52} |
| 1021 | Lₐ₁₀₂₁ | L_{b52} | 1022 | Lₐ₁₀₂₂ | L_{b52} | 1023 | Lₐ₁₀₂₃ | L_{b52} |
| 1024 | Lₐ₁₀₂₄ | L_{b52} | 1025 | Lₐ₁₀₂₅ | L_{b52} | 1026 | Lₐ₁₀₂₆ | L_{b52} |
| 1027 | Lₐ₁₀₂₇ | L_{b52} | 1028 | Lₐ₁₀₂₈ | L_{b52} | 1029 | Lₐ₁₀₂₉ | L_{b52} |
| 1030 | Lₐ₁₀₃₀ | L_{b52} | 1031 | Lₐ₁₀₃₁ | L_{b52} | 1032 | Lₐ₁₀₃₂ | L_{b52} |
| 1033 | Lₐ₁₀₃₃ | L_{b52} | 1034 | Lₐ₁₀₃₄ | L_{b52} | 1035 | Lₐ₁₀₃₅ | L_{b52} |
| 1036 | Lₐ₁₀₃₆ | L_{b52} | 1037 | Lₐ₁₀₃₇ | L_{b52} | 1038 | Lₐ₁₀₃₈ | L_{b52} |
| 1039 | Lₐ₁₀₃₉ | L_{b52} | 1040 | Lₐ₁₀₄₀ | L_{b52} | 1041 | Lₐ₁₀₄₁ | L_{b52} |
| 1042 | Lₐ₁₀₄₂ | L_{b52} | 1043 | Lₐ₁₀₄₃ | L_{b52} | 1044 | Lₐ₁₀₄₄ | L_{b52} |
| 1045 | Lₐ₁₀₄₅ | L_{b52} | 1046 | Lₐ₁₀₄₆ | L_{b52} | 1047 | Lₐ₁₀₄₇ | L_{b52} |
| 1048 | Lₐ₁₀₄₈ | L_{b52} | 1049 | Lₐ₁₀₄₉ | L_{b52} | 1050 | Lₐ₁₀₅₀ | L_{b52} |
| 1051 | Lₐ₁₀₅₁ | L_{b52} | 1052 | Lₐ₁₀₅₂ | L_{b52} | 1053 | Lₐ₁₀₅₃ | L_{b52} |
| 1054 | Lₐ₁₀₅₄ | L_{b52} | 1055 | Lₐ₁₀₅₅ | L_{b52} | 1056 | Lₐ₁₀₅₆ | L_{b52} |
| 1057 | Lₐ₁₀₅₇ | L_{b52} | 1058 | Lₐ₁₀₅₈ | L_{b52} | 1059 | Lₐ₁₀₅₉ | L_{b52} |
| 1060 | Lₐ₁₀₆₀ | L_{b52} | 1061 | Lₐ₁₀₆₁ | L_{b52} | 1062 | Lₐ₁₀₆₂ | L_{b52} |
| 1063 | Lₐ₁₀₆₃ | L_{b52} | 1064 | Lₐ₁₀₆₄ | L_{b52} | 1065 | Lₐ₁₀₆₅ | L_{b52} |
| 1066 | Lₐ₁₀₆₆ | L_{b52} | 1067 | Lₐ₁₀₆₇ | L_{b52} | 1068 | Lₐ₁₀₆₈ | L_{b52} |
| 1069 | Lₐ₁₀₆₉ | L_{b52} | 1070 | Lₐ₁₀₇₀ | L_{b52} | 1071 | Lₐ₁₀₇₁ | L_{b52} |
| 1072 | Lₐ₁₀₇₂ | L_{b52} | 1073 | Lₐ₁₀₇₃ | L_{b52} | 1074 | Lₐ₁₀₇₄ | L_{b52} |
| 1075 | Lₐ₁₀₇₅ | L_{b52} | 1076 | Lₐ₁₀₇₆ | L_{b52} | 1077 | Lₐ₁₀₇₇ | L_{b52} |
| 1078 | Lₐ₁₀₇₈ | L_{b52} | 1079 | Lₐ₁₀₇₉ | L_{b52} | 1080 | Lₐ₁₀₈₀ | L_{b52} |
| 1081 | Lₐ₁₀₈₁ | L_{b52} | 1082 | Lₐ₁₀₈₂ | L_{b52} | 1083 | Lₐ₁₀₈₃ | L_{b52} |
| 1084 | Lₐ₁₀₈₄ | L_{b52} | 1085 | Lₐ₁₀₈₅ | L_{b52} | 1086 | Lₐ₁₀₈₆ | L_{b52} |
| 1087 | Lₐ₁₀₈₇ | L_{b52} | 1088 | Lₐ₁₀₈₈ | L_{b52} | 1089 | Lₐ₁₀₈₉ | L_{b52} |
| 1090 | Lₐ₁₀₉₀ | L_{b52} | 1091 | Lₐ₁₀₉₁ | L_{b52} | 1092 | Lₐ₁₀₉₂ | L_{b52} |
| 1093 | Lₐ₁₀₉₃ | L_{b52} | 1094 | Lₐ₁₀₉₄ | L_{b52} | 1095 | Lₐ₁₀₉₅ | L_{b52} |
| 1096 | Lₐ₁₀₉₆ | L_{b52} | 1097 | Lₐ₁₀₉₇ | L_{b52} | 1098 | Lₐ₁₀₉₈ | L_{b52} |
| 1099 | Lₐ₁₀₉₉ | L_{b52} | 1100 | Lₐ₁₁₀₀ | L_{b52} | 1101 | Lₐ₁₁₀₁ | L_{b52} |
| 1102 | Lₐ₁₁₀₂ | L_{b52} | 1103 | Lₐ₁₁₀₃ | L_{b52} | 1104 | Lₐ₁₁₀₄ | L_{b52} |
| 1105 | Lₐ₁₁₀₅ | L_{b52} | 1106 | Lₐ₁₁₀₆ | L_{b52} | 1107 | Lₐ₁₁₀₇ | L_{b52} |
| 1108 | Lₐ₁₁₀₈ | L_{b52} | 1109 | Lₐ₁₁₀₉ | L_{b52} | 1110 | Lₐ₁₁₁₀ | L_{b52} |
| 1111 | Lₐ₁₁₁₁ | L_{b52} | 1112 | Lₐ₁₁₁₂ | L_{b52} | 1113 | Lₐ₁₁₁₃ | L_{b52} |
| 1114 | Lₐ₁₁₁₄ | L_{b52} | 1115 | Lₐ₁₁₁₅ | L_{b52} | 1116 | Lₐ₁₁₁₆ | L_{b52} |
| 1117 | Lₐ₁₁₁₇ | L_{b52} | 1118 | Lₐ₁₁₁₈ | L_{b52} | 1119 | Lₐ₁₁₁₉ | L_{b52} |
| 1120 | Lₐ₁₁₂₀ | L_{b52} | 1121 | Lₐ₁₁₂₁ | L_{b52} | 1122 | Lₐ₁₁₂₂ | L_{b52} |
| 1123 | Lₐ₁₁₂₃ | L_{b52} | 1124 | Lₐ₁₁₂₄ | L_{b52} | 1125 | Lₐ₁₁₂₅ | L_{b52} |
| 1126 | Lₐ₁₁₂₆ | L_{b52} | 1127 | Lₐ₁₁₂₇ | L_{b52} | 1128 | Lₐ₁₁₂₈ | L_{b52} |
| 1129 | Lₐ₁₁₂₉ | L_{b52} | 1130 | Lₐ₁₁₃₀ | L_{b52} | 1131 | Lₐ₁₁₃₁ | L_{b52} |
| 1132 | Lₐ₁₁₃₂ | L_{b52} | 1133 | Lₐ₁₁₃₃ | L_{b52} | 1134 | Lₐ₁₁₃₄ | L_{b52} |
| 1135 | Lₐ₁₁₃₅ | L_{b52} | 1136 | Lₐ₁₁₃₆ | L_{b52} | 1137 | Lₐ₁₁₃₇ | L_{b52} |
| 1138 | Lₐ₁₁₃₈ | L_{b52} | 1139 | Lₐ₁₁₃₉ | L_{b52} | 1140 | Lₐ₁₁₄₀ | L_{b52} |
| 1141 | Lₐ₁₁₄₁ | L_{b52} | 1142 | Lₐ₁₁₄₂ | L_{b52} | 1143 | Lₐ₁₁₄₃ | L_{b52} |
| 1144 | Lₐ₁₁₄₄ | L_{b52} | 1145 | Lₐ₁₁₄₅ | L_{b52} | 1146 | Lₐ₁₁₄₆ | L_{b52} |
| 1147 | Lₐ₁₁₄₇ | L_{b52} | 1148 | Lₐ₁₁₄₈ | L_{b52} | 1149 | Lₐ₁₁₄₉ | L_{b52} |
| 1150 | Lₐ₁₁₅₀ | L_{b52} | 1151 | Lₐ₁₁₅₁ | L_{b52} | 1152 | Lₐ₁₁₅₂ | L_{b52} |
| 1153 | Lₐ₁₁₅₃ | L_{b52} | 1154 | Lₐ₁₁₅₄ | L_{b52} | 1155 | Lₐ₁₁₅₅ | L_{b52} |
| 1156 | Lₐ₁₁₅₆ | L_{b52} | 1157 | Lₐ₁₁₅₇ | L_{b52} | 1158 | Lₐ₁₁₅₈ | L_{b52} |
| 1159 | Lₐ₁₁₅₉ | L_{b52} | 1160 | Lₐ₁₁₆₀ | L_{b52} | 1161 | Lₐ₁₁₆₁ | L_{b52} |
| 1162 | Lₐ₁₁₆₂ | L_{b52} | 1163 | Lₐ₁₁₆₃ | L_{b52} | 1164 | Lₐ₁₁₆₄ | L_{b52} |
| 1165 | Lₐ₁₁₆₅ | L_{b52} | 1166 | Lₐ₁₁₆₆ | L_{b52} | 1167 | Lₐ₁₁₆₇ | L_{b52} |
| 1168 | Lₐ₁₁₆₈ | L_{b52} | 1169 | Lₐ₁₁₆₉ | L_{b52} | 1170 | Lₐ₁₁₇₀ | L_{b52} |
| 1171 | Lₐ₁₁₇₁ | L_{b52} | 1172 | Lₐ₁₁₇₂ | L_{b52} | 1173 | Lₐ₁₁₇₃ | L_{b52} |
| 1174 | Lₐ₁₁₇₄ | L_{b52} | 1175 | Lₐ₁₁₇₅ | L_{b52} | 1176 | Lₐ₁₁₇₆ | L_{b52} |
| 1177 | Lₐ₁₁₇₇ | L_{b52} | 1178 | Lₐ₁₁₇₈ | L_{b52} | 1179 | Lₐ₁₁₇₉ | L_{b52} |
| 1180 | Lₐ₁₁₈₀ | L_{b52} | 1181 | Lₐ₁₁₈₁ | L_{b52} | 1182 | Lₐ₁₁₈₂ | L_{b52} |
| 1183 | Lₐ₁₁₈₃ | L_{b52} | 1184 | Lₐ₁₁₈₄ | L_{b52} | 1185 | Lₐ₁₁₈₅ | L_{b52} |
| 1186 | Lₐ₁₁₈₆ | L_{b52} | 1187 | Lₐ₁₁₈₇ | L_{b52} | 1188 | Lₐ₁₁₈₈ | L_{b52} |
| 1189 | Lₐ₁₁₈₉ | L_{b52} | 1190 | Lₐ₁₁₉₀ | L_{b52} | 1191 | Lₐ₁₁₉₁ | L_{b52} |
| 1192 | Lₐ₁₁₉₂ | L_{b52} | 1193 | Lₐ₁₁₉₃ | L_{b52} | 1194 | Lₐ₁₁₉₄ | L_{b52} |
| 1195 | Lₐ₁₁₉₅ | L_{b52} | 1196 | Lₐ₁₁₉₆ | L_{b52} | 1197 | Lₐ₁₁₉₇ | L_{b52} |
| 1198 | Lₐ₁₁₉₈ | L_{b52} | 1199 | Lₐ₁₁₉₉ | L_{b52} | 1200 | Lₐ₁₂₀₀ | L_{b52} |
| 1201 | Lₐ₁₂₀₁ | L_{b52} | 1202 | Lₐ₁₂₀₂ | L_{b52} | 1203 | Lₐ₁₂₀₃ | L_{b52} |
| 1204 | Lₐ₁₂₀₄ | L_{b52} | 1205 | Lₐ₁₂₀₅ | L_{b52} | 1206 | Lₐ₁₂₀₆ | L_{b52} |
| 1207 | Lₐ₁₂₀₇ | L_{b52} | 1208 | Lₐ₁₂₀₈ | L_{b52} | 1209 | Lₐ₁₂₀₉ | L_{b52} |
| 1210 | Lₐ₁₂₁₀ | L_{b52} | 1211 | Lₐ₁₂₁₁ | L_{b52} | 1212 | Lₐ₁₂₁₂ | L_{b52} |
| 1213 | Lₐ₁₂₁₃ | L_{b52} | 1214 | Lₐ₁₂₁₄ | L_{b52} | 1215 | Lₐ₁₂₁₅ | L_{b52} |
| 1216 | Lₐ₁₂₁₆ | L_{b52} | 1217 | Lₐ₁₂₁₇ | L_{b52} | 1218 | Lₐ₁₂₁₈ | L_{b52} |
| 1219 | Lₐ₁₂₁₉ | L_{b52} | 1220 | Lₐ₁₂₂₀ | L_{b52} | 1221 | Lₐ₁₂₂₁ | L_{b52} |
| 1222 | Lₐ₁₂₂₂ | L_{b52} | 1223 | Lₐ₁₂₂₃ | L_{b52} | 1224 | Lₐ₁₂₂₄ | L_{b52} |
| 1225 | Lₐ₁₂₂₅ | L_{b52} | 1226 | Lₐ₁₂₂₆ | L_{b52} | 1227 | Lₐ₁₂₂₇ | L_{b52} |
| 1228 | Lₐ₁₂₂₈ | L_{b52} | 1229 | Lₐ₁₂₂₉ | L_{b52} | 1230 | Lₐ₁₂₃₀ | L_{b52} |
| 1231 | Lₐ₁₂₃₁ | L_{b52} | 1232 | Lₐ₁₂₃₂ | L_{b52} | 1233 | Lₐ₁₂₃₃ | L_{b52} |
| 1234 | Lₐ₁₂₃₄ | L_{b52} | 1235 | Lₐ₁₂₃₅ | L_{b52} | 1236 | Lₐ₁₂₃₆ | L_{b52} |
| 1237 | Lₐ₁₂₃₇ | L_{b52} | 1238 | Lₐ₁₂₃₈ | L_{b52} | 1239 | Lₐ₁₂₃₉ | L_{b52} |
| 1240 | Lₐ₁₂₄₀ | L_{b52} | 1241 | Lₐ₁₂₄₁ | L_{b52} | 1242 | Lₐ₁₂₄₂ | L_{b52} |
| 1243 | Lₐ₁₂₄₃ | L_{b52} | 1244 | Lₐ₁₂₄₄ | L_{b52} | 1245 | Lₐ₁₂₄₅ | L_{b52} |
| 1246 | Lₐ₁₂₄₆ | L_{b52} | 1247 | Lₐ₁₂₄₇ | L_{b52} | 1248 | Lₐ₁₂₄₈ | L_{b52} |
| 1249 | Lₐ₁₂₄₉ | L_{b52} | 1250 | Lₐ₁₂₅₀ | L_{b52} | 1251 | Lₐ₁₂₅₁ | L_{b52} |
| 1252 | Lₐ₁₂₅₂ | L_{b52} | 1253 | Lₐ₁₂₅₃ | L_{b52} | 1254 | Lₐ₁₂₅₄ | L_{b52} |
| 1255 | Lₐ₁₂₅₅ | L_{b52} | 1256 | Lₐ₁₂₅₆ | L_{b52} | 1257 | Lₐ₁₂₅₇ | L_{b52} |
| 1258 | Lₐ₁₂₅₈ | L_{b52} | 1259 | Lₐ₁₂₅₉ | L_{b52} | 1260 | Lₐ₁₂₆₀ | L_{b52} |
| 1261 | Lₐ₁₂₆₁ | L_{b52} | 1262 | Lₐ₁₂₆₂ | L_{b52} | 1263 | Lₐ₁₂₆₃ | L_{b52} |
| 1264 | Lₐ₁₂₆₄ | L_{b52} | 1265 | Lₐ₁₂₆₅ | L_{b52} | 1266 | Lₐ₁₂₆₆ | L_{b52} |
| 1267 | Lₐ₁₂₆₇ | L_{b52} | 1268 | Lₐ₁₂₆₈ | L_{b52} | 1269 | Lₐ₁₂₆₉ | L_{b52} |
| 1270 | Lₐ₁₂₇₀ | L_{b52} | 1271 | Lₐ₁₂₇₁ | L_{b52} | 1272 | Lₐ₁₂₇₂ | L_{b52} |
| 1273 | Lₐ₁₂₇₃ | L_{b52} | 1274 | Lₐ₁₂₇₄ | L_{b52} | 1275 | Lₐ₁₂₇₅ | L_{b52} |
| 1276 | Lₐ₁₂₇₆ | L_{b52} | 1277 | Lₐ₁₂₇₇ | L_{b52} | 1278 | Lₐ₁₂₇₈ | L_{b52} |
| 1279 | Lₐ₁₂₇₉ | L_{b52} | 1280 | Lₐ₁₂₈₀ | L_{b52} | 1281 | Lₐ₁₂₈₁ | L_{b52} |
| 1282 | Lₐ₁₂₈₂ | L_{b52} | 1283 | Lₐ₁₂₈₃ | L_{b52} | 1284 | Lₐ₁₂₈₄ | L_{b52} |
| 1285 | Lₐ₁₂₈₅ | L_{b52} | 1286 | Lₐ₁₂₈₆ | L_{b52} | 1287 | Lₐ₁₂₈₇ | L_{b52} |
| 1288 | Lₐ₁₂₈₈ | L_{b52} | 1289 | Lₐ₁₂₈₉ | L_{b52} | 1290 | Lₐ₁₂₉₀ | L_{b52} |
| 1291 | Lₐ₁₂₉₁ | L_{b52} | 1292 | Lₐ₁₂₉₂ | L_{b52} | 1293 | Lₐ₁₂₉₃ | L_{b52} |
| 1294 | Lₐ₁₂₉₄ | L_{b52} | 1295 | Lₐ₁₂₉₅ | L_{b52} | 1296 | Lₐ₁₂₉₆ | L_{b52} |
| 1297 | Lₐ₁₂₉₇ | L_{b52} | 1298 | Lₐ₁₂₉₈ | L_{b52} | 1299 | Lₐ₁₂₉₉ | L_{b52} |
| 1300 | Lₐ₁₃₀₀ | L_{b52} | 1301 | Lₐ₁₃₀₁ | L_{b52} | 1302 | Lₐ₁₃₀₂ | L_{b52} |
| 1303 | Lₐ₁₃₀₃ | L_{b52} | 1304 | Lₐ₁₃₀₄ | L_{b52} | 1305 | Lₐ₁₃₀₅ | L_{b52} |
| 1306 | Lₐ₁₃₀₆ | L_{b52} | 1307 | Lₐ₁₃₀₇ | L_{b52} | 1308 | Lₐ₁₃₀₈ | L_{b52} |
| 1309 | Lₐ₁₃₀₉ | L_{b52} | 1310 | Lₐ₁₃₁₀ | L_{b52} | 1311 | Lₐ₁₃₁₁ | L_{b52} |
| 1312 | Lₐ₁₃₁₂ | L_{b52} | 1313 | Lₐ₁₃₁₃ | L_{b52} | 1314 | Lₐ₁₃₁₄ | L_{b52} |
| 1315 | Lₐ₁₃₁₅ | L_{b52} | 1316 | Lₐ₁₃₁₆ | L_{b52} | 1317 | Lₐ₁₃₁₇ | L_{b52} |
| 1318 | Lₐ₁₃₁₈ | L_{b52} | 1319 | Lₐ₁₃₁₉ | L_{b52} | 1320 | Lₐ₁₃₂₀ | L_{b52} |
| 1321 | Lₐ₁₃₂₁ | L_{b52} | 1322 | Lₐ₁₃₂₂ | L_{b52} | 1323 | Lₐ₁₃₂₃ | L_{b52} |
| 1324 | Lₐ₁₃₂₄ | L_{b52} | 1325 | Lₐ₁₃₂₅ | L_{b52} | 1326 | Lₐ₁₃₂₆ | L_{b52} |
| 1327 | Lₐ₁₃₂₇ | L_{b52} | 1328 | Lₐ₁₃₂₈ | L_{b52} | 1329 | Lₐ₁₃₂₉ | L_{b52} |
| 1330 | Lₐ₁₃₃₀ | L_{b52} | 1331 | Lₐ₁₃₃₁ | L_{b52} | 1332 | Lₐ₁₃₃₂ | L_{b52} |
| 1333 | Lₐ₁₃₃₃ | L_{b52} | 1334 | Lₐ₁₃₃₄ | L_{b52} | 1335 | Lₐ₁₃₃₅ | L_{b52} |
| 1336 | Lₐ₁₃₃₆ | L_{b52} | 1337 | Lₐ₁₃₃₇ | L_{b52} | 1338 | Lₐ₁₃₃₈ | L_{b52} |
| 1339 | Lₐ₁₃₃₉ | L_{b52} | 1340 | Lₐ₁₃₄₀ | L_{b52} | 1341 | Lₐ₁₃₄₁ | L_{b52} |
| 1342 | Lₐ₁₃₄₂ | L_{b52} | 1343 | Lₐ₁₃₄₃ | L_{b52} | 1344 | Lₐ₁₃₄₄ | L_{b52} |
| 1345 | Lₐ₁₃₄₅ | L_{b52} | 1346 | Lₐ₁₃₄₆ | L_{b52} | 1347 | Lₐ₁₃₄₇ | L_{b52} |
| 1348 | Lₐ₁₃₄₈ | L_{b52} | 1349 | Lₐ₁₃₄₉ | L_{b52} | 1350 | Lₐ₁₃₅₀ | L_{b52} |
| 1351 | Lₐ₁₃₅₁ | L_{b52} | 1352 | Lₐ₁₃₅₂ | L_{b52} | 1353 | Lₐ₁₃₅₃ | L_{b52} |
| 1354 | Lₐ₁₃₅₄ | L_{b52} | 1355 | Lₐ₁₃₅₅ | L_{b52} | 1356 | Lₐ₁₃₅₆ | L_{b52} |
| 1357 | Lₐ₁₃₅₇ | L_{b52} | 1358 | Lₐ₁₃₅₈ | L_{b52} | 1359 | Lₐ₁₃₅₉ | L_{b52} |
| 1360 | Lₐ₁₃₆₀ | L_{b52} | 1361 | Lₐ₁₃₆₁ | L_{b52} | 1362 | Lₐ₁₃₆₂ | L_{b52} |
| 1363 | Lₐ₁₃₆₃ | L_{b52} | 1364 | Lₐ₁₃₆₄ | L_{b52} | 1365 | Lₐ₁₃₆₅ | L_{b52} |
| 1366 | Lₐ₁₃₆₆ | L_{b52} | 1367 | Lₐ₁₃₆₇ | L_{b52} | 1368 | Lₐ₁₃₆₈ | L_{b52} |
| 1369 | Lₐ₁₃₆₉ | L_{b52} | 1370 | Lₐ₁₃₇₀ | L_{b52} | 1371 | Lₐ₁₃₇₁ | L_{b52} |
| 1372 | Lₐ₁₃₇₂ | L_{b52} | 1373 | Lₐ₁₃₇₃ | L_{b52} | 1374 | Lₐ₁₃₇₄ | L_{b52} |
| 1375 | Lₐ₁₃₇₅ | L_{b52} | 1376 | Lₐ₁₃₇₆ | L_{b52} | 1377 | Lₐ₁₃₇₇ | L_{b52} |
| 1378 | Lₐ₁₃₇₈ | L_{b52} | 1379 | Lₐ₁₃₇₉ | L_{b52} | 1380 | Lₐ₁₃₈₀ | L_{b52} |
| 1381 | Lₐ₁₃₈₁ | L_{b52} | 1382 | Lₐ₁₃₈₂ | L_{b52} | 1383 | Lₐ₁₃₈₃ | L_{b52} |
| 1384 | Lₐ₁₃₈₄ | L_{b52} | 1385 | Lₐ₁₃₈₅ | L_{b52} | 1386 | Lₐ₁₃₈₆ | L_{b52} |
| 1387 | Lₐ₁₃₈₇ | L_{b52} | 1388 | Lₐ₁₃₈₈ | L_{b52} | 1389 | Lₐ₁₃₈₉ | L_{b52} |
| 1390 | Lₐ₁₃₉₀ | L_{b52} | 1391 | Lₐ₁₃₉₁ | L_{b52} | 1392 | Lₐ₁₃₉₂ | L_{b52} |
| 1393 | Lₐ₁₃₉₃ | L_{b52} | 1394 | Lₐ₁₃₉₄ | L_{b52} | 1395 | Lₐ₁₃₉₅ | L_{b52} |
| 1396 | Lₐ₁₃₉₆ | L_{b52} | 1397 | Lₐ₁₃₉₇ | L_{b52} | 1398 | Lₐ₁₃₉₈ | L_{b52} |
| 1399 | Lₐ₁₃₉₉ | L_{b52} | 1400 | Lₐ₁₄₀₀ | L_{b52} | 1401 | Lₐ₁₄₀₁ | L_{b52} |
| 1402 | Lₐ₁₄₀₂ | L_{b52} | 1403 | Lₐ₁₄₀₃ | L_{b52} | 1404 | Lₐ₁₄₀₄ | L_{b52} |
| 1405 | Lₐ₁₄₀₅ | L_{b52} | 1406 | Lₐ₁₄₀₆ | L_{b52} | 1407 | Lₐ₁₄₀₇ | L_{b52} |
| 1408 | Lₐ₁₄₀₈ | L_{b52} | 1409 | Lₐ₁₄₀₉ | L_{b52} | 1410 | Lₐ₁₄₁₀ | L_{b52} |
| 1411 | Lₐ₁₄₁₁ | L_{b52} | 1412 | Lₐ₁₄₁₂ | L_{b52} | 1413 | Lₐ₁₄₁₃ | L_{b52} |
| 1414 | Lₐ₁₄₁₄ | L_{b52} | 1415 | Lₐ₁₄₁₅ | L_{b52} | 1416 | Lₐ₁₄₁₆ | L_{b52} |
| 1417 | Lₐ₁₄₁₇ | L_{b52} | 1418 | Lₐ₁₄₁₈ | L_{b52} | 1419 | Lₐ₁₄₁₉ | L_{b52} |
| 1420 | Lₐ₁₄₂₀ | L_{b52} | 1421 | Lₐ₁₄₂₁ | L_{b52} | 1422 | Lₐ₁₄₂₂ | L_{b52} |
| 1423 | Lₐ₁₄₂₃ | L_{b52} | 1424 | Lₐ₁₄₂₄ | L_{b52} | 1425 | Lₐ₁₄₂₅ | L_{b52} |
| 1426 | Lₐ₁₄₂₆ | L_{b52} | 1427 | Lₐ₁₄₂₇ | L_{b52} | 1428 | Lₐ₁₄₂₈ | L_{b52} |
| 1429 | Lₐ₁₄₂₉ | L_{b52} | 1430 | Lₐ₁₄₃₀ | L_{b52} | 1431 | Lₐ₁₄₃₁ | L_{b52} |
| 1432 | Lₐ₁₄₃₂ | L_{b52} | 1433 | Lₐ₁₄₃₃ | L_{b52} | 1434 | Lₐ₁₄₃₄ | L_{b52} |
| 1435 | Lₐ₁₄₃₅ | L_{b52} | 1436 | Lₐ₁₄₃₆ | L_{b52} | 1437 | Lₐ₁₄₃₇ | L_{b52} |
| 1438 | Lₐ₁₄₃₈ | L_{b52} | 1439 | Lₐ₁₄₃₉ | L_{b52} | 1440 | Lₐ₁₄₄₀ | L_{b52} |
| 1441 | Lₐ₁₄₄₁ | L_{b52} | 1442 | Lₐ₁₄₄₂ | L_{b52} | 1443 | Lₐ₁₄₄₃ | L_{b52} |
| 1444 | Lₐ₁₄₄₄ | L_{b52} | 1445 | Lₐ₁₄₄₅ | L_{b52} | 1446 | Lₐ₁₄₄₆ | L_{b52} |
| 1447 | Lₐ₁₄₄₇ | L_{b52} | 1448 | Lₐ₁₄₄₈ | L_{b52} | 1449 | Lₐ₁₄₄₉ | L_{b52} |
| 1450 | Lₐ₁₄₅₀ | L_{b52} | 1451 | Lₐ₁₄₅₁ | L_{b52} | 1452 | Lₐ₁₄₅₂ | L_{b52} |
| 1453 | Lₐ₁₄₅₃ | L_{b52} | 1454 | Lₐ₁₄₅₄ | L_{b52} | 1455 | Lₐ₁₄₅₅ | L_{b52} |
| 1456 | Lₐ₁₄₅₆ | L_{b52} | 1457 | Lₐ₁₄₅₇ | L_{b52} | 1458 | Lₐ₁₄₅₈ | L_{b52} |
| 1459 | Lₐ₁₄₅₉ | L_{b52} | 1460 | Lₐ₁₄₆₀ | L_{b52} | 1461 | Lₐ₁₄₆₁ | L_{b52} |
| 1462 | Lₐ₁₄₆₂ | L_{b52} | 1463 | Lₐ₁₄₆₃ | L_{b52} | 1464 | Lₐ₁₄₆₄ | L_{b52} |
| 1465 | Lₐ₁₄₆₅ | L_{b52} | 1466 | Lₐ₁₄₆₆ | L_{b52} | 1467 | Lₐ₁₄₆₇ | L_{b52} |
| 1468 | Lₐ₁₄₆₈ | L_{b52} | 1469 | Lₐ₁₄₆₉ | L_{b52} | 1470 | Lₐ₁₄₇₀ | L_{b52} |
| 1471 | Lₐ₁₄₇₁ | L_{b52} | 1472 | Lₐ₁₄₇₂ | L_{b52} | 1473 | Lₐ₁₄₇₃ | L_{b52} |
| 1474 | Lₐ₁₄₇₄ | L_{b52} | 1475 | Lₐ₁₄₇₅ | L_{b52} | 1476 | Lₐ₁₄₇₆ | L_{b52} |
| 1477 | Lₐ₁₄₇₇ | L_{b52} | 1478 | Lₐ₁₄₇₈ | L_{b52} | 1479 | Lₐ₁₄₇₉ | L_{b52} |
| 1480 | Lₐ₁₄₈₀ | L_{b52} | 1481 | Lₐ₁₄₈₁ | L_{b52} | 1482 | Lₐ₁₄₈₂ | L_{b52} |
| 1483 | Lₐ₁₄₈₃ | L_{b52} | 1484 | Lₐ₁₄₈₄ | L_{b52} | 1485 | Lₐ₁₄₈₅ | L_{b52} |
| 1486 | Lₐ₁₄₈₆ | L_{b52} | 1487 | Lₐ₁₄₈₇ | L_{b52} | 1488 | Lₐ₁₄₈₈ | L_{b52} |
| 1489 | Lₐ₁₄₈₉ | L_{b52} | 1490 | Lₐ₁₄₉₀ | L_{b52} | 1491 | Lₐ₁₄₉₁ | L_{b52} |
| 1492 | Lₐ₁₄₉₂ | L_{b52} | 1493 | Lₐ₁₄₉₃ | L_{b52} | 1494 | Lₐ₁₄₉₄ | L_{b52} |
| 1495 | Lₐ₁₄₉₅ | L_{b52} | 1496 | Lₐ₁₄₉₆ | L_{b52} | 1497 | Lₐ₁₄₉₇ | L_{b52} |
| 1498 | Lₐ₁₄₉₈ | L_{b52} | 1499 | Lₐ₁₄₉₉ | L_{b52} | 1500 | Lₐ₁₅₀₀ | L_{b52} |
| 1501 | Lₐ₁₅₀₁ | L_{b52} | 1502 | Lₐ₁₅₀₂ | L_{b52} | 1503 | Lₐ₁₅₀₃ | L_{b52} |
| 1504 | Lₐ₁₅₀₄ | L_{b52} | 1505 | Lₐ₁₅₀₅ | L_{b52} | 1506 | Lₐ₁₅₀₆ | L_{b52} |
| 1507 | Lₐ₁₅₀₇ | L_{b52} | 1508 | Lₐ₁₅₀₈ | L_{b52} | 1509 | Lₐ₁₅₀₉ | L_{b52} |
| 1510 | Lₐ₁₅₁₀ | L_{b52} | 1511 | Lₐ₁₅₁₁ | L_{b52} | 1512 | Lₐ₁₅₁₂ | L_{b52} |
| 1513 | Lₐ₁₅₁₃ | L_{b52} | 1514 | Lₐ₁₅₁₄ | L_{b52} | 1515 | Lₐ₁₅₁₅ | L_{b52} |
| 1516 | Lₐ₁₅₁₆ | L_{b52} | 1517 | Lₐ₁₅₁₇ | L_{b52} | 1518 | Lₐ₁₅₁₈ | L_{b52} |
| 1519 | Lₐ₁₅₁₉ | L_{b52} | 1520 | Lₐ₁₅₂₀ | L_{b52} | 1521 | Lₐ₁₅₂₁ | L_{b52} |
| 1522 | Lₐ₁₅₂₂ | L_{b52} | 1523 | Lₐ₁₅₂₃ | L_{b52} | 1524 | Lₐ₁₅₂₄ | L_{b52} |
| 1525 | Lₐ₁₅₂₅ | L_{b52} | 1526 | Lₐ₁₅₂₆ | L_{b52} | 1527 | Lₐ₁₅₂₇ | L_{b52} |
| 1528 | Lₐ₁₅₂₈ | L_{b52} | 1529 | Lₐ₁₅₂₉ | L_{b52} | 1530 | Lₐ₁₅₃₀ | L_{b52} |
| 1531 | Lₐ₁₅₃₁ | L_{b52} | 1532 | Lₐ₁₅₃₂ | L_{b52} | 1533 | Lₐ₁₅₃₃ | L_{b52} |
| 1534 | Lₐ₁₅₃₄ | L_{b52} | 1535 | Lₐ₁₅₃₅ | L_{b52} | 1536 | Lₐ₁₅₃₆ | L_{b52} |
| 1537 | Lₐ₁₅₃₇ | L_{b52} | 1538 | Lₐ₁₅₃₈ | L_{b52} | 1539 | Lₐ₁₅₃₉ | L_{b52} |
| 1540 | Lₐ₁₅₄₀ | L_{b52} | 1541 | Lₐ₁₅₄₁ | L_{b52} | 1542 | Lₐ₁₅₄₂ | L_{b52} |
| 1543 | Lₐ₁₅₄₃ | L_{b52} | 1544 | Lₐ₁₅₄₄ | L_{b52} | 1545 | Lₐ₁₅₄₅ | L_{b52} |
| 1546 | Lₐ₁₅₄₆ | L_{b52} | 1547 | Lₐ₁₅₄₇ | L_{b52} | 1548 | Lₐ₁₅₄₈ | L_{b52} |
| 1549 | Lₐ₁₅₄₉ | L_{b52} | 1550 | Lₐ₁₅₅₀ | L_{b52} | 1551 | Lₐ₁₅₅₁ | L_{b52} |
| 1552 | Lₐ₁₅₅₂ | L_{b52} | 1553 | Lₐ₁₅₅₃ | L_{b52} | 1554 | Lₐ₁₅₅₄ | L_{b52} |
| 1555 | Lₐ₁₅₅₅ | L_{b52} | 1556 | Lₐ₁₅₅₆ | L_{b52} | 1557 | Lₐ₁₅₅₇ | L_{b52} |
| 1558 | Lₐ₁₅₅₈ | L_{b52} | 1559 | Lₐ₁₅₅₉ | L_{b52} | 1560 | Lₐ₁₅₆₀ | L_{b52} |
| 1561 | Lₐ₁₅₆₁ | L_{b52} | 1562 | Lₐ₁₅₆₂ | L_{b52} | 1563 | Lₐ₁₅₆₃ | L_{b52} |
| 1564 | Lₐ₁₅₆₄ | L_{b52} | 1565 | Lₐ₁₅₆₅ | L_{b52} | 1566 | Lₐ₁₅₆₆ | L_{b52} |
| 1567 | Lₐ₁₅₆₇ | L_{b52} | 1568 | Lₐ₁₅₆₈ | L_{b52} | 1569 | Lₐ₁₅₆₉ | L_{b52} |
| 1570 | Lₐ₁₅₇₀ | L_{b52} | 1571 | Lₐ₁₅₇₁ | L_{b52} | 1572 | Lₐ₁₅₇₂ | L_{b52} |
| 1573 | Lₐ₁₅₇₃ | L_{b52} | 1574 | Lₐ₁₅₇₄ | L_{b52} | 1575 | Lₐ₁₅₇₅ | L_{b52} |
| 1576 | Lₐ₁₅₇₆ | L_{b52} | 1577 | Lₐ₁₅₇₇ | L_{b52} | 1578 | Lₐ₁₅₇₈ | L_{b52} |
| 1579 | Lₐ₁₅₇₉ | L_{b52} | 1580 | Lₐ₁₅₈₀ | L_{b52} | 1581 | Lₐ₁₅₈₁ | L_{b52} |
| 1582 | Lₐ₁₅₈₂ | L_{b52} | 1583 | Lₐ₁₅₈₃ | L_{b52} | 1584 | Lₐ₁₅₈₄ | L_{b52} |
| 1585 | Lₐ₁₅₈₅ | L_{b52} | 1586 | Lₐ₁₅₈₆ | L_{b52} | 1587 | Lₐ₁₅₈₇ | L_{b52} |
| 1588 | Lₐ₁₅₈₈ | L_{b52} | 1589 | Lₐ₁₅₈₉ | L_{b52} | 1590 | Lₐ₁₅₉₀ | L_{b52} |
| 1591 | Lₐ₁₅₉₁ | L_{b52} | 1592 | Lₐ₁₅₉₂ | L_{b52} | 1593 | Lₐ₁₅₉₃ | L_{b52} |
| 1594 | Lₐ₁₅₉₄ | L_{b52} | 1595 | Lₐ₁₅₉₅ | L_{b52} | 1596 | Lₐ₁₅₉₆ | L_{b52} |
| 1597 | Lₐ₁₅₉₇ | L_{b52} | 1598 | Lₐ₁₅₉₈ | L_{b52} | 1599 | Lₐ₁₅₉₉ | L_{b52} |
| 1600 | Lₐ₁₆₀₀ | L_{b52} | 1601 | Lₐ₁₆₀₁ | L_{b52} | 1602 | Lₐ₁₆₀₂ | L_{b52} |
| 1603 | Lₐ₁₆₀₃ | L_{b52} | 1604 | Lₐ₁₆₀₄ | L_{b52} | 1605 | Lₐ₁₆₀₅ | L_{b52} |
| 1606 | Lₐ₁₆₀₆ | L_{b52} | 1607 | Lₐ₁₆₀₇ | L_{b52} | 1608 | Lₐ₁₆₀₈ | L_{b52} |
| 1609 | Lₐ₁₆₀₉ | L_{b52} | 1610 | Lₐ₁₆₁₀ | L_{b52} | 1611 | Lₐ₁₆₁₁ | L_{b52} |
| 1612 | Lₐ₁₆₁₂ | L_{b52} | 1613 | Lₐ₁₆₁₃ | L_{b52} | 1614 | Lₐ₁₆₁₄ | L_{b52} |
| 1615 | Lₐ₁₆₁₅ | L_{b52} | 1616 | Lₐ₁₆₁₆ | L_{b52} | 1617 | Lₐ₁₆₁₇ | L_{b52} |
| 1618 | Lₐ₁₆₁₈ | L_{b52} | 1619 | Lₐ₁₆₁₉ | L_{b52} | 1620 | Lₐ₁₆₂₀ | L_{b52} |
| 1621 | Lₐ₁₆₂₁ | L_{b52} | 1622 | Lₐ₁₆₂₂ | L_{b52} | 1623 | Lₐ₁₆₂₃ | L_{b52} |
| 1624 | Lₐ₁₆₂₄ | L_{b52} | 1625 | Lₐ₁₆₂₅ | L_{b52} | 1626 | Lₐ₁₆₂₆ | L_{b52} |
| 1627 | Lₐ₁₆₂₇ | L_{b52} | 1628 | Lₐ₁₆₂₈ | L_{b52} | 1629 | Lₐ₁₆₂₉ | L_{b52} |
| 1630 | Lₐ₁₆₃₀ | L_{b52} | 1631 | Lₐ₁₆₃₁ | L_{b52} | 1632 | Lₐ₁₆₃₂ | L_{b52} |
| 1633 | Lₐ₁₆₃₃ | L_{b52} | 1634 | Lₐ₁₆₃₄ | L_{b52} | 1635 | Lₐ₁₆₃₅ | L_{b52} |
| 1636 | Lₐ₁₆₃₆ | L_{b52} | 1637 | Lₐ₁₆₃₇ | L_{b52} | 1638 | Lₐ₁₆₃₈ | L_{b52} |
| 1639 | Lₐ₁₆₃₉ | L_{b52} | 1640 | Lₐ₁₆₄₀ | L_{b52} | 1641 | Lₐ₁₆₄₁ | L_{b52} |
| 1642 | Lₐ₁₆₄₂ | L_{b52} | 1643 | Lₐ₁₆₄₃ | L_{b52} | 1644 | Lₐ₁₆₄₄ | L_{b52} |
| 1645 | Lₐ₁₆₄₅ | L_{b52} | 1646 | Lₐ₁₆₄₆ | L_{b52} | 1647 | Lₐ₁₆₄₇ | L_{b52} |
| 1648 | Lₐ₁₆₄₈ | L_{b52} | 1649 | Lₐ₁₆₄₉ | L_{b52} | 1650 | Lₐ₁₆₅₀ | L_{b52} |
| 1651 | Lₐ₁₆₅₁ | L_{b52} | 1652 | Lₐ₁₆₅₂ | L_{b52} | 1653 | Lₐ₁₆₅₃ | L_{b52} |
| 1654 | Lₐ₁₆₅₄ | L_{b52} | 1655 | Lₐ₁₆₅₅ | L_{b52} | 1656 | Lₐ₁₆₅₆ | L_{b52} |
| 1657 | Lₐ₁₆₅₇ | L_{b52} | 1658 | Lₐ₁₆₅₈ | L_{b52} | 1659 | Lₐ₁₆₅₉ | L_{b52} |
| 1660 | Lₐ₁₆₆₀ | L_{b52} | 1661 | Lₐ₁₆₆₁ | L_{b52} | 1662 | Lₐ₁₆₆₂ | L_{b52} |
| 1663 | Lₐ₁₆₆₃ | L_{b52} | 1664 | Lₐ₁₆₆₄ | L_{b52} | 1665 | Lₐ₁₆₆₅ | L_{b52} |
| 1666 | Lₐ₁₆₆₆ | L_{b52} | 1667 | Lₐ₁₆₆₇ | L_{b52} | 1668 | Lₐ₁₆₆₈ | L_{b52} |
| 1669 | Lₐ₁₆₆₉ | L_{b52} | 1670 | Lₐ₁₆₇₀ | L_{b52} | 1671 | Lₐ₁₆₇₁ | L_{b52} |
| 1672 | Lₐ₁₆₇₂ | L_{b52} | 1673 | Lₐ₁₆₇₃ | L_{b52} | 1674 | Lₐ₁₆₇₄ | L_{b52} |
| 1675 | Lₐ₁₆₇₅ | L_{b52} | 1676 | Lₐ₁₆₇₆ | L_{b52} | 1677 | Lₐ₁₆₇₇ | L_{b52} |
| 1678 | Lₐ₁₆₇₈ | L_{b52} | 1679 | Lₐ₁₆₇₉ | L_{b52} | 1680 | Lₐ₁₆₈₀ | L_{b52} |
| 1681 | Lₐ₁₆₈₁ | L_{b52} | 1682 | Lₐ₁₆₈₂ | L_{b52} | 1683 | Lₐ₁₆₈₃ | L_{b52} |
| 1684 | Lₐ₁₆₈₄ | L_{b52} | 1685 | Lₐ₁₆₈₅ | L_{b52} | 1686 | Lₐ₁₆₈₆ | L_{b52} |
| 1687 | Lₐ₁₆₈₇ | L_{b52} | 1688 | Lₐ₁₆₈₈ | L_{b52} | 1689 | Lₐ₁₆₈₉ | L_{b52} |
| 1690 | Lₐ₁₆₉₀ | L_{b52} | 1691 | Lₐ₁₆₉₁ | L_{b52} | 1692 | Lₐ₁₆₉₂ | L_{b52} |
| 1693 | Lₐ₁₆₉₃ | L_{b52} | 1694 | Lₐ₁₆₉₄ | L_{b52} | 1695 | Lₐ₁₆₉₅ | L_{b52} |
| 1696 | Lₐ₁₆₉₆ | L_{b52} | 1697 | Lₐ₁₆₉₇ | L_{b52} | 1698 | Lₐ₁₆₉₈ | L_{b52} |
| 1699 | Lₐ₁₆₉₉ | L_{b52} | 1700 | Lₐ₁₇₀₀ | L_{b52} | 1701 | Lₐ₁₇₀₁ | L_{b52} |
| 1702 | Lₐ₁₇₀₂ | L_{b52} | 1703 | Lₐ₁₇₀₃ | L_{b52} | 1704 | Lₐ₁₇₀₄ | L_{b52} |
| 1705 | Lₐ₁₇₀₅ | L_{b52} | 1706 | Lₐ₁₇₀₆ | L_{b52} | 1707 | Lₐ₁₇₀₇ | L_{b52} |
| 1708 | Lₐ₁₇₀₈ | L_{b52} | 1709 | Lₐ₁₇₀₉ | L_{b52} | 1710 | Lₐ₁₇₁₀ | L_{b52} |
| 1711 | Lₐ₁₇₁₁ | L_{b52} | 1712 | Lₐ₁₇₁₂ | L_{b52} | 1713 | Lₐ₁₇₁₃ | L_{b52} |
| 1714 | Lₐ₁₇₁₄ | L_{b52} | 1715 | Lₐ₁₇₁₅ | L_{b52} | 1716 | Lₐ₁₇₁₆ | L_{b52} |
| 1717 | Lₐ₁₇₁₇ | L_{b52} | 1718 | Lₐ₁₇₁₈ | L_{b52} | 1719 | Lₐ₁₇₁₉ | L_{b52} |
| 1720 | Lₐ₁₇₂₀ | L_{b52} | 1721 | Lₐ₁₇₂₁ | L_{b52} | 1722 | Lₐ₁₇₂₂ | L_{b52} |
| 1723 | Lₐ₁₇₂₃ | L_{b52} | 1724 | Lₐ₁₇₂₄ | L_{b52} | 1725 | Lₐ₁₇₂₅ | L_{b52} |
| 1726 | Lₐ₁₇₂₆ | L_{b52} | 1727 | Lₐ₁₇₂₇ | L_{b52} | 1728 | Lₐ₁₇₂₈ | L_{b52} |
| 1729 | Lₐ₁₇₂₉ | L_{b52} | 1730 | Lₐ₁₇₃₀ | L_{b52} | 1731 | Lₐ₁₇₃₁ | L_{b52} |
| 1732 | Lₐ₁₇₃₂ | L_{b52} | 1733 | Lₐ₁₇₃₃ | L_{b52} | 1734 | Lₐ₁₇₃₄ | L_{b52} |
| 1735 | Lₐ₁₇₃₅ | L_{b52} | 1736 | Lₐ₁₇₃₆ | L_{b52} | 1737 | Lₐ₁₇₃₇ | L_{b52} |
| 1738 | Lₐ₁₇₃₈ | L_{b52} | 1739 | Lₐ₁₇₃₉ | L_{b52} | 1740 | Lₐ₁₇₄₀ | L_{b52} |
| 1741 | Lₐ₁₇₄₁ | L_{b52} | 1742 | Lₐ₁₇₄₂ | L_{b52} | 1743 | Lₐ₁₇₄₃ | L_{b52} |
| 1744 | Lₐ₁₇₄₄ | L_{b52} | 1745 | Lₐ₁₇₄₅ | L_{b52} | 1746 | Lₐ₁₇₄₆ | L_{b52} |
| 1747 | Lₐ₁₇₄₇ | L_{b52} | 1748 | Lₐ₁₇₄₈ | L_{b52} | 1749 | Lₐ₁₇₄₉ | L_{b52} |
| 1750 | Lₐ₁₇₅₀ | L_{b52} | 1751 | Lₐ₁₇₅₁ | L_{b52} | 1752 | Lₐ₁₇₅₂ | L_{b52} |
| 1753 | Lₐ₁₇₅₃ | L_{b52} | 1754 | Lₐ₁₇₅₄ | L_{b52} | 1755 | Lₐ₁₇₅₅ | L_{b52} |
| 1756 | Lₐ₁₇₅₆ | L_{b52} | 1757 | Lₐ₁₇₅₇ | L_{b52} | 1758 | Lₐ₁₇₅₈ | L_{b52} |
| 1759 | Lₐ₁₇₅₉ | L_{b52} | 1760 | Lₐ₁₇₆₀ | L_{b52} | 1761 | Lₐ₁₇₆₁ | L_{b52} |
| 1762 | Lₐ₁₇₆₂ | L_{b52} | 1763 | Lₐ₁₇₆₃ | L_{b52} | 1764 | Lₐ₁₇₆₄ | L_{b52} |
| 1765 | Lₐ₁₇₆₅ | L_{b52} | 1766 | Lₐ₁₇₆₆ | L_{b52} | 1767 | Lₐ₁₇₆₇ | L_{b52} |
| 1768 | Lₐ₁₇₆₈ | L_{b52} | 1769 | Lₐ₁₇₆₉ | L_{b52} | 1770 | Lₐ₁₇₇₀ | L_{b52} |
| 1771 | Lₐ₁₇₇₁ | L_{b52} | 1772 | Lₐ₁₇₇₂ | L_{b52} | 1773 | Lₐ₁₇₇₃ | L_{b52} |
| 1774 | Lₐ₁₇₇₄ | L_{b52} | 1775 | Lₐ₁₇₇₅ | L_{b52} | 1776 | Lₐ₁₇₇₆ | L_{b52} |
| 1777 | Lₐ₁₇₇₇ | L_{b52} | 1778 | Lₐ₁₇₇₈ | L_{b52} | 1779 | Lₐ₁₇₇₉ | L_{b52} |
| 1780 | Lₐ₁₇₈₀ | L_{b52} | 1781 | Lₐ₁₇₈₁ | L_{b52} | 1782 | Lₐ₁₇₈₂ | L_{b52} |
| 1783 | Lₐ₁₇₈₃ | L_{b52} | 1784 | Lₐ₁₇₈₄ | L_{b52} | 1785 | Lₐ₁₇₈₅ | L_{b52} |
| 1786 | Lₐ₁₇₈₆ | L_{b52} | 1787 | Lₐ₁₇₈₇ | L_{b52} | 1788 | Lₐ₁₇₈₈ | L_{b52} |
| 1789 | Lₐ₁₇₈₉ | L_{b52} | 1790 | Lₐ₁₇₉₀ | L_{b52} | 1791 | Lₐ₁₇₉₁ | L_{b52} |
| 1792 | Lₐ₁₇₉₂ | L_{b52} | 1793 | Lₐ₁₇₉₃ | L_{b52} | 1794 | Lₐ₁₇₉₄ | L_{b52} |
| 1795 | Lₐ₁₇₉₅ | L_{b52} | 1796 | Lₐ₁₇₉₆ | L_{b52} | 1797 | Lₐ₁₇₉₇ | L_{b52} |
| 1798 | Lₐ₁₇₉₈ | L_{b52} | 1799 | Lₐ₁₇₉₉ | L_{b52} | 1800 | Lₐ₁₈₀₀ | L_{b52} |
| 1801 | Lₐ₁₈₀₁ | L_{b52} | 1802 | Lₐ₁₈₀₂ | L_{b52} | 1803 | Lₐ₁₈₀₃ | L_{b52} |
| 1804 | Lₐ₁₈₀₄ | L_{b52} | 1805 | Lₐ₁₈₀₅ | L_{b52} | 1806 | Lₐ₁₈₀₆ | L_{b52} |
| 1807 | Lₐ₁₈₀₇ | L_{b52} | 1808 | Lₐ₁₈₀₈ | L_{b52} | 1809 | Lₐ₁₈₀₉ | L_{b52} |
| 1810 | Lₐ₁₈₁₀ | L_{b52} | 1811 | Lₐ₁₈₁₁ | L_{b52} | 1812 | Lₐ₁₈₁₂ | L_{b52} |
| 1813 | Lₐ₁₈₁₃ | L_{b52} | 1814 | Lₐ₁₈₁₄ | L_{b52} | 1815 | Lₐ₁₈₁₅ | L_{b52} |
| 1816 | Lₐ₁₈₁₆ | L_{b52} | 1817 | Lₐ₁₈₁₇ | L_{b52} | 1818 | Lₐ₁₈₁₈ | L_{b52} |
| 1819 | Lₐ₁₈₁₉ | L_{b52} | 1820 | Lₐ₁₈₂₀ | L_{b52} | 1821 | Lₐ₁₈₂₁ | L_{b52} |
| 1822 | Lₐ₁₈₂₂ | L_{b52} | 1823 | Lₐ₁₈₂₃ | L_{b52} | 1824 | Lₐ₁₈₂₄ | L_{b52} |
| 1825 | Lₐ₁₈₂₅ | L_{b52} | 1826 | Lₐ₁₈₂₆ | L_{b52} | 1827 | Lₐ₁₈₂₇ | L_{b52} |
| 1828 | Lₐ₁₈₂₈ | L_{b52} | 1829 | Lₐ₁₈₂₉ | L_{b52} | 1830 | Lₐ₁₈₃₀ | L_{b52} |
| 1831 | Lₐ₁₈₃₁ | L_{b52} | 1832 | Lₐ₁₈₃₂ | L_{b52} | 1833 | Lₐ₁₈₃₃ | L_{b52} |
| 1834 | Lₐ₁₈₃₄ | L_{b52} | 1835 | Lₐ₁₈₃₅ | L_{b52} | 1836 | Lₐ₁₈₃₆ | L_{b52} |
| 1837 | Lₐ₁₈₃₇ | L_{b52} | 1838 | Lₐ₁₈₃₈ | L_{b52} | 1839 | Lₐ₁₈₃₉ | L_{b52} |
| 1840 | Lₐ₁₈₄₀ | L_{b52} | 1841 | Lₐ₁₈₄₁ | L_{b52} | 1842 | Lₐ₁₈₄₂ | L_{b52} |
| 1843 | Lₐ₁₈₄₃ | L_{b52} | 1844 | Lₐ₁₈₄₄ | L_{b52} | 1845 | Lₐ₁₈₄₅ | L_{b52} |
| 1846 | Lₐ₁₈₄₆ | L_{b52} | 1847 | Lₐ₁₈₄₇ | L_{b52} | 1848 | Lₐ₁₈₄₈ | L_{b52} |
| 1849 | Lₐ₁₈₄₉ | L_{b52} | 1850 | Lₐ₁₈₅₀ | L_{b52} | 1851 | Lₐ₁₈₅₁ | L_{b52} |
| 1852 | Lₐ₁₈₅₂ | L_{b52} | 1853 | Lₐ₁₈₅₃ | L_{b52} | 1854 | Lₐ₁₈₅₄ | L_{b52} |
| 1855 | Lₐ₁₈₅₅ | L_{b52} | 1856 | Lₐ₁₈₅₆ | L_{b52} | 1857 | Lₐ₁₈₅₇ | L_{b52} |
| 1858 | Lₐ₁₈₅₈ | L_{b52} | 1859 | Lₐ₁₈₅₉ | L_{b52} | 1860 | Lₐ₁₈₆₀ | L_{b52} |
| 1861 | Lₐ₁₈₆₁ | L_{b52} | 1862 | Lₐ₁₈₆₂ | L_{b52} | 1863 | Lₐ₁₈₆₃ | L_{b52} |
| 1864 | Lₐ₁₈₆₄ | L_{b52} | 1865 | Lₐ₁₈₆₅ | L_{b52} | 1866 | Lₐ₁₈₆₆ | L_{b52} |
| 1867 | Lₐ₁₈₆₇ | L_{b52} | 1868 | Lₐ₁₈₆₈ | L_{b52} | 1869 | Lₐ₁₈₆₉ | L_{b52} |
| 1870 | Lₐ₁₈₇₀ | L_{b52} | 1871 | Lₐ₁₈₇₁ | L_{b52} | 1872 | Lₐ₁₈₇₂ | L_{b52} |
| 1873 | Lₐ₁₈₇₃ | L_{b52} | 1874 | Lₐ₁₈₇₄ | L_{b52} | 1875 | Lₐ₁₈₇₅ | L_{b52} |
| 1876 | Lₐ₁₈₇₆ | L_{b52} | 1877 | Lₐ₁₈₇₇ | L_{b52} | 1878 | Lₐ₁₈₇₈ | L_{b52} |
| 1879 | Lₐ₁₈₇₉ | L_{b52} | 1880 | Lₐ₁₈₈₀ | L_{b52} | 1881 | Lₐ₁₈₈₁ | L_{b52} |
| 1882 | Lₐ₁ | L_{b135} | 1883 | Lₐ₂ | L_{b135} | 1884 | Lₐ₃ | L_{b135} |
| 1885 | Lₐ₄ | L_{b135} | 1886 | Lₐ₅ | L_{b135} | 1887 | Lₐ₆ | L_{b135} |
| 1888 | Lₐ₇ | L_{b135} | 1889 | Lₐ₈ | L_{b135} | 1890 | Lₐ₉ | L_{b135} |
| 1891 | Lₐ₁₀ | L_{b135} | 1892 | Lₐ₁₁ | L_{b135} | 1893 | Lₐ₁₂ | L_{b135} |
| 1894 | Lₐ₁₃ | L_{b135} | 1895 | Lₐ₁₄ | L_{b135} | 1896 | Lₐ₁₅ | L_{b135} |
| 1897 | Lₐ₁₆ | L_{b135} | 1898 | Lₐ₁₇ | L_{b52} | 1899 | Lₐ₁₈ | L_{b135} |
| 1900 | Lₐ₁₉ | L_{b135} | 1901 | Lₐ₂₀ | L_{b135} | 1902 | Lₐ₂₁ | L_{b135} |
| 1903 | Lₐ₂₂ | L_{b135} | 1904 | Lₐ₂₃ | L_{b135} | 1905 | Lₐ₂₄ | L_{b135} |
| 1906 | Lₐ₂₅ | L_{b135} | 1907 | Lₐ₂₆ | L_{b135} | 1908 | Lₐ₂₇ | L_{b135} |
| 1909 | Lₐ₂₈ | L_{b135} | 1910 | Lₐ₂₉ | L_{b135} | 1911 | Lₐ₃₀ | L_{b135} |
| 1912 | Lₐ₃₁ | L_{b135} | 1913 | Lₐ₃₂ | L_{b135} | 1914 | Lₐ₃₃ | L_{b135} |
| 1915 | Lₐ₃₄ | L_{b135} | 1916 | Lₐ₃₅ | L_{b52} | 1917 | Lₐ₃₆ | L_{b135} |
| 1918 | Lₐ₃₇ | L_{b135} | 1919 | Lₐ₃₈ | L_{b135} | 1920 | Lₐ₃₉ | L_{b135} |
| 1921 | Lₐ₄₀ | L_{b135} | 1922 | Lₐ₄₁ | L_{b135} | 1923 | Lₐ₄₂ | L_{b135} |
| 1924 | Lₐ₄₃ | L_{b135} | 1925 | Lₐ₄₄ | L_{b135} | 1926 | Lₐ₄₅ | L_{b135} |
| 1927 | Lₐ₄₆ | L_{b135} | 1928 | Lₐ₄₇ | L_{b135} | 1929 | Lₐ₄₈ | L_{b135} |
| 1930 | Lₐ₄₉ | L_{b135} | 1931 | Lₐ₅₀ | L_{b135} | 1932 | Lₐ₅₁ | L_{b135} |
| 1933 | Lₐ₅₂ | L_{b135} | 1934 | Lₐ₅₃ | L_{b52} | 1935 | Lₐ₅₄ | L_{b135} |
| 1936 | Lₐ₅₅ | L_{b135} | 1937 | Lₐ₅₆ | L_{b135} | 1938 | Lₐ₅₇ | L_{b135} |
| 1939 | Lₐ₅₈ | L_{b135} | 1940 | Lₐ₅₉ | L_{b135} | 1941 | Lₐ₆₀ | L_{b135} |
| 1942 | Lₐ₆₁ | L_{b135} | 1943 | Lₐ₆₂ | L_{b135} | 1944 | Lₐ₆₃ | L_{b135} |
| 1945 | Lₐ₆₄ | L_{b135} | 1946 | Lₐ₆₅ | L_{b135} | 1947 | Lₐ₆₆ | L_{b135} |
| 1948 | Lₐ₆₇ | L_{b135} | 1949 | Lₐ₆₈ | L_{b135} | 1950 | Lₐ₆₉ | L_{b135} |
| 1951 | Lₐ₇₀ | L_{b135} | 1952 | Lₐ₇₁ | L_{b52} | 1953 | Lₐ₇₂ | L_{b135} |
| 1954 | Lₐ₇₃ | L_{b135} | 1955 | Lₐ₇₄ | L_{b135} | 1956 | Lₐ₇₅ | L_{b135} |
| 1957 | Lₐ₇₆ | L_{b135} | 1958 | Lₐ₇₇ | L_{b135} | 1959 | Lₐ₇₈ | L_{b135} |
| 1960 | Lₐ₇₉ | L_{b135} | 1961 | Lₐ₈₀ | L_{b135} | 1962 | Lₐ₈₁ | L_{b135} |
| 1963 | Lₐ₈₂ | L_{b135} | 1964 | Lₐ₈₃ | L_{b135} | 1965 | Lₐ₈₄ | L_{b135} |
| 1966 | Lₐ₈₅ | L_{b135} | 1967 | Lₐ₈₆ | L_{b135} | 1968 | Lₐ₈₇ | L_{b135} |
| 1969 | Lₐ₈₈ | L_{b135} | 1970 | Lₐ₈₉ | L_{b52} | 1971 | Lₐ₉₀ | L_{b135} |
| 1972 | Lₐ₉₁ | L_{b135} | 1973 | Lₐ₉₂ | L_{b135} | 1974 | Lₐ₉₃ | L_{b135} |
| 1975 | Lₐ₉₄ | L_{b135} | 1976 | Lₐ₉₅ | L_{b135} | 1977 | Lₐ₉₆ | L_{b135} |
| 1978 | Lₐ₉₇ | L_{b135} | 1979 | Lₐ₉₈ | L_{b135} | 1980 | Lₐ₉₉ | L_{b135} |
| 1981 | Lₐ₁₀₀ | L_{b135} | 1982 | Lₐ₁₀₁ | L_{b135} | 1983 | Lₐ₁₀₂ | L_{b135} |
| 1984 | Lₐ₁₀₃ | L_{b135} | 1985 | Lₐ₁₀₄ | L_{b135} | 1986 | Lₐ₁₀₅ | L_{b135} |
| 1987 | Lₐ₁₀₆ | L_{b135} | 1988 | Lₐ₁₀₇ | L_{b52} | 1989 | Lₐ₁₀₈ | L_{b135} |
| 1990 | Lₐ₁₀₉ | L_{b135} | 1991 | Lₐ₁₁₀ | L_{b135} | 1992 | Lₐ₁₁₁ | L_{b135} |
| 1993 | Lₐ₁₁₂ | L_{b135} | 1994 | Lₐ₁₁₃ | L_{b135} | 1995 | Lₐ₁₁₄ | L_{b135} |
| 1996 | Lₐ₁₁₅ | L_{b135} | 1997 | Lₐ₁₁₆ | L_{b135} | 1998 | Lₐ₁₁₇ | L_{b135} |
| 1999 | Lₐ₁₁₈ | L_{b135} | 2000 | Lₐ₁₁₉ | L_{b135} | 2001 | Lₐ₁₂₀ | L_{b135} |
| 2002 | Lₐ₁₂₁ | L_{b135} | 2003 | Lₐ₁₂₂ | L_{b135} | 2004 | Lₐ₁₂₃ | L_{b135} |
| 2005 | Lₐ₁₂₄ | L_{b135} | 2006 | Lₐ₁₂₅ | L_{b52} | 2007 | Lₐ₁₂₆ | L_{b135} |
| 2008 | Lₐ₁₂₇ | L_{b135} | 2009 | Lₐ₁₂₈ | L_{b135} | 2010 | Lₐ₁₂₉ | L_{b135} |
| 2011 | Lₐ₁₃₀ | L_{b135} | 2012 | Lₐ₁₃₁ | L_{b135} | 2013 | Lₐ₁₃₂ | L_{b135} |
| 2014 | Lₐ₁₃₃ | L_{b135} | 2015 | Lₐ₁₃₄ | L_{b135} | 2016 | Lₐ₁₃₅ | L_{b135} |
| 2017 | Lₐ₁₃₆ | L_{b135} | 2018 | Lₐ₁₃₇ | L_{b135} | 2019 | Lₐ₁₃₈ | L_{b135} |
| 2020 | Lₐ₁₃₉ | L_{b135} | 2021 | Lₐ₁₄₀ | L_{b135} | 2022 | Lₐ₁₄₁ | L_{b135} |
| 2023 | Lₐ₁₄₂ | L_{b135} | 2024 | Lₐ₁₄₃ | L_{b52} | 2025 | Lₐ₁₄₄ | L_{b135} |
| 2026 | Lₐ₁₄₅ | L_{b135} | 2027 | Lₐ₁₄₆ | L_{b135} | 2028 | Lₐ₁₄₇ | L_{b135} |
| 2029 | Lₐ₁₄₈ | L_{b135} | 2030 | Lₐ₁₄₉ | L_{b135} | 2031 | Lₐ₁₅₀ | L_{b135} |
| 2032 | Lₐ₁₅₁ | L_{b135} | 2033 | Lₐ₁₅₂ | L_{b135} | 2034 | Lₐ₁₅₃ | L_{b135} |
| 2035 | Lₐ₁₅₄ | L_{b135} | 2036 | Lₐ₁₅₅ | L_{b135} | 2037 | Lₐ₁₅₆ | L_{b135} |
| 2038 | Lₐ₁₅₇ | L_{b135} | 2039 | Lₐ₁₅₈ | L_{b135} | 2040 | Lₐ₁₅₉ | L_{b135} |
| 2041 | Lₐ₁₆₀ | L_{b135} | 2042 | Lₐ₁₆₁ | L_{b52} | 2043 | Lₐ₁₆₂ | L_{b135} |
| 2044 | Lₐ₁₆₃ | L_{b135} | 2045 | Lₐ₁₆₄ | L_{b135} | 2046 | Lₐ₁₆₅ | L_{b135} |
| 2047 | Lₐ₁₆₆ | L_{b135} | 2048 | Lₐ₁₆₇ | L_{b135} | 2049 | Lₐ₁₆₈ | L_{b135} |
| 2050 | Lₐ₁₆₉ | L_{b135} | 2051 | Lₐ₁₇₀ | L_{b135} | 2052 | Lₐ₁₇₁ | L_{b135} |
| 2053 | Lₐ₁₇₂ | L_{b135} | 2054 | Lₐ₁₇₃ | L_{b135} | 2055 | Lₐ₁₇₄ | L_{b135} |
| 2056 | Lₐ₁₇₅ | L_{b135} | 2057 | Lₐ₁₇₆ | L_{b135} | 2058 | Lₐ₁₇₇ | L_{b135} |
| 2059 | Lₐ₁₇₈ | L_{b135} | 2060 | Lₐ₁₇₉ | L_{b52} | 2061 | Lₐ₁₈₀ | L_{b135} |
| 2062 | Lₐ₁₈₁ | L_{b135} | 2063 | Lₐ₁₈₂ | L_{b135} | 2064 | Lₐ₁₈₃ | L_{b135} |
| 2065 | Lₐ₁₈₄ | L_{b135} | 2066 | Lₐ₁₈₅ | L_{b135} | 2067 | Lₐ₁₈₆ | L_{b135} |
| 2068 | Lₐ₁₈₇ | L_{b135} | 2069 | Lₐ₁₈₈ | L_{b135} | 2070 | Lₐ₁₈₉ | L_{b135} |
| 2071 | Lₐ₁₉₀ | L_{b135} | 2072 | Lₐ₁₉₁ | L_{b135} | 2073 | Lₐ₁₉₂ | L_{b135} |
| 2074 | Lₐ₁₉₃ | L_{b135} | 2075 | Lₐ₁₉₄ | L_{b135} | 2076 | Lₐ₁₉₅ | L_{b135} |
| 2077 | Lₐ₁₉₆ | L_{b135} | 2078 | Lₐ₁₉₇ | L_{b52} | 2079 | Lₐ₁₉₈ | L_{b135} |
| 2080 | Lₐ₁₉₉ | L_{b135} | 2081 | Lₐ₂₀₀ | L_{b135} | 2082 | Lₐ₂₀₁ | L_{b135} |
| 2083 | Lₐ₂₀₂ | L_{b135} | 2084 | Lₐ₂₀₃ | L_{b135} | 2085 | Lₐ₂₀₄ | L_{b135} |
| 2086 | Lₐ₂₀₅ | L_{b135} | 2087 | Lₐ₂₀₆ | L_{b135} | 2088 | Lₐ₂₀₇ | L_{b135} |
| 2089 | Lₐ₂₀₈ | L_{b135} | 2090 | Lₐ₂₀₉ | L_{b135} | 2091 | Lₐ₂₁₀ | L_{b135} |
| 2092 | Lₐ₂₁₁ | L_{b135} | 2093 | Lₐ₂₁₂ | L_{b135} | 2094 | Lₐ₂₁₃ | L_{b135} |
| 2095 | Lₐ₂₁₄ | L_{b135} | 2096 | Lₐ₂₁₅ | L_{b52} | 2097 | Lₐ₂₁₆ | L_{b135} |
| 2098 | Lₐ₂₁₇ | L_{b135} | 2099 | Lₐ₂₁₈ | L_{b135} | 2100 | Lₐ₂₁₉ | L_{b135} |
| 2101 | Lₐ₂₂₀ | L_{b135} | 2102 | Lₐ₂₂₁ | L_{b135} | 2103 | Lₐ₂₂₂ | L_{b135} |
| 2104 | Lₐ₂₂₃ | L_{b135} | 2105 | Lₐ₂₂₄ | L_{b135} | 2106 | Lₐ₂₂₅ | L_{b135} |
| 2107 | Lₐ₂₂₆ | L_{b135} | 2108 | Lₐ₂₂₇ | L_{b135} | 2109 | Lₐ₂₂₈ | L_{b135} |
| 2110 | Lₐ₂₂₉ | L_{b135} | 2111 | Lₐ₂₃₀ | L_{b135} | 2112 | Lₐ₂₃₁ | L_{b135} |
| 2113 | Lₐ₂₃₂ | L_{b135} | 2114 | Lₐ₂₃₃ | L_{b52} | 2115 | Lₐ₂₃₄ | L_{b135} |
| 2116 | Lₐ₂₃₅ | L_{b135} | 2117 | Lₐ₂₃₆ | L_{b135} | 2118 | Lₐ₂₃₇ | L_{b135} |
| 2119 | Lₐ₂₃₈ | L_{b135} | 2120 | Lₐ₂₃₉ | L_{b135} | 2121 | Lₐ₂₄₀ | L_{b135} |
| 2122 | Lₐ₂₄₁ | L_{b135} | 2123 | Lₐ₂₄₂ | L_{b135} | 2124 | Lₐ₂₄₃ | L_{b135} |
| 2125 | Lₐ₂₄₄ | L_{b135} | 2126 | Lₐ₂₄₅ | L_{b135} | 2127 | Lₐ₂₄₆ | L_{b135} |
| 2128 | Lₐ₂₄₇ | L_{b135} | 2129 | Lₐ₂₄₈ | L_{b135} | 2130 | Lₐ₂₄₉ | L_{b135} |
| 2131 | Lₐ₂₅₀ | L_{b135} | 2132 | Lₐ₂₅₁ | L_{b52} | 2133 | Lₐ₂₅₂ | L_{b135} |
| 2134 | Lₐ₂₅₃ | L_{b135} | 2135 | Lₐ₂₅₄ | L_{b135} | 2136 | Lₐ₂₅₅ | L_{b135} |
| 2137 | Lₐ₂₅₆ | L_{b135} | 2138 | Lₐ₂₅₇ | L_{b135} | 2139 | Lₐ₂₅₈ | L_{b135} |
| 2140 | Lₐ₂₅₉ | L_{b135} | 2141 | Lₐ₂₆₀ | L_{b135} | 2142 | Lₐ₂₆₁ | L_{b135} |
| 2143 | Lₐ₂₆₂ | L_{b135} | 2144 | Lₐ₂₆₃ | L_{b135} | 2145 | Lₐ₂₆₄ | L_{b135} |
| 2146 | Lₐ₂₆₅ | L_{b135} | 2147 | Lₐ₂₆₆ | L_{b135} | 2148 | Lₐ₂₆₇ | L_{b135} |
| 2149 | Lₐ₂₆₈ | L_{b135} | 2150 | Lₐ₂₆₉ | L_{b52} | 2151 | Lₐ₂₇₀ | L_{b135} |
| 2152 | Lₐ₂₇₁ | L_{b135} | 2153 | Lₐ₂₇₂ | L_{b135} | 2154 | Lₐ₂₇₃ | L_{b135} |
| 2155 | Lₐ₂₇₄ | L_{b135} | 2156 | Lₐ₂₇₅ | L_{b135} | 2157 | Lₐ₂₇₆ | L_{b135} |
| 2158 | Lₐ₂₇₇ | L_{b135} | 2159 | Lₐ₂₇₈ | L_{b135} | 2160 | Lₐ₂₇₉ | L_{b135} |
| 2161 | Lₐ₂₈₀ | L_{b135} | 2162 | Lₐ₂₈₁ | L_{b135} | 2163 | Lₐ₂₈₂ | L_{b135} |
| 2164 | Lₐ₂₈₃ | L_{b135} | 2165 | Lₐ₂₈₄ | L_{b135} | 2166 | Lₐ₂₈₅ | L_{b135} |
| 2167 | Lₐ₂₈₆ | L_{b135} | 2168 | Lₐ₂₈₇ | L_{b52} | 2169 | Lₐ₂₈₈ | L_{b135} |
| 2170 | Lₐ₂₈₉ | L_{b135} | 2171 | Lₐ₂₉₀ | L_{b135} | 2172 | Lₐ₂₉₁ | L_{b135} |
| 2173 | Lₐ₂₉₂ | L_{b135} | 2174 | Lₐ₂₉₃ | L_{b135} | 2175 | Lₐ₂₉₄ | L_{b135} |
| 2176 | Lₐ₂₉₅ | L_{b135} | 2177 | Lₐ₂₉₆ | L_{b135} | 2178 | Lₐ₂₉₇ | L_{b135} |
| 2179 | Lₐ₂₉₈ | L_{b135} | 2180 | Lₐ₂₉₉ | L_{b135} | 2181 | Lₐ₃₀₀ | L_{b135} |
| 2182 | Lₐ₃₀₁ | L_{b135} | 2183 | Lₐ₃₀₂ | L_{b135} | 2184 | Lₐ₃₀₃ | L_{b135} |
| 2185 | Lₐ₃₀₄ | L_{b135} | 2186 | Lₐ₃₀₅ | L_{b52} | 2187 | Lₐ₃₀₆ | L_{b135} |
| 2188 | Lₐ₃₀₇ | L_{b135} | 2189 | Lₐ₃₀₈ | L_{b135} | 2190 | Lₐ₃₀₉ | L_{b135} |
| 2191 | Lₐ₃₁₀ | L_{b135} | 2192 | Lₐ₃₁₁ | L_{b135} | 2193 | Lₐ₃₁₂ | L_{b135} |
| 2194 | Lₐ₃₁₃ | L_{b135} | 2195 | Lₐ₃₁₄ | L_{b135} | 2196 | Lₐ₃₁₅ | L_{b135} |
| 2197 | Lₐ₃₁₆ | L_{b135} | 2198 | Lₐ₃₁₇ | L_{b135} | 2199 | Lₐ₃₁₈ | L_{b135} |
| 2200 | Lₐ₃₁₉ | L_{b135} | 2201 | Lₐ₃₂₀ | L_{b135} | 2202 | Lₐ₃₂₁ | L_{b135} |
| 2203 | Lₐ₃₂₂ | L_{b135} | 2204 | Lₐ₃₂₃ | L_{b52} | 2205 | Lₐ₃₂₄ | L_{b135} |
| 2206 | Lₐ₃₂₅ | L_{b135} | 2207 | Lₐ₃₂₆ | L_{b135} | 2208 | Lₐ₃₂₇ | L_{b135} |
| 2209 | Lₐ₃₂₈ | L_{b135} | 2210 | Lₐ₃₂₉ | L_{b135} | 2211 | Lₐ₃₃₀ | L_{b135} |
| 2212 | Lₐ₃₃₁ | L_{b135} | 2213 | Lₐ₃₃₂ | L_{b135} | 2214 | Lₐ₃₃₃ | L_{b135} |
| 2215 | Lₐ₃₃₄ | L_{b135} | 2216 | Lₐ₃₃₅ | L_{b135} | 2217 | Lₐ₃₃₆ | L_{b135} |
| 2218 | Lₐ₃₃₇ | L_{b135} | 2219 | Lₐ₃₃₈ | L_{b135} | 2220 | Lₐ₃₃₉ | L_{b135} |
| 2221 | Lₐ₃₄₀ | L_{b135} | 2222 | Lₐ₃₄₁ | L_{b52} | 2223 | Lₐ₃₄₂ | L_{b135} |
| 2224 | Lₐ₃₄₃ | L_{b135} | 2225 | Lₐ₃₄₄ | L_{b135} | 2226 | Lₐ₃₄₅ | L_{b135} |
| 2227 | Lₐ₃₄₆ | L_{b135} | 2228 | Lₐ₃₄₇ | L_{b135} | 2229 | Lₐ₃₄₈ | L_{b135} |
| 2230 | Lₐ₃₄₉ | L_{b135} | 2231 | Lₐ₃₅₀ | L_{b135} | 2232 | Lₐ₃₅₁ | L_{b135} |
| 2233 | Lₐ₃₅₂ | L_{b135} | 2234 | Lₐ₃₅₃ | L_{b135} | 2235 | Lₐ₃₅₄ | L_{b135} |
| 2236 | Lₐ₃₅₅ | L_{b135} | 2237 | Lₐ₃₅₆ | L_{b135} | 2238 | Lₐ₃₅₇ | L_{b135} |
| 2239 | Lₐ₃₅₈ | L_{b135} | 2240 | Lₐ₃₅₉ | L_{b52} | 2241 | Lₐ₃₆₀ | L_{b135} |
| 2242 | Lₐ₃₆₁ | L_{b135} | 2243 | Lₐ₃₆₂ | L_{b135} | 2244 | Lₐ₃₆₃ | L_{b135} |
| 2245 | Lₐ₃₆₄ | L_{b135} | 2246 | Lₐ₃₆₅ | L_{b135} | 2247 | Lₐ₃₆₆ | L_{b135} |
| 2248 | Lₐ₃₆₇ | L_{b135} | 2249 | Lₐ₃₆₈ | L_{b135} | 2250 | Lₐ₃₆₉ | L_{b135} |
| 2251 | Lₐ₃₇₀ | L_{b135} | 2252 | Lₐ₃₇₁ | L_{b135} | 2253 | Lₐ₃₇₂ | L_{b135} |
| 2254 | Lₐ₃₇₃ | L_{b135} | 2255 | Lₐ₃₇₄ | L_{b135} | 2256 | Lₐ₃₇₅ | L_{b135} |
| 2257 | Lₐ₃₇₆ | L_{b135} | 2258 | Lₐ₃₇₇ | L_{b52} | 2259 | Lₐ₃₇₈ | L_{b135} |
| 2260 | Lₐ₃₇₉ | L_{b135} | 2261 | Lₐ₃₈₀ | L_{b135} | 2262 | Lₐ₃₈₁ | L_{b135} |
| 2263 | Lₐ₃₈₂ | L_{b135} | 2264 | Lₐ₃₈₃ | L_{b135} | 2265 | Lₐ₃₈₄ | L_{b135} |
| 2266 | Lₐ₃₈₅ | L_{b135} | 2267 | Lₐ₃₈₆ | L_{b135} | 2268 | Lₐ₃₈₇ | L_{b135} |
| 2269 | Lₐ₃₈₈ | L_{b135} | 2270 | Lₐ₃₈₉ | L_{b135} | 2271 | Lₐ₃₉₀ | L_{b135} |
| 2272 | Lₐ₃₉₁ | L_{b135} | 2273 | Lₐ₃₉₂ | L_{b135} | 2274 | Lₐ₃₉₃ | L_{b135} |
| 2275 | Lₐ₃₉₄ | L_{b135} | 2276 | Lₐ₃₉₅ | L_{b52} | 2277 | Lₐ₃₉₆ | L_{b135} |
| 2278 | Lₐ₃₉₇ | L_{b135} | 2279 | Lₐ₃₉₈ | L_{b135} | 2280 | Lₐ₃₉₉ | L_{b135} |
| 2281 | Lₐ₄₀₀ | L_{b135} | 2282 | Lₐ₄₀₁ | L_{b135} | 2283 | Lₐ₄₀₂ | L_{b135} |
| 2284 | Lₐ₄₀₃ | L_{b135} | 2285 | Lₐ₄₀₄ | L_{b135} | 2286 | Lₐ₄₀₅ | L_{b135} |
| 2287 | Lₐ₄₀₆ | L_{b135} | 2288 | Lₐ₄₀₇ | L_{b135} | 2289 | Lₐ₄₀₈ | L_{b135} |
| 2290 | Lₐ₄₀₉ | L_{b135} | 2291 | Lₐ₄₁₀ | L_{b135} | 2292 | Lₐ₄₁₁ | L_{b135} |
| 2293 | Lₐ₄₁₂ | L_{b135} | 2294 | Lₐ₄₁₃ | L_{b52} | 2295 | Lₐ₄₁₄ | L_{b135} |
| 2296 | Lₐ₄₁₅ | L_{b135} | 2297 | Lₐ₄₁₆ | L_{b135} | 2298 | Lₐ₄₁₇ | L_{b135} |
| 2299 | Lₐ₄₁₈ | L_{b135} | 2300 | Lₐ₄₁₉ | L_{b135} | 2301 | Lₐ₄₂₀ | L_{b135} |
| 2302 | Lₐ₄₂₁ | L_{b135} | 2303 | Lₐ₄₂₂ | L_{b135} | 2304 | Lₐ₄₂₃ | L_{b135} |
| 2305 | Lₐ₄₂₄ | L_{b135} | 2306 | Lₐ₄₂₅ | L_{b135} | 2307 | Lₐ₄₂₆ | L_{b135} |
| 2308 | Lₐ₄₂₇ | L_{b135} | 2309 | Lₐ₄₂₈ | L_{b135} | 2310 | Lₐ₄₂₉ | L_{b135} |
| 2311 | Lₐ₄₃₀ | L_{b135} | 2312 | Lₐ₄₃₁ | L_{b52} | 2313 | Lₐ₄₃₂ | L_{b135} |
| 2314 | Lₐ₄₃₃ | L_{b135} | 2315 | Lₐ₄₃₄ | L_{b135} | 2316 | Lₐ₄₃₅ | L_{b135} |
| 2317 | Lₐ₄₃₆ | L_{b135} | 2318 | Lₐ₄₃₇ | L_{b135} | 2319 | Lₐ₄₃₈ | L_{b135} |
| 2320 | Lₐ₄₃₉ | L_{b135} | 2321 | Lₐ₄₄₀ | L_{b135} | 2322 | Lₐ₄₄₁ | L_{b135} |
| 2323 | Lₐ₄₄₂ | L_{b135} | 2324 | Lₐ₄₄₃ | L_{b135} | 2325 | Lₐ₄₄₄ | L_{b135} |
| 2326 | Lₐ₄₄₅ | L_{b135} | 2327 | Lₐ₄₄₆ | L_{b135} | 2328 | Lₐ₄₄₇ | L_{b135} |
| 2329 | Lₐ₄₄₈ | L_{b135} | 2330 | Lₐ₄₄₉ | L_{b52} | 2331 | Lₐ₄₅₀ | L_{b135} |
| 2332 | Lₐ₄₅₁ | L_{b135} | 2333 | Lₐ₄₅₂ | L_{b135} | 2334 | Lₐ₄₅₃ | L_{b135} |
| 2335 | Lₐ₄₅₄ | L_{b135} | 2336 | Lₐ₄₅₅ | L_{b135} | 2337 | Lₐ₄₅₆ | L_{b135} |
| 2338 | Lₐ₄₅₇ | L_{b135} | 2339 | Lₐ₄₅₈ | L_{b135} | 2340 | Lₐ₄₅₉ | L_{b135} |
| 2341 | Lₐ₄₆₀ | L_{b135} | 2342 | Lₐ₄₆₁ | L_{b135} | 2343 | Lₐ₄₆₂ | L_{b135} |
| 2344 | Lₐ₄₆₃ | L_{b135} | 2345 | Lₐ₄₆₄ | L_{b135} | 2346 | Lₐ₄₆₅ | L_{b135} |
| 2347 | Lₐ₄₆₆ | L_{b135} | 2348 | Lₐ₄₆₇ | L_{b52} | 2349 | Lₐ₄₆₈ | L_{b135} |
| 2350 | Lₐ₄₆₉ | L_{b135} | 2351 | Lₐ₄₇₀ | L_{b135} | 2352 | Lₐ₄₇₁ | L_{b135} |
| 2353 | Lₐ₄₇₂ | L_{b135} | 2354 | Lₐ₄₇₃ | L_{b135} | 2355 | Lₐ₄₇₄ | L_{b135} |
| 2356 | Lₐ₄₇₅ | L_{b135} | 2357 | Lₐ₄₇₆ | L_{b135} | 2358 | Lₐ₄₇₇ | L_{b135} |
| 2359 | Lₐ₄₇₈ | L_{b135} | 2360 | Lₐ₄₇₉ | L_{b135} | 2361 | Lₐ₄₈₀ | L_{b135} |
| 2362 | Lₐ₄₈₁ | L_{b135} | 2363 | Lₐ₄₈₂ | L_{b135} | 2364 | Lₐ₄₈₃ | L_{b135} |
| 2365 | Lₐ₄₈₄ | L_{b135} | 2366 | Lₐ₄₈₅ | L_{b52} | 2367 | Lₐ₄₈₆ | L_{b135} |
| 2368 | Lₐ₄₈₇ | L_{b135} | 2369 | Lₐ₄₈₈ | L_{b135} | 2370 | Lₐ₄₈₉ | L_{b135} |
| 2371 | Lₐ₄₉₀ | L_{b135} | 2372 | Lₐ₄₉₁ | L_{b135} | 2373 | Lₐ₄₉₂ | L_{b135} |
| 2374 | Lₐ₄₉₃ | L_{b135} | 2375 | Lₐ₄₉₄ | L_{b135} | 2376 | Lₐ₄₉₅ | L_{b135} |
| 2377 | Lₐ₄₉₆ | L_{b135} | 2378 | Lₐ₄₉₇ | L_{b135} | 2379 | Lₐ₄₉₈ | L_{b135} |
| 2380 | Lₐ₄₉₉ | L_{b135} | 2381 | Lₐ₅₀₀ | L_{b135} | 2382 | Lₐ₅₀₁ | L_{b135} |
| 2383 | Lₐ₅₀₂ | L_{b135} | 2384 | Lₐ₅₀₃ | L_{b52} | 2385 | Lₐ₅₀₄ | L_{b135} |
| 2386 | Lₐ₅₀₅ | L_{b135} | 2387 | Lₐ₅₀₆ | L_{b135} | 2388 | Lₐ₅₀₇ | L_{b135} |
| 2389 | Lₐ₅₀₈ | L_{b135} | 2390 | Lₐ₅₀₉ | L_{b135} | 2391 | Lₐ₅₁₀ | L_{b135} |
| 2392 | Lₐ₅₁₁ | L_{b135} | 2393 | Lₐ₅₁₂ | L_{b135} | 2394 | Lₐ₅₁₃ | L_{b135} |
| 2395 | Lₐ₅₁₄ | L_{b135} | 2396 | Lₐ₅₁₅ | L_{b135} | 2397 | Lₐ₅₁₆ | L_{b135} |
| 2398 | Lₐ₅₁₇ | L_{b135} | 2399 | Lₐ₅₁₈ | L_{b135} | 2400 | Lₐ₅₁₉ | L_{b135} |
| 2401 | Lₐ₅₂₀ | L_{b135} | 2402 | Lₐ₅₂₁ | L_{b52} | 2403 | Lₐ₅₂₂ | L_{b135} |
| 2404 | Lₐ₅₂₃ | L_{b135} | 2405 | Lₐ₅₂₄ | L_{b135} | 2406 | Lₐ₅₂₅ | L_{b135} |
| 2407 | Lₐ₅₂₆ | L_{b135} | 2408 | Lₐ₅₂₇ | L_{b135} | 2409 | Lₐ₅₂₈ | L_{b135} |
| 2410 | Lₐ₅₂₉ | L_{b135} | 2411 | Lₐ₅₃₀ | L_{b135} | 2412 | Lₐ₅₃₁ | L_{b135} |
| 2413 | Lₐ₅₃₂ | L_{b135} | 2414 | Lₐ₅₃₃ | L_{b135} | 2415 | Lₐ₅₃₄ | L_{b135} |
| 2416 | Lₐ₅₃₅ | L_{b135} | 2417 | Lₐ₅₃₆ | L_{b135} | 2418 | Lₐ₅₃₇ | L_{b135} |
| 2419 | Lₐ₅₃₈ | L_{b135} | 2420 | Lₐ₅₃₉ | L_{b52} | 2421 | Lₐ₅₄₀ | L_{b135} |
| 2422 | Lₐ₅₄₁ | L_{b135} | 2423 | Lₐ₅₄₂ | L_{b135} | 2424 | Lₐ₅₄₃ | L_{b135} |
| 2425 | Lₐ₅₄₄ | L_{b135} | 2426 | Lₐ₅₄₅ | L_{b135} | 2427 | Lₐ₅₄₆ | L_{b135} |
| 2428 | Lₐ₅₄₇ | L_{b135} | 2429 | Lₐ₅₄₈ | L_{b135} | 2430 | Lₐ₅₄₉ | L_{b135} |
| 2431 | Lₐ₅₅₀ | L_{b135} | 2432 | Lₐ₅₅₁ | L_{b135} | 2433 | Lₐ₅₅₂ | L_{b135} |
| 2434 | Lₐ₅₅₃ | L_{b135} | 2435 | Lₐ₅₅₄ | L_{b135} | 2436 | Lₐ₅₅₅ | L_{b135} |
| 2437 | Lₐ₅₅₆ | L_{b135} | 2438 | Lₐ₅₅₇ | L_{b52} | 2439 | Lₐ₅₅₈ | L_{b135} |
| 2440 | Lₐ₅₅₉ | L_{b135} | 2441 | Lₐ₅₆₀ | L_{b135} | 2442 | Lₐ₅₆₁ | L_{b135} |
| 2443 | Lₐ₅₆₂ | L_{b135} | 2444 | Lₐ₅₆₃ | L_{b135} | 2445 | Lₐ₅₆₄ | L_{b135} |
| 2446 | Lₐ₅₆₅ | L_{b135} | 2447 | Lₐ₅₆₆ | L_{b135} | 2448 | Lₐ₅₆₇ | L_{b135} |
| 2449 | Lₐ₅₆₈ | L_{b135} | 2450 | Lₐ₅₆₉ | L_{b135} | 2451 | Lₐ₅₇₀ | L_{b135} |
| 2452 | Lₐ₅₇₁ | L_{b135} | 2453 | Lₐ₅₇₂ | L_{b135} | 2454 | Lₐ₅₇₃ | L_{b135} |
| 2455 | Lₐ₅₇₄ | L_{b135} | 2456 | Lₐ₅₇₅ | L_{b52} | 2457 | Lₐ₅₇₆ | L_{b135} |
| 2458 | Lₐ₅₇₇ | L_{b135} | 2459 | Lₐ₅₇₈ | L_{b135} | 2460 | Lₐ₅₇₉ | L_{b135} |
| 2461 | Lₐ₅₈₀ | L_{b135} | 2462 | Lₐ₅₈₁ | L_{b135} | 2463 | Lₐ₅₈₂ | L_{b135} |
| 2464 | Lₐ₅₈₃ | L_{b135} | 2465 | Lₐ₅₈₄ | L_{b135} | 2466 | Lₐ₅₈₅ | L_{b135} |
| 2467 | Lₐ₅₈₆ | L_{b135} | 2468 | Lₐ₅₈₇ | L_{b135} | 2469 | Lₐ₅₈₈ | L_{b135} |
| 2470 | Lₐ₅₈₉ | L_{b135} | 2471 | Lₐ₅₉₀ | L_{b135} | 2472 | Lₐ₅₉₁ | L_{b135} |
| 2473 | Lₐ₅₉₂ | L_{b135} | 2474 | Lₐ₅₉₃ | L_{b52} | 2475 | Lₐ₅₉₄ | L_{b135} |
| 2476 | Lₐ₅₉₅ | L_{b135} | 2477 | Lₐ₅₉₆ | L_{b135} | 2478 | Lₐ₅₉₇ | L_{b135} |
| 2479 | Lₐ₅₉₈ | L_{b135} | 2480 | Lₐ₅₉₉ | L_{b135} | 2481 | Lₐ₆₀₀ | L_{b135} |
| 2482 | Lₐ₆₀₁ | L_{b135} | 2483 | Lₐ₆₀₂ | L_{b135} | 2484 | Lₐ₆₀₃ | L_{b135} |
| 2485 | Lₐ₆₀₄ | L_{b135} | 2486 | Lₐ₆₀₅ | L_{b135} | 2487 | Lₐ₆₀₆ | L_{b135} |
| 2488 | Lₐ₆₀₇ | L_{b135} | 2489 | Lₐ₆₀₈ | L_{b135} | 2490 | Lₐ₆₀₉ | L_{b135} |
| 2491 | Lₐ₆₁₀ | L_{b135} | 2492 | Lₐ₆₁₁ | L_{b52} | 2493 | Lₐ₆₁₂ | L_{b135} |
| 2494 | Lₐ₆₁₃ | L_{b135} | 2495 | Lₐ₆₁₄ | L_{b135} | 2496 | Lₐ₆₁₅ | L_{b135} |
| 2497 | Lₐ₆₁₆ | L_{b135} | 2498 | Lₐ₆₁₇ | L_{b135} | 2499 | Lₐ₆₁₈ | L_{b135} |
| 2500 | Lₐ₆₁₉ | L_{b135} | 2501 | Lₐ₆₂₀ | L_{b135} | 2502 | Lₐ₆₂₁ | L_{b135} |
| 2503 | Lₐ₆₂₂ | L_{b135} | 2504 | Lₐ₆₂₃ | L_{b135} | 2505 | Lₐ₆₂₄ | L_{b135} |
| 2506 | Lₐ₆₂₅ | L_{b135} | 2507 | Lₐ₆₂₆ | L_{b135} | 2508 | Lₐ₆₂₇ | L_{b135} |
| 2509 | Lₐ₆₂₈ | L_{b135} | 2510 | Lₐ₆₂₉ | L_{b52} | 2511 | Lₐ₆₃₀ | L_{b135} |
| 2512 | Lₐ₆₃₁ | L_{b135} | 2513 | Lₐ₆₃₂ | L_{b135} | 2514 | Lₐ₆₃₃ | L_{b135} |
| 2515 | Lₐ₆₃₄ | L_{b135} | 2516 | Lₐ₆₃₅ | L_{b135} | 2517 | Lₐ₆₃₆ | L_{b135} |
| 2518 | Lₐ₆₃₇ | L_{b135} | 2519 | Lₐ₆₃₈ | L_{b135} | 2520 | Lₐ₆₃₉ | L_{b135} |
| 2521 | Lₐ₆₄₀ | L_{b135} | 2522 | Lₐ₆₄₁ | L_{b135} | 2523 | Lₐ₆₄₂ | L_{b135} |
| 2524 | Lₐ₆₄₃ | L_{b135} | 2525 | Lₐ₆₄₄ | L_{b135} | 2526 | Lₐ₆₄₅ | L_{b135} |
| 2527 | Lₐ₆₄₆ | L_{b135} | 2528 | Lₐ₆₄₇ | L_{b52} | 2529 | Lₐ₆₄₈ | L_{b135} |
| 2530 | Lₐ₆₄₉ | L_{b135} | 2531 | Lₐ₆₅₀ | L_{b135} | 2532 | Lₐ₆₅₁ | L_{b135} |
| 2533 | Lₐ₆₅₂ | L_{b135} | 2534 | Lₐ₆₅₃ | L_{b135} | 2535 | Lₐ₆₅₄ | L_{b135} |
| 2536 | Lₐ₆₅₅ | L_{b135} | 2537 | Lₐ₆₅₆ | L_{b135} | 2538 | Lₐ₆₅₇ | L_{b135} |
| 2539 | Lₐ₆₅₈ | L_{b135} | 2540 | Lₐ₆₅₉ | L_{b135} | 2541 | Lₐ₆₆₀ | L_{b135} |
| 2542 | Lₐ₆₆₁ | L_{b135} | 2543 | Lₐ₆₆₂ | L_{b135} | 2544 | Lₐ₆₆₃ | L_{b135} |
| 2545 | Lₐ₆₆₄ | L_{b135} | 2546 | Lₐ₆₆₅ | L_{b52} | 2547 | Lₐ₆₆₆ | L_{b135} |
| 2548 | Lₐ₆₆₇ | L_{b135} | 2549 | Lₐ₆₆₈ | L_{b135} | 2550 | Lₐ₆₆₉ | L_{b135} |
| 2551 | Lₐ₆₇₀ | L_{b135} | 2552 | Lₐ₆₇₁ | L_{b135} | 2553 | Lₐ₆₇₂ | L_{b135} |
| 2554 | Lₐ₆₇₃ | L_{b135} | 2555 | Lₐ₆₇₄ | L_{b135} | 2556 | Lₐ₆₇₅ | L_{b135} |
| 2557 | Lₐ₆₇₆ | L_{b135} | 2558 | Lₐ₆₇₇ | L_{b135} | 2559 | Lₐ₆₇₈ | L_{b135} |
| 2560 | Lₐ₆₇₉ | L_{b135} | 2561 | Lₐ₆₈₀ | L_{b135} | 2562 | Lₐ₆₈₁ | L_{b135} |
| 2563 | Lₐ₆₈₂ | L_{b135} | 2564 | Lₐ₆₈₃ | L_{b52} | 2565 | Lₐ₆₈₄ | L_{b135} |
| 2566 | Lₐ₆₈₅ | L_{b135} | 2567 | Lₐ₆₈₆ | L_{b135} | 2568 | Lₐ₆₈₇ | L_{b135} |
| 2569 | Lₐ₆₈₈ | L_{b135} | 2570 | Lₐ₆₈₉ | L_{b135} | 2571 | Lₐ₆₉₀ | L_{b135} |
| 2572 | Lₐ₆₉₁ | L_{b135} | 2573 | Lₐ₆₉₂ | L_{b135} | 2574 | Lₐ₆₉₃ | L_{b135} |
| 2575 | Lₐ₆₉₄ | L_{b135} | 2576 | Lₐ₆₉₅ | L_{b135} | 2577 | Lₐ₆₉₆ | L_{b135} |
| 2578 | Lₐ₆₉₇ | L_{b135} | 2579 | Lₐ₆₉₈ | L_{b135} | 2580 | Lₐ₆₉₉ | L_{b135} |
| 2581 | Lₐ₇₀₀ | L_{b135} | 2582 | Lₐ₇₀₁ | L_{b52} | 2583 | Lₐ₇₀₂ | L_{b135} |
| 2584 | Lₐ₇₀₃ | L_{b135} | 2585 | Lₐ₇₀₄ | L_{b135} | 2586 | Lₐ₇₀₅ | L_{b135} |
| 2587 | Lₐ₇₀₆ | L_{b135} | 2588 | Lₐ₇₀₇ | L_{b135} | 2589 | Lₐ₇₀₈ | L_{b135} |
| 2590 | Lₐ₇₀₉ | L_{b135} | 2591 | Lₐ₇₁₀ | L_{b135} | 2592 | Lₐ₇₁₁ | L_{b135} |
| 2593 | Lₐ₇₁₂ | L_{b135} | 2594 | Lₐ₇₁₃ | L_{b135} | 2595 | Lₐ₇₁₄ | L_{b135} |
| 2596 | Lₐ₇₁₅ | L_{b135} | 2597 | Lₐ₇₁₆ | L_{b135} | 2598 | Lₐ₇₁₇ | L_{b135} |
| 2599 | Lₐ₇₁₈ | L_{b135} | 2600 | Lₐ₇₁₉ | L_{b52} | 2601 | Lₐ₇₂₀ | L_{b135} |
| 2602 | Lₐ₇₂₁ | L_{b135} | 2603 | Lₐ₇₂₂ | L_{b135} | 2604 | Lₐ₇₂₃ | L_{b135} |
| 2605 | Lₐ₇₂₄ | L_{b135} | 2606 | Lₐ₇₂₅ | L_{b135} | 2607 | Lₐ₇₂₆ | L_{b135} |
| 2608 | Lₐ₇₂₇ | L_{b135} | 2609 | Lₐ₇₂₈ | L_{b135} | 2610 | Lₐ₇₂₉ | L_{b135} |
| 2611 | Lₐ₇₃₀ | L_{b135} | 2612 | Lₐ₇₃₁ | L_{b135} | 2613 | Lₐ₇₃₂ | L_{b135} |
| 2614 | Lₐ₇₃₃ | L_{b135} | 2615 | Lₐ₇₃₄ | L_{b135} | 2616 | Lₐ₇₃₅ | L_{b135} |
| 2617 | Lₐ₇₃₆ | L_{b135} | 2618 | Lₐ₇₃₇ | L_{b52} | 2619 | Lₐ₇₃₈ | L_{b135} |
| 2620 | Lₐ₇₃₉ | L_{b135} | 2621 | Lₐ₇₄₀ | L_{b135} | 2622 | Lₐ₇₄₁ | L_{b135} |
| 2623 | Lₐ₇₄₂ | L_{b135} | 2624 | Lₐ₇₄₃ | L_{b135} | 2625 | Lₐ₇₄₄ | L_{b135} |
| 2626 | Lₐ₇₄₅ | L_{b135} | 2627 | Lₐ₇₄₆ | L_{b135} | 2628 | Lₐ₇₄₇ | L_{b135} |
| 2629 | Lₐ₇₄₈ | L_{b135} | 2630 | Lₐ₇₄₉ | L_{b135} | 2631 | Lₐ₇₅₀ | L_{b135} |
| 2632 | Lₐ₇₅₁ | L_{b135} | 2633 | Lₐ₇₅₂ | L_{b135} | 2634 | Lₐ₇₅₃ | L_{b135} |
| 2635 | Lₐ₇₅₄ | L_{b135} | 2636 | Lₐ₇₅₅ | L_{b52} | 2637 | Lₐ₇₅₆ | L_{b135} |
| 2638 | Lₐ₇₅₇ | L_{b135} | 2639 | Lₐ₇₅₈ | L_{b135} | 2640 | Lₐ₇₅₉ | L_{b135} |
| 2641 | Lₐ₇₆₀ | L_{b135} | 2642 | Lₐ₇₆₁ | L_{b135} | 2643 | Lₐ₇₆₂ | L_{b135} |
| 2644 | Lₐ₇₆₃ | L_{b135} | 2645 | Lₐ₇₆₄ | L_{b135} | 2646 | Lₐ₇₆₅ | L_{b135} |
| 2647 | Lₐ₇₆₆ | L_{b135} | 2648 | Lₐ₇₆₇ | L_{b135} | 2649 | Lₐ₇₆₈ | L_{b135} |
| 2650 | Lₐ₇₆₉ | L_{b135} | 2651 | Lₐ₇₇₀ | L_{b135} | 2652 | Lₐ₇₇₁ | L_{b135} |
| 2653 | Lₐ₇₇₂ | L_{b135} | 2654 | Lₐ₇₇₃ | L_{b52} | 2655 | Lₐ₇₇₄ | L_{b135} |
| 2656 | Lₐ₇₇₅ | L_{b135} | 2657 | Lₐ₇₇₆ | L_{b135} | 2658 | Lₐ₇₇₇ | L_{b135} |
| 2659 | Lₐ₇₇₈ | L_{b135} | 2660 | Lₐ₇₇₉ | L_{b135} | 2661 | Lₐ₇₈₀ | L_{b135} |
| 2662 | Lₐ₇₈₁ | L_{b135} | 2663 | Lₐ₇₈₂ | L_{b135} | 2664 | Lₐ₇₈₃ | L_{b135} |
| 2665 | Lₐ₇₈₄ | L_{b135} | 2666 | Lₐ₇₈₅ | L_{b135} | 2667 | Lₐ₇₈₆ | L_{b135} |
| 2668 | Lₐ₇₈₇ | L_{b135} | 2669 | Lₐ₇₈₈ | L_{b135} | 2670 | Lₐ₇₈₉ | L_{b135} |
| 2671 | Lₐ₇₉₀ | L_{b135} | 2672 | Lₐ₇₉₁ | L_{b52} | 2673 | Lₐ₇₉₂ | L_{b135} |
| 2674 | Lₐ₇₉₃ | L_{b135} | 2675 | Lₐ₇₉₄ | L_{b135} | 2676 | Lₐ₇₉₅ | L_{b135} |
| 2677 | Lₐ₇₉₆ | L_{b135} | 2678 | Lₐ₇₉₇ | L_{b135} | 2679 | Lₐ₇₉₈ | L_{b135} |
| 2680 | Lₐ₇₉₉ | L_{b135} | 2681 | Lₐ₈₀₀ | L_{b135} | 2682 | Lₐ₈₀₁ | L_{b135} |
| 2683 | Lₐ₈₀₂ | L_{b135} | 2684 | Lₐ₈₀₃ | L_{b135} | 2685 | Lₐ₈₀₄ | L_{b135} |
| 2686 | Lₐ₈₀₅ | L_{b135} | 2687 | Lₐ₈₀₆ | L_{b135} | 2688 | Lₐ₈₀₇ | L_{b135} |
| 2689 | Lₐ₈₀₈ | L_{b135} | 2690 | Lₐ₈₀₉ | L_{b52} | 2691 | Lₐ₈₁₀ | L_{b135} |
| 2692 | Lₐ₈₁₁ | L_{b135} | 2693 | Lₐ₈₁₂ | L_{b135} | 2694 | Lₐ₈₁₃ | L_{b135} |
| 2695 | Lₐ₈₁₄ | L_{b135} | 2696 | Lₐ₈₁₅ | L_{b135} | 2697 | Lₐ₈₁₆ | L_{b135} |
| 2698 | Lₐ₈₁₇ | L_{b135} | 2699 | Lₐ₈₁₈ | L_{b135} | 2700 | Lₐ₈₁₉ | L_{b135} |
| 2701 | Lₐ₈₂₀ | L_{b135} | 2702 | Lₐ₈₂₁ | L_{b135} | 2703 | Lₐ₈₂₂ | L_{b135} |
| 2704 | Lₐ₈₂₃ | L_{b135} | 2705 | Lₐ₈₂₄ | L_{b135} | 2706 | Lₐ₈₂₅ | L_{b135} |
| 2707 | Lₐ₈₂₆ | L_{b135} | 2708 | Lₐ₈₂₇ | L_{b52} | 2709 | Lₐ₈₂₈ | L_{b135} |
| 2710 | Lₐ₈₂₉ | L_{b135} | 2711 | Lₐ₈₃₀ | L_{b135} | 2712 | Lₐ₈₃₁ | L_{b135} |
| 2713 | Lₐ₈₃₂ | L_{b135} | 2714 | Lₐ₈₃₃ | L_{b135} | 2715 | Lₐ₈₃₄ | L_{b135} |
| 2716 | Lₐ₈₃₅ | L_{b135} | 2717 | Lₐ₈₃₆ | L_{b135} | 2718 | Lₐ₈₃₇ | L_{b135} |
| 2719 | Lₐ₈₃₈ | L_{b135} | 2720 | Lₐ₈₃₉ | L_{b135} | 2721 | Lₐ₈₄₀ | L_{b135} |
| 2722 | Lₐ₈₄₁ | L_{b135} | 2723 | Lₐ₈₄₂ | L_{b135} | 2724 | Lₐ₈₄₃ | L_{b135} |
| 2725 | Lₐ₈₄₄ | L_{b135} | 2726 | Lₐ₈₄₅ | L_{b52} | 2727 | Lₐ₈₄₆ | L_{b135} |
| 2728 | Lₐ₈₄₇ | L_{b135} | 2729 | Lₐ₈₄₈ | L_{b135} | 2730 | Lₐ₈₄₉ | L_{b135} |
| 2731 | Lₐ₈₅₀ | L_{b135} | 2732 | Lₐ₈₅₁ | L_{b135} | 2733 | Lₐ₈₅₂ | L_{b135} |
| 2734 | Lₐ₈₅₃ | L_{b135} | 2735 | Lₐ₈₅₄ | L_{b135} | 2736 | Lₐ₈₅₅ | L_{b135} |
| 2737 | Lₐ₈₅₆ | L_{b135} | 2738 | Lₐ₈₅₇ | L_{b135} | 2739 | Lₐ₈₅₈ | L_{b135} |
| 2740 | Lₐ₈₅₉ | L_{b135} | 2741 | Lₐ₈₆₀ | L_{b135} | 2742 | Lₐ₈₆₁ | L_{b135} |
| 2743 | Lₐ₈₆₂ | L_{b135} | 2744 | Lₐ₈₆₃ | L_{b52} | 2745 | Lₐ₈₆₄ | L_{b135} |
| 2746 | Lₐ₈₆₅ | L_{b135} | 2747 | Lₐ₈₆₆ | L_{b135} | 2748 | Lₐ₈₆₇ | L_{b135} |
| 2749 | Lₐ₈₆₈ | L_{b135} | 2750 | Lₐ₈₆₉ | L_{b135} | 2751 | Lₐ₈₇₀ | L_{b135} |
| 2752 | Lₐ₈₇₁ | L_{b135} | 2753 | Lₐ₈₇₂ | L_{b135} | 2754 | Lₐ₈₇₃ | L_{b135} |
| 2755 | Lₐ₈₇₄ | L_{b135} | 2756 | Lₐ₈₇₅ | L_{b135} | 2757 | Lₐ₈₇₆ | L_{b135} |
| 2758 | Lₐ₈₇₇ | L_{b135} | 2759 | Lₐ₈₇₈ | L_{b135} | 2760 | Lₐ₈₇₉ | L_{b135} |
| 2761 | Lₐ₈₈₀ | L_{b135} | 2762 | Lₐ₈₈₁ | L_{b52} | 2763 | Lₐ₈₈₂ | L_{b135} |
| 2764 | Lₐ₈₈₃ | L_{b135} | 2765 | Lₐ₈₈₄ | L_{b135} | 2766 | Lₐ₈₈₅ | L_{b135} |
| 2767 | Lₐ₈₈₆ | L_{b135} | 2768 | Lₐ₈₈₇ | L_{b135} | 2769 | Lₐ₈₈₈ | L_{b135} |
| 2770 | Lₐ₈₈₉ | L_{b135} | 2771 | Lₐ₈₉₀ | L_{b135} | 2772 | Lₐ₈₉₁ | L_{b135} |
| 2773 | Lₐ₈₉₂ | L_{b135} | 2774 | Lₐ₈₉₃ | L_{b135} | 2775 | Lₐ₈₉₄ | L_{b135} |
| 2776 | Lₐ₈₉₅ | L_{b135} | 2777 | Lₐ₈₉₆ | L_{b135} | 2778 | Lₐ₈₉₇ | L_{b135} |
| 2779 | Lₐ₈₉₈ | L_{b135} | 2780 | Lₐ₈₉₉ | L_{b52} | 2781 | Lₐ₉₀₀ | L_{b135} |
| 2782 | Lₐ₉₀₁ | L_{b135} | 2783 | Lₐ₉₀₂ | L_{b135} | 2784 | Lₐ₉₀₃ | L_{b135} |
| 2785 | Lₐ₉₀₄ | L_{b135} | 2786 | Lₐ₉₀₅ | L_{b135} | 2787 | Lₐ₉₀₆ | L_{b135} |
| 2788 | Lₐ₉₀₇ | L_{b135} | 2789 | Lₐ₉₀₈ | L_{b135} | 2790 | Lₐ₉₀₉ | L_{b135} |
| 2791 | Lₐ₉₁₀ | L_{b135} | 2792 | Lₐ₉₁₁ | L_{b135} | 2793 | Lₐ₉₁₂ | L_{b135} |
| 2794 | Lₐ₉₁₃ | L_{b135} | 2795 | Lₐ₉₁₄ | L_{b135} | 2796 | Lₐ₉₁₅ | L_{b135} |
| 2797 | Lₐ₉₁₆ | L_{b135} | 2798 | Lₐ₉₁₇ | L_{b52} | 2799 | Lₐ₉₁₈ | L_{b135} |
| 2800 | Lₐ₉₁₉ | L_{b135} | 2801 | Lₐ₉₂₀ | L_{b135} | 2802 | Lₐ₉₂₁ | L_{b135} |
| 2803 | Lₐ₉₂₂ | L_{b135} | 2804 | Lₐ₉₂₃ | L_{b135} | 2805 | Lₐ₉₂₄ | L_{b135} |
| 2806 | Lₐ₉₂₅ | L_{b135} | 2807 | Lₐ₉₂₆ | L_{b135} | 2808 | Lₐ₉₂₇ | L_{b135} |
| 2809 | Lₐ₉₂₈ | L_{b135} | 2810 | Lₐ₉₂₉ | L_{b135} | 2811 | Lₐ₉₃₀ | L_{b135} |
| 2812 | Lₐ₉₃₁ | L_{b135} | 2813 | Lₐ₉₃₂ | L_{b135} | 2814 | Lₐ₉₃₃ | L_{b135} |
| 2815 | Lₐ₉₃₄ | L_{b135} | 2816 | Lₐ₉₃₅ | L_{b52} | 2817 | Lₐ₉₃₆ | L_{b135} |
| 2818 | Lₐ₉₃₇ | L_{b135} | 2819 | Lₐ₉₃₈ | L_{b135} | 2820 | Lₐ₉₃₉ | L_{b135} |
| 2821 | Lₐ₉₄₀ | L_{b135} | 2822 | Lₐ₉₄₁ | L_{b135} | 2823 | Lₐ₉₄₂ | L_{b135} |
| 2824 | Lₐ₉₄₃ | L_{b135} | 2825 | Lₐ₉₄₄ | L_{b135} | 2826 | Lₐ₉₄₅ | L_{b135} |
| 2827 | Lₐ₉₄₆ | L_{b135} | 2828 | Lₐ₉₄₇ | L_{b135} | 2829 | Lₐ₉₄₈ | L_{b135} |
| 2830 | Lₐ₉₄₉ | L_{b135} | 2831 | Lₐ₉₅₀ | L_{b135} | 2832 | Lₐ₉₅₁ | L_{b135} |
| 2833 | Lₐ₉₅₂ | L_{b135} | 2834 | Lₐ₉₅₃ | L_{b52} | 2835 | Lₐ₉₅₄ | L_{b135} |
| 2836 | Lₐ₉₅₅ | L_{b135} | 2837 | Lₐ₉₅₆ | L_{b135} | 2838 | Lₐ₉₅₇ | L_{b135} |
| 2839 | Lₐ₉₅₈ | L_{b135} | 2840 | Lₐ₉₅₉ | L_{b135} | 2841 | Lₐ₉₆₀ | L_{b135} |
| 2842 | Lₐ₉₆₁ | L_{b135} | 2843 | Lₐ₉₆₂ | L_{b135} | 2844 | Lₐ₉₆₃ | L_{b135} |
| 2845 | Lₐ₉₆₄ | L_{b135} | 2846 | Lₐ₉₆₅ | L_{b135} | 2847 | Lₐ₉₆₆ | L_{b135} |
| 2848 | Lₐ₉₆₇ | L_{b135} | 2849 | Lₐ₉₆₈ | L_{b135} | 2850 | Lₐ₉₆₉ | L_{b135} |
| 2851 | Lₐ₉₇₀ | L_{b135} | 2852 | Lₐ₉₇₁ | L_{b52} | 2853 | Lₐ₉₇₂ | L_{b135} |
| 2854 | Lₐ₉₇₃ | L_{b135} | 2855 | Lₐ₉₇₄ | L_{b135} | 2856 | Lₐ₉₇₅ | L_{b135} |
| 2857 | Lₐ₉₇₆ | L_{b135} | 2858 | Lₐ₉₇₇ | L_{b135} | 2859 | Lₐ₉₇₈ | L_{b135} |
| 2860 | Lₐ₉₇₉ | L_{b135} | 2861 | Lₐ₉₈₀ | L_{b135} | 2862 | Lₐ₉₈₁ | L_{b135} |
| 2863 | Lₐ₉₈₂ | L_{b135} | 2864 | Lₐ₉₈₃ | L_{b135} | 2865 | Lₐ₉₈₄ | L_{b135} |
| 2866 | Lₐ₉₈₅ | L_{b135} | 2867 | Lₐ₉₈₆ | L_{b135} | 2868 | Lₐ₉₈₇ | L_{b135} |
| 2869 | Lₐ₉₈₈ | L_{b135} | 2870 | Lₐ₉₈₉ | L_{b52} | 2871 | Lₐ₉₉₀ | L_{b135} |
| 2872 | Lₐ₉₉₁ | L_{b135} | 2873 | Lₐ₉₉₂ | L_{b135} | 2874 | Lₐ₉₉₃ | L_{b135} |
| 2875 | Lₐ₉₉₄ | L_{b135} | 2876 | Lₐ₉₉₅ | L_{b135} | 2877 | Lₐ₉₉₆ | L_{b135} |
| 2878 | Lₐ₉₉₇ | L_{b135} | 2879 | Lₐ₉₉₈ | L_{b135} | 2880 | Lₐ₉₉₉ | L_{b135} |
| 2881 | Lₐ₁₀₀₀ | L_{b135} | 2882 | Lₐ₁₀₀₁ | L_{b135} | 2883 | Lₐ₁₀₀₂ | L_{b135} |
| 2884 | Lₐ₁₀₀₃ | L_{b135} | 2885 | Lₐ₁₀₀₄ | L_{b135} | 2886 | Lₐ₁₀₀₅ | L_{b135} |
| 2887 | Lₐ₁₀₀₆ | L_{b135} | 2888 | Lₐ₁₀₀₇ | L_{b52} | 2889 | Lₐ₁₀₀₈ | L_{b135} |
| 2890 | Lₐ₁₀₀₉ | L_{b135} | 2891 | Lₐ₁₀₁₀ | L_{b135} | 2892 | Lₐ₁₀₁₁ | L_{b135} |
| 2893 | Lₐ₁₀₁₂ | L_{b135} | 2894 | Lₐ₁₀₁₃ | L_{b135} | 2895 | Lₐ₁₀₁₄ | L_{b135} |
| 2896 | Lₐ₁₀₁₅ | L_{b135} | 2897 | Lₐ₁₀₁₆ | L_{b135} | 2898 | Lₐ₁₀₁₇ | L_{b135} |
| 2899 | Lₐ₁₀₁₈ | L_{b135} | 2900 | Lₐ₁₀₁₉ | L_{b135} | 2901 | Lₐ₁₀₂₀ | L_{b135} |
| 2902 | Lₐ₁₀₂₁ | L_{b135} | 2903 | Lₐ₁₀₂₂ | L_{b135} | 2904 | Lₐ₁₀₂₃ | L_{b135} |
| 2905 | Lₐ₁₀₂₄ | L_{b135} | 2906 | Lₐ₁₀₂₅ | L_{b52} | 2907 | Lₐ₁₀₂₆ | L_{b135} |
| 2908 | Lₐ₁₀₂₇ | L_{b135} | 2909 | Lₐ₁₀₂₈ | L_{b135} | 2910 | Lₐ₁₀₂₉ | L_{b135} |
| 2911 | Lₐ₁₀₃₀ | L_{b135} | 2912 | Lₐ₁₀₃₁ | L_{b135} | 2913 | Lₐ₁₀₃₂ | L_{b135} |
| 2914 | Lₐ₁₀₃₃ | L_{b135} | 2915 | Lₐ₁₀₃₄ | L_{b135} | 2916 | Lₐ₁₀₃₅ | L_{b135} |
| 2917 | Lₐ₁₀₃₆ | L_{b135} | 2918 | Lₐ₁₀₃₇ | L_{b135} | 2919 | Lₐ₁₀₃₈ | L_{b135} |
| 2920 | Lₐ₁₀₃₉ | L_{b135} | 2921 | Lₐ₁₀₄₀ | L_{b135} | 2922 | Lₐ₁₀₄₁ | L_{b135} |
| 2923 | Lₐ₁₀₄₂ | L_{b135} | 2924 | Lₐ₁₀₄₃ | L_{b52} | 2925 | Lₐ₁₀₄₄ | L_{b135} |
| 2926 | Lₐ₁₀₄₅ | L_{b135} | 2927 | Lₐ₁₀₄₆ | L_{b135} | 2928 | Lₐ₁₀₄₇ | L_{b135} |
| 2929 | Lₐ₁₀₄₈ | L_{b135} | 2930 | Lₐ₁₀₄₉ | L_{b135} | 2931 | Lₐ₁₀₅₀ | L_{b135} |
| 2932 | Lₐ₁₀₅₁ | L_{b135} | 2933 | Lₐ₁₀₅₂ | L_{b135} | 2934 | Lₐ₁₀₅₃ | L_{b135} |
| 2935 | Lₐ₁₀₅₄ | L_{b135} | 2936 | Lₐ₁₀₅₅ | L_{b135} | 2937 | Lₐ₁₀₅₆ | L_{b135} |
| 2938 | Lₐ₁₀₅₇ | L_{b135} | 2939 | Lₐ₁₀₅₈ | L_{b135} | 2940 | Lₐ₁₀₅₉ | L_{b135} |
| 2941 | Lₐ₁₀₆₀ | L_{b135} | 2942 | Lₐ₁₀₆₁ | L_{b52} | 2943 | Lₐ₁₀₆₂ | L_{b135} |
| 2944 | Lₐ₁₀₆₃ | L_{b135} | 2945 | Lₐ₁₀₆₄ | L_{b135} | 2946 | Lₐ₁₀₆₅ | L_{b135} |
| 2947 | Lₐ₁₀₆₆ | L_{b135} | 2948 | Lₐ₁₀₆₇ | L_{b135} | 2949 | Lₐ₁₀₆₈ | L_{b135} |
| 2950 | Lₐ₁₀₆₉ | L_{b135} | 2951 | Lₐ₁₀₇₀ | L_{b135} | 2952 | Lₐ₁₀₇₁ | L_{b135} |
| 2953 | Lₐ₁₀₇₂ | L_{b135} | 2954 | Lₐ₁₀₇₃ | L_{b135} | 2955 | Lₐ₁₀₇₄ | L_{b135} |
| 2956 | Lₐ₁₀₇₅ | L_{b135} | 2957 | Lₐ₁₀₇₆ | L_{b135} | 2958 | Lₐ₁₀₇₇ | L_{b135} |
| 2959 | Lₐ₁₀₇₈ | L_{b135} | 2960 | Lₐ₁₀₇₉ | L_{b52} | 2961 | Lₐ₁₀₈₀ | L_{b135} |
| 2962 | Lₐ₁₀₈₁ | L_{b135} | 2963 | Lₐ₁₀₈₂ | L_{b135} | 2964 | Lₐ₁₀₈₃ | L_{b135} |
| 2965 | Lₐ₁₀₈₄ | L_{b135} | 2966 | Lₐ₁₀₈₅ | L_{b135} | 2967 | Lₐ₁₀₈₆ | L_{b135} |
| 2968 | Lₐ₁₀₈₇ | L_{b135} | 2969 | Lₐ₁₀₈₈ | L_{b135} | 2970 | Lₐ₁₀₈₉ | L_{b135} |
| 2971 | Lₐ₁₀₉₀ | L_{b135} | 2972 | Lₐ₁₀₉₁ | L_{b135} | 2973 | Lₐ₁₀₉₂ | L_{b135} |
| 2974 | Lₐ₁₀₉₃ | L_{b135} | 2975 | Lₐ₁₀₉₄ | L_{b135} | 2976 | Lₐ₁₀₉₅ | L_{b135} |
| 2977 | Lₐ₁₀₉₆ | L_{b135} | 2978 | Lₐ₁₀₉₇ | L_{b52} | 2979 | Lₐ₁₀₉₈ | L_{b135} |
| 2980 | Lₐ₁₀₉₉ | L_{b135} | 2981 | Lₐ₁₁₀₀ | L_{b135} | 2982 | Lₐ₁₁₀₁ | L_{b135} |
| 2983 | Lₐ₁₁₀₂ | L_{b135} | 2984 | Lₐ₁₁₀₃ | L_{b135} | 2985 | Lₐ₁₁₀₄ | L_{b135} |
| 2986 | Lₐ₁₁₀₅ | L_{b135} | 2987 | Lₐ₁₁₀₆ | L_{b135} | 2988 | Lₐ₁₁₀₇ | L_{b135} |
| 2989 | Lₐ₁₁₀₈ | L_{b135} | 2990 | Lₐ₁₁₀₉ | L_{b135} | 2991 | Lₐ₁₁₁₀ | L_{b135} |
| 2992 | Lₐ₁₁₁₁ | L_{b135} | 2993 | Lₐ₁₁₁₂ | L_{b135} | 2994 | Lₐ₁₁₁₃ | L_{b135} |
| 2995 | Lₐ₁₁₁₄ | L_{b135} | 2996 | Lₐ₁₁₁₅ | L_{b52} | 2997 | Lₐ₁₁₁₆ | L_{b135} |
| 2998 | Lₐ₁₁₁₇ | L_{b135} | 2999 | Lₐ₁₁₁₈ | L_{b135} | 3000 | Lₐ₁₁₁₉ | L_{b135} |
| 3001 | Lₐ₁₁₂₀ | L_{b135} | 3002 | Lₐ₁₁₂₁ | L_{b135} | 3003 | Lₐ₁₁₂₂ | L_{b135} |
| 3004 | Lₐ₁₁₂₃ | L_{b135} | 3005 | Lₐ₁₁₂₄ | L_{b135} | 3006 | Lₐ₁₁₂₅ | L_{b135} |
| 3007 | Lₐ₁₁₂₆ | L_{b135} | 3008 | Lₐ₁₁₂₇ | L_{b135} | 3009 | Lₐ₁₁₂₈ | L_{b135} |
| 3010 | Lₐ₁₁₂₉ | L_{b135} | 3011 | Lₐ₁₁₃₀ | L_{b135} | 3012 | Lₐ₁₁₃₁ | L_{b135} |
| 3013 | Lₐ₁₁₃₂ | L_{b135} | 3014 | Lₐ₁₁₃₃ | L_{b52} | 3015 | Lₐ₁₁₃₄ | L_{b135} |
| 3016 | Lₐ₁₁₃₅ | L_{b135} | 3017 | Lₐ₁₁₃₆ | L_{b135} | 3018 | Lₐ₁₁₃₇ | L_{b135} |
| 3019 | Lₐ₁₁₃₈ | L_{b135} | 3020 | Lₐ₁₁₃₉ | L_{b135} | 3021 | Lₐ₁₁₄₀ | L_{b135} |
| 3022 | Lₐ₁₁₄₁ | L_{b135} | 3023 | Lₐ₁₁₄₂ | L_{b135} | 3024 | Lₐ₁₁₄₃ | L_{b135} |
| 3025 | Lₐ₁₁₄₄ | L_{b135} | 3026 | Lₐ₁₁₄₅ | L_{b135} | 3027 | Lₐ₁₁₄₆ | L_{b135} |
| 3028 | Lₐ₁₁₄₇ | L_{b135} | 3029 | Lₐ₁₁₄₈ | L_{b135} | 3030 | Lₐ₁₁₄₉ | L_{b135} |
| 3031 | Lₐ₁₁₅₀ | L_{b135} | 3032 | Lₐ₁₁₅₁ | L_{b52} | 3033 | Lₐ₁₁₅₂ | L_{b135} |
| 3034 | Lₐ₁₁₅₃ | L_{b135} | 3035 | Lₐ₁₁₅₄ | L_{b135} | 3036 | Lₐ₁₁₅₅ | L_{b135} |
| 3037 | Lₐ₁₁₅₆ | L_{b135} | 3038 | Lₐ₁₁₅₇ | L_{b135} | 3039 | Lₐ₁₁₅₈ | L_{b135} |
| 3040 | Lₐ₁₁₅₉ | L_{b135} | 3041 | Lₐ₁₁₆₀ | L_{b135} | 3042 | Lₐ₁₁₆₁ | L_{b135} |
| 3043 | Lₐ₁₁₆₂ | L_{b135} | 3044 | Lₐ₁₁₆₃ | L_{b135} | 3045 | Lₐ₁₁₆₄ | L_{b135} |
| 3046 | Lₐ₁₁₆₅ | L_{b135} | 3047 | Lₐ₁₁₆₆ | L_{b135} | 3048 | Lₐ₁₁₆₇ | L_{b135} |
| 3049 | Lₐ₁₁₆₈ | L_{b135} | 3050 | Lₐ₁₁₆₉ | L_{b52} | 3051 | Lₐ₁₁₇₀ | L_{b135} |
| 3052 | Lₐ₁₁₇₁ | L_{b135} | 3053 | Lₐ₁₁₇₂ | L_{b135} | 3054 | Lₐ₁₁₇₃ | L_{b135} |
| 3055 | Lₐ₁₁₇₄ | L_{b135} | 3056 | Lₐ₁₁₇₅ | L_{b135} | 3057 | Lₐ₁₁₇₆ | L_{b135} |
| 3058 | Lₐ₁₁₇₇ | L_{b135} | 3059 | Lₐ₁₁₇₈ | L_{b135} | 3060 | Lₐ₁₁₇₉ | L_{b135} |
| 3061 | Lₐ₁₁₈₀ | L_{b135} | 3062 | Lₐ₁₁₈₁ | L_{b135} | 3063 | Lₐ₁₁₈₂ | L_{b135} |
| 3064 | Lₐ₁₁₈₃ | L_{b135} | 3065 | Lₐ₁₁₈₄ | L_{b135} | 3066 | Lₐ₁₁₈₅ | L_{b135} |
| 3067 | Lₐ₁₁₈₆ | L_{b135} | 3068 | Lₐ₁₁₈₇ | L_{b52} | 3069 | Lₐ₁₁₈₈ | L_{b135} |
| 3070 | Lₐ₁₁₈₉ | L_{b135} | 3071 | Lₐ₁₁₉₀ | L_{b135} | 3072 | Lₐ₁₁₉₁ | L_{b135} |
| 3073 | Lₐ₁₁₉₂ | L_{b135} | 3074 | Lₐ₁₁₉₃ | L_{b135} | 3075 | Lₐ₁₁₉₄ | L_{b135} |
| 3076 | Lₐ₁₁₉₅ | L_{b135} | 3077 | Lₐ₁₁₉₆ | L_{b135} | 3078 | Lₐ₁₁₉₇ | L_{b135} |
| 3079 | Lₐ₁₁₉₈ | L_{b135} | 3080 | Lₐ₁₁₉₉ | L_{b135} | 3081 | Lₐ₁₂₀₀ | L_{b135} |
| 3082 | Lₐ₁₂₀₁ | L_{b135} | 3083 | Lₐ₁₂₀₂ | L_{b135} | 3084 | Lₐ₁₂₀₃ | L_{b135} |
| 3085 | Lₐ₁₂₀₄ | L_{b135} | 3086 | Lₐ₁₂₀₅ | L_{b52} | 3087 | Lₐ₁₂₀₆ | L_{b135} |
| 3088 | Lₐ₁₂₀₇ | L_{b135} | 3089 | Lₐ₁₂₀₈ | L_{b135} | 3090 | Lₐ₁₂₀₉ | L_{b135} |
| 3091 | Lₐ₁₂₁₀ | L_{b135} | 3092 | Lₐ₁₂₁₁ | L_{b135} | 3093 | Lₐ₁₂₁₂ | L_{b135} |
| 3094 | Lₐ₁₂₁₃ | L_{b135} | 3095 | Lₐ₁₂₁₄ | L_{b135} | 3096 | Lₐ₁₂₁₅ | L_{b135} |
| 3097 | Lₐ₁₂₁₆ | L_{b135} | 3098 | Lₐ₁₂₁₇ | L_{b135} | 3099 | Lₐ₁₂₁₈ | L_{b135} |
| 3100 | Lₐ₁₂₁₉ | L_{b135} | 3101 | Lₐ₁₂₂₀ | L_{b135} | 3102 | Lₐ₁₂₂₁ | L_{b135} |
| 3103 | Lₐ₁₂₂₂ | L_{b135} | 3104 | Lₐ₁₂₂₃ | L_{b52} | 3105 | Lₐ₁₂₂₄ | L_{b135} |
| 3106 | Lₐ₁₂₂₅ | L_{b135} | 3107 | Lₐ₁₂₂₆ | L_{b135} | 3108 | Lₐ₁₂₂₇ | L_{b135} |
| 3109 | Lₐ₁₂₂₈ | L_{b135} | 3110 | Lₐ₁₂₂₉ | L_{b135} | 3111 | Lₐ₁₂₃₀ | L_{b135} |
| 3112 | Lₐ₁₂₃₁ | L_{b135} | 3113 | Lₐ₁₂₃₂ | L_{b135} | 3114 | Lₐ₁₂₃₃ | L_{b135} |
| 3115 | Lₐ₁₂₃₄ | L_{b135} | 3116 | Lₐ₁₂₃₅ | L_{b135} | 3117 | Lₐ₁₂₃₆ | L_{b135} |
| 3118 | Lₐ₁₂₃₇ | L_{b135} | 3119 | Lₐ₁₂₃₈ | L_{b135} | 3120 | Lₐ₁₂₃₉ | L_{b135} |
| 3121 | Lₐ₁₂₄₀ | L_{b135} | 3122 | Lₐ₁₂₄₁ | L_{b52} | 3123 | Lₐ₁₂₄₂ | L_{b135} |
| 3124 | Lₐ₁₂₄₃ | L_{b135} | 3125 | Lₐ₁₂₄₄ | L_{b135} | 3126 | Lₐ₁₂₄₅ | L_{b135} |
| 3127 | Lₐ₁₂₄₆ | L_{b135} | 3128 | Lₐ₁₂₄₇ | L_{b135} | 3129 | Lₐ₁₂₄₈ | L_{b135} |
| 3130 | Lₐ₁₂₄₉ | L_{b135} | 3131 | Lₐ₁₂₅₀ | L_{b135} | 3132 | Lₐ₁₂₅₁ | L_{b135} |
| 3133 | Lₐ₁₂₅₂ | L_{b135} | 3134 | Lₐ₁₂₅₃ | L_{b135} | 3135 | Lₐ₁₂₅₄ | L_{b135} |
| 3136 | Lₐ₁₂₅₅ | L_{b135} | 3137 | Lₐ₁₂₅₆ | L_{b135} | 3138 | Lₐ₁₂₅₇ | L_{b135} |
| 3139 | Lₐ₁₂₅₈ | L_{b135} | 3140 | Lₐ₁₂₅₉ | L_{b52} | 3141 | Lₐ₁₂₆₀ | L_{b135} |
| 3142 | Lₐ₁₂₆₁ | L_{b135} | 3143 | Lₐ₁₂₆₂ | L_{b135} | 3144 | Lₐ₁₂₆₃ | L_{b135} |
| 3145 | Lₐ₁₂₆₄ | L_{b135} | 3146 | Lₐ₁₂₆₅ | L_{b135} | 3147 | Lₐ₁₂₆₆ | L_{b135} |
| 3148 | Lₐ₁₂₆₇ | L_{b135} | 3149 | Lₐ₁₂₆₈ | L_{b135} | 3150 | Lₐ₁₂₆₉ | L_{b135} |
| 3151 | Lₐ₁₂₇₀ | L_{b135} | 3152 | Lₐ₁₂₇₁ | L_{b135} | 3153 | Lₐ₁₂₇₂ | L_{b135} |
| 3154 | Lₐ₁₂₇₃ | L_{b135} | 3155 | Lₐ₁₂₇₄ | L_{b135} | 3156 | Lₐ₁₂₇₅ | L_{b135} |
| 3157 | Lₐ₁₂₇₆ | L_{b135} | 3158 | Lₐ₁₂₇₇ | L_{b52} | 3159 | Lₐ₁₂₇₈ | L_{b135} |
| 3160 | Lₐ₁₂₇₉ | L_{b135} | 3161 | Lₐ₁₂₈₀ | L_{b135} | 3162 | Lₐ₁₂₈₁ | L_{b135} |
| 3163 | Lₐ₁₂₈₂ | L_{b135} | 3164 | Lₐ₁₂₈₃ | L_{b135} | 3165 | Lₐ₁₂₈₄ | L_{b135} |
| 3166 | Lₐ₁₂₈₅ | L_{b135} | 3167 | Lₐ₁₂₈₆ | L_{b135} | 3168 | Lₐ₁₂₈₇ | L_{b135} |
| 3169 | Lₐ₁₂₈₈ | L_{b135} | 3170 | Lₐ₁₂₈₉ | L_{b135} | 3171 | Lₐ₁₂₉₀ | L_{b135} |
| 3172 | Lₐ₁₂₉₁ | L_{b135} | 3173 | Lₐ₁₂₉₂ | L_{b135} | 3174 | Lₐ₁₂₉₃ | L_{b135} |
| 3175 | Lₐ₁₂₉₄ | L_{b135} | 3176 | Lₐ₁₂₉₅ | L_{b52} | 3177 | Lₐ₁₂₉₆ | L_{b135} |
| 3178 | Lₐ₁₂₉₇ | L_{b135} | 3179 | Lₐ₁₂₉₈ | L_{b135} | 3180 | Lₐ₁₂₉₉ | L_{b135} |
| 3181 | Lₐ₁₃₀₀ | L_{b135} | 3182 | Lₐ₁₃₀₁ | L_{b135} | 3183 | Lₐ₁₃₀₂ | L_{b135} |
| 3184 | Lₐ₁₃₀₃ | L_{b135} | 3185 | Lₐ₁₃₀₄ | L_{b135} | 3186 | Lₐ₁₃₀₅ | L_{b135} |
| 3187 | Lₐ₁₃₀₆ | L_{b135} | 3188 | Lₐ₁₃₀₇ | L_{b135} | 3189 | Lₐ₁₃₀₈ | L_{b135} |
| 3190 | Lₐ₁₃₀₉ | L_{b135} | 3191 | Lₐ₁₃₁₀ | L_{b135} | 3192 | Lₐ₁₃₁₁ | L_{b135} |
| 3193 | Lₐ₁₃₁₂ | L_{b135} | 3194 | Lₐ₁₃₁₃ | L_{b52} | 3195 | Lₐ₁₃₁₄ | L_{b135} |
| 3196 | Lₐ₁₃₁₅ | L_{b135} | 3197 | Lₐ₁₃₁₆ | L_{b135} | 3198 | Lₐ₁₃₁₇ | L_{b135} |
| 3199 | Lₐ₁₃₁₈ | L_{b135} | 3200 | Lₐ₁₃₁₉ | L_{b135} | 3201 | Lₐ₁₃₂₀ | L_{b135} |
| 3202 | Lₐ₁₃₂₁ | L_{b135} | 3203 | Lₐ₁₃₂₂ | L_{b135} | 3204 | Lₐ₁₃₂₃ | L_{b135} |
| 3205 | Lₐ₁₃₂₄ | L_{b135} | 3206 | Lₐ₁₃₂₅ | L_{b135} | 3207 | Lₐ₁₃₂₆ | L_{b135} |
| 3208 | Lₐ₁₃₂₇ | L_{b135} | 3209 | Lₐ₁₃₂₈ | L_{b135} | 3210 | Lₐ₁₃₂₉ | L_{b135} |
| 3211 | Lₐ₁₃₃₀ | L_{b135} | 3212 | Lₐ₁₃₃₁ | L_{b52} | 3213 | Lₐ₁₃₃₂ | L_{b135} |
| 3214 | Lₐ₁₃₃₃ | L_{b135} | 3215 | Lₐ₁₃₃₄ | L_{b135} | 3216 | Lₐ₁₃₃₅ | L_{b135} |
| 3217 | Lₐ₁₃₃₆ | L_{b135} | 3218 | Lₐ₁₃₃₇ | L_{b135} | 3219 | Lₐ₁₃₃₈ | L_{b135} |
| 3220 | Lₐ₁₃₃₉ | L_{b135} | 3221 | Lₐ₁₃₄₀ | L_{b135} | 3222 | Lₐ₁₃₄₁ | L_{b135} |
| 3223 | Lₐ₁₃₄₂ | L_{b135} | 3224 | Lₐ₁₃₄₃ | L_{b135} | 3225 | Lₐ₁₃₄₄ | L_{b135} |
| 3226 | Lₐ₁₃₄₅ | L_{b135} | 3227 | Lₐ₁₃₄₆ | L_{b135} | 3228 | Lₐ₁₃₄₇ | L_{b135} |
| 3229 | Lₐ₁₃₄₈ | L_{b135} | 3230 | Lₐ₁₃₄₉ | L_{b52} | 3231 | Lₐ₁₃₅₀ | L_{b135} |
| 3232 | Lₐ₁₃₅₁ | L_{b135} | 3233 | Lₐ₁₃₅₂ | L_{b135} | 3234 | Lₐ₁₃₅₃ | L_{b135} |
| 3235 | Lₐ₁₃₅₄ | L_{b135} | 3236 | Lₐ₁₃₅₅ | L_{b135} | 3237 | Lₐ₁₃₅₆ | L_{b135} |
| 3238 | Lₐ₁₃₅₇ | L_{b135} | 3239 | Lₐ₁₃₅₈ | L_{b135} | 3240 | Lₐ₁₃₅₉ | L_{b135} |
| 3241 | Lₐ₁₃₆₀ | L_{b135} | 3242 | Lₐ₁₃₆₁ | L_{b135} | 3243 | Lₐ₁₃₆₂ | L_{b135} |
| 3244 | Lₐ₁₃₆₃ | L_{b135} | 3245 | Lₐ₁₃₆₄ | L_{b135} | 3246 | Lₐ₁₃₆₅ | L_{b135} |
| 3247 | Lₐ₁₃₆₆ | L_{b135} | 3248 | Lₐ₁₃₆₇ | L_{b52} | 3249 | Lₐ₁₃₆₈ | L_{b135} |
| 3250 | Lₐ₁₃₆₉ | L_{b135} | 3251 | Lₐ₁₃₇₀ | L_{b135} | 3252 | Lₐ₁₃₇₁ | L_{b135} |
| 3253 | Lₐ₁₃₇₂ | L_{b135} | 3254 | Lₐ₁₃₇₃ | L_{b135} | 3255 | Lₐ₁₃₇₄ | L_{b135} |
| 3256 | Lₐ₁₃₇₅ | L_{b135} | 3257 | Lₐ₁₃₇₆ | L_{b135} | 3258 | Lₐ₁₃₇₇ | L_{b135} |
| 3259 | Lₐ₁₃₇₈ | L_{b135} | 3260 | Lₐ₁₃₇₉ | L_{b135} | 3261 | Lₐ₁₃₈₀ | L_{b135} |
| 3262 | Lₐ₁₃₈₁ | L_{b135} | 3263 | Lₐ₁₃₈₂ | L_{b135} | 3264 | Lₐ₁₃₈₃ | L_{b135} |
| 3265 | Lₐ₁₃₈₄ | L_{b135} | 3266 | Lₐ₁₃₈₅ | L_{b52} | 3267 | Lₐ₁₃₈₆ | L_{b135} |
| 3268 | Lₐ₁₃₈₇ | L_{b135} | 3269 | Lₐ₁₃₈₈ | L_{b135} | 3270 | Lₐ₁₃₈₉ | L_{b135} |
| 3271 | Lₐ₁₃₉₀ | L_{b135} | 3272 | Lₐ₁₃₉₁ | L_{b135} | 3273 | Lₐ₁₃₉₂ | L_{b135} |
| 3274 | Lₐ₁₃₉₃ | L_{b135} | 3275 | Lₐ₁₃₉₄ | L_{b135} | 3276 | Lₐ₁₃₉₅ | L_{b135} |
| 3277 | Lₐ₁₃₉₆ | L_{b135} | 3278 | Lₐ₁₃₉₇ | L_{b135} | 3279 | Lₐ₁₃₉₈ | L_{b135} |
| 3280 | Lₐ₁₃₉₉ | L_{b135} | 3281 | Lₐ₁₄₀₀ | L_{b135} | 3282 | Lₐ₁₄₀₁ | L_{b135} |
| 3283 | Lₐ₁₄₀₂ | L_{b135} | 3284 | Lₐ₁₄₀₃ | L_{b52} | 3285 | Lₐ₁₄₀₄ | L_{b135} |
| 3286 | Lₐ₁₄₀₅ | L_{b135} | 3287 | Lₐ₁₄₀₆ | L_{b135} | 3288 | Lₐ₁₄₀₇ | L_{b135} |
| 3289 | Lₐ₁₄₀₈ | L_{b135} | 3290 | Lₐ₁₄₀₉ | L_{b135} | 3291 | Lₐ₁₄₁₀ | L_{b135} |
| 3292 | Lₐ₁₄₁₁ | L_{b135} | 3293 | Lₐ₁₄₁₂ | L_{b135} | 3294 | Lₐ₁₄₁₃ | L_{b135} |
| 3295 | Lₐ₁₄₁₄ | L_{b135} | 3296 | Lₐ₁₄₁₅ | L_{b135} | 3297 | Lₐ₁₄₁₆ | L_{b135} |
| 3298 | Lₐ₁₄₁₇ | L_{b135} | 3299 | Lₐ₁₄₁₈ | L_{b135} | 3300 | Lₐ₁₄₁₉ | L_{b135} |
| 3301 | Lₐ₁₄₂₀ | L_{b135} | 3302 | Lₐ₁₄₂₁ | L_{b52} | 3303 | Lₐ₁₄₂₂ | L_{b135} |
| 3304 | Lₐ₁₄₂₃ | L_{b135} | 3305 | Lₐ₁₄₂₄ | L_{b135} | 3306 | Lₐ₁₄₂₅ | L_{b135} |
| 3307 | Lₐ₁₄₂₆ | L_{b135} | 3308 | Lₐ₁₄₂₇ | L_{b135} | 3309 | Lₐ₁₄₂₈ | L_{b135} |
| 3310 | Lₐ₁₄₂₉ | L_{b135} | 3311 | Lₐ₁₄₃₀ | L_{b135} | 3312 | Lₐ₁₄₃₁ | L_{b135} |
| 3313 | Lₐ₁₄₃₂ | L_{b135} | 3314 | Lₐ₁₄₃₃ | L_{b135} | 3315 | Lₐ₁₄₃₄ | L_{b135} |
| 3316 | Lₐ₁₄₃₅ | L_{b135} | 3317 | Lₐ₁₄₃₆ | L_{b135} | 3318 | Lₐ₁₄₃₇ | L_{b135} |
| 3319 | Lₐ₁₄₃₈ | L_{b135} | 3320 | Lₐ₁₄₃₉ | L_{b52} | 3321 | Lₐ₁₄₄₀ | L_{b135} |
| 3322 | Lₐ₁₄₄₁ | L_{b135} | 3323 | Lₐ₁₄₄₂ | L_{b135} | 3324 | Lₐ₁₄₄₃ | L_{b135} |
| 3325 | Lₐ₁₄₄₄ | L_{b135} | 3326 | Lₐ₁₄₄₅ | L_{b135} | 3327 | Lₐ₁₄₄₆ | L_{b135} |
| 3328 | Lₐ₁₄₄₇ | L_{b135} | 3329 | Lₐ₁₄₄₈ | L_{b135} | 3330 | Lₐ₁₄₄₉ | L_{b135} |
| 3331 | Lₐ₁₄₅₀ | L_{b135} | 3332 | Lₐ₁₄₅₁ | L_{b135} | 3333 | Lₐ₁₄₅₂ | L_{b135} |
| 3334 | Lₐ₁₄₅₃ | L_{b135} | 3335 | Lₐ₁₄₅₄ | L_{b135} | 3336 | Lₐ₁₄₅₅ | L_{b135} |
| 3337 | Lₐ₁₄₅₆ | L_{b135} | 3338 | Lₐ₁₄₅₇ | L_{b52} | 3339 | Lₐ₁₄₅₈ | L_{b135} |
| 3340 | Lₐ₁₄₅₉ | L_{b135} | 3341 | Lₐ₁₄₆₀ | L_{b135} | 3342 | Lₐ₁₄₆₁ | L_{b135} |
| 3343 | Lₐ₁₄₆₂ | L_{b135} | 3344 | Lₐ₁₄₆₃ | L_{b135} | 3345 | Lₐ₁₄₆₄ | L_{b135} |
| 3346 | Lₐ₁₄₆₅ | L_{b135} | 3347 | Lₐ₁₄₆₆ | L_{b135} | 3348 | Lₐ₁₄₆₇ | L_{b135} |
| 3349 | Lₐ₁₄₆₈ | L_{b135} | 3350 | Lₐ₁₄₆₉ | L_{b135} | 3351 | Lₐ₁₄₇₀ | L_{b135} |
| 3352 | Lₐ₁₄₇₁ | L_{b135} | 3353 | Lₐ₁₄₇₂ | L_{b135} | 3354 | Lₐ₁₄₇₃ | L_{b135} |
| 3355 | Lₐ₁₄₇₄ | L_{b135} | 3356 | Lₐ₁₄₇₅ | L_{b52} | 3357 | Lₐ₁₄₇₆ | L_{b135} |
| 3358 | Lₐ₁₄₇₇ | L_{b135} | 3359 | Lₐ₁₄₇₈ | L_{b135} | 3360 | Lₐ₁₄₇₉ | L_{b135} |
| 3361 | Lₐ₁₄₈₀ | L_{b135} | 3362 | Lₐ₁₄₈₁ | L_{b135} | 3363 | Lₐ₁₄₈₂ | L_{b135} |
| 3364 | Lₐ₁₄₈₃ | L_{b135} | 3365 | Lₐ₁₄₈₄ | L_{b135} | 3366 | Lₐ₁₄₈₅ | L_{b135} |
| 3367 | Lₐ₁₄₈₆ | L_{b135} | 3368 | Lₐ₁₄₈₇ | L_{b135} | 3369 | Lₐ₁₄₈₈ | L_{b135} |
| 3370 | Lₐ₁₄₈₉ | L_{b135} | 3371 | Lₐ₁₄₉₀ | L_{b135} | 3372 | Lₐ₁₄₉₁ | L_{b135} |
| 3373 | Lₐ₁₄₉₂ | L_{b135} | 3374 | Lₐ₁₄₉₃ | L_{b52} | 3375 | Lₐ₁₄₉₄ | L_{b135} |
| 3376 | Lₐ₁₄₉₅ | L_{b135} | 3377 | Lₐ₁₄₉₆ | L_{b135} | 3378 | Lₐ₁₄₉₇ | L_{b135} |
| 3379 | Lₐ₁₄₉₈ | L_{b135} | 3380 | Lₐ₁₄₉₉ | L_{b135} | 3381 | Lₐ₁₅₀₀ | L_{b135} |
| 3382 | Lₐ₁₅₀₁ | L_{b135} | 3383 | Lₐ₁₅₀₂ | L_{b135} | 3384 | Lₐ₁₅₀₃ | L_{b135} |
| 3385 | Lₐ₁₅₀₄ | L_{b135} | 3386 | Lₐ₁₅₀₅ | L_{b135} | 3387 | Lₐ₁₅₀₆ | L_{b135} |
| 3388 | Lₐ₁₅₀₇ | L_{b135} | 3389 | Lₐ₁₅₀₈ | L_{b135} | 3390 | Lₐ₁₅₀₉ | L_{b135} |
| 3391 | Lₐ₁₅₁₀ | L_{b135} | 3392 | Lₐ₁₅₁₁ | L_{b52} | 3393 | Lₐ₁₅₁₂ | L_{b135} |
| 3394 | Lₐ₁₅₁₃ | L_{b135} | 3395 | Lₐ₁₅₁₄ | L_{b135} | 3396 | Lₐ₁₅₁₅ | L_{b135} |
| 3397 | Lₐ₁₅₁₆ | L_{b135} | 3398 | Lₐ₁₅₁₇ | L_{b135} | 3399 | Lₐ₁₅₁₈ | L_{b135} |
| 3400 | Lₐ₁₅₁₉ | L_{b135} | 3401 | Lₐ₁₅₂₀ | L_{b135} | 3402 | Lₐ₁₅₂₁ | L_{b135} |
| 3403 | Lₐ₁₅₂₂ | L_{b135} | 3404 | Lₐ₁₅₂₃ | L_{b135} | 3405 | Lₐ₁₅₂₄ | L_{b135} |
| 3406 | Lₐ₁₅₂₅ | L_{b135} | 3407 | Lₐ₁₅₂₆ | L_{b135} | 3408 | Lₐ₁₅₂₇ | L_{b135} |
| 3409 | Lₐ₁₅₂₈ | L_{b135} | 3410 | Lₐ₁₅₂₉ | L_{b52} | 3411 | Lₐ₁₅₃₀ | L_{b135} |
| 3412 | Lₐ₁₅₃₁ | L_{b135} | 3413 | Lₐ₁₅₃₂ | L_{b135} | 3414 | Lₐ₁₅₃₃ | L_{b135} |
| 3415 | Lₐ₁₅₃₄ | L_{b135} | 3416 | Lₐ₁₅₃₅ | L_{b135} | 3417 | Lₐ₁₅₃₆ | L_{b135} |
| 3418 | Lₐ₁₅₃₇ | L_{b135} | 3419 | Lₐ₁₅₃₈ | L_{b135} | 3420 | Lₐ₁₅₃₉ | L_{b135} |
| 3421 | Lₐ₁₅₄₀ | L_{b135} | 3422 | Lₐ₁₅₄₁ | L_{b135} | 3423 | Lₐ₁₅₄₂ | L_{b135} |
| 3424 | Lₐ₁₅₄₃ | L_{b135} | 3425 | Lₐ₁₅₄₄ | L_{b135} | 3426 | Lₐ₁₅₄₅ | L_{b135} |
| 3427 | Lₐ₁₅₄₆ | L_{b135} | 3428 | Lₐ₁₅₄₇ | L_{b52} | 3429 | Lₐ₁₅₄₈ | L_{b135} |
| 3430 | Lₐ₁₅₄₉ | L_{b135} | 3431 | Lₐ₁₅₅₀ | L_{b135} | 3432 | Lₐ₁₅₅₁ | L_{b135} |
| 3433 | Lₐ₁₅₅₂ | L_{b135} | 3434 | Lₐ₁₅₅₃ | L_{b135} | 3435 | Lₐ₁₅₅₄ | L_{b135} |
| 3436 | Lₐ₁₅₅₅ | L_{b135} | 3437 | Lₐ₁₅₅₆ | L_{b135} | 3438 | Lₐ₁₅₅₇ | L_{b135} |
| 3439 | Lₐ₁₅₅₈ | L_{b135} | 3440 | Lₐ₁₅₅₉ | L_{b135} | 3441 | Lₐ₁₅₆₀ | L_{b135} |
| 3442 | Lₐ₁₅₆₁ | L_{b135} | 3443 | Lₐ₁₅₆₂ | L_{b135} | 3444 | Lₐ₁₅₆₃ | L_{b135} |
| 3445 | Lₐ₁₅₆₄ | L_{b135} | 3446 | Lₐ₁₅₆₅ | L_{b52} | 3447 | Lₐ₁₅₆₆ | L_{b135} |
| 3448 | Lₐ₁₅₆₇ | L_{b135} | 3449 | Lₐ₁₅₆₈ | L_{b135} | 3450 | Lₐ₁₅₆₉ | L_{b135} |
| 3451 | Lₐ₁₅₇₀ | L_{b135} | 3452 | Lₐ₁₅₇₁ | L_{b135} | 3453 | Lₐ₁₅₇₂ | L_{b135} |
| 3454 | Lₐ₁₅₇₃ | L_{b135} | 3455 | Lₐ₁₅₇₄ | L_{b135} | 3456 | Lₐ₁₅₇₅ | L_{b135} |
| 3457 | Lₐ₁₅₇₆ | L_{b135} | 3458 | Lₐ₁₅₇₇ | L_{b135} | 3459 | Lₐ₁₅₇₈ | L_{b135} |
| 3460 | Lₐ₁₅₇₉ | L_{b135} | 3461 | Lₐ₁₅₈₀ | L_{b135} | 3462 | Lₐ₁₅₈₁ | L_{b135} |
| 3463 | Lₐ₁₅₈₂ | L_{b135} | 3464 | Lₐ₁₅₈₃ | L_{b52} | 3465 | Lₐ₁₅₈₄ | L_{b135} |
| 3466 | Lₐ₁₅₈₅ | L_{b135} | 3467 | Lₐ₁₅₈₆ | L_{b135} | 3468 | Lₐ₁₅₈₇ | L_{b135} |
| 3469 | Lₐ₁₅₈₈ | L_{b135} | 3470 | Lₐ₁₅₈₉ | L_{b135} | 3471 | Lₐ₁₅₉₀ | L_{b135} |
| 3472 | Lₐ₁₅₉₁ | L_{b135} | 3473 | Lₐ₁₅₉₂ | L_{b135} | 3474 | Lₐ₁₅₉₃ | L_{b135} |
| 3475 | Lₐ₁₅₉₄ | L_{b135} | 3476 | Lₐ₁₅₉₅ | L_{b135} | 3477 | Lₐ₁₅₉₆ | L_{b135} |
| 3478 | Lₐ₁₅₉₇ | L_{b135} | 3479 | Lₐ₁₅₉₈ | L_{b135} | 3480 | Lₐ₁₅₉₉ | L_{b135} |
| 3481 | Lₐ₁₆₀₀ | L_{b135} | 3482 | Lₐ₁₆₀₁ | L_{b52} | 3483 | Lₐ₁₆₀₂ | L_{b135} |
| 3484 | Lₐ₁₆₀₃ | L_{b135} | 3485 | Lₐ₁₆₀₄ | L_{b135} | 3486 | Lₐ₁₆₀₅ | L_{b135} |
| 3487 | Lₐ₁₆₀₆ | L_{b135} | 3488 | Lₐ₁₆₀₇ | L_{b135} | 3489 | Lₐ₁₆₀₈ | L_{b135} |
| 3490 | Lₐ₁₆₀₉ | L_{b135} | 3491 | Lₐ₁₆₁₀ | L_{b135} | 3492 | Lₐ₁₆₁₁ | L_{b135} |
| 3493 | Lₐ₁₆₁₂ | L_{b135} | 3494 | Lₐ₁₆₁₃ | L_{b135} | 3495 | Lₐ₁₆₁₄ | L_{b135} |
| 3496 | Lₐ₁₆₁₅ | L_{b135} | 3497 | Lₐ₁₆₁₆ | L_{b135} | 3498 | Lₐ₁₆₁₇ | L_{b135} |
| 3499 | Lₐ₁₆₁₈ | L_{b135} | 3500 | Lₐ₁₆₁₉ | L_{b52} | 3501 | Lₐ₁₆₂₀ | L_{b135} |
| 3502 | Lₐ₁₆₂₁ | L_{b135} | 3503 | Lₐ₁₆₂₂ | L_{b135} | 3504 | Lₐ₁₆₂₃ | L_{b135} |
| 3505 | Lₐ₁₆₂₄ | L_{b135} | 3506 | Lₐ₁₆₂₅ | L_{b135} | 3507 | Lₐ₁₆₂₆ | L_{b135} |
| 3508 | Lₐ₁₆₂₇ | L_{b135} | 3509 | Lₐ₁₆₂₈ | L_{b135} | 3510 | Lₐ₁₆₂₉ | L_{b135} |
| 3511 | Lₐ₁₆₃₀ | L_{b135} | 3512 | Lₐ₁₆₃₁ | L_{b135} | 3513 | Lₐ₁₆₃₂ | L_{b135} |
| 3514 | Lₐ₁₆₃₃ | L_{b135} | 3515 | Lₐ₁₆₃₄ | L_{b135} | 3516 | Lₐ₁₆₃₅ | L_{b135} |
| 3517 | Lₐ₁₆₃₆ | L_{b135} | 3518 | Lₐ₁₆₃₇ | L_{b52} | 3519 | Lₐ₁₆₃₈ | L_{b135} |
| 3520 | Lₐ₁₆₃₉ | L_{b135} | 3521 | Lₐ₁₆₄₀ | L_{b135} | 3522 | Lₐ₁₆₄₁ | L_{b135} |
| 3523 | Lₐ₁₆₄₂ | L_{b135} | 3524 | Lₐ₁₆₄₃ | L_{b135} | 3525 | Lₐ₁₆₄₄ | L_{b135} |
| 3526 | Lₐ₁₆₄₅ | L_{b135} | 3527 | Lₐ₁₆₄₆ | L_{b135} | 3528 | Lₐ₁₆₄₇ | L_{b135} |
| 3529 | Lₐ₁₆₄₈ | L_{b135} | 3530 | Lₐ₁₆₄₉ | L_{b135} | 3531 | Lₐ₁₆₅₀ | L_{b135} |
| 3532 | Lₐ₁₆₅₁ | L_{b135} | 3533 | Lₐ₁₆₅₂ | L_{b135} | 3534 | Lₐ₁₆₅₃ | L_{b135} |
| 3535 | Lₐ₁₆₅₄ | L_{b135} | 3536 | Lₐ₁₆₅₅ | L_{b52} | 3537 | Lₐ₁₆₅₆ | L_{b135} |
| 3538 | Lₐ₁₆₅₇ | L_{b135} | 3539 | Lₐ₁₆₅₈ | L_{b135} | 3540 | Lₐ₁₆₅₉ | L_{b135} |
| 3541 | Lₐ₁₆₆₀ | L_{b135} | 3542 | Lₐ₁₆₆₁ | L_{b135} | 3543 | Lₐ₁₆₆₂ | L_{b135} |
| 3544 | Lₐ₁₆₆₃ | L_{b135} | 3545 | Lₐ₁₆₆₄ | L_{b135} | 3546 | Lₐ₁₆₆₅ | L_{b135} |
| 3547 | Lₐ₁₆₆₆ | L_{b135} | 3548 | Lₐ₁₆₆₇ | L_{b135} | 3549 | Lₐ₁₆₆₈ | L_{b135} |
| 3550 | Lₐ₁₆₆₉ | L_{b135} | 3551 | Lₐ₁₆₇₀ | L_{b135} | 3552 | Lₐ₁₆₇₁ | L_{b135} |
| 3553 | Lₐ₁₆₇₂ | L_{b135} | 3554 | Lₐ₁₆₇₃ | L_{b52} | 3555 | Lₐ₁₆₇₄ | L_{b135} |
| 3556 | Lₐ₁₆₇₅ | L_{b135} | 3557 | Lₐ₁₆₇₆ | L_{b135} | 3558 | Lₐ₁₆₇₇ | L_{b135} |
| 3559 | Lₐ₁₆₇₈ | L_{b135} | 3560 | Lₐ₁₆₇₉ | L_{b135} | 3561 | Lₐ₁₆₈₀ | L_{b135} |
| 3562 | Lₐ₁₆₈₁ | L_{b135} | 3563 | Lₐ₁₆₈₂ | L_{b135} | 3564 | Lₐ₁₆₈₃ | L_{b135} |
| 3565 | Lₐ₁₆₈₄ | L_{b135} | 3566 | Lₐ₁₆₈₅ | L_{b135} | 3567 | Lₐ₁₆₈₆ | L_{b135} |
| 3568 | Lₐ₁₆₈₇ | L_{b135} | 3569 | Lₐ₁₆₈₈ | L_{b135} | 3570 | Lₐ₁₆₈₉ | L_{b135} |
| 3571 | Lₐ₁₆₉₀ | L_{b135} | 3572 | Lₐ₁₆₉₁ | L_{b52} | 3573 | Lₐ₁₆₉₂ | L_{b135} |
| 3574 | Lₐ₁₆₉₃ | L_{b135} | 3575 | Lₐ₁₆₉₄ | L_{b135} | 3576 | Lₐ₁₆₉₅ | L_{b135} |
| 3577 | Lₐ₁₆₉₆ | L_{b135} | 3578 | Lₐ₁₆₉₇ | L_{b135} | 3579 | Lₐ₁₆₉₈ | L_{b135} |
| 3580 | Lₐ₁₆₉₉ | L_{b135} | 3581 | Lₐ₁₇₀₀ | L_{b135} | 3582 | Lₐ₁₇₀₁ | L_{b135} |
| 3583 | Lₐ₁₇₀₂ | L_{b135} | 3584 | Lₐ₁₇₀₃ | L_{b135} | 3585 | Lₐ₁₇₀₄ | L_{b135} |
| 3586 | Lₐ₁₇₀₅ | L_{b135} | 3587 | Lₐ₁₇₀₆ | L_{b135} | 3588 | Lₐ₁₇₀₇ | L_{b135} |
| 3589 | Lₐ₁₇₀₈ | L_{b135} | 3590 | Lₐ₁₇₀₉ | L_{b52} | 3591 | Lₐ₁₇₁₀ | L_{b135} |
| 3592 | Lₐ₁₇₁₁ | L_{b135} | 3593 | Lₐ₁₇₁₂ | L_{b135} | 3594 | Lₐ₁₇₁₃ | L_{b135} |
| 3595 | Lₐ₁₇₁₄ | L_{b135} | 3596 | Lₐ₁₇₁₅ | L_{b135} | 3597 | Lₐ₁₇₁₆ | L_{b135} |
| 3598 | Lₐ₁₇₁₇ | L_{b135} | 3599 | Lₐ₁₇₁₈ | L_{b135} | 3600 | Lₐ₁₇₁₉ | L_{b135} |
| 3601 | Lₐ₁₇₂₀ | L_{b135} | 3602 | Lₐ₁₇₂₁ | L_{b135} | 3603 | Lₐ₁₇₂₂ | L_{b135} |
| 3604 | Lₐ₁₇₂₃ | L_{b135} | 3605 | Lₐ₁₇₂₄ | L_{b135} | 3606 | Lₐ₁₇₂₅ | L_{b135} |
| 3607 | Lₐ₁₇₂₆ | L_{b135} | 3608 | Lₐ₁₇₂₇ | L_{b52} | 3609 | Lₐ₁₇₂₈ | L_{b135} |
| 3610 | Lₐ₁₇₂₉ | L_{b135} | 3611 | Lₐ₁₇₃₀ | L_{b135} | 3612 | Lₐ₁₇₃₁ | L_{b135} |
| 3613 | Lₐ₁₇₃₂ | L_{b135} | 3614 | Lₐ₁₇₃₃ | L_{b135} | 3615 | Lₐ₁₇₃₄ | L_{b135} |
| 3616 | Lₐ₁₇₃₅ | L_{b135} | 3617 | Lₐ₁₇₃₆ | L_{b135} | 3618 | Lₐ₁₇₃₇ | L_{b135} |
| 3619 | Lₐ₁₇₃₈ | L_{b135} | 3620 | Lₐ₁₇₃₉ | L_{b135} | 3621 | Lₐ₁₇₄₀ | L_{b135} |
| 3622 | Lₐ₁₇₄₁ | L_{b135} | 3623 | Lₐ₁₇₄₂ | L_{b135} | 3624 | Lₐ₁₇₄₃ | L_{b135} |
| 3625 | Lₐ₁₇₄₄ | L_{b135} | 3626 | Lₐ₁₇₄₅ | L_{b52} | 3627 | Lₐ₁₇₄₆ | L_{b135} |
| 3628 | Lₐ₁₇₄₇ | L_{b135} | 3629 | Lₐ₁₇₄₈ | L_{b135} | 3630 | Lₐ₁₇₄₉ | L_{b135} |
| 3631 | Lₐ₁₇₅₀ | L_{b135} | 3632 | Lₐ₁₇₅₁ | L_{b135} | 3633 | Lₐ₁₇₅₂ | L_{b135} |
| 3634 | Lₐ₁₇₅₃ | L_{b135} | 3635 | Lₐ₁₇₅₄ | L_{b135} | 3636 | Lₐ₁₇₅₅ | L_{b135} |
| 3637 | Lₐ₁₇₅₆ | L_{b135} | 3638 | Lₐ₁₇₅₇ | L_{b135} | 3639 | Lₐ₁₇₅₈ | L_{b135} |
| 3640 | Lₐ₁₇₅₉ | L_{b135} | 3641 | Lₐ₁₇₆₀ | L_{b135} | 3642 | Lₐ₁₇₆₁ | L_{b135} |
| 3643 | Lₐ₁₇₆₂ | L_{b135} | 3644 | Lₐ₁₇₆₃ | L_{b52} | 3645 | Lₐ₁₇₆₄ | L_{b135} |
| 3646 | Lₐ₁₇₆₅ | L_{b135} | 3647 | Lₐ₁₇₆₆ | L_{b135} | 3648 | Lₐ₁₇₆₇ | L_{b135} |
| 3649 | Lₐ₁₇₆₈ | L_{b135} | 3650 | Lₐ₁₇₆₉ | L_{b135} | 3651 | Lₐ₁₇₇₀ | L_{b135} |
| 3652 | Lₐ₁₇₇₁ | L_{b135} | 3653 | Lₐ₁₇₇₂ | L_{b135} | 3654 | Lₐ₁₇₇₃ | L_{b135} |
| 3655 | Lₐ₁₇₇₄ | L_{b135} | 3656 | Lₐ₁₇₇₅ | L_{b135} | 3657 | Lₐ₁₇₇₆ | L_{b135} |
| 3658 | Lₐ₁₇₇₇ | L_{b135} | 3659 | Lₐ₁₇₇₈ | L_{b135} | 3660 | Lₐ₁₇₇₉ | L_{b135} |
| 3661 | Lₐ₁₇₈₀ | L_{b135} | 3662 | Lₐ₁₇₈₁ | L_{b52} | 3663 | Lₐ₁₇₈₂ | L_{b135} |
| 3664 | Lₐ₁₇₈₃ | L_{b135} | 3665 | Lₐ₁₇₈₄ | L_{b135} | 3666 | Lₐ₁₇₈₅ | L_{b135} |
| 3667 | Lₐ₁₇₈₆ | L_{b135} | 3668 | Lₐ₁₇₈₇ | L_{b135} | 3669 | Lₐ₁₇₈₈ | L_{b135} |
| 3670 | Lₐ₁₇₈₉ | L_{b135} | 3671 | Lₐ₁₇₉₀ | L_{b135} | 3672 | Lₐ₁₇₉₁ | L_{b135} |
| 3673 | Lₐ₁₇₉₂ | L_{b135} | 3674 | Lₐ₁₇₉₃ | L_{b135} | 3675 | Lₐ₁₇₉₄ | L_{b135} |
| 3676 | Lₐ₁₇₉₅ | L_{b135} | 3677 | Lₐ₁₇₉₆ | L_{b135} | 3678 | Lₐ₁₇₉₇ | L_{b135} |
| 3679 | Lₐ₁₇₉₈ | L_{b135} | 3680 | Lₐ₁₇₉₉ | L_{b52} | 3681 | Lₐ₁₈₀₀ | L_{b135} |
| 3682 | Lₐ₁₈₀₁ | L_{b135} | 3683 | Lₐ₁₈₀₂ | L_{b135} | 3684 | Lₐ₁₈₀₃ | L_{b135} |
| 3685 | Lₐ₁₈₀₄ | L_{b135} | 3686 | Lₐ₁₈₀₅ | L_{b135} | 3687 | Lₐ₁₈₀₆ | L_{b135} |
| 3688 | Lₐ₁₈₀₇ | L_{b135} | 3689 | Lₐ₁₈₀₈ | L_{b135} | 3690 | Lₐ₁₈₀₉ | L_{b135} |
| 3691 | Lₐ₁₈₁₀ | L_{b135} | 3692 | Lₐ₁₈₁₁ | L_{b135} | 3693 | Lₐ₁₈₁₂ | L_{b135} |
| 3694 | Lₐ₁₈₁₃ | L_{b135} | 3695 | Lₐ₁₈₁₄ | L_{b135} | 3696 | Lₐ₁₈₁₅ | L_{b135} |
| 3697 | Lₐ₁₈₁₆ | L_{b135} | 3698 | Lₐ₁₈₁₇ | L_{b52} | 3699 | Lₐ₁₈₁₈ | L_{b135} |
| 3700 | Lₐ₁₈₁₉ | L_{b135} | 3701 | Lₐ₁₈₂₀ | L_{b135} | 3702 | Lₐ₁₈₂₁ | L_{b135} |
| 3703 | Lₐ₁₈₂₂ | L_{b135} | 3704 | Lₐ₁₈₂₃ | L_{b135} | 3705 | Lₐ₁₈₂₄ | L_{b135} |
| 3706 | Lₐ₁₈₂₅ | L_{b135} | 3707 | Lₐ₁₈₂₆ | L_{b135} | 3708 | Lₐ₁₈₂₇ | L_{b135} |
| 3709 | Lₐ₁₈₂₈ | L_{b135} | 3710 | Lₐ₁₈₂₉ | L_{b135} | 3711 | Lₐ₁₈₃₀ | L_{b135} |
| 3712 | Lₐ₁₈₃₁ | L_{b135} | 3713 | Lₐ₁₈₃₂ | L_{b135} | 3714 | Lₐ₁₈₃₃ | L_{b135} |
| 3715 | Lₐ₁₈₃₄ | L_{b135} | 3716 | Lₐ₁₈₃₅ | L_{b52} | 3717 | Lₐ₁₈₃₆ | L_{b135} |
| 3718 | Lₐ₁₈₃₇ | L_{b135} | 3719 | Lₐ₁₈₃₈ | L_{b135} | 3720 | Lₐ₁₈₃₉ | L_{b135} |
| 3721 | Lₐ₁₈₄₀ | L_{b135} | 3722 | Lₐ₁₈₄₁ | L_{b135} | 3723 | Lₐ₁₈₄₂ | L_{b135} |
| 3724 | Lₐ₁₈₄₃ | L_{b135} | 3725 | Lₐ₁₈₄₄ | L_{b135} | 3726 | Lₐ₁₈₄₅ | L_{b135} |
| 3727 | Lₐ₁₈₄₆ | L_{b135} | 3728 | Lₐ₁₈₄₇ | L_{b135} | 3729 | Lₐ₁₈₄₈ | L_{b135} |
| 3730 | Lₐ₁₈₄₉ | L_{b135} | 3731 | Lₐ₁₈₅₀ | L_{b135} | 3732 | Lₐ₁₈₅₁ | L_{b135} |
| 3733 | Lₐ₁₈₅₂ | L_{b135} | 3734 | Lₐ₁₈₅₃ | L_{b52} | 3735 | Lₐ₁₈₅₄ | L_{b135} |
| 3736 | Lₐ₁₈₅₅ | L_{b135} | 3737 | Lₐ₁₈₅₆ | L_{b135} | 3738 | Lₐ₁₈₅₇ | L_{b135} |
| 3739 | Lₐ₁₈₅₈ | L_{b135} | 3740 | Lₐ₁₈₅₉ | L_{b135} | 3741 | Lₐ₁₈₆₀ | L_{b135} |
| 3742 | Lₐ₁₈₆₁ | L_{b135} | 3743 | Lₐ₁₈₆₂ | L_{b135} | 3744 | Lₐ₁₈₆₃ | L_{b135} |
| 3745 | Lₐ₁₈₆₄ | L_{b135} | 3746 | Lₐ₁₈₆₅ | L_{b135} | 3747 | Lₐ₁₈₆₆ | L_{b135} |
| 3748 | Lₐ₁₈₆₇ | L_{b135} | 3749 | Lₐ₁₈₆₈ | L_{b135} | 3750 | Lₐ₁₈₆₉ | L_{b135} |
| 3751 | Lₐ₁₈₇₀ | L_{b135} | 3752 | Lₐ₁₈₇₁ | L_{b52} | 3753 | Lₐ₁₈₇₂ | L_{b135} |
| 3754 | Lₐ₁₈₇₃ | L_{b135} | 3755 | Lₐ₁₈₇₄ | L_{b135} | 3756 | Lₐ₁₈₇₅ | L_{b135} |
| 3757 | Lₐ₁₈₇₆ | L_{b135} | 3758 | Lₐ₁₈₇₇ | L_{b135} | 3759 | Lₐ₁₈₇₈ | L_{b135} |
| 3760 | Lₐ₁₈₇₉ | L_{b135} | 3761 | Lₐ₁₈₈₀ | L_{b135} | 3762 | Lₐ₁₈₈₁ | L_{b135} |
| 3763 | Lₐ₁₆ | L_{b1} | 3764 | Lₐ₁₆ | L_{b2} | 3765 | Lₐ₁₆ | L_{b3} |
| 3766 | Lₐ₁₆ | L_{b4} | 3767 | Lₐ₁₆ | L_{b5} | 3768 | Lₐ₁₆ | L_{b6} |
| 3769 | Lₐ₁₆ | L_{b7} | 3770 | Lₐ₁₆ | L_{b8} | 3771 | Lₐ₁₆ | L_{b9} |
| 3772 | Lₐ₁₆ | L_{b10} | 3773 | Lₐ₁₆ | L_{b11} | 3774 | Lₐ₁₆ | L_{b12} |
| 3775 | Lₐ₁₆ | L_{b13} | 3776 | Lₐ₁₆ | L_{b14} | 3777 | Lₐ₁₆ | L_{b15} |
| 3778 | Lₐ₁₆ | L_{b16} | 3779 | Lₐ₁₆ | L_{b17} | 3780 | Lₐ₁₆ | L_{b18} |
| 3781 | Lₐ₁₆ | L_{b19} | 3782 | Lₐ₁₆ | L_{b20} | 3783 | Lₐ₁₆ | L_{b21} |
| 3784 | Lₐ₁₆ | L_{b22} | 3785 | Lₐ₁₆ | L_{b23} | 3786 | Lₐ₁₆ | L_{b24} |
| 3787 | Lₐ₁₆ | L_{b25} | 3788 | Lₐ₁₆ | L_{b26} | 3789 | Lₐ₁₆ | L_{b27} |
| 3790 | Lₐ₁₆ | L_{b28} | 3791 | Lₐ₁₆ | L_{b29} | 3792 | Lₐ₁₆ | L_{b30} |
| 3793 | Lₐ₁₆ | L_{b31} | 3794 | Lₐ₁₆ | L_{b32} | 3795 | Lₐ₁₆ | L_{b33} |
| 3796 | Lₐ₁₆ | L_{b34} | 3797 | Lₐ₁₆ | L_{b35} | 3798 | Lₐ₁₆ | L_{b36} |
| 3799 | Lₐ₁₆ | L_{b37} | 3800 | Lₐ₁₆ | L_{b38} | 3801 | Lₐ₁₆ | L_{b39} |
| 3802 | Lₐ₁₆ | L_{b40} | 3803 | Lₐ₁₆ | L_{b41} | 3804 | Lₐ₁₆ | L_{b42} |
| 3805 | Lₐ₁₆ | L_{b43} | 3806 | Lₐ₁₆ | L_{b44} | 3807 | Lₐ₁₆ | L_{b45} |
| 3808 | Lₐ₁₆ | L_{b46} | 3809 | Lₐ₁₆ | L_{b47} | 3810 | Lₐ₁₆ | L_{b48} |
| 3811 | Lₐ₁₆ | L_{b49} | 3812 | Lₐ₁₆ | L_{b50} | 3813 | Lₐ₁₆ | L_{b51} |
| 3814 | Lₐ₁₆ | L_{b155} | 3815 | Lₐ₁₆ | L_{b53} | 3816 | Lₐ₁₆ | L_{b54} |
| 3817 | Lₐ₁₆ | L_{b55} | 3818 | Lₐ₁₆ | L_{b56} | 3819 | Lₐ₁₆ | L_{b57} |
| 3820 | Lₐ₁₆ | L_{b58} | 3821 | Lₐ₁₆ | L_{b59} | 3822 | Lₐ₁₆ | L_{b60} |
| 3823 | Lₐ₁₆ | L_{b61} | 3824 | Lₐ₁₆ | L_{b62} | 3825 | Lₐ₁₆ | L_{b63} |
| 3826 | Lₐ₁₆ | L_{b64} | 3827 | Lₐ₁₆ | L_{b65} | 3828 | Lₐ₁₆ | L_{b66} |
| 3829 | Lₐ₁₆ | L_{b67} | 3830 | Lₐ₁₆ | L_{b68} | 3831 | Lₐ₁₆ | L_{b69} |
| 3832 | Lₐ₁₆ | L_{b70} | 3833 | Lₐ₁₆ | L_{b71} | 3834 | Lₐ₁₆ | L_{b72} |
| 3835 | Lₐ₁₆ | L_{b73} | 3836 | Lₐ₁₆ | L_{b74} | 3837 | Lₐ₁₆ | L_{b75} |
| 3838 | Lₐ₁₆ | L_{b76} | 3839 | Lₐ₁₆ | L_{b77} | 3840 | Lₐ₁₆ | L_{b78} |
| 3841 | Lₐ₁₆ | L_{b79} | 3842 | Lₐ₁₆ | L_{b80} | 3843 | Lₐ₁₆ | L_{b81} |
| 3844 | Lₐ₁₆ | L_{b82} | 3845 | Lₐ₁₆ | L_{b83} | 3846 | Lₐ₁₆ | L_{b84} |
| 3847 | Lₐ₁₆ | L_{b85} | 3848 | Lₐ₁₆ | L_{b86} | 3849 | Lₐ₁₆ | L_{b87} |
| 3850 | Lₐ₁₆ | L_{b88} | 3851 | Lₐ₁₆ | L_{b89} | 3852 | Lₐ₁₆ | L_{b90} |
| 3853 | Lₐ₁₆ | L_{b91} | 3854 | Lₐ₁₆ | L_{b92} | 3855 | Lₐ₁₆ | L_{b93} |
| 3856 | Lₐ₁₆ | L_{b94} | 3857 | Lₐ₁₆ | L_{b95} | 3858 | Lₐ₁₆ | L_{b96} |
| 3859 | Lₐ₁₆ | L_{b97} | 3860 | Lₐ₁₆ | L_{b98} | 3861 | Lₐ₁₆ | L_{b99} |
| 3862 | Lₐ₁₆ | L_{b100} | 3863 | Lₐ₁₆ | L_{b101} | 3864 | Lₐ₁₆ | L_{b102} |
| 3865 | Lₐ₁₆ | L_{b103} | 3866 | Lₐ₁₆ | L_{b104} | 3867 | Lₐ₁₆ | L_{b105} |
| 3868 | Lₐ₁₆ | L_{b106} | 3869 | Lₐ₁₆ | L_{b107} | 3870 | Lₐ₁₆ | L_{b108} |
| 3871 | Lₐ₁₆ | L_{b109} | 3872 | Lₐ₁₆ | L_{b110} | 3873 | Lₐ₁₆ | L_{b111} |
| 3874 | Lₐ₁₆ | L_{b112} | 3875 | Lₐ₁₆ | L_{b113} | 3876 | Lₐ₁₆ | L_{b114} |
| 3877 | Lₐ₁₆ | L_{b115} | 3878 | Lₐ₁₆ | L_{b116} | 3879 | Lₐ₁₆ | L_{b117} |
| 3880 | Lₐ₁₆ | L_{b118} | 3881 | Lₐ₁₆ | L_{b119} | 3882 | Lₐ₁₆ | L_{b120} |
| 3883 | Lₐ₁₆ | L_{b121} | 3884 | Lₐ₁₆ | L_{b122} | 3885 | Lₐ₁₆ | L_{b123} |
| 3886 | Lₐ₁₆ | L_{b124} | 3887 | Lₐ₁₆ | L_{b125} | 3888 | Lₐ₁₆ | L_{b126} |
| 3889 | Lₐ₁₆ | L_{b127} | 3890 | Lₐ₁₆ | L_{b128} | 3891 | Lₐ₁₆ | L_{b129} |
| 3892 | Lₐ₁₆ | L_{b130} | 3893 | Lₐ₁₆ | L_{b131} | 3894 | Lₐ₁₆ | L_{b132} |
| 3895 | Lₐ₁₆ | L_{b133} | 3896 | Lₐ₁₆ | L_{b134} | 3897 | Lₐ₁₆ | L_{b157} |
| 3898 | Lₐ₁₆ | L_{b136} | 3899 | Lₐ₁₆ | L_{b137} | 3900 | Lₐ₁₆ | L_{b138} |
| 3901 | Lₐ₁₆ | L_{b139} | 3902 | Lₐ₁₆ | L_{b140} | 3903 | Lₐ₁₆ | L_{b141} |
| 3904 | Lₐ₁₆ | L_{b142} | 3905 | Lₐ₁₆ | L_{b143} | 3906 | Lₐ₁₆ | L_{b144} |
| 3907 | Lₐ₁₆ | L_{b145} | 3908 | Lₐ₁₆ | L_{b146} | 3909 | Lₐ₁₆ | L_{b147} |
| 3910 | Lₐ₁₆ | L_{b148} | 3911 | Lₐ₁₆ | L_{b149} | 3912 | Lₐ₁₆ | L_{b150} |
| 3913 | Lₐ₁₆ | L_{b151} | 3914 | Lₐ₁₆ | L_{b152} | 3915 | Lₐ₁₆ | L_{b153} |
| 3916 | Lₐ₁₆ | L_{b158} | 3917 | Lₐ₁₆ | L_{b159} | 3918 | Lₐ₁₆ | L_{b160} |
| 3919 | Lₐ₂₈₄ | L_{b1} | 3920 | Lₐ₂₈₄ | L_{b2} | 3921 | Lₐ₂₈₄ | L_{b3} |
| 3922 | Lₐ₂₈₄ | L_{b4} | 3923 | Lₐ₂₈₄ | L_{b5} | 3924 | Lₐ₂₈₄ | L_{b6} |
| 3925 | Lₐ₂₈₄ | L_{b7} | 3926 | Lₐ₂₈₄ | L_{b8} | 3927 | Lₐ₂₈₄ | L_{b9} |
| 3928 | Lₐ₂₈₄ | L_{b10} | 3929 | Lₐ₂₈₄ | L_{b11} | 3930 | Lₐ₂₈₄ | L_{b12} |
| 3931 | Lₐ₂₈₄ | L_{b13} | 3932 | Lₐ₂₈₄ | L_{b14} | 3933 | Lₐ₂₈₄ | L_{b15} |
| 3934 | Lₐ₂₈₄ | L_{b16} | 3935 | Lₐ₂₈₄ | L_{b17} | 3936 | Lₐ₂₈₄ | L_{b18} |
| 3937 | Lₐ₂₈₄ | L_{b19} | 3938 | Lₐ₂₈₄ | L_{b20} | 3939 | Lₐ₂₈₄ | L_{b21} |
| 3940 | Lₐ₂₈₄ | L_{b22} | 3941 | Lₐ₂₈₄ | L_{b23} | 3942 | Lₐ₂₈₄ | L_{b24} |
| 3943 | Lₐ₂₈₄ | L_{b25} | 3944 | Lₐ₂₈₄ | L_{b26} | 3945 | Lₐ₂₈₄ | L_{b27} |
| 3946 | Lₐ₂₈₄ | L_{b28} | 3947 | Lₐ₂₈₄ | L_{b29} | 3948 | Lₐ₂₈₄ | L_{b30} |
| 3949 | Lₐ₂₈₄ | L_{b31} | 3950 | Lₐ₂₈₄ | L_{b32} | 3951 | Lₐ₂₈₄ | L_{b33} |
| 3952 | Lₐ₂₈₄ | L_{b34} | 3953 | Lₐ₂₈₄ | L_{b35} | 3954 | Lₐ₂₈₄ | L_{b36} |
| 3955 | Lₐ₂₈₄ | L_{b37} | 3956 | Lₐ₂₈₄ | L_{b38} | 3957 | Lₐ₂₈₄ | L_{b39} |
| 3958 | Lₐ₂₈₄ | L_{b40} | 3959 | Lₐ₂₈₄ | L_{b41} | 3960 | Lₐ₂₈₄ | L_{b42} |
| 3961 | Lₐ₂₈₄ | L_{b43} | 3962 | Lₐ₂₈₄ | L_{b44} | 3963 | Lₐ₂₈₄ | L_{b45} |
| 3964 | Lₐ₂₈₄ | L_{b46} | 3965 | Lₐ₂₈₄ | L_{b47} | 3966 | Lₐ₂₈₄ | L_{b48} |
| 3967 | Lₐ₂₈₄ | L_{b49} | 3968 | Lₐ₂₈₄ | L_{b50} | 3969 | Lₐ₂₈₄ | L_{b51} |
| 3970 | Lₐ₂₈₄ | L_{b155} | 3971 | Lₐ₂₈₄ | L_{b53} | 3972 | Lₐ₂₈₄ | L_{b54} |
| 3973 | Lₐ₂₈₄ | L_{b55} | 3974 | Lₐ₂₈₄ | L_{b56} | 3975 | Lₐ₂₈₄ | L_{b57} |
| 3976 | Lₐ₂₈₄ | L_{b58} | 3977 | Lₐ₂₈₄ | L_{b59} | 3978 | Lₐ₂₈₄ | L_{b60} |
| 3979 | Lₐ₂₈₄ | L_{b61} | 3980 | Lₐ₂₈₄ | L_{b62} | 3981 | Lₐ₂₈₄ | L_{b63} |
| 3982 | Lₐ₂₈₄ | L_{b64} | 3983 | Lₐ₂₈₄ | L_{b65} | 3984 | Lₐ₂₈₄ | L_{b66} |
| 3985 | Lₐ₂₈₄ | L_{b67} | 3986 | Lₐ₂₈₄ | L_{b68} | 3987 | Lₐ₂₈₄ | L_{b69} |
| 3988 | Lₐ₂₈₄ | L_{b70} | 3989 | Lₐ₂₈₄ | L_{b71} | 3990 | Lₐ₂₈₄ | L_{b72} |
| 3991 | Lₐ₂₈₄ | L_{b73} | 3992 | Lₐ₂₈₄ | L_{b74} | 3993 | Lₐ₂₈₄ | L_{b75} |
| 3994 | Lₐ₂₈₄ | L_{b76} | 3995 | Lₐ₂₈₄ | L_{b77} | 3996 | Lₐ₂₈₄ | L_{b78} |
| 3997 | Lₐ₂₈₄ | L_{b79} | 3998 | Lₐ₂₈₄ | L_{b80} | 3999 | Lₐ₂₈₄ | L_{b81} |
| 4000 | Lₐ₂₈₄ | L_{b82} | 4001 | Lₐ₂₈₄ | L_{b83} | 4002 | Lₐ₂₈₄ | L_{b84} |
| 4003 | Lₐ₂₈₄ | L_{b85} | 4004 | Lₐ₂₈₄ | L_{b86} | 4005 | Lₐ₂₈₄ | L_{b87} |
| 4006 | Lₐ₂₈₄ | L_{b88} | 4007 | Lₐ₂₈₄ | L_{b89} | 4008 | Lₐ₂₈₄ | L_{b90} |
| 4009 | Lₐ₂₈₄ | L_{b91} | 4010 | Lₐ₂₈₄ | L_{b92} | 4011 | Lₐ₂₈₄ | L_{b93} |
| 4012 | Lₐ₂₈₄ | L_{b94} | 4013 | Lₐ₂₈₄ | L_{b95} | 4014 | Lₐ₂₈₄ | L_{b96} |
| 4015 | Lₐ₂₈₄ | L_{b97} | 4016 | Lₐ₂₈₄ | L_{b98} | 4017 | Lₐ₂₈₄ | L_{b99} |
| 4018 | Lₐ₂₈₄ | L_{b100} | 4019 | Lₐ₂₈₄ | L_{b101} | 4020 | Lₐ₂₈₄ | L_{b102} |
| 4021 | Lₐ₂₈₄ | L_{b103} | 4022 | Lₐ₂₈₄ | L_{b104} | 4023 | Lₐ₂₈₄ | L_{b105} |
| 4024 | Lₐ₂₈₄ | L_{b106} | 4025 | Lₐ₂₈₄ | L_{b107} | 4026 | Lₐ₂₈₄ | L_{b108} |
| 4027 | Lₐ₂₈₄ | L_{b109} | 4028 | Lₐ₂₈₄ | L_{b110} | 4029 | Lₐ₂₈₄ | L_{b111} |
| 4030 | Lₐ₂₈₄ | L_{b112} | 4031 | Lₐ₂₈₄ | L_{b113} | 4032 | Lₐ₂₈₄ | L_{b114} |
| 4033 | Lₐ₂₈₄ | L_{b115} | 4034 | Lₐ₂₈₄ | L_{b116} | 4035 | Lₐ₂₈₄ | L_{b117} |
| 4036 | Lₐ₂₈₄ | L_{b118} | 4037 | Lₐ₂₈₄ | L_{b119} | 4038 | Lₐ₂₈₄ | L_{b120} |
| 4039 | Lₐ₂₈₄ | L_{b121} | 4040 | Lₐ₂₈₄ | L_{b122} | 4041 | Lₐ₂₈₄ | L_{b123} |
| 4042 | Lₐ₂₈₄ | L_{b124} | 4043 | Lₐ₂₈₄ | L_{b125} | 4044 | Lₐ₂₈₄ | L_{b126} |
| 4045 | Lₐ₂₈₄ | L_{b127} | 4046 | Lₐ₂₈₄ | L_{b128} | 4047 | Lₐ₂₈₄ | L_{b129} |
| 4048 | Lₐ₂₈₄ | L_{b130} | 4049 | Lₐ₂₈₄ | L_{b131} | 4050 | Lₐ₂₈₄ | L_{b132} |
| 4051 | Lₐ₂₈₄ | L_{b133} | 4052 | Lₐ₂₈₄ | L_{b134} | 4053 | Lₐ₂₈₄ | L_{b157} |
| 4054 | Lₐ₂₈₄ | L_{b136} | 4055 | Lₐ₂₈₄ | L_{b137} | 4056 | Lₐ₂₈₄ | L_{b138} |
| 4057 | Lₐ₂₈₄ | L_{b139} | 4058 | Lₐ₂₈₄ | L_{b140} | 4059 | Lₐ₂₈₄ | L_{b141} |
| 4060 | Lₐ₂₈₄ | L_{b142} | 4061 | Lₐ₂₈₄ | L_{b143} | 4062 | Lₐ₂₈₄ | L_{b144} |
| 4063 | Lₐ₂₈₄ | L_{b145} | 4064 | Lₐ₂₈₄ | L_{b146} | 4065 | Lₐ₂₈₄ | L_{b147} |
| 4066 | Lₐ₂₈₄ | L_{b148} | 4067 | Lₐ₂₈₄ | L_{b149} | 4068 | Lₐ₂₈₄ | L_{b150} |
| 4069 | Lₐ₂₈₄ | L_{b151} | 4070 | Lₐ₂₈₄ | L_{b152} | 4071 | Lₐ₂₈₄ | L_{b153} |
| 4072 | Lₐ₂₈₄ | L_{b158} | 4073 | Lₐ₂₈₄ | L_{b159} | 4074 | Lₐ₂₈₄ | L_{b160} |

wherein optionally, hydrogens in Metal Complex 1 to Metal Complex 4074 can be partially or fully deuterated.

24. An electroluminescent device, comprising an anode, a cathode, and an organic layer disposed between the anode and the cathode, wherein the organic layer comprises the metal complex according to claim 1.

25. The electroluminescent device according to claim 24, wherein the organic layer is an emissive layer, and the metal complex is an emissive material.

26. The electroluminescent device according to claim 25, wherein the emissive layer emits green light or white light.

27. The electroluminescent device according to claim 24, wherein the organic layer further comprises a host material.

28. The electroluminescent device according to claim 25, wherein the emissive layer comprises a first host compound;
preferably, the emissive layer further comprises a second host compound;
more preferably, the first host compound and/or the second host compound comprise at least one chemical group selected from the group consisting of benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

29. The electroluminescent device according to claim 28, wherein in the emissive layer, the metal complex is doped in the first host compound and the second host compound, and a weight of the metal complex accounts for 1% to 30% of a total weight of the emissive layer;
preferably, the weight of the metal complex accounts for 3% to 13% of the total weight of the emissive layer.

30. A compound combination, comprising the metal complex according to claim 1.

31. A display assembly, comprising the metal complex according to claim 1.
